(19) United States
(12) Patent Application Publication
(10) Pub. No.: US 2012/0135348 A1
(43) Pub. Date: May 31, 2012

(54) ACTINIC-RAY-SENSITIVE OR RADIATION-SENSITIVE RESIN COMPOSITION, ACTINIC-RAY-SENSITIVE OR RADIATION-SENSITIVE FILM, AND PATTERN FORMING METHOD

(75) Inventors: Akinori SHIBUYA, Shizuoka (JP); Yoko TOKUGAWA, Shizuoka (JP); Tomoki MATSUDA, Shizuoka (JP)

(73) Assignee: FUJIFILM CORPORATION, Tokyo (JP)

(21) Appl. No.: 13/305,494

(22) Filed: Nov. 28, 2011

(30) Foreign Application Priority Data
Nov. 29, 2010 (JP) 2010-265713
Nov. 10, 2011 (JP) 2011-246335

(51) Int. Cl. G03F 7/20; G03F 7/027

(52) U.S. Cl. 430/281.1; 430/325

(57) ABSTRACT

Provided are an actinic-ray-sensitive or radiation-sensitive resin composition which has improved development defect and is capable of forming a good pattern shape, an actinic-ray-sensitive or radiation-sensitive film formed using the composition, and a pattern forming method using the composition.

The actinic-ray-sensitive or radiation-sensitive resin composition includes (A) a compound which generates an acid represented by the following general formula (I) or (I′) upon irradiation with an actinic-ray or a radiation, and (B) a resin which decomposes by an action of an acid to increase a solubility of the resin in an alkaline developer [each of the symbols in the general formulae (I) and (I′) indicates the meaning described in Claims].

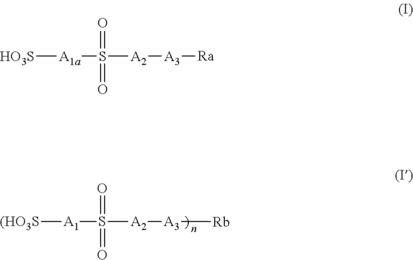

### BACKGROUND OF THE INVENTION

1. Field of the Invention

The present invention relates to an actinic-ray-sensitive or radiation-sensitive resin composition which reacts upon irradiation with an actinic-ray or a radiation to have changed properties, a film formed using the composition, and a pattern forming method using the composition. More specifically, the present invention relates to an actinic-ray-sensitive or radiation-sensitive resin composition for use in a production process of a semiconductor such as IC, a production process of a circuit board for a liquid crystal, a thermal head, or the like, and other photofabrication processes, or in lithographic printing plates or acid-curable compositions, to a film formed using the composition, and to a pattern forming method using the composition.

Furthermore, the “actinic-ray” or the “radiation” as used herein means, for example, brightline spectra from a mercury lamp, far ultraviolet radioactive rays typically such as an excimer laser, extreme ultraviolet (EUV) radiation, X-rays, or an electron beam (EB). Further, the “light” as used in the present invention means an actinic-ray or a radiation.

In addition, the “exposure” as used herein includes not only light irradiation with a mercury lamp, far ultraviolet radioactive rays, X-rays, EUV radiation, or the like but also the lithography by means of particle beams such as an electron beam, an ion beam, and the like, unless otherwise specified.

2. Description of the Related Art

A chemical amplification type resist composition is a material for pattern formation, which generates an acid in the exposed areas upon irradiation with radiation such as far ultraviolet rays and the like, and undergoes a reaction catalyzed by this acid, and as a result, comes to have a variance in the solubility in a developing solution between the areas irradiated with the actinic radioactive ray and the unirradiated areas, thereby forming a pattern on the substrate.

In the case where a KrF excimer laser is employed as an exposure light source, a resin having a poly(hydroxystyrene) skeleton which shows reduced absorption mainly in a 248-nm region, is used as the main component in the chemical amplification resist composition. Consequently, the composition has high sensitivity and high resolution, and forms a good pattern, and it is hence a better system, as compared with a conventional naphthoquinonediazide/novolak resin system.

On the other hand, in the case where a light source having a shorter wavelength, for example, an ArF excimer laser (193 nm), is employed as an exposure light source, compounds having aromatic groups used in the chemical amplification type system intrinsically show considerable absorption in a 193-nm region, and thus, this composition cannot be said to be a favorable system. Consequently, resist compositions for an ArF excimer laser containing a resin with an alicyclic hydrocarbon structure have been developed.

In addition, various compounds have been developed in photoacid generators which are main constituents of the chemical amplification type resist composition (see, for example, JP2003-140332A, Specification of EP1270553A, WO02/042845A, JP2002-131897A, JP2002-214774A, Specification of US2004/0087690A, and JP2005-266766A).

However, at present, it is extremely difficult and thus cannot still be said to be sufficient to find an appropriate combination of resins, photoacid generators, basic compounds, additives, solvents, or the like, which are used in terms of comprehensive performances as a resist. For example, there has been a demand for development of a resist composition that has reduced development defect and is capable of forming a good pattern shape.

### SUMMARY OF THE INVENTION

The present invention has been made by taking into consideration the above-described prior art, and an object of the invention is to provide an actinic-ray-sensitive or radiation-sensitive resin composition which has improved development defect and is capable of forming a good pattern shape, an actinic-ray-sensitive or radiation-sensitive film formed using the composition, and a pattern forming method using the composition.

The present inventors have conducted extensive studies to solve the above-described problems, and led to the completion of the present invention. An actinic-ray-sensitive or radiation-sensitive resin composition of the present invention is characterized in that it includes (A) a compound which generates an acid represented by the following general formula (I) or (I′) upon irradiation with an actinic-ray or a radiation, and (B) a resin which decomposes by an action of an acid to increase a solubility of the resin in an alkaline developer.

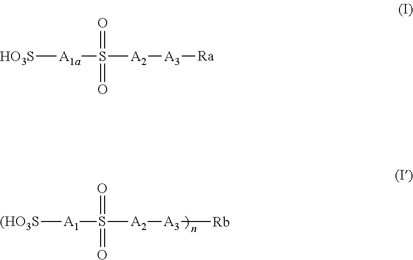

In the general formulae (I) and (I′),

each of A₁ₐ and A₁ independently represents a methylene group or ethylene group which may be substituted with a fluorine atom or a fluoroalkyl group. In case of an ethylene group, the ethylene group is containable an oxygen atom in the ethylene chain,

A₂ represents a single bond, an oxygen atom, or —N(Rx)-, and when a plurality of A₂'s are present, each of A₂ independently represents a single bond, an oxygen atom, or —N(Rx)-,

Rx represents a hydrogen atom, an aryl group, an alkyl group, or a cycloalkyl group, and the alkyl group is containable an oxygen atom, a sulfur atom, or a nitrogen atom in the alkyl chain,

A₃ represents a single bond or —C(═O)—, and when a plurality of A₃'s are present, each of A₃ independently represents a single bond or —C(═O)—,

Ra represents a hydrogen atom or an organic group,

n represents 2 or 3, and

Rb represents an n-valent linking group.

When A₂ is —N(Rx)-, Ra and Rx, or Rb and Rx may be bonded to each other to form a ring.

In the present invention, it is a preferable embodiment that the compound (A) is an onium salt of the sulfonic acid represented by the general formula (I) or (I′), that the compound (A) is a sulfonium salt of the sulfonic acid represented by the general formula (I) or (I′), that in the general formulae (I) and (I′), A₂ is —N(Rx)-, and Ra and Rx, or Rb and Rx are bonded to each other to form a ring, that the composition includes (C) a hydrophobic resin, and that in the general formula (I), the organic group represented by Ra has a cyclic structure.

Further, it is also a preferable embodiment that the cationic moiety of the compound (A) is a sulfonium salt having a structure represented by the following general formula (ZI-3) or (ZI-4).

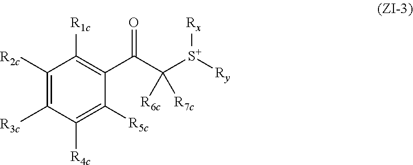

In the general formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,

each of R_{6c} and R_{7c} independently represents a hydrogen atom, an alkyl group, a cycloalkyl group, a halogen atom, a cyano group, or an aryl group,

each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group, and

at least any two or more of R_{1c} to R_{5c}, R_{5c} and R_{6c}, R_{6c} and R_{7c}, R_{5c} and Rₓ, and Rₓ and R_{y} may be bonded to each other to form a ring structure, and wherein the ring structure is containable of an oxygen atom, a sulfur atom, a ketone group, an ester bond, or an amide bond.

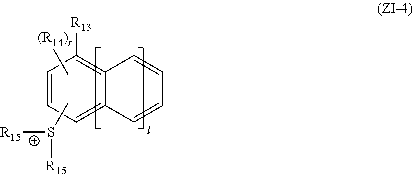

In the general formula (ZI-4),

R₁₃ represents a group containing a hydrogen atom, a fluorine atom, a hydroxyl group, an alkyl group, a cycloalkyl group, an alkoxy group, an alkoxycarbonyl group, or a cycloalkyl group. The groups containing an alkyl group, a cycloalkyl group, an alkoxy group, an alkoxycarbonyl group, and a cycloalkyl group may have a substituent.

R₁₄ represents a group containing a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group, and when a plurality of R₁₄'s are present, each of R₁₄'s independently represents a group containing a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. The groups containing an alkyl group, a cycloalkyl group, an alkoxy group, an alkoxycarbonyl group, an alkylcarbonyl group, an alkylsulfonyl group, a cycloalkylsulfonyl group, and a cycloalkyl group may have a substituent.

Each R₁₅ independently represents an alkyl group, a cycloalkyl group, or a naphthyl group. Two R₁₅'s may be bonded to each other to form a ring. The groups may have a substituent.

l represents an integer of 0 to 2.

r represents an integer of 0 to 8.

Furthermore, in the present invention, it is a preferable embodiment that the resin (B) includes a repeating unit having a lactone structure.

An actinic-ray-sensitive or radiation-sensitive film is characterized in that it is formed using any one of the composition as described above encompassed by the present invention.

In addition, a pattern forming method is characterized in that it includes:

forming a film using any one of the composition as described above,

exposing the film, and

developing the exposed film.

In the present invention, it is a preferable embodiment that the exposure is carried out through a liquid for liquid immersion.

Using the present invention, it is possible to provide an actinic-ray-sensitive or radiation-sensitive resin composition which has improved development defect and is capable of forming a good pattern shape, an actinic-ray-sensitive or radiation-sensitive film including the composition, and a pattern forming method using the composition. The actinic-ray-sensitive or radiation-sensitive resin composition of the present invention can be suitably used in, for example, an ArF dry exposure process and an ArF liquid immersion exposure process.

### DESCRIPTION OF THE PREFERRED EMBODIMENTS

Preferable embodiments of the present invention are described in detail below.

Incidentally, a group or atomic group as denoted herein without specifying whether substituted or unsubstituted includes both a group having no substituent and a group having a substituent. For example, the “alkyl group” includes, when whether substituted or unsubstituted is unspecified, not only an alkyl group having no substituent (unsubstituted alkyl group) but also an alkyl group having a substituent (substituted alkyl group).

[1] Compound Which Generates Acid Represented by General Formula (I) or (I′) upon Irradiation with Actinic-Ray or Radiation

The actinic-ray-sensitive or radiation-sensitive resin composition of the present invention includes a compound which generates a sulfonic acid represented by the following general formula (I) or (I′) upon irradiation with an actinic-ray or a radiation (which is also referred to as a “compound (A)” or a “photoacid generator (A)”). The photosensitive composition including the compound (A) has inhibited development defect and an excellent pattern shape. Although the reason is not clear, since the compound (A) has 1 or 2 of carbon atom(s) between the sulfonic acid group and the sulfonyl group and has appropriate hydrophobicity, the affinity for an alkaline developer increases, thus, development defect does not easily occur. Furthermore the affinity of the compound (A) for the resin (B) that is an essential component in the present invention, that is, a resin which decomposes by an action of an acid to increase a solubility of the resin in an alkaline developer, increases, and thus, the distribution of the compound (A) in the film thickness direction becomes homogenous. In this regard, it is presumed that the shape of the pattern becomes a rectangle. The compound which generates a sulfonic acid represented by the general formula (I) or (I′) of the present invention will be described in detail.

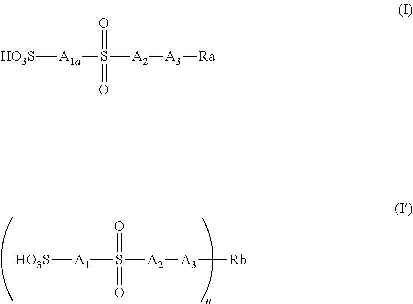

In the general formulae (I) and (I′),

each of A₁ₐ and A₁ independently represents a methylene group or ethylene group which may be substituted with a fluorine atom or a fluoroalkyl group. If it is an ethylene group, it may contain an oxygen atom in the ethylene chain,

when a plurality of A₂'s are present, each of them independently represents a single bond, an oxygen atom, or —N(Rx)-,

Rx represents a hydrogen atom, an aryl group, an alkyl group, or a cycloalkyl group, and the alkyl group may contain an oxygen atom, a sulfur atom, or a nitrogen atom in the alkyl chain,

when a plurality of A₃'s are present, each of them independently represents a single bond or —C(═O)—,

Ra represents a hydrogen atom or an organic group,

n represents 2 or 3, and

Rb represents an n-valent linking group.

When A₂ is —N(Rx)-, Ra and Rx, or Rb and Rx may be bonded to each other to form a ring.

A₁ₐ and A₁ are each a methylene group or ethylene group which may be substituted with at least one fluorine atom or fluoroalkyl group. The fluoroalkyl group is preferably a trifluoromethyl group. A₁ₐ and A₁ are each preferably the methylene group or ethylene group substituted with at least one fluorine atom, and more preferably a difluoromethylene group or a tetrafluoroethylene group.

In the —N(Rx)- as A₂, the aryl group in the Rx group may have a substituent, and is preferably an aryl group having 6 to 14 carbon atoms. Examples thereof include a phenyl group, a naphthyl group, and the like.

The alkyl group as Rx may have a substituent, and preferably a linear and branched alkyl group having 1 to 20 carbon atoms. The alkyl chain may have an oxygen atom, a sulfur atom, or a nitrogen atom. Specific examples thereof include linear alkyl groups such as a methyl group, an ethyl group, an n-propyl group, an n-butyl group, an n-pentyl group, an n-hexyl group, an n-octyl group, an n-dodecyl group, an n-tetradecyl group, an n-octadecyl group, and the like, and branched alkyl groups such as an isopropyl group, an isobutyl group, a t-butyl group, a neopentyl group, a 2-ethylhexyl group, and the like.

Further, examples of the alkyl group having a substituent particularly include a linear or branched alkyl group substituted with a cycloalkyl group (for example, an adamantylmethyl group, an adamantylethyl group, a cyclohexylethyl group, a camphor-residue, and the like).

The cycloalkyl group as Rx may have a substituent, and is preferably a cycloalkyl group having 3 to 20 carbon atoms. The ring may have an oxygen atom. Specific examples thereof include a cyclopropyl group, a cyclopentyl group, a cyclohexyl group, a norbornyl group, an adamantyl group, and the like.

Ra represents a hydrogen atom or a monovalent organic group.

The monovalent organic group as Ra preferably has 1 to 20 carbon atoms, and examples thereof include an alkyl group, a cycloalkyl group, an aryl group, an aralkyl group, an alkenyl group, and the like.

Specific examples of the alkyl group, the cycloalkyl group, or the aryl group as Ra include the same as those mentioned as Rx.

The aralkyl group as Ra is preferably an aralkyl group having 7 to 20 carbon atoms, and examples thereof include a benzyl group, a phenethyl group, a naphthylmethyl group, and a naphthylethyl group.

Specific examples of the alkenyl group as Ra include a group having a double bond at an arbitrary position of the alkyl group mentioned as Rx.

The n-valent linking group as Rb preferably has 1 to 20 carbon atoms and may contain an oxygen atom or a nitrogen atom. In the case of n=2 in the general formula (I′), examples of the divalent linking group as Rb include an alkylene group (preferably having 1 to 20 carbon atoms), an arylene group (preferably having 6 to 10 carbon atoms), an aralkylene group (preferably having 7 to 13 carbon atoms), an alkenylene group (preferably having 2 to 12 carbon atoms), a group resulting from removing a hydrogen atom from an N atom of piperazine, and a group represented by —N(Rz)-. Rz represent the same group as Rx above. These may have a substituent.

Examples of the trivalent linking group as Rb in the case of n=3 include a trivalent group resulting from an arbitrary hydrogen atom from the divalent linking group.

Examples of the substituent that each group may have include a halogen atom, a hydroxyl group, a nitro group, a cyano group, a carboxy group, a carbonyl group, a cycloalkyl group (preferably having 3 to 20 carbon atoms), an aryl group (preferably having 6 to 14 carbon atoms), an alkoxy group (preferably having 1 to 20 carbon atoms), an acyl group (preferably having 2 to 20 carbon atoms), an acyloxy group (preferably having 2 to 20 carbon atoms), an alkoxycarbonyl group (preferably having 2 to 20 carbon atoms), an aminoacyl group (preferably having 2 to 20 carbon atoms), and the like. Examples of the substituent of a cyclic structure in the aryl group, the cycloalkyl group, or the like include an alkyl group (preferably having 1 to 20 carbon atoms) and examples of the substituent of an aminoacyl group include one or two alkyl groups (preferably having 1 to 20 carbon atoms).

The sulfonic acid of each of the general formulae (I) and (I′) is preferably a sulfonic acid represented by any of the following general formulae (IA) to (ID).

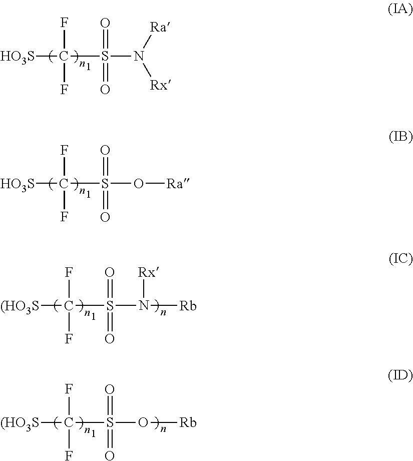

In the general formulae (IA) to (ID),

Ra′ has the same meaning as Ra in the general formula (I),

Rb and n have the same meaning as Rb and n in the general formula (I′),

Ra″ represents an alkyl group, an aryl group, an aralkyl group, or an alkenyl group,

Rx′ has the same meaning as Rx in the general formulae (I) and (I′), and

n₁ represents an integer of 1 or 2.

In the general formula (IA), Ra′ and Rx′ are preferably bonded to each other to form a ring, which results in improvement of stability and storage stability of a composition formed using the compound. The ring formed preferably has 4 to 20 carbon atoms, may be monocyclic or polycyclic, and may contain an oxygen atom, a sulfur atom, or a nitrogen atom in the ring.

Examples of the monocyclic structure include a 4-membered ring, a 5-membered ring, a 6-membered ring, a 7-membered ring, a 8-membered ring, and the like, each containing a nitrogen atom. Examples of the polycyclic structure are those including combinations of two, three, or more of the monocyclic structures. These may further contain an oxygen atom, or a sulfur atom, in addition to the nitrogen in the ring. The monocyclic and polycyclic structures may have a substituent, preferably such as, a halogen atom, a hydroxyl group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms), and the like. With respect to the cyclic structure such as an aryl group, a cycloalkyl group, and the like, an alkyl group (preferably having 1 to 15 carbon atoms) as a substituent is more preferred. With respect to the aminoacyl group, one or two alkyl groups (preferably having 1 to 15 carbon atoms) as substituents are preferred.

Examples of the alkyl group, the aryl group, the aralkyl group, or the alkenyl group as Ra″ include the same as those mentioned as the alkyl group, the aryl group, the aralkyl group, or the alkenyl group as Ra.

n₁ is preferably 1.

Specific preferable examples of the sulfonic acid represented by the general formula (I) or (I′) include those shown below, but the present invention is not limited thereto.

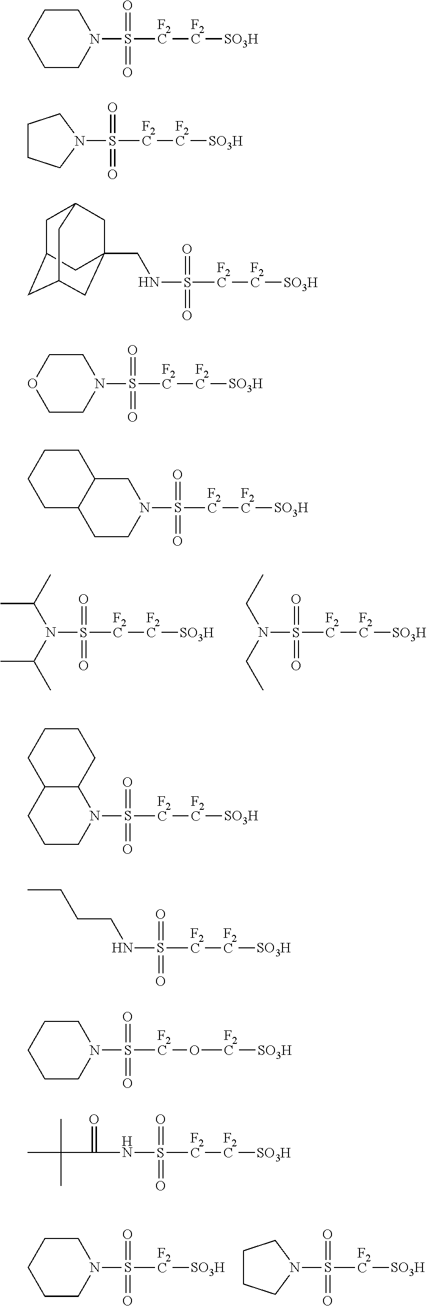

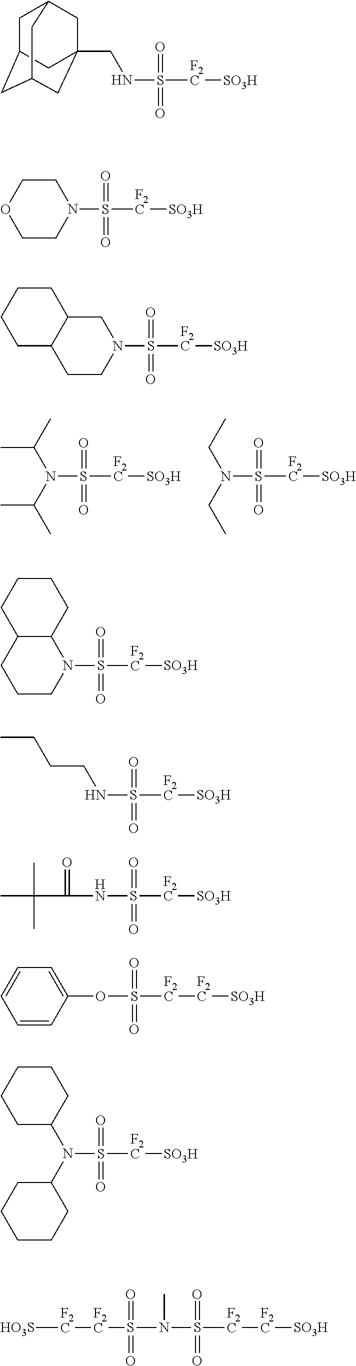

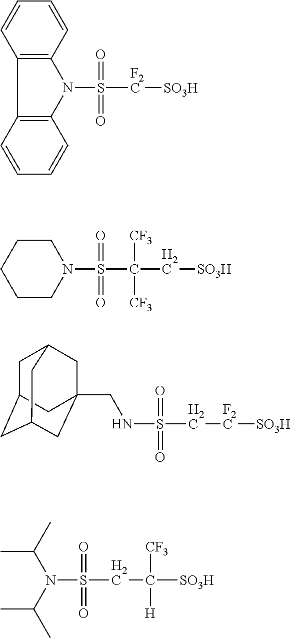

Examples of the preferable compound among the compounds (A) which generate a sulfonic acid represented by the general formula (I) or (I′) upon irradiation with an actinic-ray or a radiation include the compound having an ionic structure, for example, those of an onium salt such as a sulfonium salt and an iodium salt, and the like, and the compound having a non-ionic structure, for example, an oxime ester, an imide ester, and the like. As the onium salt, a sulfonium salt is more preferred.

One of the compounds (A) is preferably a compound represented by the following general formula (I-A) or (I′-A).

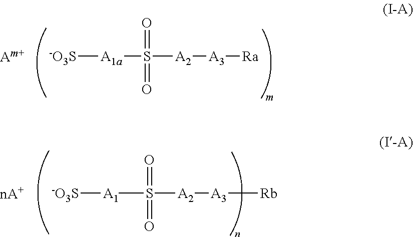

In the general formula (I-A), A^{m+} represents an m-valent cation, and m represents 1 or 2. m is preferably 1. Each of A₁ₐ, A₂, A₃, and Ra has the same meaning as each of the groups in the general formula (I).

In the general formula (I′-A), A⁺ represents a monovalent cation, and each of A₁, A₂, A₃, Rb, and n has the same meaning as each of the groups in the general formula (I′).

Examples of the monovalent cation represented by A⁺ in the general formula (I-A) or (I′-A) include cations represented the following general formula (ZI) or (ZII).

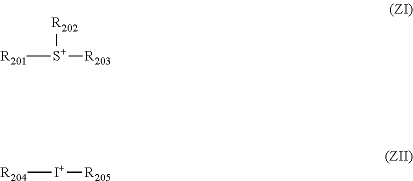

First, the general formula (ZI) will be described.

In the general formula (ZI),

each of R₂₀₁, R₂₀₂, and R₂₀₃ independently represents an organic group, and the organic group as R₂₀₁, R₂₀₂, or R₂₀₃ usually has 1 to 30 carbon atoms, and preferably has 1 to 20 carbon atoms.

Furthermore, two of R₂₀₁ to R₂₀₃ may be bonded to each other to form a ring structure, and the ring may contain an oxygen atom, a sulfur atom, an ester bond, an amide bond, or a carbonyl group. Examples of the group formed by the mutual bonding of two of R₂₀₁ to R₂₀₃ include alkylene groups (for example, a butylene group and a pentylene group).

Examples of the organic groups represented by R₂₀₁, R₂₀₂, and R₂₀₃ include the corresponding groups in the cations (ZI-1), (ZI-2), (ZI-3), and (ZI-4) as described later.

The cation (ZI-1) is an arylsulfonium cation in which at least one of R₂₀₁ to R₂₀₃ in the general formula (ZI) is an aryl group.

In the arylsulfonium cation, all of R₂₀₁ to R₂₀₃ may be aryl groups, or a part of R₂₀₁ to R₂₀₃ may be aryl groups and the remainder thereof may be alkyl groups or cycloalkyl groups.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

The aryl group of the arylsulfonium cation is preferably a phenyl group or a naphthyl group, and more preferably a phenyl group. The aryl group may be an aryl group having a heterocyclic structure, containing an oxygen atom, a nitrogen atom, a sulfur atom, or the like. Examples of the heterocyclic structure include a pyrrole residue, a furan residue, a thiophene residue, an indole residue, a benzofuran residue, a benzothiophene residue, and the like. In the case where the arylsulfonium compound has two or more aryl groups, the two or more aryl groups may be the same as or different from each other.

The alkyl group, or a cycloalkyl group which the arylsulfonium cation may have, if necessary, is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, a cyclohexyl group, and the like.

The aryl group, the alkyl group, or the cycloalkyl group of R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as a substituent. Examples of the preferable substituent include a linear or branched alkyl group having 1 to 12 carbon atoms, a cycloalkyl group having 3 to 12 carbon atoms, and a linear, branched, or cyclic alkoxy group having 1 to 12 carbon atoms, and more preferably an alkyl group having 1 to 4 carbon atoms and an alkoxy group having 1 to 4 carbon atoms. The substituent may be substituted with any one of the three groups, R₂₀₁ to R₂₀₃, or may be substituted with all of the three groups. Further, in the case where R₂₀₁ to R₂₀₃ are aryl groups, the substituent is preferably substituted at the p-position of the aryl group.

Next, the cation (ZI-2) will be described.

The cation (ZI-2) is a compound in which each of R₂₀₁ to R₂₀₃ in the formula (ZI) independently represents an organic group having no aromatic ring. Here, the aromatic ring also includes an aromatic ring containing a heteroatom.

The organic group containing no aromatic ring as R₂₀₁ to R₂₀₃ generally has 1 to 30 carbon atoms, and preferably has 1 to 20 carbon atoms.

Each of R₂₀₁ to R₂₀₃ preferably independently represents an alkyl group, a cycloalkyl group, an allyl group, or a vinyl group, still more preferably a linear or branched 2-oxoalkyl group, a 2-oxocycloalkyl group, or an alkoxycarbonylmethyl group, and particularly preferably a linear or branched 2-oxoalkyl group.

Preferable examples of the alkyl group and the cycloalkyl group of R₂₀₁ to R₂₀₃ include a linear or branched alkyl group having 1 to 10 carbon atoms (for example, a methyl group, an ethyl group, a propyl group, a butyl group, and a pentyl group), and a cycloalkyl group having 3 to 10 carbon atoms (a cyclopentyl group, a cyclohexyl group, and a norbornyl group). More preferable examples of the alkyl group include a 2-oxoalkyl group and an alkoxycarbonylmethyl group, and more preferable examples of the cycloalkyl group include a 2-oxocycloalkyl group.

The 2-oxoalkyl group may be either linear or branched, and examples thereof include a group containing >C═O at the 2-position of the alkyl group.

The 2-oxocycloalkyl group is preferably the group containing >C═O at the 2-position of the cycloalkyl group.

Examples of the alkoxy group in the alkoxycarbonylmethyl group preferably include an alkoxy group having 1 to 5 carbon atoms (a methoxy group, an ethoxy group, a propoxy group, a butoxy group, and a pentoxy group).

R₂₀₁ to R₂₀₃ may be further substituted with a halogen atom, an alkoxyl group (for example, having 1 to 5 carbon atoms), a hydroxyl group, a cyano group, or a nitro group.

Next, the cation (ZI-3) will be described.

The cation (ZI-3) is a compound represented by the following general formula (ZI-3), which is a compound having a phenacylsulfonium structure.

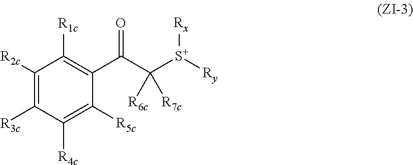

In the general formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ, and Rₓ and R_{y} may be bonded to each other to form a ring structure, and this ring structure may contain an oxygen atom, a sulfur atom, a ketone group, an ester bond, or an amide bond.

The ring structure includes an aromatic or non-aromatic hydrocarbon ring, an aromatic or non-aromatic heterocyclic ring, and a polycyclic condensed ring formed by combination of two or more of these rings. The ring structure includes a 3- to 10-membered ring, and is preferably a 4- to 8-membered ring, and more preferably a 5- or 6-membered ring.

Examples of the group formed by bonding of any two or more of R_{1c} to R_{5c}, R_{6c} and R_{7c}, and Rₓ and R_{y} include a butylene group, a pentylene group, and the like.

The group formed by bonding of R_{5c} and R_{6c}, and R_{5c} and Rₓ is preferably a single bond or an alkylene group, and examples of the alkylene group include a methylene group, an ethylene group, and the like.

The alkyl group as R_{1c} to R_{7c} may be either linear or branched, and examples thereof include an alkyl group having 1 to 20 carbon atoms, and preferably a linear or branched alkyl group having 1 to 12 carbon atoms (for example, a methyl group, an ethyl group, a linear or branched propyl group, a linear or branched butyl group, and a linear or branched pentyl group), and examples of the cycloalkyl group include a cycloalkyl group having 3 to 10 carbon atoms (for example, a cyclopentyl group and a cyclohexyl group).

The aryl group as R_{1c} to R_{7c} preferably has 5 to 15 carbon atoms, and examples thereof include a phenyl group and a naphthyl group.

The alkoxy group as R_{1c} to R_{5c} may be any of linear, branched, and cyclic, and examples thereof include an alkoxy group having 1 to 10 carbon atoms, preferably a linear and branched alkoxy group having 1 to 5 carbon atoms (for example, a methoxy group, an ethoxy group, a linear or branched propoxy group, a linear or branched butoxy group, and a linear or branched pentoxy group), and cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} include the same as the specific examples of the alkoxy group as R_{1c} to R_{5c}.

Specific examples of the alkyl group in the alkylcarbonyloxy group and the alkylthio group as R_{1c} to R_{5c} include the same as the specific examples of the alkyl group as R_{1c} to R_{5c}.

Specific examples of the cycloalkyl group in the cycloalkylcarbonyloxy group as R_{1c} to R_{5c} include the same as the specific examples of the cycloalkyl group as R_{1c} to R_{5c}.

Specific examples of the aryl group in the aryloxy group and the arylthio group as R_{1c} to R_{5c} include the same as the specific examples of the aryl group as R_{1c} to R_{5c}.

Preferably, any one of R_{1c} to R_{5c} is a linear or branched alkyl group, a cycloalkyl group, or a linear, branched, or cyclic alkoxy group, and R_{1c} to R_{5c} more preferably has 2 to 15 carbon atoms, due to which the solvent solubility is more enhanced and production of particles during storage is be suppressed.

The ring structure formed by boding of any two or more of R_{1c} to R_{5c} preferably includes a 5- or 6-membered ring, and particularly preferably a 6-membered ring (such as a phenyl ring).

The ring structure formed by the mutual bonding of R_{5c} and R_{6c} preferably includes a 4 or greater-membered ring (preferably a 5- or 6-membered ring) formed with the carbonyl carbon atom and carbon atom in the general formula (ZI-3) by the mutual bonding of R_{5c} and R_{6c} to constitute a single bond or an alkylene group (a methylene group, an ethylene group, and the like).

An embodiment where R_{6c} and R_{7c} both are an alkyl group is preferred, an embodiment where each of R_{6c} and R_{7c} is a linear or branched alkyl group having 1 to 4 carbon atoms is particularly preferred, and embodiment where both are a methyl group is more particularly preferred.

Furthermore, in the case where R_{6c} and R_{7c} are combined to form a ring, the group formed by bonding of R_{6c} and R_{7c} is preferably an alkylene group having 2 to 10 carbon atoms, and examples thereof include an ethylene group, a propylene group, a butylene group, a pentylene group, a hexylene group, and the like. Further, the ring formed by bonding of R_{6c} and R_{7c} may contain a heteroatom such as an oxygen atom and the like in the ring.

Examples of the alkyl group and the cycloalkyl group as Rₓ and R_{y} include the same as those of the alkyl group and the cycloalkyl group as in R_{1c} to R_{7c}.

Examples of the 2-oxoalkyl group and the 2-oxocycloalkyl group as Rₓ and R_{y} include a group containing >C═O at the 2-position of the alkyl group and the cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}. Examples of the alkyl group include an alkyl group having 1 to 12 carbon atoms, and preferably a linear alkyl group having 1 to 5 carbon atoms (for example, a methyl group and an ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having 3 to 10 carbon atoms).

The vinyl group as Rₓ and R_{y} is not particularly limited but is preferably an unsubstituted vinyl group or a vinyl group substituted with a monocyclic or polycyclic cycloalkyl group (preferably a cycloalkyl group having 3 to 10 carbon atoms).

Examples of the ring structure which may be formed by the mutual bonding of R_{5c} and Rₓ includes a 5 or greater-membered ring (preferably a 5-membered ring) formed together with the sulfur atom and carbonyl carbon atom in the general formula (I) by combining R_{5c} and Rₓ with each other to constitute a single bond or an alkylene group (for example, a methylene group and an ethylene group).

The ring structure which may be formed by the mutual bonding of Rₓ and R_{y} include a 5- or 6-membered ring, and preferably a 5-membered ring (that is, a tetraydrothiophene ring), formed together with the sulfur atom in the general formula (ZI-3) by divalent Rₓ and R_{y} (for example, a methylene group, an ethylene group, a propylene group, and the like).

Rₓ and R_{y} are each preferably an alkyl group, or a cycloalkyl group having 4 or more carbon atoms, more preferably an alkyl group, or a cycloalkyl group having 6 or more carbon atoms, and still more preferably an alkyl group, or a cycloalkyl group having 8 or more carbon atoms.

R_{1c} to R_{7c}, Rₓ and R_{y} may further contain a substituent, and examples of such a substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group, and the like.

Examples of the alkyl group include a linear or branched alkyl group having 1 to 12 carbon atoms, such as a methyl group, an ethyl group, an n-propyl group, an i-propyl group, an n-butyl group, a 2-methylpropyl group, a 1-methylpropyl group, a t-butyl group, and the like.

Examples of the cycloalkyl group include a cycloalkyl group having 3 to 10 carbon atoms, such as a cyclopentyl group, a cyclohexyl group, and the like.

Examples of the aryl group include an aryl group having 6 to 15 carbon atoms, such as a phenyl group, a naphthyl group, and the like.

Examples of the alkoxy group include a linear, branched, or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, a cyclohexyloxy group, and the like.

Examples of the aryloxy group include an aryloxy group having 6 to 10 carbon atoms, such as a phenyloxy group, a naphthyloxy group, and the like.

Examples of the acyl group include a linear or branched acyl group having 2 to 12 carbon atoms, such as an acetyl group, a propionyl group, an n-butanoyl group, an i-butanoyl group, an n-heptanoyl group, a 2-methylbutanoyl group, a 1-methylbutanoyl group, a t-heptanoyl group, and the like.

Examples of the arylcarbonyl group include an aryloxy group having 6 to 10 carbon atoms, such as a phenylcarbonyl group, a naphthylcarbonyl group, and the like.

Examples of the alkoxyalkyl group include a linear, branched, or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, a 2-ethoxyethyl group, and the like.

Examples of the aryloxyalkyl group include an aryloxy group having 7 to 12 carbon atoms, such as a phenyloxymethyl group, phenyloxyethyl group, a naphthyloxymethyl group, a naphthyloxyethyl group, and the like.

Examples of the alkoxycarbonyl group include a linear, branched, or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, a cyclohexyloxycarbonyl, and the like.

Examples of the aryloxycarbonyl group include an aryloxycarbonyl group having 7 to 11 carbon atoms, such as a phenyloxycarbonyl group, a naphthyloxycarbonyl group, and the like.

Examples of the alkoxycarbonyloxy group include a linear, branched, or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, a cyclohexyloxycarbonyloxy, and the like.

Examples of the aryloxycarbonyloxy group include an aryloxycarbonyloxy group having 7 to 11 carbon atoms, such as a phenyloxycarbonyloxy group, a naphthyloxycarbonyloxy group, and the like.

In the general formula (ZI-3), it is more preferable that each of R_{1c}, R_{2c}, R_{4c}, and R_{5c} independently represents a hydrogen atom, and R_{3c} represent a group except for a hydrogen atom, that is, represent an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Specific examples of the cation represented by the general formula (ZI-2) or (ZI-3) of the present invention will be shown below.

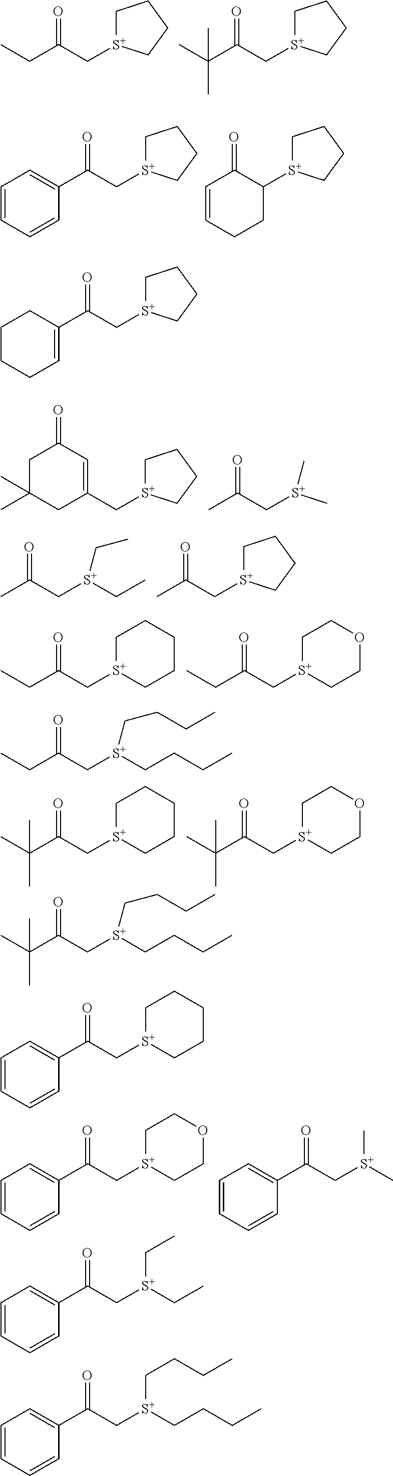

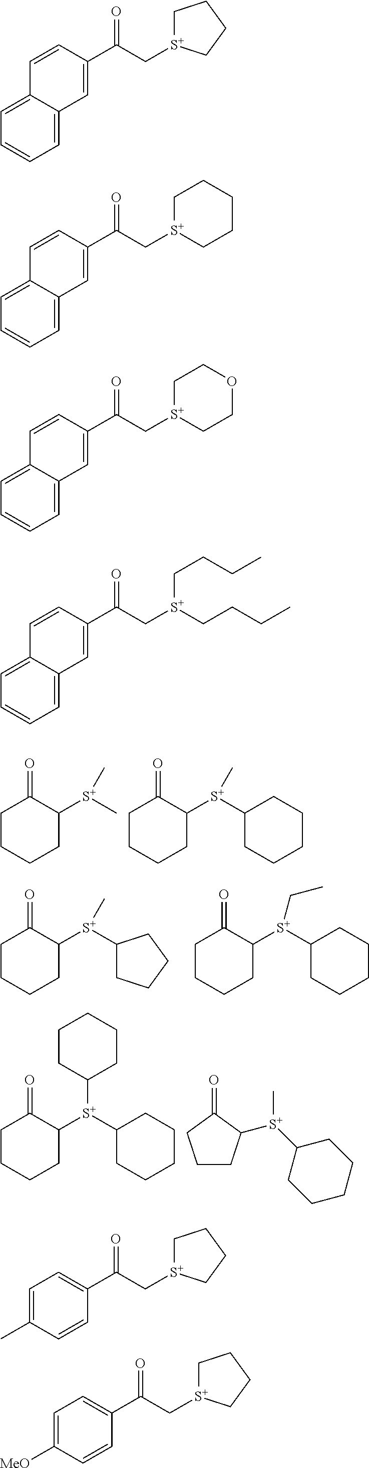

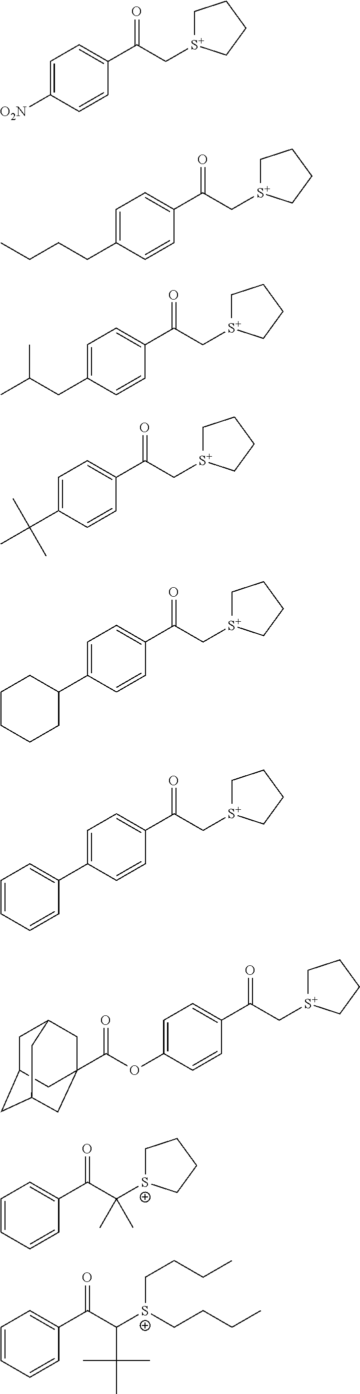

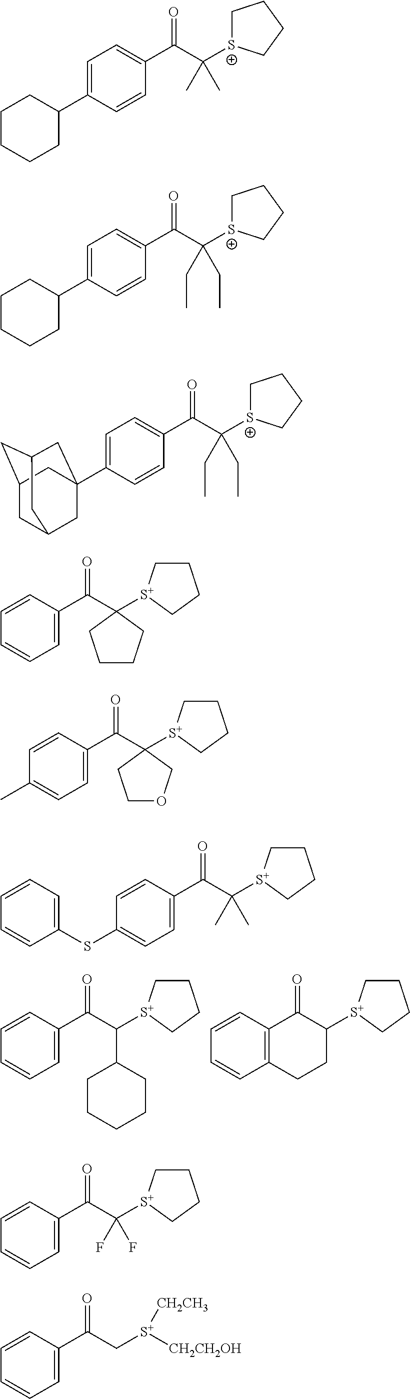

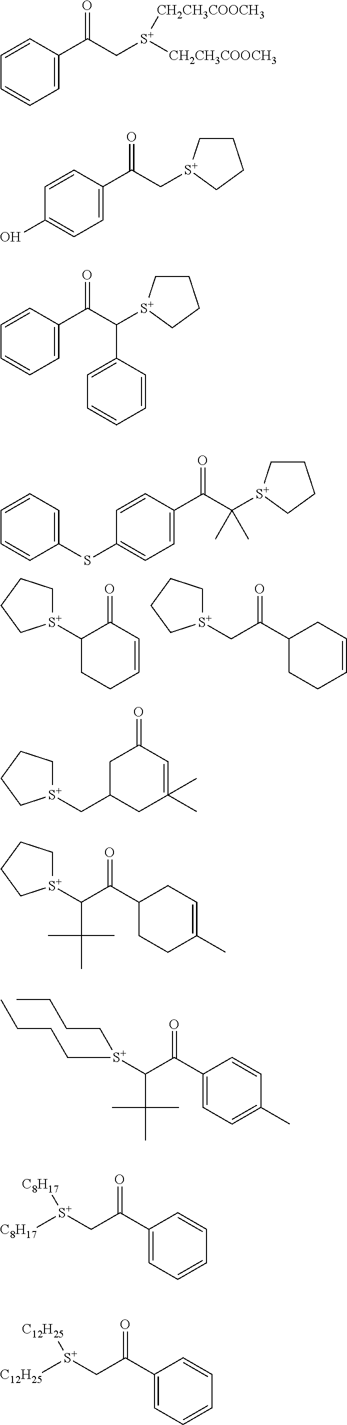

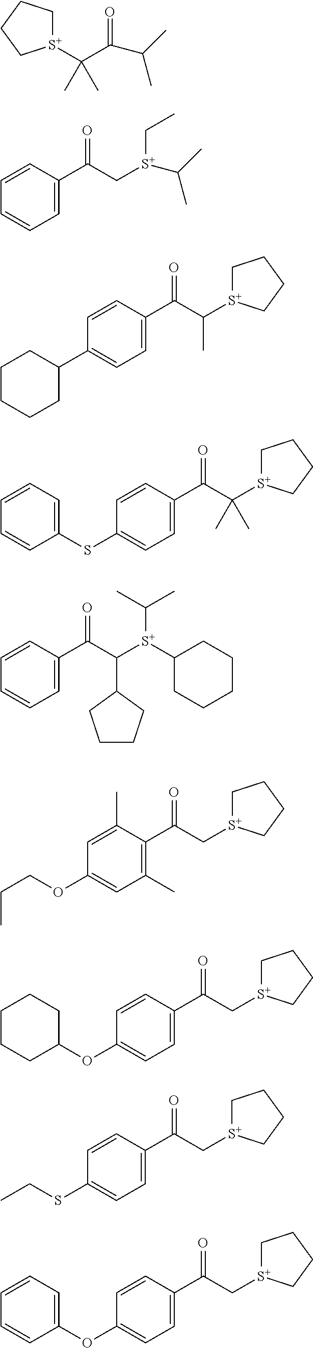

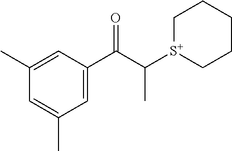

Next, the cation (ZI-4) will be described.

The cation (ZI-4) is represented by the following general formula (ZI-4).

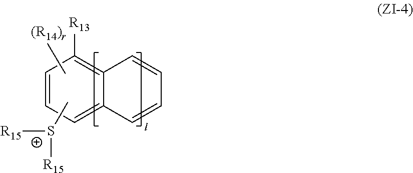

In the general formula (ZI-4),

R₁₃ represents a group containing a hydrogen atom, a fluorine atom, a hydroxyl group, an alkyl group, a cycloalkyl group, an alkoxy group, an alkoxycarbonyl group, or a cycloalkyl group. These groups may have a substituent.

When a plurality of R₁₄'s are present, each of them independently represents a group containing a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. These groups may have a substituent.

Each R₁₅ independently represents an alkyl group, a cycloalkyl group, or a naphthyl group. Two R₁₅'s may be bonded to each other to form a ring. These groups may have a substituent.

l represents an integer of 0 to 2.

r represents an integer of 0 to 8.

In the general formula (ZI-4), the alkyl group of R₁₃, R₁₄ and R₁₅ is a linear or branched alkyl group preferably having 1 to 10 carbon atoms. Examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among these alkyl groups, a methyl group, an ethyl group, an n-butyl group, a t-butyl group, and the like are preferred.

Examples of the cycloalkyl group of R₁₃, R₁₄, and R₁₅ include a cycloalkenyl group, and also include a monocyclic or polycyclic cycloalkyl group (preferably a cycloalkyl group having 3 to 20 carbon atoms). Specific examples thereof include cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl, adamantyl, and the like, and particularly preferably cyclopropyl, cyclopentyl, cyclohexyl, cycloheptyl, and cyclooctyl.

The alkoxy group of R₁₃ and R₁₄ is a linear or branched alkoxy group preferably having 1 to 10 carbon atoms, and examples thereof include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. Among these alkoxy groups, a methoxy group, an ethoxy group, an n-propoxy group, an n-butoxy group, and the like are preferred.

The alkoxycarbonyl group of R₁₃ and R₁₄ is a linear or branched alkoxycarbonyl group preferably having 2 to 11 carbon atoms, and examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among these alkoxycarbonyl groups, a methoxycarbonyl group, an ethoxycarbonyl group, an n-butoxycarbonyl group, and the like are preferred.

The group having a cycloalkyl group of R₁₃ and R₁₄ includes a monocyclic or polycyclic cycloalkyloxy group (preferably a cycloalkyl group having of 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and preferably has a monocyclic cycloalkyl group. The monocyclic cycloalkyloxy group having a total carbon number of 7 or more indicates a monocyclic cycloalkyloxy group where a cycloalkyloxy group such as a cyclopropyloxy group, a cyclobutyloxy group, a cyclopentyloxy group, a cyclohexyloxy group, a cycloheptyloxy group, a cyclooctyloxy group, a cyclododecanyloxy group, and the like arbitrarily has a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, an iso-amyl group, and the like; a hydroxyl group; a halogen atom (fluorine, chlorine, bromine, or iodine); a nitro group; a cyano group; an amido group; a sulfonamido group; an alkoxy group such as a methoxy group, an ethoxy group, a hydroxyethoxy group, a propoxy group, a hydroxypropoxy group, a butoxy group, and the like; an alkoxycarbonyl group such as a methoxycarbonyl group, an ethoxycarbonyl group, and the like; an acyl group such as a formyl group, an acetyl group, a benzoyl group, and the like; an acyloxy group such as an acetoxy group, a butyryloxy group, and the like; a carboxy group; and the like, and where the total carbon number inclusive of the carbon number of an arbitrary substituent on the cycloalkyl group is 7 or more.

Furthermore, examples of the polycyclic cycloalkyloxy group having a total carbon number of 7 or more include a norbornyloxy group, a tricyclodecanyloxy group, a tetracyclodecanyloxy group, an adamantyloxy group, and the like.

The alkoxy group having a monocyclic or polycyclic cycloalkyl group of R₁₃ and R₁₄ preferably has a total carbon number of 7 or more, and more preferably a total carbon number of 7 to 15, and is preferably an alkoxy group having a monocyclic cycloalkyl group. The alkoxy group having a total carbon number of 7 or more and having a monocyclic cycloalkyl group indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, iso-amyloxy, and the like, in which where the total carbon number inclusive of the carbon number of the substituent is 7 or more. Examples thereof include a cyclohexylmethoxy group, a cyclopentylethoxy group, a cyclohexylethoxy group, and the like, with a cyclohexylmethoxy group being preferred.

Furthermore, examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group, and the like, with a norbornylmethoxy group and a norbornylethoxy group being preferred.

Specific examples of the alkyl group in the alkylcarbonyl group of R₁₄ are the same as those of the alkyl group of R₁₃ to R₁₅.

The alkylsulfonyl group or the cycloalkylsulfonyl group of R₁₄ is a linear, branched, or cyclic alkylsulfonyl group preferably having 1 to 10 carbon atoms, and examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, and the like. Among these alkylsulfonyl groups and cycloalkylsulfonyl groups, alkylsulfonyl groups and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group, and the like are preferred.

Examples of the substituent which each of the groups above may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, and the like.

Examples of the alkoxy group include a linear, branched, or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, a cyclohexyloxy group, and the like.

Examples of the alkoxyalkyl group include a linear, branched, or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, a 2-ethoxyethyl group, and the like.

Examples of the alkoxycarbonyl group include a linear, branched, or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, a cyclohexyloxycarbonyl, and the like.

Examples of the alkoxycarbonyloxy group include a linear, branched, or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, a cyclohexyloxycarbonyloxy, and the like.

The ring structure which may be formed by the mutual bonding of two R₁₅'s includes a 5- or 6-membered ring, preferably a 5-membered ring (that is, a tetrahydrothiophene ring), formed together with the sulfur atom in the general formula (ZI-4) by two divalent R₁₅'s and may be fused with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group, and the like. As for the substituent on the ring structure, a plurality of substituents may be present, and they may be combined with each other to form a ring (an aromatic or non-aromatic hydrocarbon ring, an aromatic or non-aromatic heterocyclic ring, a polycyclic condensed ring formed by combination of two or more of these rings, or the like).

In the general formula (ZI-4), R₁₅ is preferably, for example, a methyl group, an ethyl group, a naphthyl group, a divalent group of forming a tetrahydrothiophene ring structure together with the sulfur atom when two R₁₅'s are bonded to each other, or the like.

The substituent which R₁₃ and R₁₄ may have is preferably a hydroxyl group, an alkoxy group, an alkoxycarbonyl group, or a halogen atom (particularly a fluorine atom).

l is preferably 0 or 1, and more preferably 1.

r is preferably from 0 to 2.

Specific preferable examples of the cation in the compound represented by the general formula (ZI-4) of the present invention will be shown below.

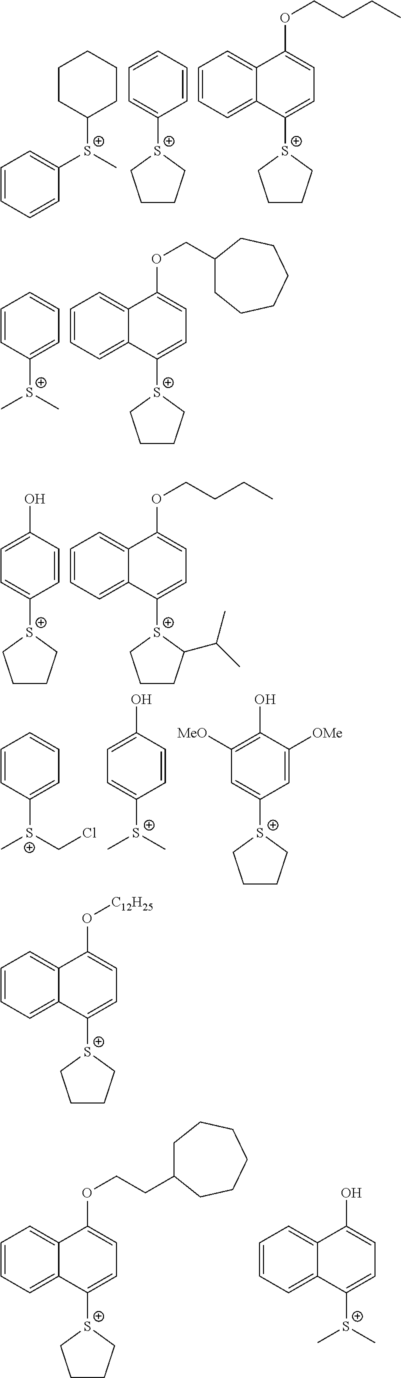

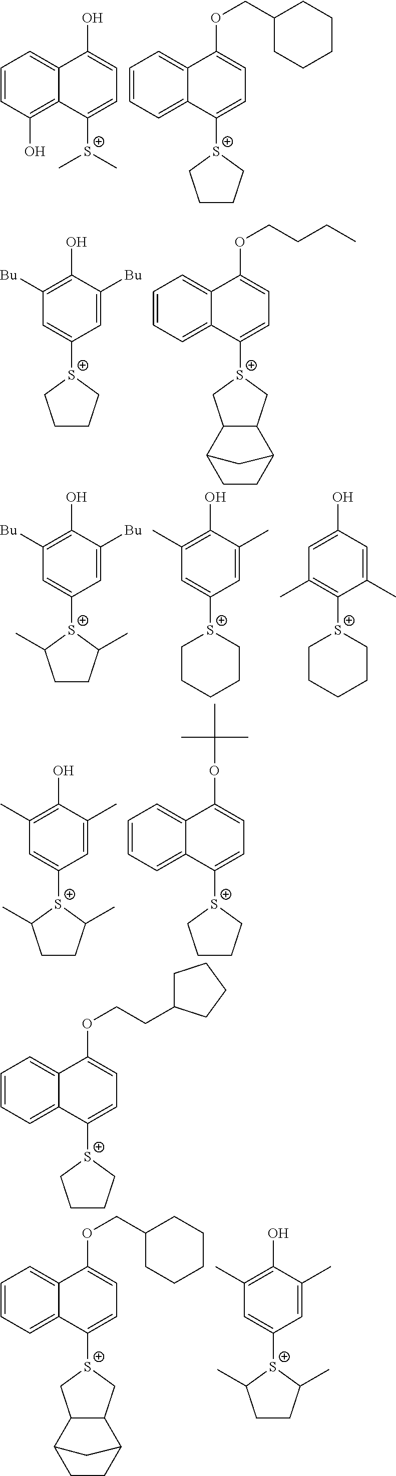

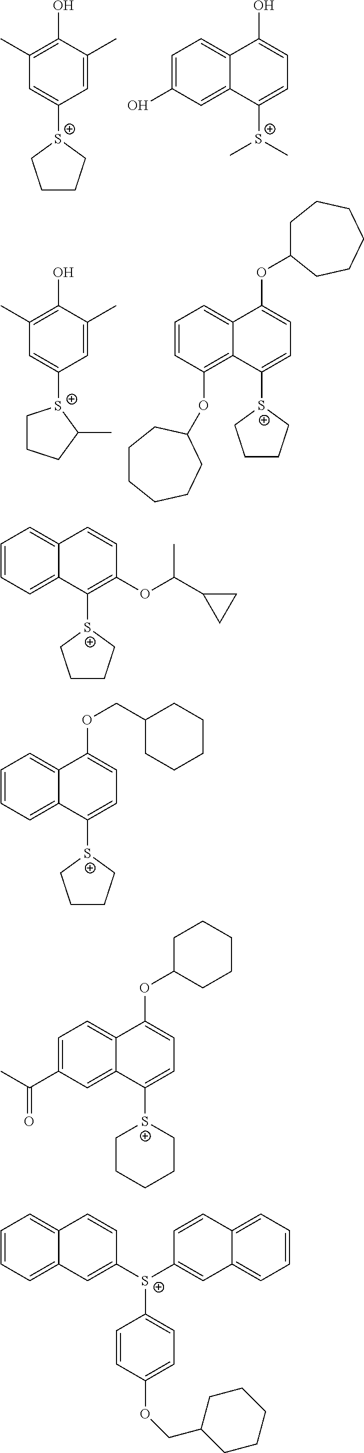

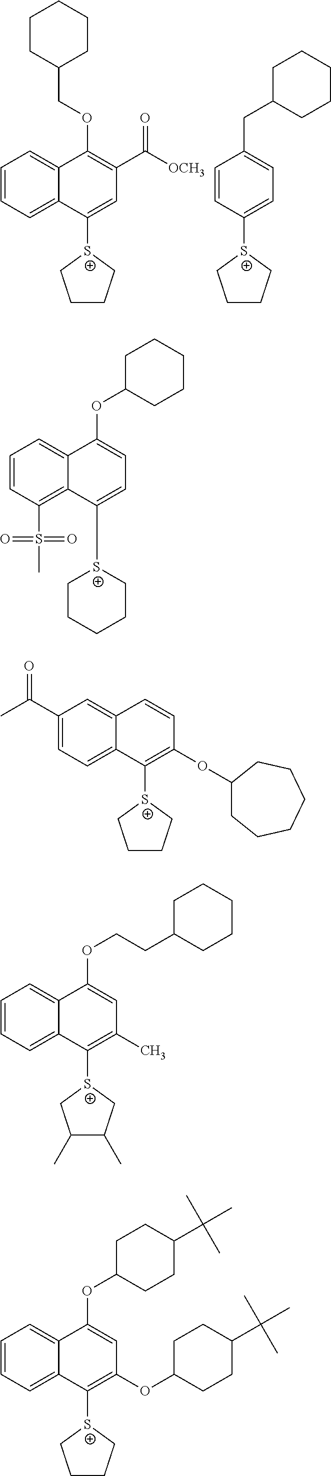

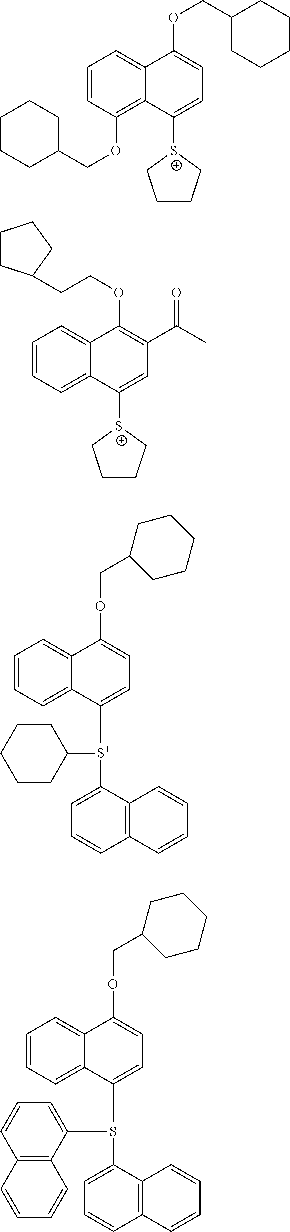

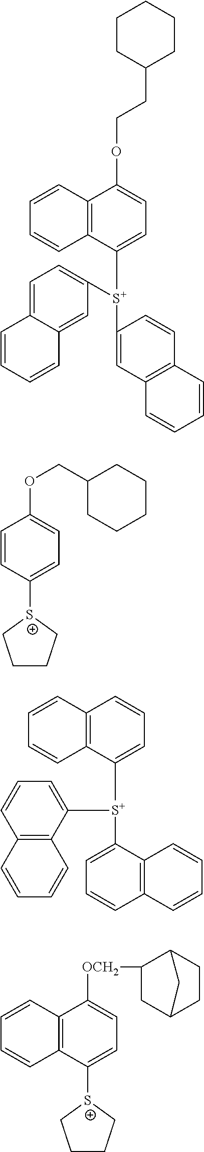

In the case where m is 2 in the general formula (I-A), the compound represented by the general formula (I-A) includes a compound having a plurality of structures represented by the general formula (ZI). For example, it may also be a compound having a structure in which at least one of R₂₀₁ to R₂₀₃ of a compound represented by the general formula (ZI) is bonded to at least one of R₂₀₁ to R₂₀₃ of another compound represented by the general formula (ZI) via a single bond or linking group.

In the case where m is 2 in the general formula (I-A), the divalent cation A²⁺ is preferably a sulfonium cation represented by the following general formula (III).

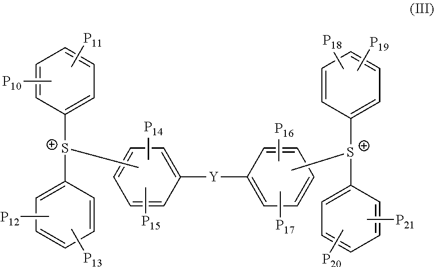

In the formula (III), each of P₁₀ to P₂₁ independently represents a hydrogen atom, a hydroxyl group, an alkyl group, a cycloalkyl group, an alkoxy group, or a halogen atom (a fluorine atom, a chlorine atom, a bromine atom, an iodine atom, and the like). Y represents a sulfur atom or an oxygen atom.

The alkyl group may be linear or a branched chain and is preferably an alkyl group preferably having 1 to 12 carbon atoms. Specific examples of the alkyl group include a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, an iso-amyl group, and the like.

The cycloalkyl group is preferably a cycloalkyl group including a cycloalkenyl group preferably having 3 to 12 carbon atoms. Specific examples of the cycloalkyl group include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, a cyclooctadienyl group, a bicyclo[4.3.0]nonanyl group, a decahydronaphthalenyl group, a tricyclo[5.2.1.0(2,6)]decanyl group, a bornyl group, an isobornyl group, a norbornyl group, an adamantyl group, a noradamantyl group, a 1,7,7-trimethyltricyclo[2.2.1.0^{2,6}]heptanyl group, a 3,7,7-trimethylbicyclo[4.1.0]heptanyl group, and the like, with a cyclopropyl group, a cyclopentyl group, a cyclohexyl group, a cyclooctyl group, a norbornyl group, an adamantyl group, and a noradamantyl group being particularly preferred.

The alkoxy group may linear or branched and may also have an alicyclic skeleton. Examples of the linear alkoxy group include a methoxy group, an ethoxy group, a propoxy group, a butoxy group, a pentyloxy group, a hexyloxy group, a heptyloxy group, an octyloxy group, a dodecyloxy group, a 2-ethylhexyloxy group, an isopropyloxy group, a sec-butyloxy group, a t-butyloxy group, an iso-amyloxy group, and the like. Examples of the cyclic alkoxy group include a cyclopropoxy group, a cyclobutoxy group, a cyclopentyloxy group, a cyclohexyloxy group, a cycloheptyloxy group, a cyclooctyloxy group, a cyclododecanyloxy group, a cyclopentenyloxy group, a cyclohexenyloxy group, a cyclooctadienyloxy group, and the like, with a cyclopropoxy group, a cyclopentyloxy group, a cyclohexyloxy group, and a cyclooctyloxy group being particularly preferred. The alkyl group, the cycloalkyl group, and the alkoxy group as P₁₀ to P₂₁ may further contain a substituent, and specific examples of such a substituent include the substituents same as those which may be further included for the group having a cyclic structure as R₁ and R₂ as the general formula (I) as described above.

Next, the general formula (ZII) will be described.

In the general formula (ZII), each of R₂₀₄ and R₂₀₅ independently represents an aryl group, an alkyl group, or a cycloalkyl group.

The aryl group as R₂₀₄ or R₂₀₅ is preferably a phenyl group or a naphthyl group, and more preferably a phenyl group. The aryl group as each of R₂₀₄ and R₂₀₅ may be an aryl group having a heterocyclic structure having an oxygen atom, a nitrogen atom, a sulfur atom, or the like. Examples of the skeleton of the aryl group having the heterocyclic structure include pyrrole, furan, thiophene, indole, benzofuran, benzothiophene, and the like.

Preferable examples of the alkyl group and the cycloalkyl group as R₂₀₄ or R₂₀₅ include a linear or branched alkyl group having 1 to 10 carbon atoms (for example, a methyl group, an ethyl group, a propyl group, a butyl group, and a pentyl group), and a cycloalkyl group having 3 to 10 carbon atoms (a cyclopentyl group, a cyclohexyl group, and a norbornyl group).

The aryl group, the alkyl group, or the cycloalkyl group as R₂₀₄ or R₂₀₅ may have a substituent. Examples of the substituent which the aryl group, the alkyl group, or the cycloalkyl group as R₂₀₄ or R₂₀₅ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group, and the like.

Specific examples of the cation represented by the general formula (ZII) will be shown below.

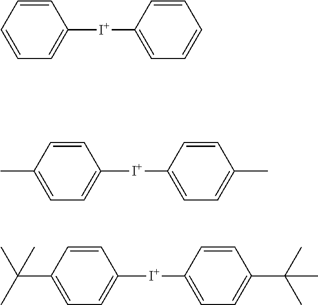

The compound (A) further has a nonionic compound structure, and examples thereof include compounds represented by the following general formulae (ZV) and (ZVI).

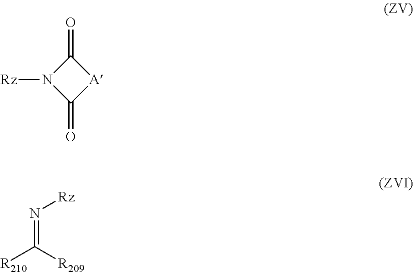

In the general formulae (ZV) and (ZVI),

each of R₂₀₉ and R₂₁₀ independently represents an alkyl group, a cycloalkyl group, a cyano group, or an aryl group. The aryl group, the alkyl group, or the cycloalkyl group of R₂₀₉ or R₂₁₀ is the same as the group described as the aryl group, the alkyl group, or the cycloalkyl group of R₂₀₁ to R₂₀₃ in the compound (ZI-1) as described above. The aryl group, the alkyl group, or the cycloalkyl group of R₂₀₉ or R₂₁₀ may have a substituent. Examples of the substituent include the same as those of the substituent of the aryl group, the alkyl group, or the cycloalkyl group of R₂₀₁ to R₂₀₃ in the compound (ZI-1) as described above.

A′ represents an alkylene group, an alkenylene group, or an arylene group.

The alkylene group as A′ may have a substituent, and preferably has 1 to 8 carbon atoms, and examples thereof include a methylene group, an ethylene group, a propylene group, a butylene group, a hexylene group, an octylene group, and the like.

The alkenylene group as A′ may have a substituent, and preferably has 2 to 6 carbon atoms, and examples thereof include an ethenylene group, a propenylene group, a butenylene group, and the like.

The arylene group as A′ may have a substituent, and preferably has 6 to 15 carbon atoms, and examples thereof include a phenylene group, a tolylene group, a naphthylene group, and the like.

Examples of the substituent which A′ may has include groups having active hydrogen, such as a cycloalkyl group, an aryl group, an amino group, an amido group, a ureido group, a urethane group, a hydroxyl group, a carboxyl group, and the like, a halogen atom (a fluorine atom, a chlorine atom, a bromine atom, and an iodine atom), an alkoxy group (for example, a methoxy group, an ethoxy group, a propoxy group, a butoxy group, and the like), a thioether group, an acyl group (an acetyl group, a propanoyl group, a benzoyl group, and the like), an acyloxy group (an acetoxy group, a propanoyloxy group, benzoyloxy group, and the like), an alkoxycarbonyl group (a methoxycarbonyl group, an ethoxycarbonyl group, a propoxycarbonyl group, and the like), a cyano group, a nitro group, and the like. Further, further examples of the arylene group include an alkyl group (a methyl group, an ethyl group, a propyl group, a butyl group, and the like).

Rz represents a structure in which H of an acid represented by the general formula (I) is dissociated, and is represented by the following general formula (I-s).

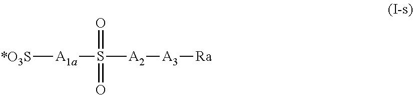

In the formula, A₁ₐ, A₂, A₃, and Ra are each the same as those in the general formula (I). * represents a bonding portion with a compound residue represented by the general formula (ZV) or (ZVI).

Specific examples of the compound residue represented by the general formula (ZV) or (ZVI) will be shown below. * represents in the specific examples represents a bonding portion with * of the general formula (I-s).

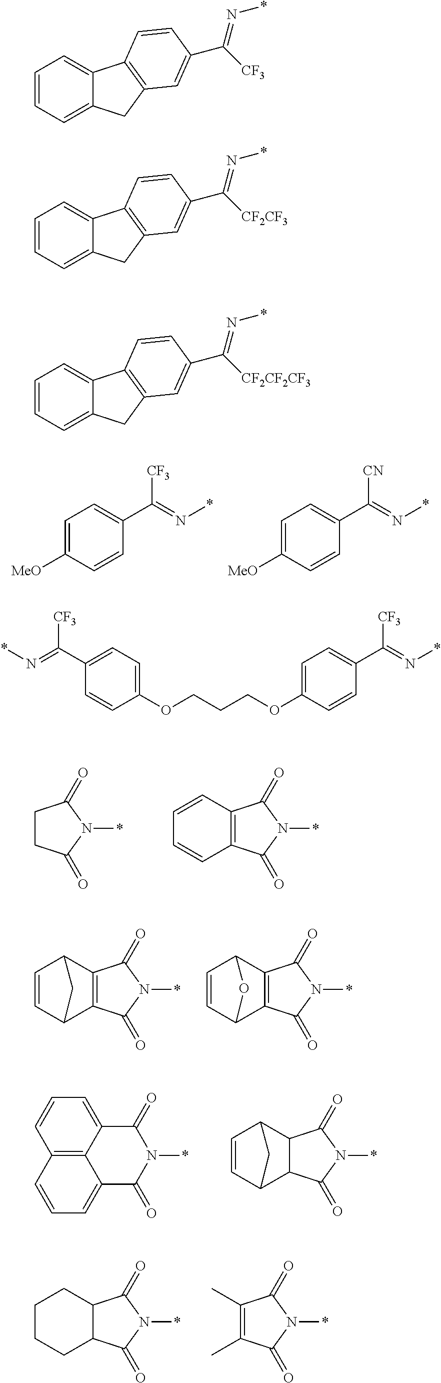

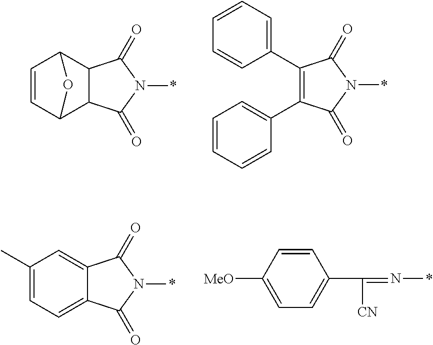

(A) Specific preferable examples of the compound which generates an acid represented by the general formula (I) or (I′) upon irradiation of an actinic-ray or a radiation will be shown below, but the present invention is not limited thereto.

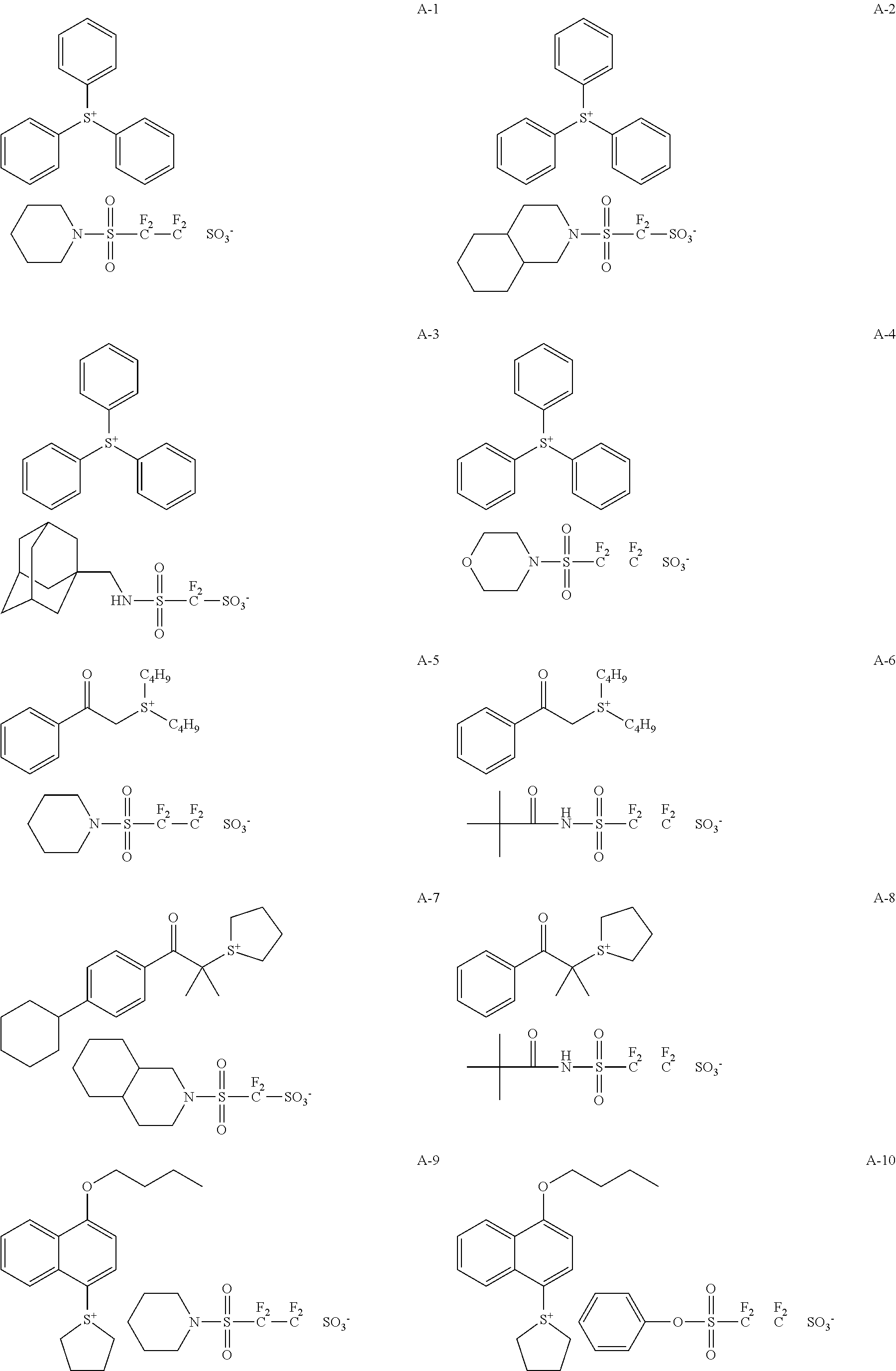

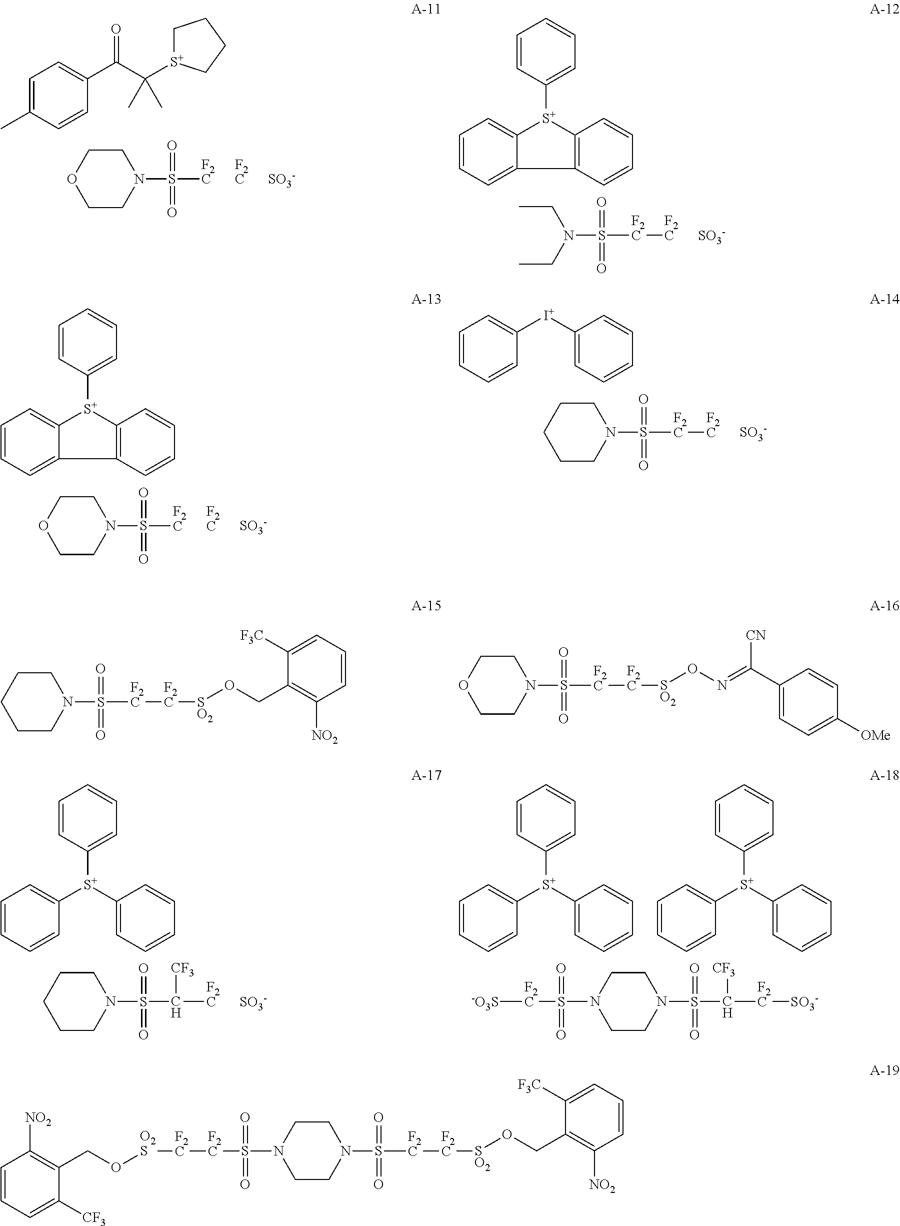

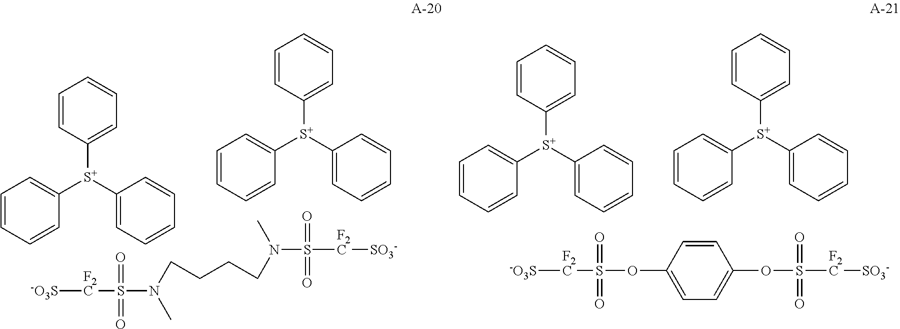

A sulfonic acid represented by the general formula (I) or (I′) or a salt thereof (for example, an onium salt or metal salt) can be synthesized by a general sulfonic esterification reaction or a sulfonamide-forming reaction. For example, the sulfonic acid can be obtained by a method in which a bissulfonyl halide compound is reacted in such a manner that one of the sulfonyl halide moieties is selectively reacted with an amine, alcohol, or amide compound or the like to form a sulfonamide bond, a sulfonic ester bond, or a sulfonimide bond and thereafter the other sulfonyl halide moiety is hydrolyzed, or by a method in which a cyclic sulfonic anhydride is subjected to ring cleavage with an amine, alcohol, or amide compound.

Examples of the salt of the sulfonic acid represented by the general formula (I) or (I′) include sulfonic acid metal salts and sulfonic acid onium salts. Examples of the metal in the sulfonic acid metal salts include Na, Li, K, and the like. Examples of the onium cation in the sulfonic acid onium salts include ammonium cations, sulfonium cations, iodonium cations, phosphonium cations, diazonium cations, and the like.

A sulfonic acid represented by the general formula (I) or (I′) or a salt thereof can be used for synthesizing the compound which generates a sulfonic acid represented by the general formula (I) or (I′) upon irradiation with an actinic-ray or a radiation.

The compound (A) can be synthesized by a method in which the sulfonic acid represented by the general formula (I) or (I′) is subjected to salt exchange with an optically active onium salt such as a sulfonium salt, an iodonium salt, and the like, or can be synthesized by forming an ester of the sulfonic acid represented by the general formula (I) or (I′) with a nitrobenzyl alcohol, an N-hydroxyimide, or an oxime compound.

The content of the compound (A) in the composition of the present invention is preferably from 0.1 to 30% by mass, more preferably from 0.5 to 25% by mass, and still more preferably from 5 to 20% by mass, based on all solids of the composition.

Furthermore, the compound (A) may be used in combination with an acid generator (which is also referred to as compound (A′)), in addition to the compound (A).

The compound (A′) is not particularly limited, but preferable examples thereof include compounds represented by the following general formulae (ZI′), (ZII′), and (ZIII′).

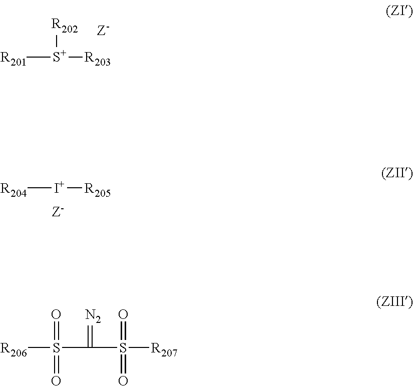

In the general formula (ZI′), each of R₂₀₁, R₂₀₂, and R₂₀₃ has the same meaning as each of R₂₀₁, R₂₀₂, and R₂₀₃ in the general formula (ZI) as described above.

Z⁻ represents a non-nucleophilic anion (anion having an exceedingly low ability of causing a nucleophilic reaction).

Examples of Z⁻ include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, a tris(alkylsulfonyl)methide anion, and the like.

The aliphatic moiety of the aliphatic sulfonate anion and the aliphatic carboxylate anion may be an alkyl group or a cycloalkyl group, and preferable examples thereof include a linear or branched alkyl group having 1 to 30 carbon atoms and a cycloalkyl group having 3 to 30 carbon atoms.

Preferable examples of the aromatic group in the aromatic sulfonate anion and the aromatic carboxylate anion include an aryl group preferably having 6 to 14 carbon atoms, such as a phenyl group, a tolyl group, a naphthyl group, and the like.

The alkyl group, the cycloalkyl group, and the aryl group of the aliphatic sulfonate anion and the aromatic sulfonate anion may have a substituent. Examples of the substituent of the alkyl group, the cycloalkyl group, and the aryl group of the aliphatic sulfonate anion and the aromatic sulfonate anion include a nitro group, a halogen atom such as a fluorine atom and the like, a carboxyl group, a hydroxyl group, an amino group, a cyano group, an alkoxy group (preferably having 1 to 15 carbon atoms), an a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), an a cycloalkylaryloxysulfonyl group (preferably having 10 to 20 carbon atoms), an alkyloxyalkyloxy group (preferably having 5 to 20 carbon atoms), an a cycloalkylalkyloxyalkyloxy group (preferably having 8 to 20 carbon atoms), and the like. The aryl group or the ring structure which may be further contained in these groups has an alkyl group (preferably having 1 to 15 carbon atoms) as its substituent.

Preferable examples of the aralkyl group in the aralkylcarboxylate anion include an aralkyl group having 6 to 12 carbon atoms, such as a benzyl group, a phenethyl group, a naphthylmethyl group, a naphthylethyl group, a naphthylbutyl group, and the like.

Examples of the sulfonylimide anion include a saccharin anion.

The alkyl group of the bis(alkylsulfonyl)imido anion and the tris(alkylsulfonyl)methyl anion is preferably an alkyl group having 1 to 5 carbon atoms. Examples of the substituent of the alkyl group include a halogen atom, an alkyl group substituted with a halogen atom, an alkoxy group, an alkylthio group, an alkyloxysulfonyl group, an aryloxysulfonyl group, a cycloalkylaryloxysulfonyl group, and the like, and an alkyl group substituted with a fluorine atom is preferred.

Examples of the other Z⁻ include phosphorus fluoride, boron fluoride, antimony fluoride, and the like.

Z⁻ is preferably an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom, or a tris(alkylsulfonyl)methide anion whose alkyl group is substituted with a fluorine atom. The normucleophilic anion is more preferably a perfluorinated aliphatic sulfonate anion (more preferably having 4 to 8 carbon atoms) or a benzene sulfonate anion having a fluorine atom, and still more preferably a nonafluorobutane sulfonate anion, a perfluorooctane sulfonate anion, a pentafluorobenzene sulfonate anion, or a 3,5-bis(trifluoromethyl)benzene sulfonate anion.

From the viewpoint of acid strength, the pKa of the acid generated is preferably −1 or less in order to improve the sensitivity.

Next, the general formulae (ZII′) and (ZIII′) will be described.

In the general formula (ZII′) or (ZIII′),

each of R₂₀₄ to R₂₀₇ independently represents an aryl group, an alkyl group, or a cycloalkyl group.

The aryl group, the alkyl group, and the cycloalkyl group of R₂₀₄ to R₂₀₇ are the same as the aryl group described as the aryl group, the alkyl group, and the cycloalkyl group of R₂₀₁ to R₂₀₃ of the compound (ZI-1) as described above.

The aryl group, the alkyl group, and the cycloalkyl group of R₂₀₄ to R₂₀₇ may have a substituent. Examples of the substituent include those which may be contained in the aryl group, the alkyl group, and the cycloalkyl group of R₂₀₁ to R₂₀₃ of the compound (ZI-1).

Z⁻ represents a non-nucleophilic anion, and examples thereof include the same as the non-nucleophilic anion in E in the general formula (ZI′).

Further examples of the acid generator (A′) which can be used in combination with the acid generator of the present invention include compounds represented by the following general formulae (ZIV′), (ZV′), and (ZVI′).

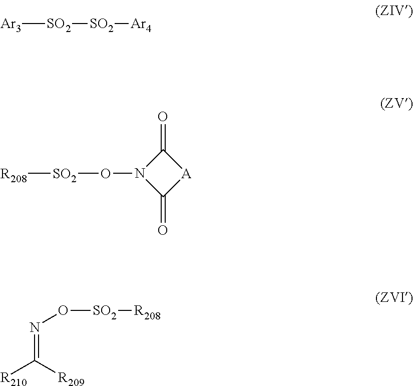

In the general formulae (ZIV′) to (ZVI′),

each of Ar₃ and Ar₄ independently represents an aryl group,

each of R₂₀₈, R₂₀₉ and R₂₁₀ independently represents an alkyl group, a cycloalkyl group, or an aryl group, and

A represents an alkylene group, an alkenylene group, or an arylene group.

Particularly preferable examples of the acid generator which can be used in combination with the acid generator of the present invention will be shown below.

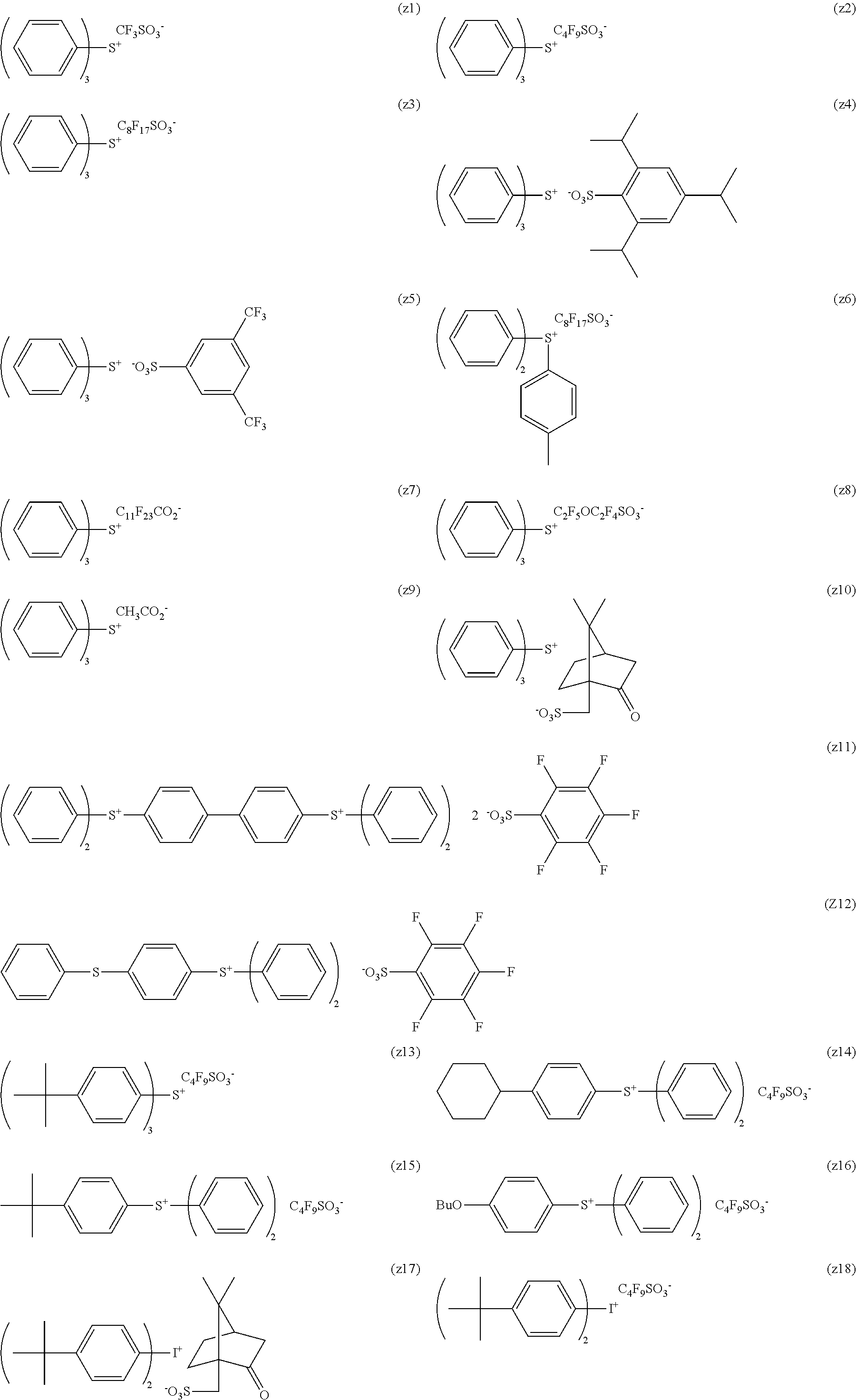

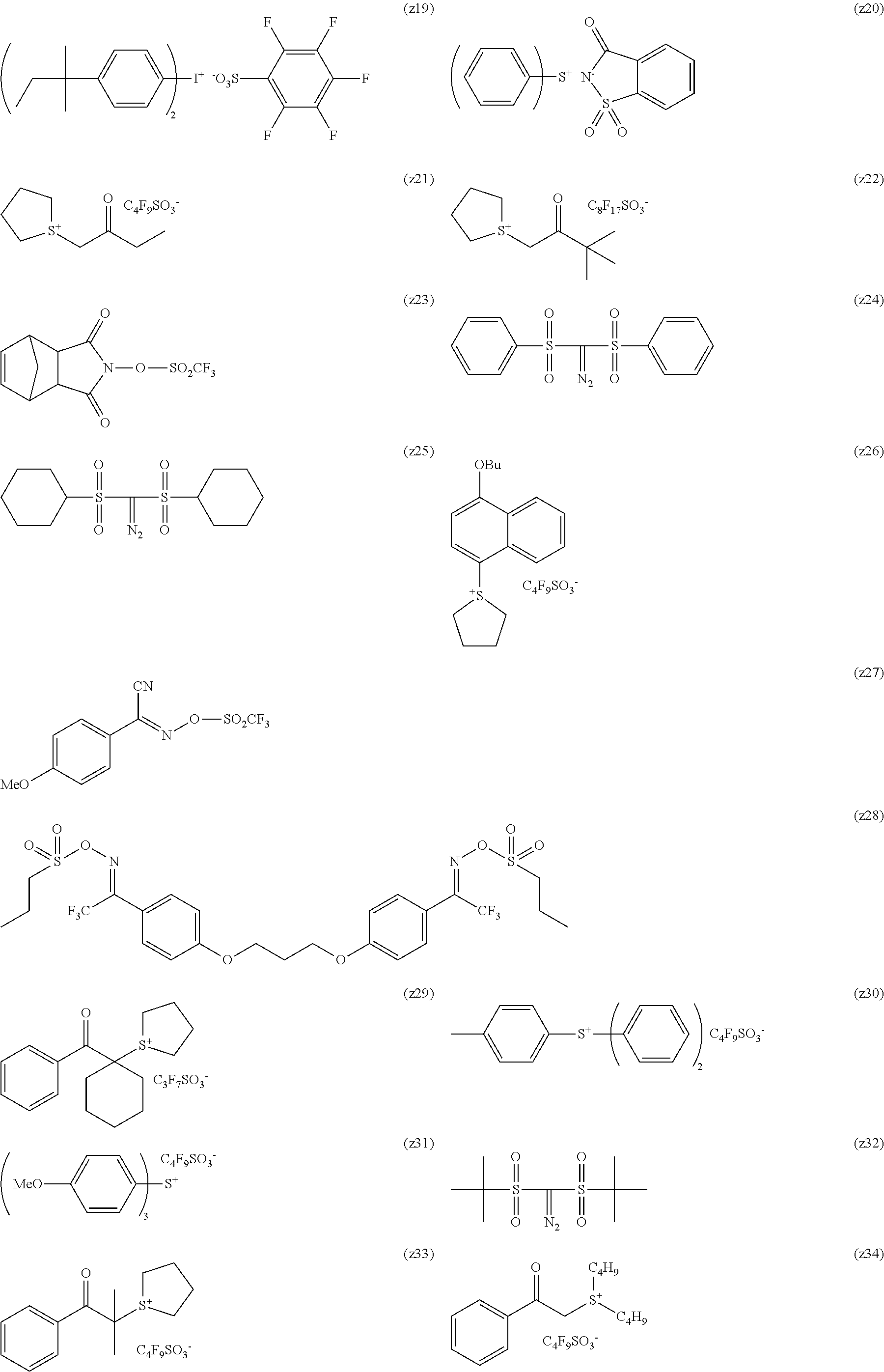

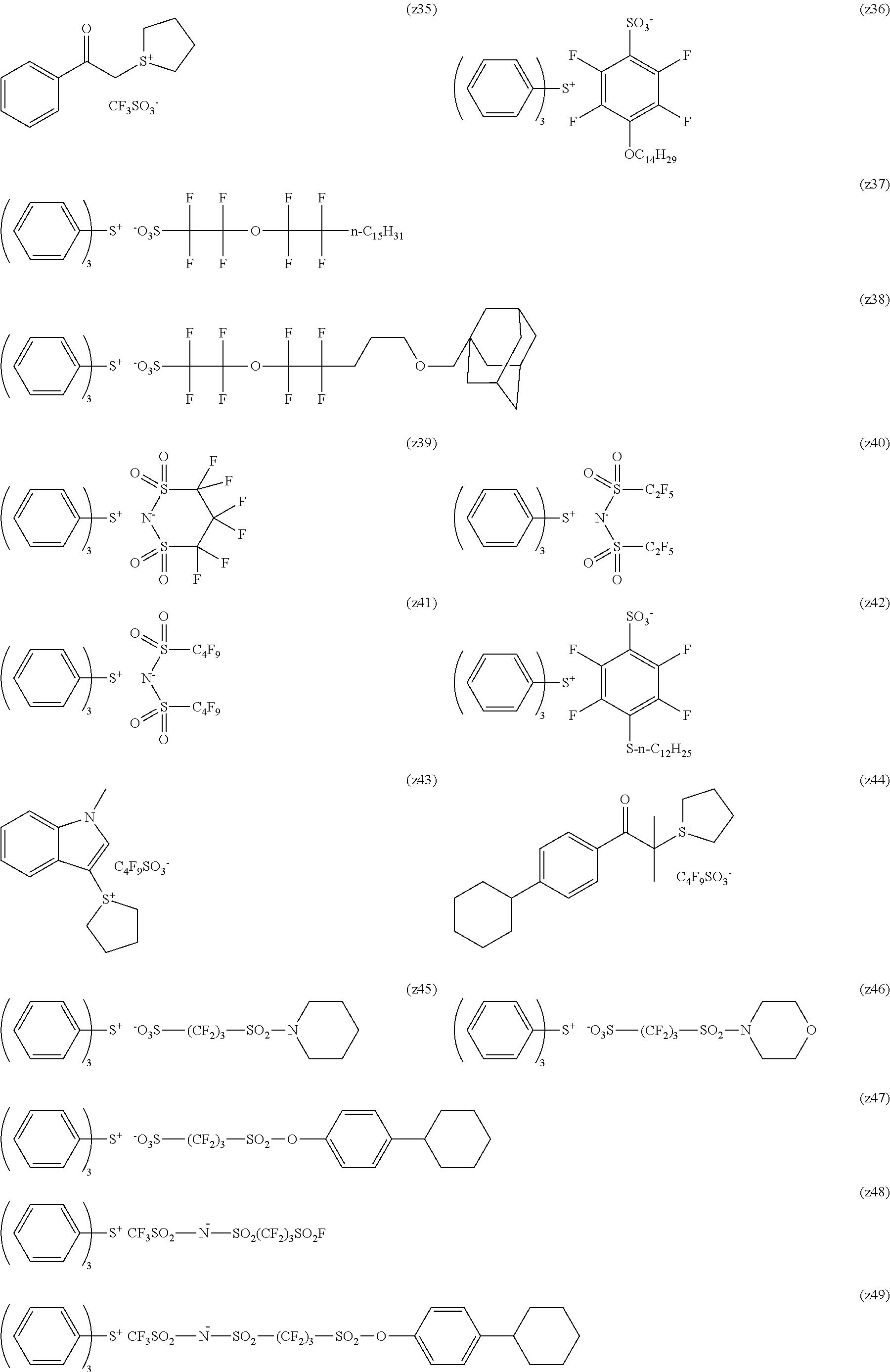

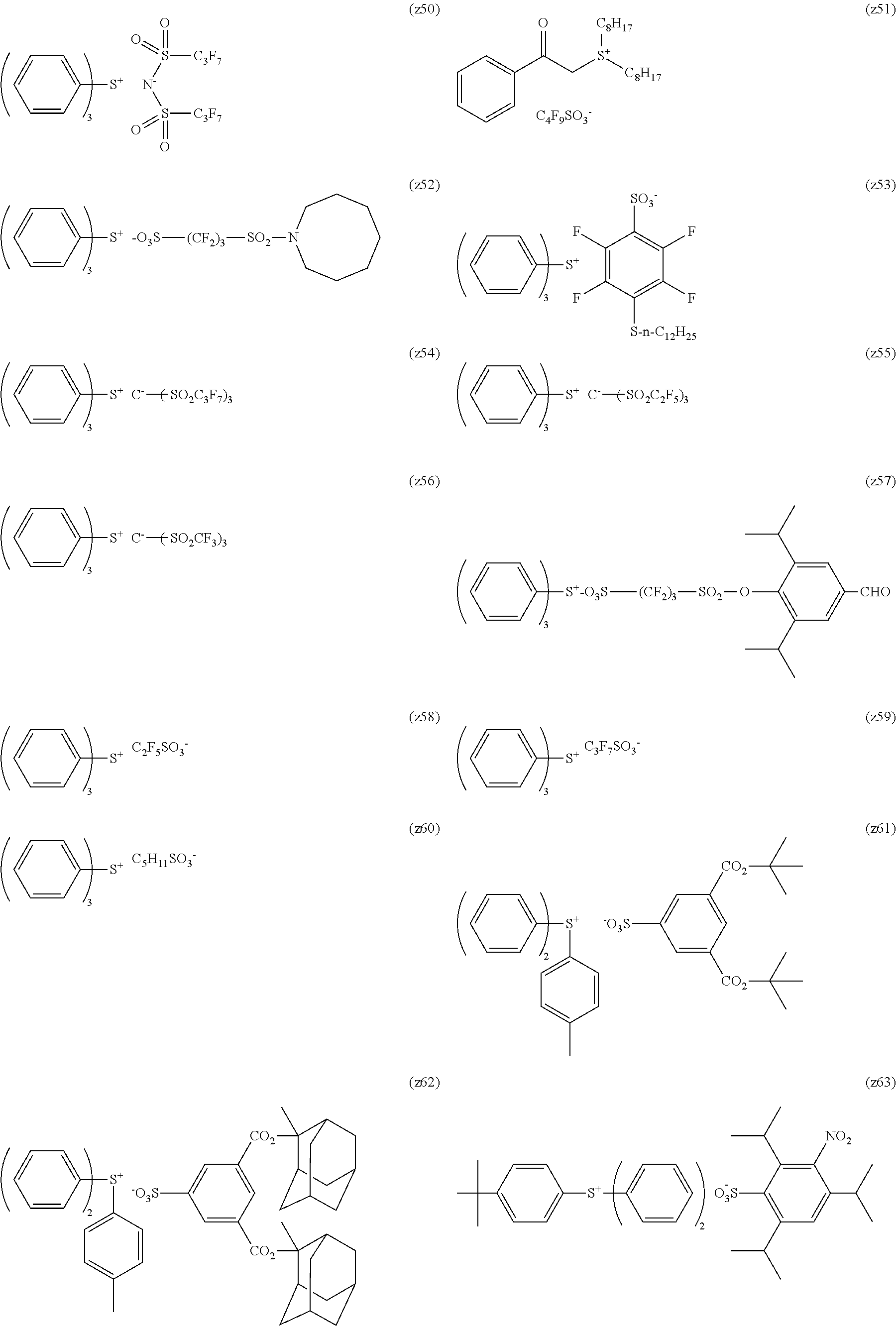

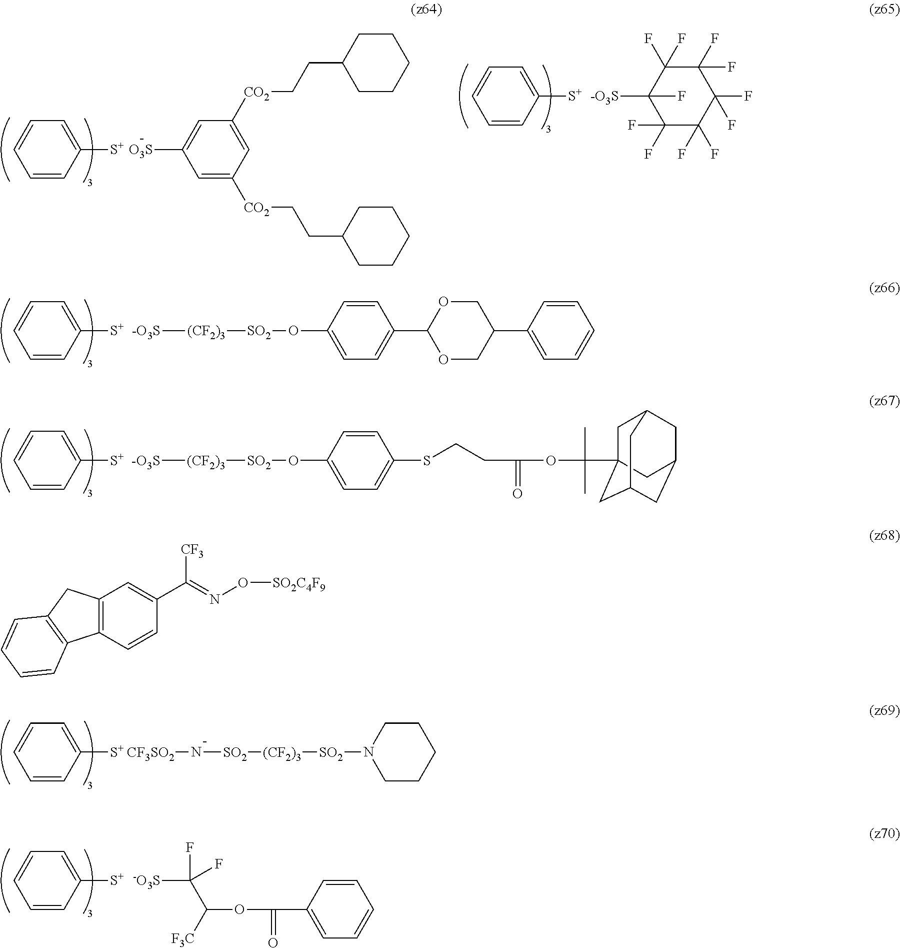

In the case where the composition of the present invention contains the compound (A′) as an acid generator, the content of the compound (A′) is preferably 50% by mass or less, more preferably 25% by mass or less, and still more preferably 20% or less, based on the total amount of the acid generator (A) of the present invention.

[2] Resin Which Decomposes by Action of Acid to Increase Solubility of Resin in Alkaline Developer

The actinic-ray-sensitive or radiation-sensitive resin composition of the present invention includes a resin which decomposes by an action of an acid to increase a solubility of the resin in an alkaline developer (which is also referred to as an “acid-decomposable resin”, a “resin (B)”, or the like).

The acid-decomposable resin contains a group that decomposes by the action of an acid to produce an alkali-soluble group (hereinafter also referred to as “acid-decomposable group”) in the main chain or side chain, or both the main chain and the side chain, of the resin.

The resin (B) is preferably insoluble or poorly soluble in an alkaline developer.

The acid-decomposable group preferably has a structure in which the alkali-soluble group is protected with a group which decomposes and is cleaved by the action of an acid.

Examples of the alkali-soluble group include a phenolic hydroxyl group, a carboxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group, and the like.

Preferable examples of the alkali-soluble group include a carboxyl group, a fluorinated alcohol group (preferably hexafluoroisopropanol), and a sulfonic acid group.

The acid-decomposable group is preferably a group as obtained by substituting the hydrogen atom of any of these alkali-soluble groups with an acid-cleavable group.

Examples of the acid-cleavable group include —C(R₃₆)(R₃₇)(R₃₈), —C(R₃₆)(R₃₇)(OR₃₉), —C(R₀₁)(R₀₂)(OR₃₉), and the like.

In the formulae, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ to R₀₂ independently represents a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, and the like, and more preferably a tertiary alkyl ester group.

The repeating unit having an acid-decomposable group that may be contained in the resin (B) is preferably a repeating unit represented by the following general formula (AI).

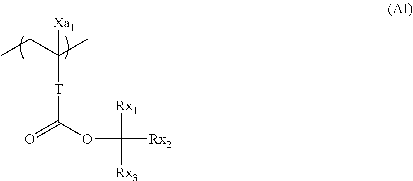

In the general formula (AI),

Xa₁ represents a hydrogen atom, a methyl group which may have a substituent, or a group represented by —CH₂—R₉. R₉ represents a hydroxyl group or a monovalent organic group, and examples thereof include an alkyl group having 5 or less carbon atoms, and an acyl group, preferably an alkyl group having 3 or less carbon atoms, and more preferably a methyl group. Xa₁ preferably represents a hydrogen atom, a methyl group, a trifluoromethyl group, or a hydroxymethyl group.

T represents a single bond or a divalent linking group.

Each of Rx₁ to Rx₃ independently represents an (linear or branched) alkyl group or a (monocyclic or polycyclic) cycloalkyl group.

At least two of Rx₁ to Rx₃ may be bonded to each other to form a (monocyclic or polycyclic) cycloalkyl group.

Examples of the divalent linking group of T include an alkylene group, a —COO-Rt- group, an —O-Rt- group, and the like. In the formula, Rt represents an alkylene group or a cycloalkylene group.

T is preferably a single bond or a —COO-Rt- group. Rt is preferably an alkylene group having 1 to 5 carbon atoms, and more preferably a —CH₂— group or a —(CH₂)₃— group.

The alkyl groups of Rx₁ to Rx₃ preferably have 1 to 4 carbon atoms, and examples thereof include a methyl group, an ethyl group, an n-propyl group, an isopropyl group, an n-butyl group, an isobutyl group, a t-butyl group, and the like.

The cycloalkyl group of each of Rx₁ to Rx₃ is preferably a monocyclic cycloalkyl group such as a cyclopentyl group, a cyclohexyl group, and the like, or a polycyclic cycloalkyl group such as a norbornyl group, a tetracyclodecanyl group, a tetracyclododecanyl group, and an adamantyl group.

The cycloalkyl group formed by bonding of at least two of Rx₁ to Rx₃ is preferably a monocyclic cycloalkyl group such as a cyclopentyl group, a cyclohexyl group, and the like, or a polycyclic cycloalkyl group such as a norbornyl group, a tetracyclodecanyl group, a tetracyclododecanyl group, an adamantyl group, and the like, and particularly preferably a monocyclic cycloalkyl group having 5 to 6 carbon atoms.

It is a preferably embodiment that Rx₁ is a methyl group or an ethyl group, and Rx₂ and Rx₃ are bonded to each other to form the cycloalkyl group as described above.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like, with a substituent having 8 or less carbon atoms being preferred.

The total content of the repeating units having acid-decomposable groups is preferably in the range of 20 to 70 mol %, and more preferably 30 to 50 mol %, based on all the repeating units of the resin.

Specific examples of the preferable repeating units having acid-decomposable groups will be shown below, but the present invention is not limited thereto.

In the following formulae, each of Rx and Xa₁ represents a hydrogen atom, CH₃, CF₃, or CH₂OH. Each of Rxa and Rxb represents an alkyl group having 1 to 4 carbon atoms. Z, each independently in the presence of two or more groups, represents a substituent containing a polar group. p represents 0 or a positive (+) integer.

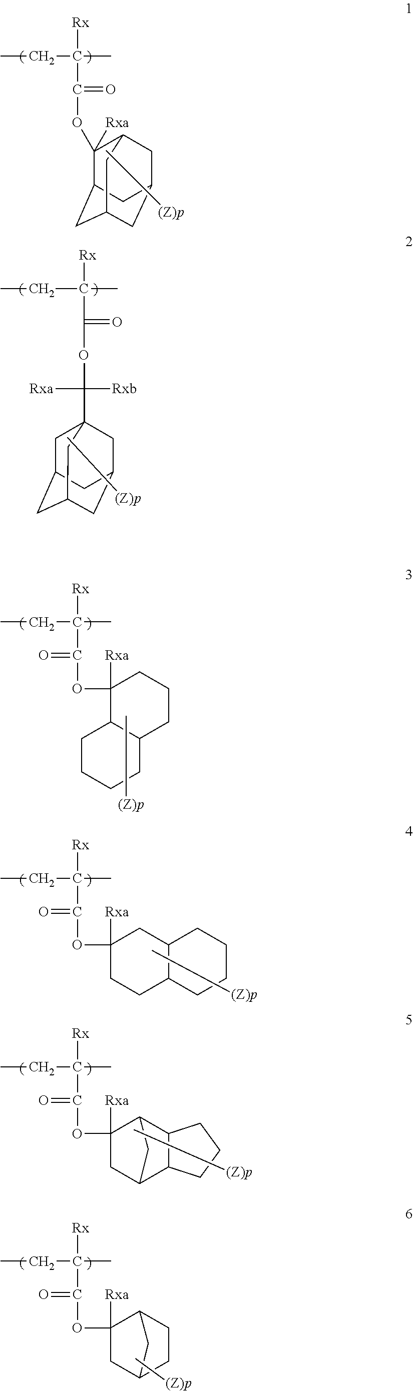

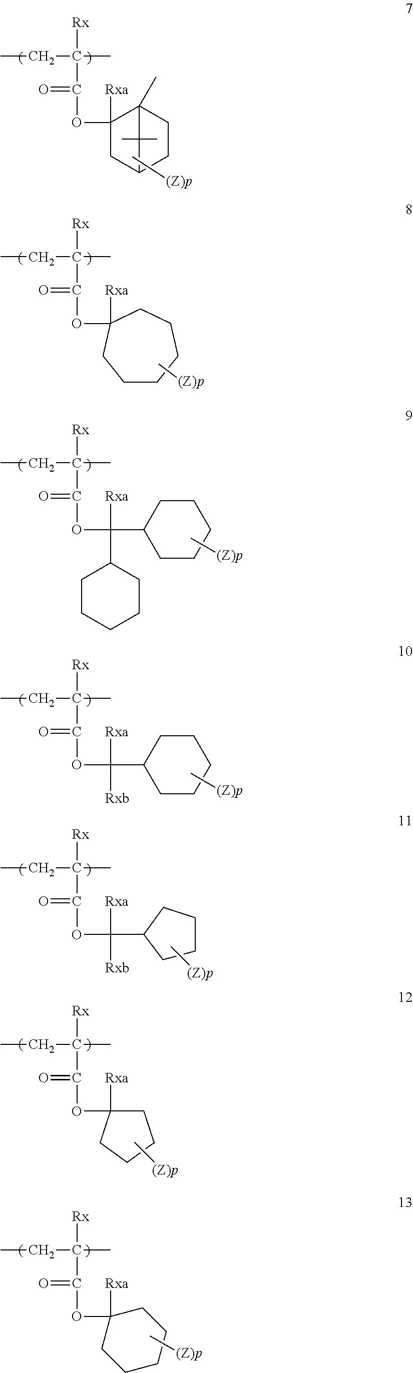

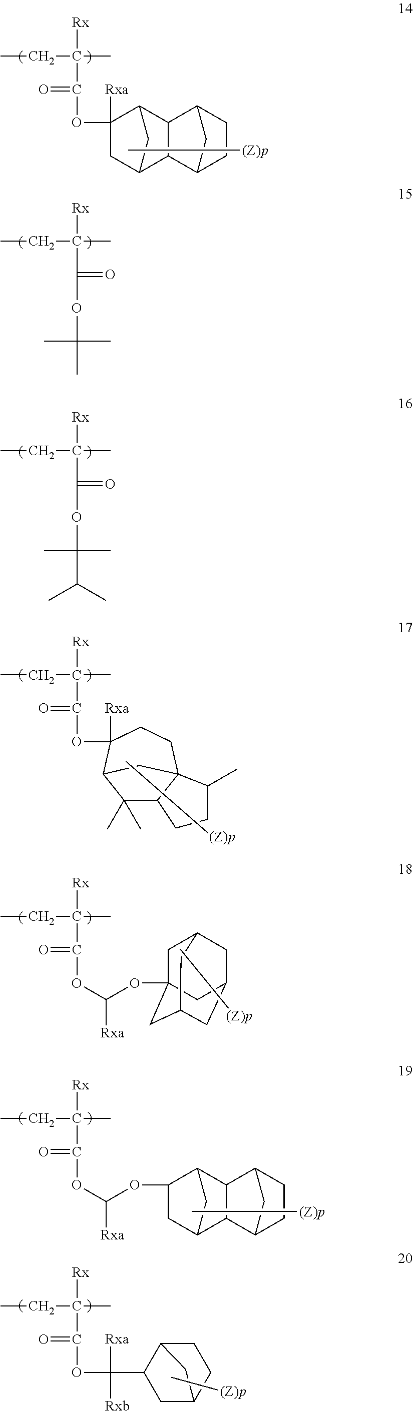

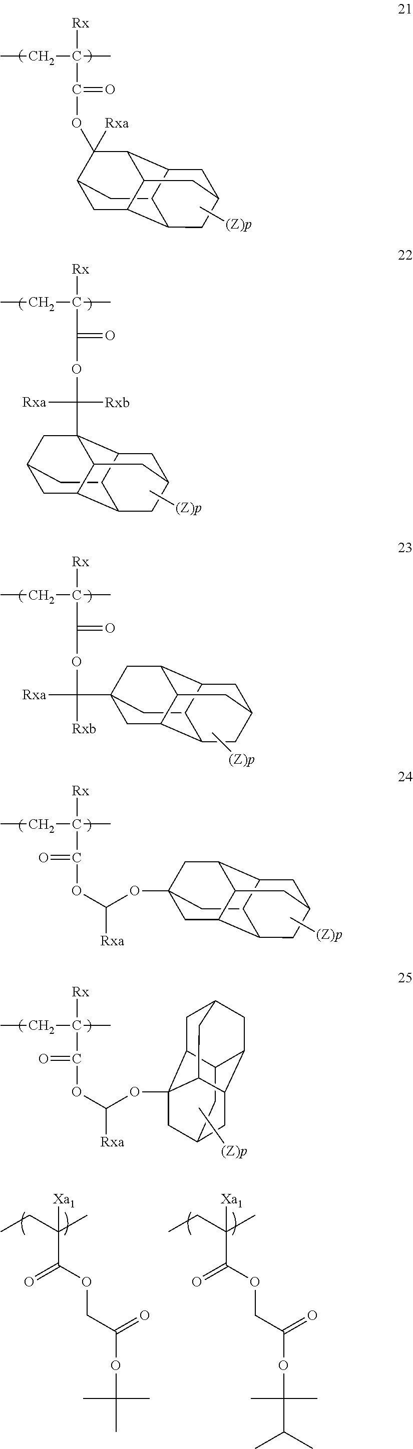

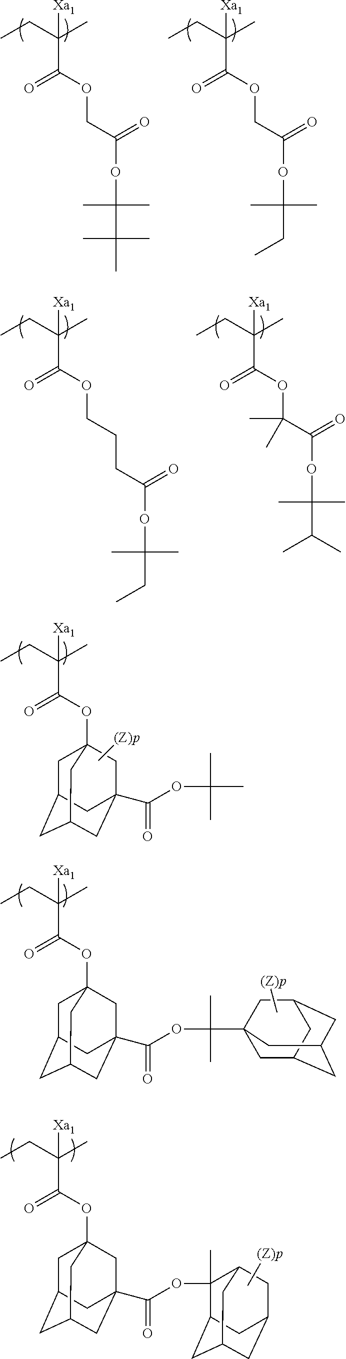

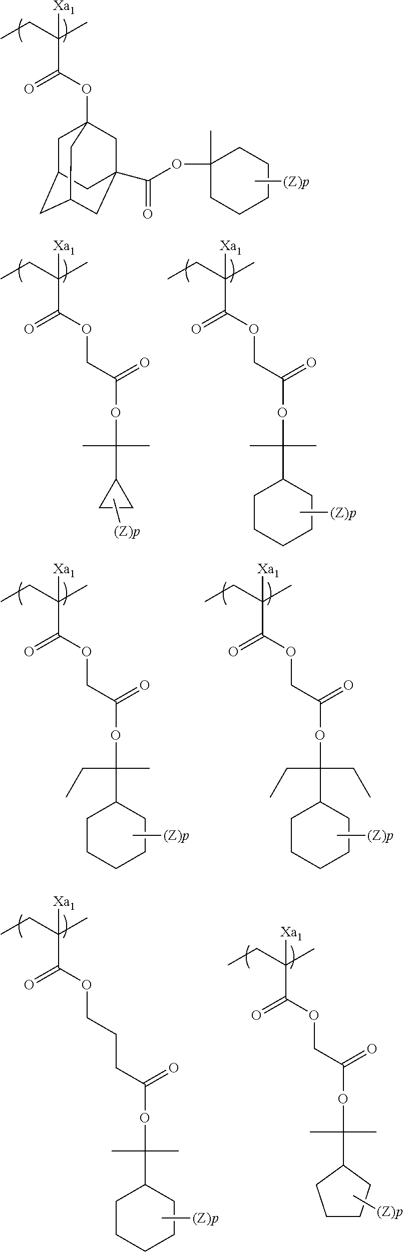

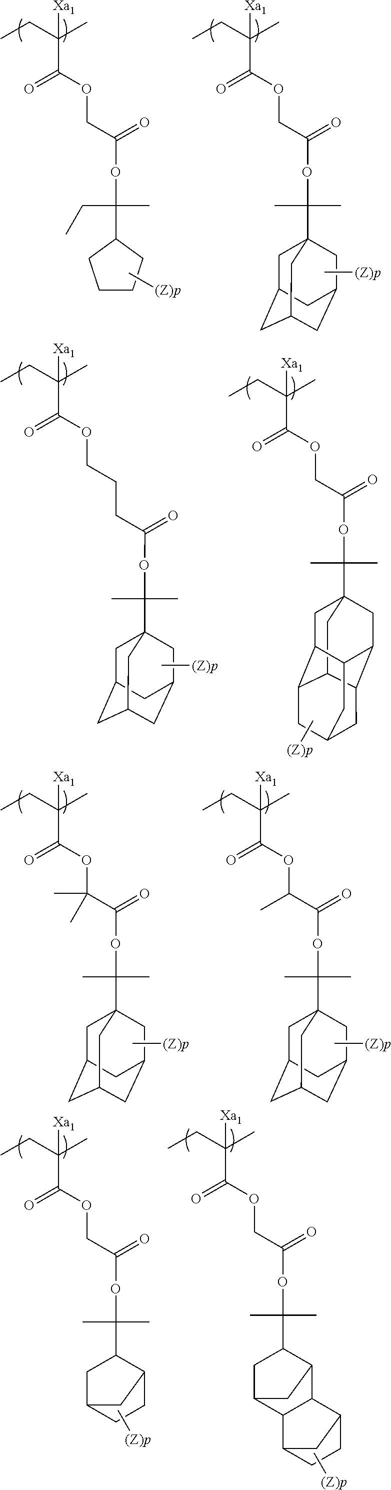

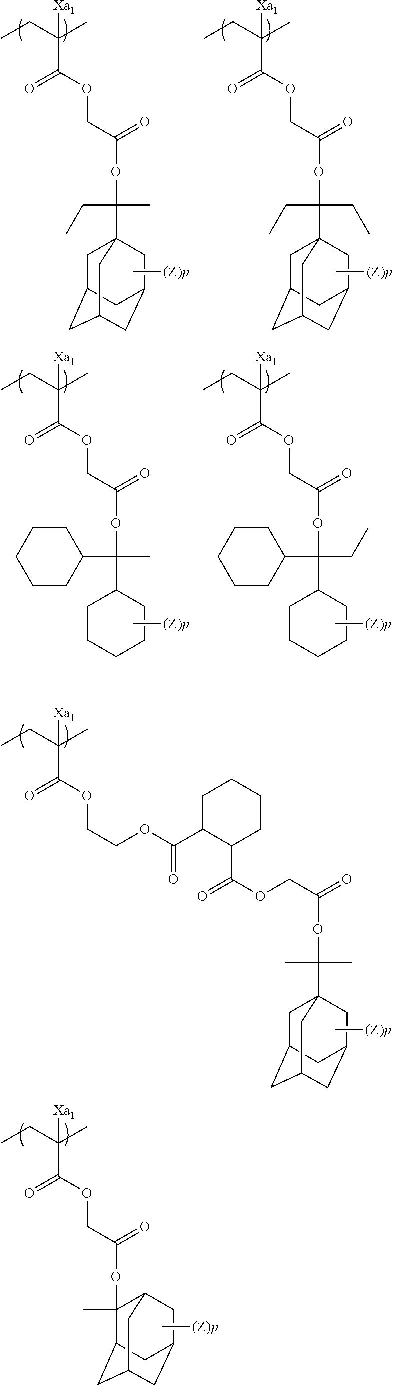

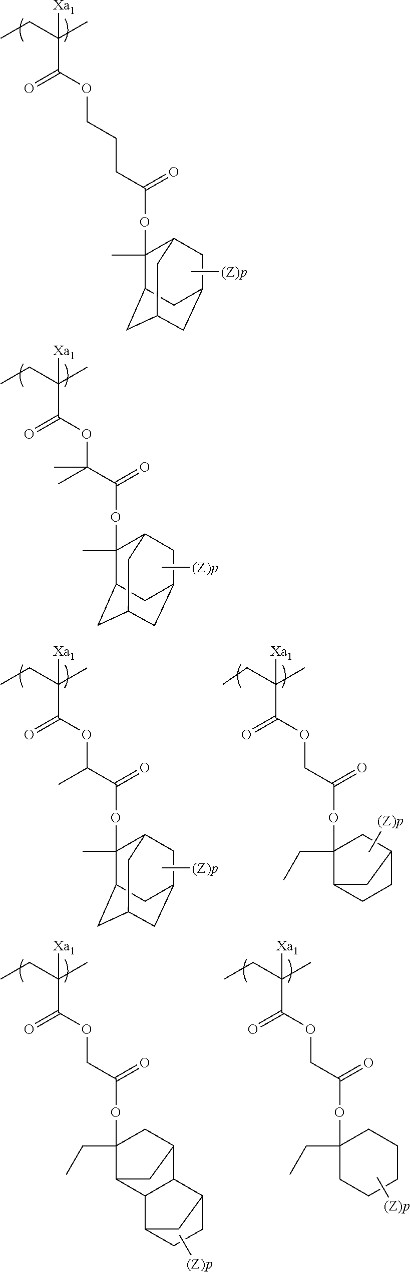

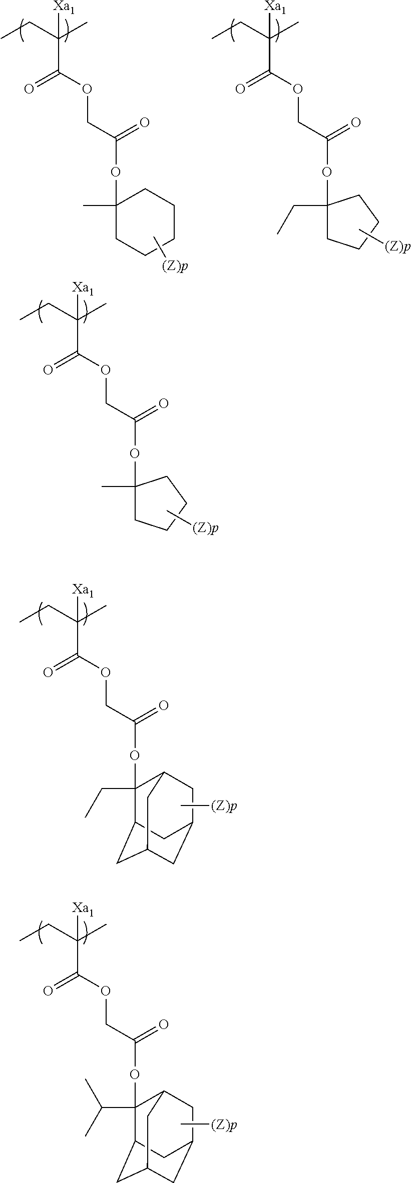

It is more preferable that the resin (B) have as the repeating units of the general formula (AI), at least any of the repeating units represented by the general formula (I) below and repeating units represented by the general formula (II) below.

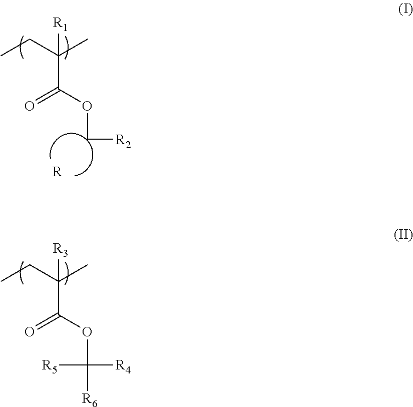

In the formulae (I) and (II),

each of R₁ and R₃ independently represents a hydrogen atom, a methyl group which may have a substituent, or a group represented by —CH₂—R₉. R₉ represents a monovalent organic group,

each of R₂, R₄, R₅, and R₆ independently represents an alkyl group or a cycloalkyl group, and

R represents an atomic group required for forming an alicyclic structure in cooperation with a carbon atom.

R₁ preferably represents a hydrogen atom, a methyl group, a trifluoromethyl group, or a hydroxymethyl group.

The alkyl group in R₂ may be linear or branched, and may have a substituent.

The cycloalkyl group in R₂ may be monocyclic or polycyclic, and may have a substituent.

R₂ is preferably an alkyl group, more preferably an alkyl group having 1 to 10 carbon atoms, and still more preferably an alkyl group having 1 to 5 carbon atoms. Examples thereof include a methyl group and an ethyl group.

R represents an atomic group required for forming an alicyclic structure in cooperation with a carbon atom. The alicyclic structure formed by R is preferably an alicyclic structure of a single ring, and preferably has 3 to 7 carbon atoms, and more preferably 5 or 6 carbon atoms.

R₃ is preferably a hydrogen atom or a methyl group, and more preferably a methyl group.

The alkyl group in R₄, R₅, or R₆ may be linear or branched, and may have a substituent. The alkyl group is one having 1 to 4 carbon atoms, such as a methyl group, an ethyl group, an n-propyl group, an isopropyl group, an n-butyl group, an isobutyl group, a t-butyl group, and the like.

The cycloalkyl group in R₄, R₅, or R₆ may be linear or branched, and may have a substituent. The cycloalkyl group is a monocyclic cycloalkyl group such as a cyclopentyl group, a cyclohexyl group, and the like, and a polycyclic cycloalkyl group such as a norbornyl group, a tetracyclodecanyl group, a tetracyclododecanyl group, an adamantyl group, and the like.

Examples of the repeating unit represented by the general formula (I) include a repeating unit represented by the following general formula (1-a).

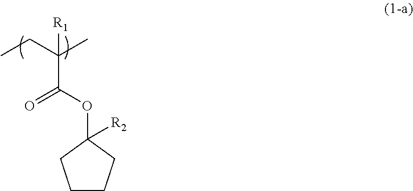

In the formula, R₁ and R₂ have the same meaning as those in the general formula (1).

The repeating unit represented by the general formula (II) is preferably a repeating unit represented by the following general formula (II-1).

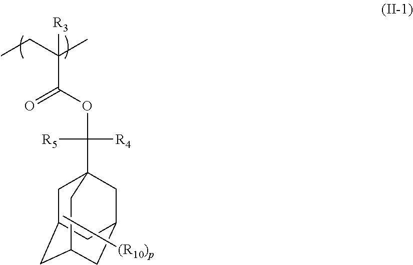

In the formula (II-1),

R₃ to R₅ have the same meaning as those in the general formula (II).

R₁₀ represents a substituent containing a polar group. In the case where a plurality of R₁₀'s are present, they may be the same as or different from each other. Examples of the substituent containing a polar group include a linear or branched alkyl group such as a hydroxyl group, a cyano group, an amino group, an alkylamido group, or sulfonamido group, and a cycloalkyl group, and preferably an alkyl group containing a hydroxyl group. The branched alkyl group is particularly preferably an isopropyl group.

p represents an integer of 0 to 15, preferably 0 to 2, and more preferably 0 or 1.

The acid-decomposable resin is preferably a resin including, as a repeating unit represented by the general formula (AI), at least one of a repeating unit represented by the general formula (I) and a repeating unit represented by the general formula (II). Further, in another embodiment, the acid-decomposable resin is more preferably a resin including, as a repeating unit represented by the general formula (AI), at least two of repeating units represented by the general formula (I).

In the case where the resin (B) includes a combination of the acid-decomposable repeating unit, preferable examples of the combination will be shown below. In the formulae below, each R independently represents a hydrogen atom or a methyl group.

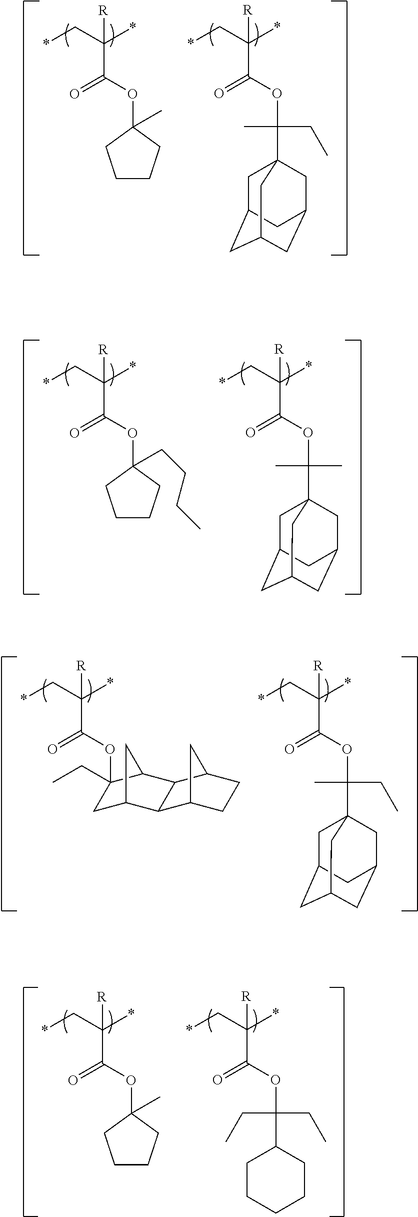

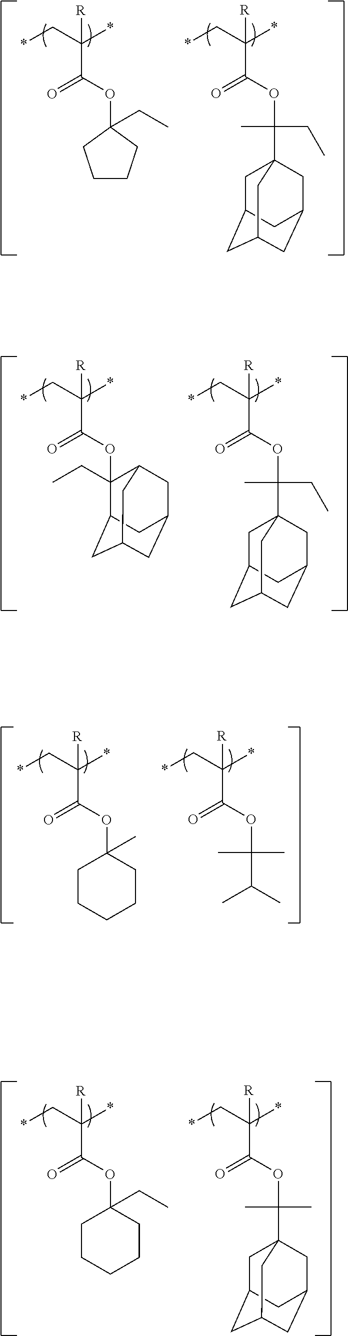

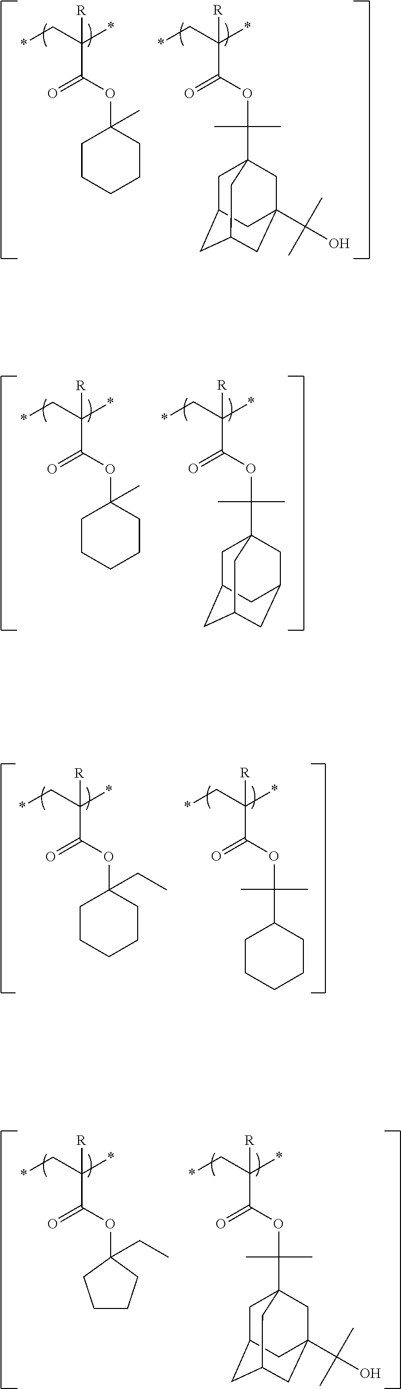

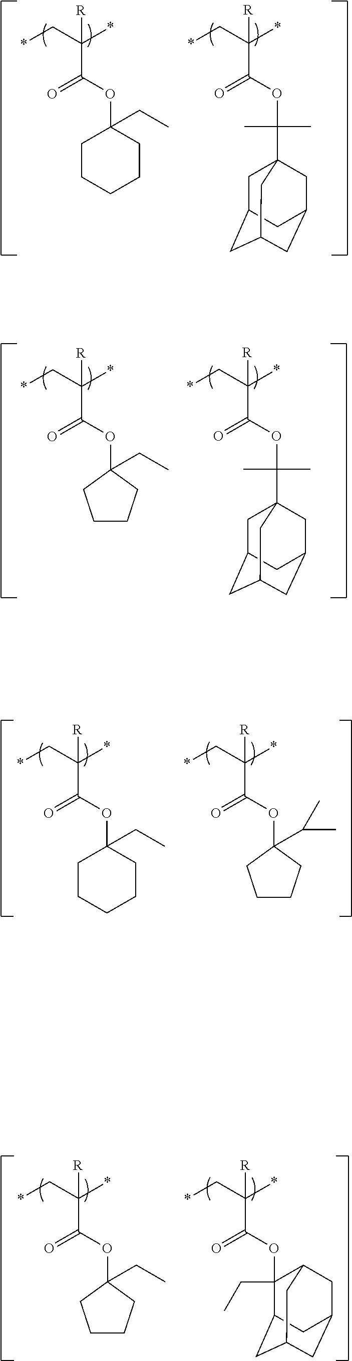

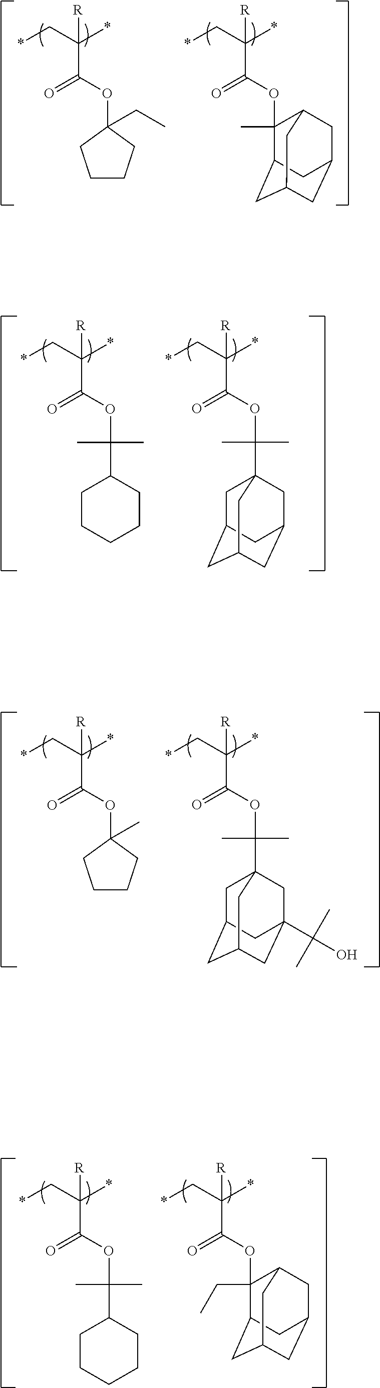

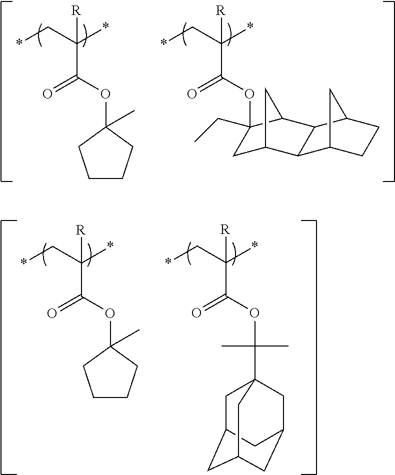

The resin (B) preferably includes a repeating unit having a lactone structure represented by the following general formula (III).

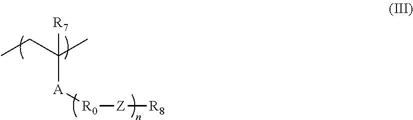

In the formula (III),

A represents an ester bond (a group represented by —COO—) or an amide bond (a group represented by —CONH—).

In the case where a plurality of R₀'s are present, each of them independently represents an alkylene group, a cycloalkylene group, or a combination thereof.

In the case where a plurality of Z's are present, each of them independently represents an ether bond, an ester bond, an amide bond, a urethane bond

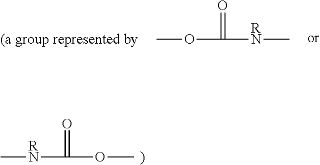

a urea bond.

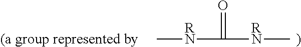

Here, R represents a hydrogen atom, an alkyl group, a cycloalkyl group, or an aryl group.

R₈ represents a monovalent organic group having a lactone structure.

n is the number of repetitions of the structure represented by —R₀—Z— and represents an integer of 1 to 5.

R₇ represents a hydrogen atom, a halogen atom, or an alkyl group.

The alkylene group or the cycloalkylene group of R₀ may have a substituent.

Z is preferably an ether bond or an ester bond, and particularly preferably an ester bond.

The alkyl group of R₇ is preferably an alkyl group having 1 to 4 carbon atoms, more preferably a methyl group or an ethyl group, and particularly preferably a methyl group. The alkyl group in R₇ may be substituted, and examples of the substituent include halogen atoms such as a fluorine atom, a chlorine atom, a bromine atom, and the like; a mercapto group; a hydroxyl group; an alkoxy group such as a methoxy group, an ethoxy group, an isopropoxy group, a t-butoxy group, benzyloxy group, and the like; an acyl group such as an acetyl group, a propionyl group, and the like; and an acetoxy group. R₇ is preferably a hydrogen atom, a methyl group, a trifluoromethyl group, or a hydroxymethyl group.

The chained alkylene group in R₀ is preferably a chained alkylene group having 1 to 10 carbon atoms, and more preferably having 1 to 5 carbon atoms, and examples thereof include a methylene group, an ethylene group, a propylene group or the like. The cycloalkylene group is preferably a cycloalkylene group having 1 to 20 carbon atoms, and examples thereof include cyclohexylene, cyclopentylene, norbornylene, adamantylene, and the like. The chained alkylene groups are preferred from the viewpoint of the exertion of the effect of the present invention, and a methylene group is particularly preferred.

The substituent having a lactone structure represented by R₈ is not limited as long as the lactone structure is contained. Specific examples thereof include the lactone structures of the general formulae (LC1-1) to (LC1-17) as described later, and among these, the structures represented by the general formula (LC1-4) are most preferred. Further, in (LC1-1) to (LC1-17), n_{z} is more preferably 2 or less.

Furthermore, R₈ preferably represents a monovalent organic group having an unsubstituted lactone structure or a monovalent organic group having a lactone structure substituted with a methyl group, a cyano group, or an alkoxycarbonyl group. More preferably, R₈ represents a monovalent organic group having a lactone structure substituted with a cyano group (cyanolactone).

Specific examples of the repeating units having groups having a lactone structure represented by the general formula (III) will be shown below, but the present invention is not limited thereto.

In the following specific examples, R represents a hydrogen atom, an alkyl group which may be substituted, or a halogen atom. Preferably, R represents a hydrogen atom, a methyl group, a hydroxymethyl group, or an acetoxymethyl group.

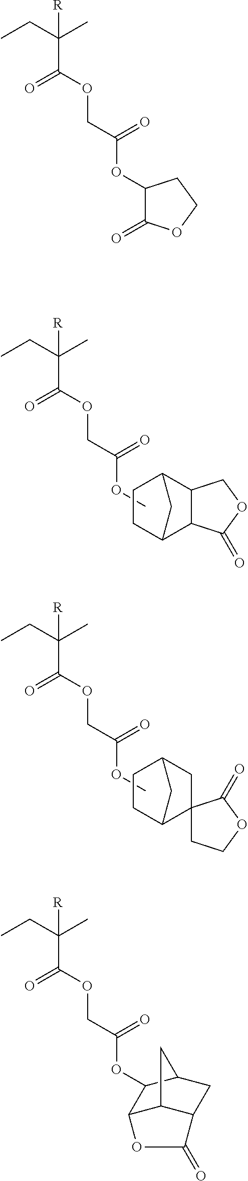

The repeating unit having a lactone structure is more preferably a repeating unit represented by the following general formula (III-1).

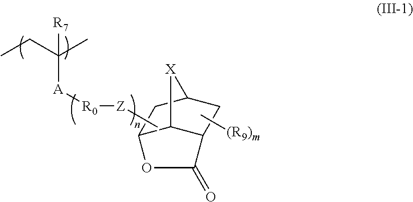

In the general formula (III-1),

R₇, A, R₀, Z, and n have the same meaning as those in the general formula (III).

In the case where a plurality of R₉'s are present, each of them may independently represent an alkyl group, a cycloalkyl group, an alkoxycarbonyl group, a cyano group, a hydroxyl group, or an alkoxy group, and in the case where a plurality of the groups are present, two of R₉ may be bonded to each other to form a ring,

X represents an alkylene group, an oxygen atom, or a sulfur atom, and

m is the number of the substituents, and represents an integer of 0 to 5. m is preferably 0 or 1.

The alkyl group of R₉ is preferably an alkyl group having 1 to 4 carbon atoms, more preferably a methyl group or an ethyl group, and most preferably a methyl group. Examples of the cycloalkyl group include a cyclopropyl group, a cyclobutyl group, a cyclopentyl group, and a cyclohexyl group. Examples of the alkoxycarbonyl group include a methoxycarbonyl group, an ethoxycarbonyl group, an n-butoxycarbonyl group, a t-butoxycarbonyl group, and the like. Examples of the substituent include a hydroxyl group, an alkoxy group such as a methoxy group, an ethoxy group, and the like, a cyano group, and a halogen atom such as a fluorine atom and the like. R₉ more preferably represents a methyl group, a cyano group, or an alkoxycarbonyl group, and still more preferably a cyano group.

Examples of the alkylene group of X include a methylene group, an ethylene group, and the like. Preferably, X is an oxygen atom or a methylene group, and more preferably a methylene group.

When m is 1 or more, the substitution site of at least one R₉ is preferably the α-position or β-position of the carbonyl group of the lactone. The substitution at the α-position is particularly preferred.

Specific examples of the repeating units having groups having a lactone structure represented by the general formula (III-1) will be shown below, but the present invention is not limited thereto. In the following specific examples, R represents a hydrogen atom, an alkyl group which may be substituted, or a halogen atom. Preferably, R represents a hydrogen atom, a methyl group, a hydroxymethyl group, or an acetoxymethyl group.

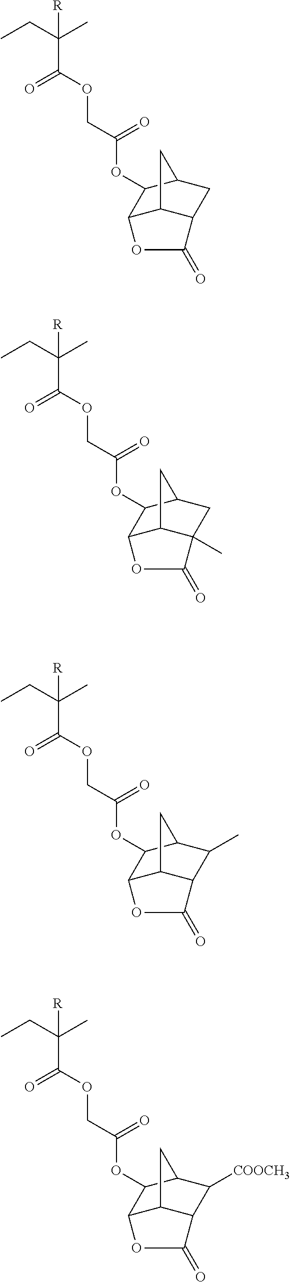

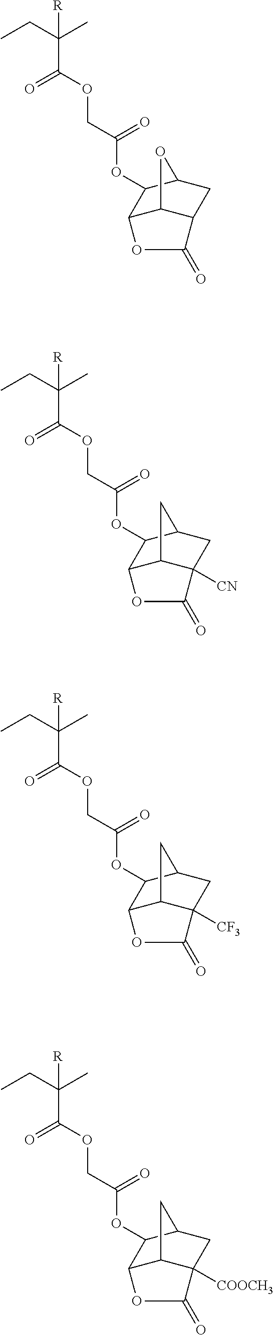

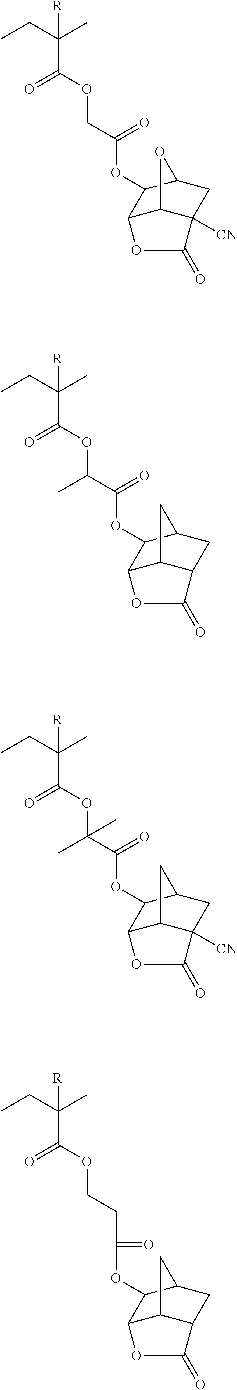

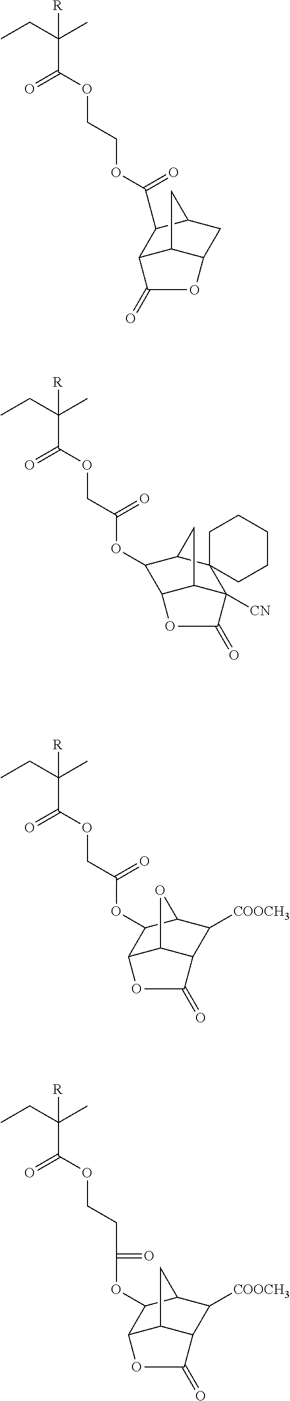

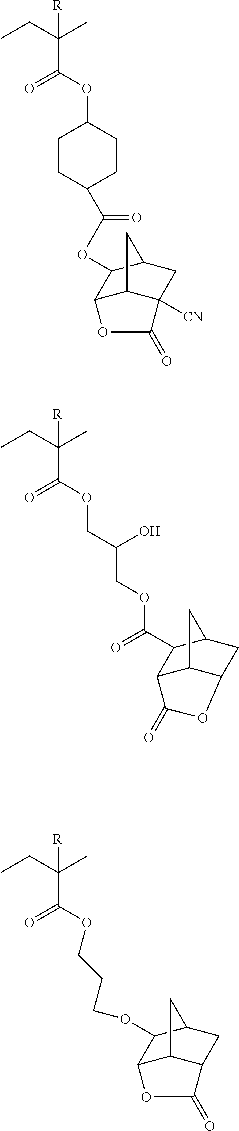

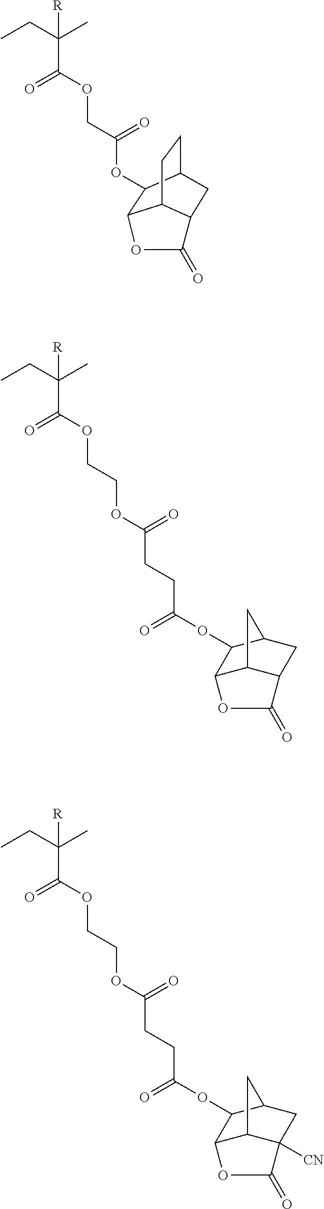

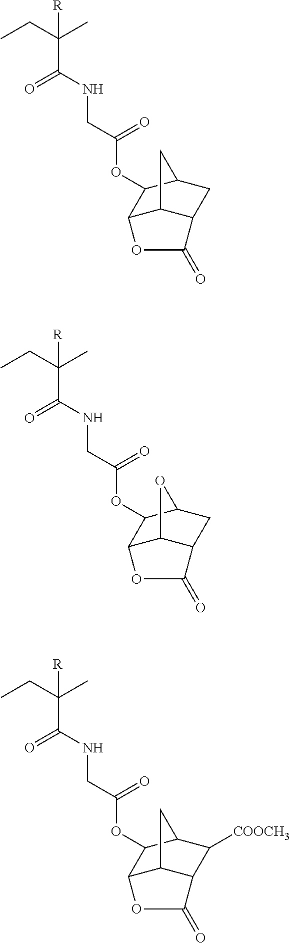

In the case where a plurality of kinds of the repeating units represented by the general formula (III) are present, the total content of the repeating units is preferably in the range of 15 to 60 mol %, more preferably 20 to 60 mol %, and still more preferably 30 to 50 mol %, based on all the repeating units in the resin.

The resin (B) may include a repeating unit having a lactone group other than the units represented by the general formula (III).

Any lactone group can be employed as long as it contains a lactone structure. However, lactone structures of 5- to 7-membered rings are preferred, and in particular, those resulting from condensation of lactone structures of 5- to 7-membered rings with other cyclic structures effected in a fashion to form a bicyclo structure or spiro structure are preferred. The possession of repeating units having a lactone structure represented by any of the following general formulae (LC1-1) to (LC1-17) is more preferred. The lactone structures may be directly bonded to the main chain of the resin. Preferred lactone structures are those of (LC1-1), (LC1-4), (LC₁₋₅), (LC1-6), (LC1-13), (LC1-14), and (LC1-17), and the use of these specified lactone structures ensures improvement in the LWR and development defect.

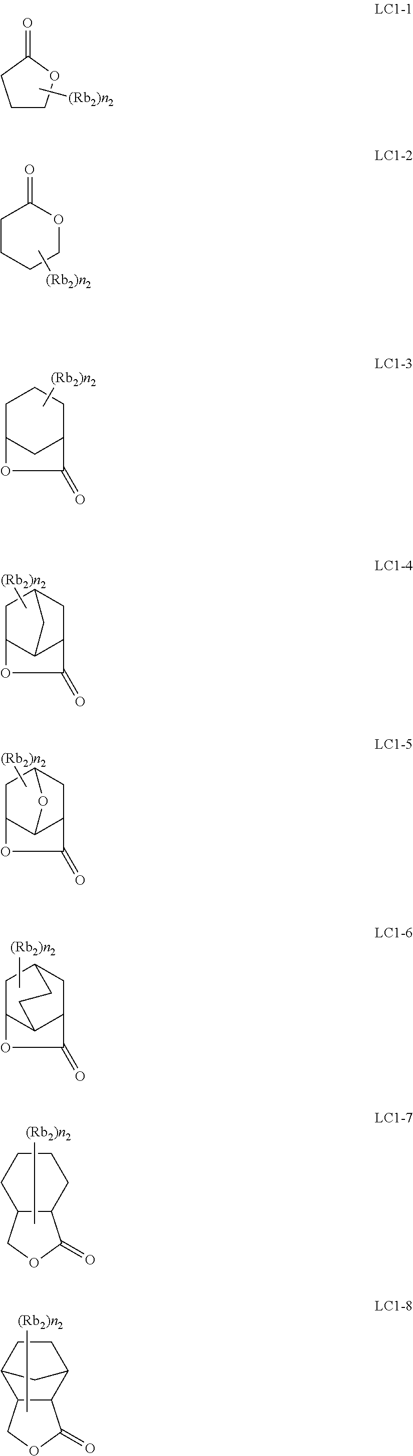

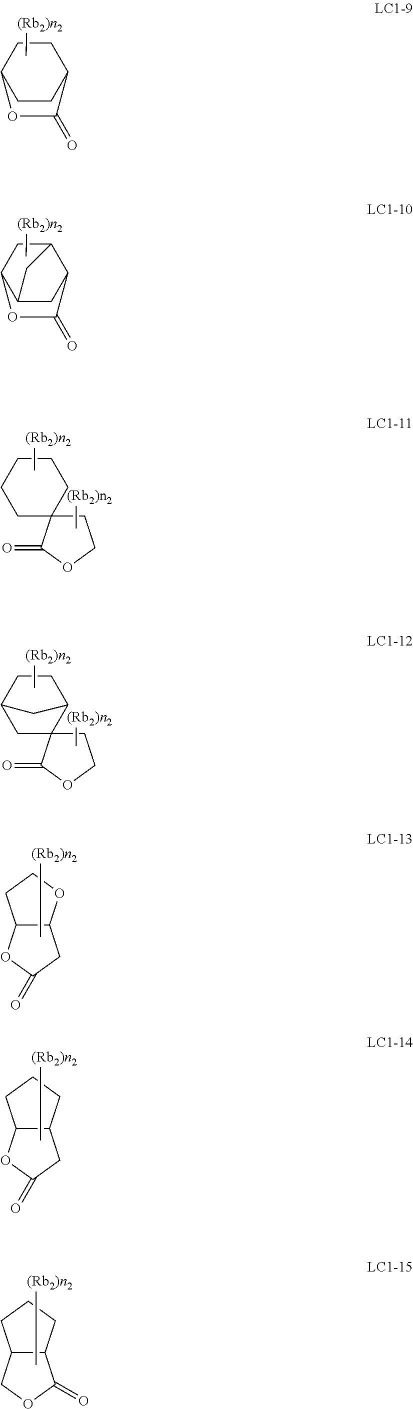

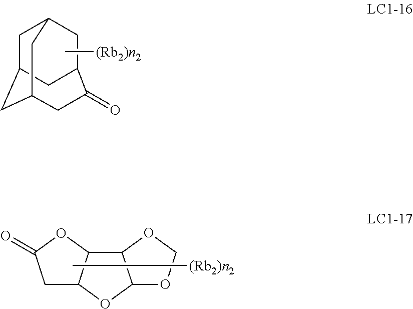

The portion of the lactone structure may not have a substituent (Rb₂). Examples of the substituent (Rb₂) preferably include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group, and the like, and more preferably an alkyl group having 1 to 4 carbon atoms, a cyano group, and an acid-decomposable group. In the formulae, n₂ represents an integer of 0 to 4. When n₂ is 2 or more, the plurality of present substituents (Rb₂) may be the same as or different from each other. Further, the plurality of present substituents (Rb₂) may be bonded to each other to form a ring.

The repeating units represented by the general formula (MP), below, can preferably be employed as the repeating units having a lactone structure other than the units represented by the general formula (III).

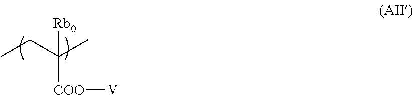

In the general formula (AII′),

Rb₀ represents a hydrogen atom, a halogen atom, or an alkyl group having 1 to 4 carbon atoms, which may be substituted. Examples of the preferable substituent which may be contained in the alkyl group of Rb₀ include a hydroxyl group and a halogen atom. Examples of the halogen atom of Rb₀ include a fluorine atom, a chlorine atom, a bromine atom, and an iodine atom. Preferable examples thereof include a hydrogen atom, a methyl group, a hydroxymethyl group, and a trifluoromethyl group, and a hydrogen atom and a methyl group are particularly preferred.

V represents a group having a structure represented by any represented by the general formulae (LC1-1) to (LC1-17).

Specific examples of the repeating units having a lactone group other than the units represented by the general formula (III) will be shown below, but the present invention is not limited thereto.

(In the formulae, Rx represents H, CH₃, CH₂OH, or CF₃)

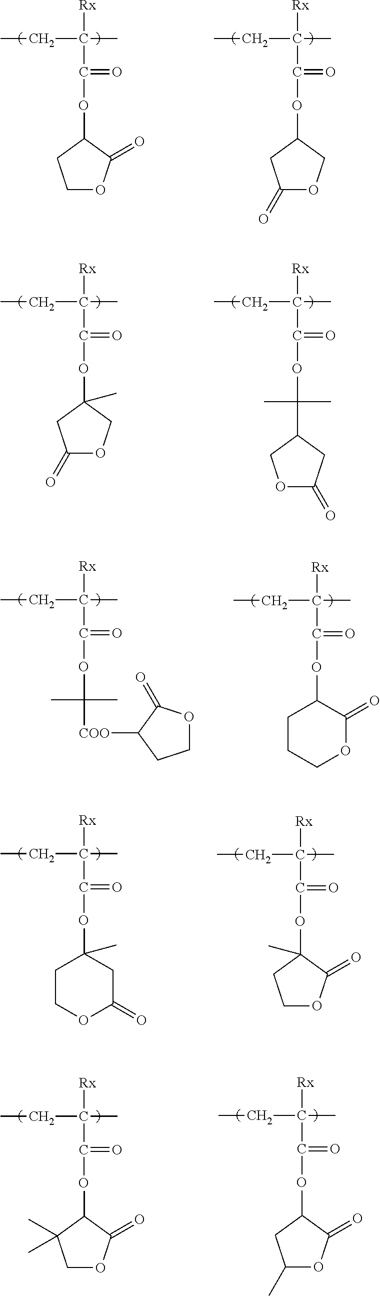

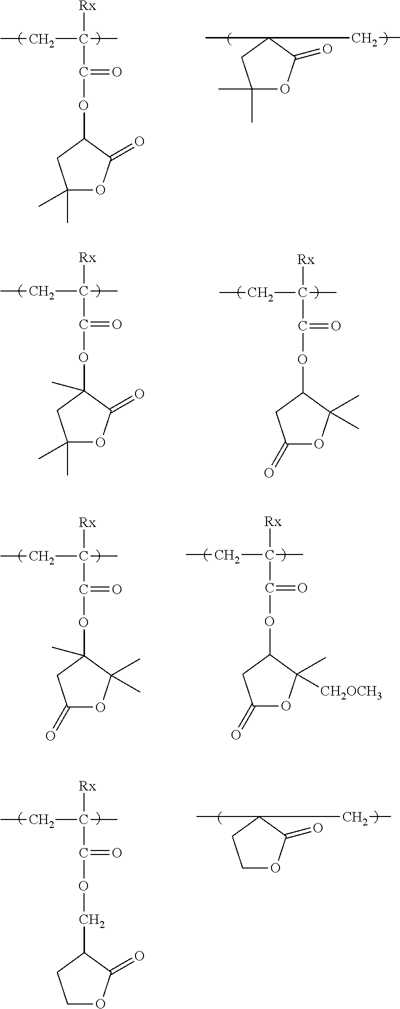

(In the formulae, Rx represents H, CH₃, CH₂OH, or CF₃)

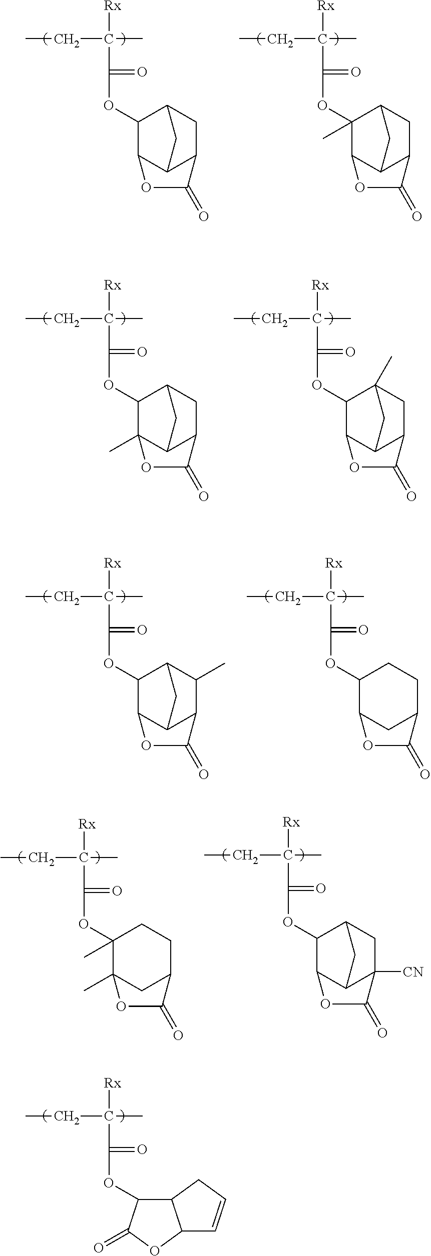

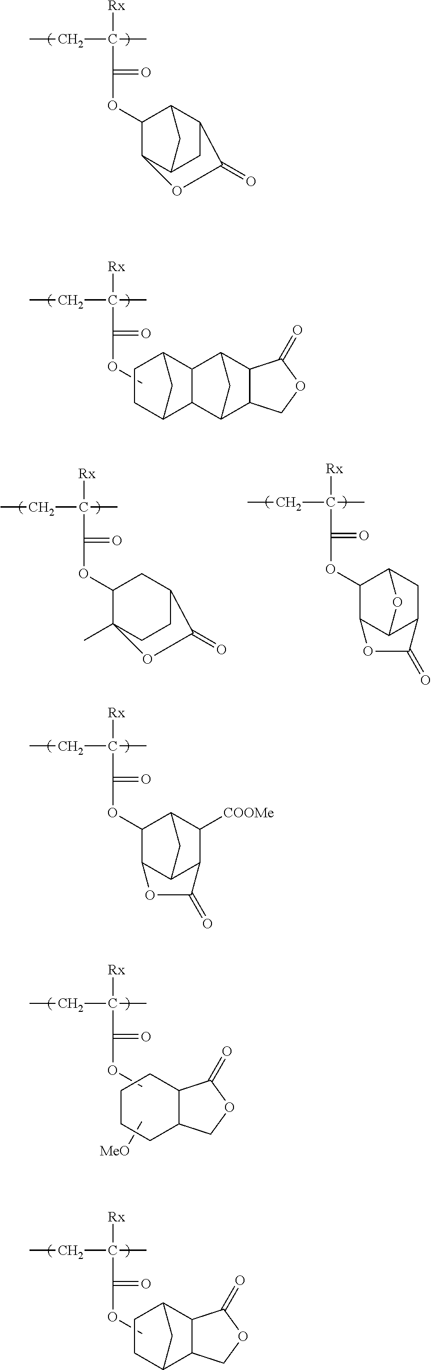

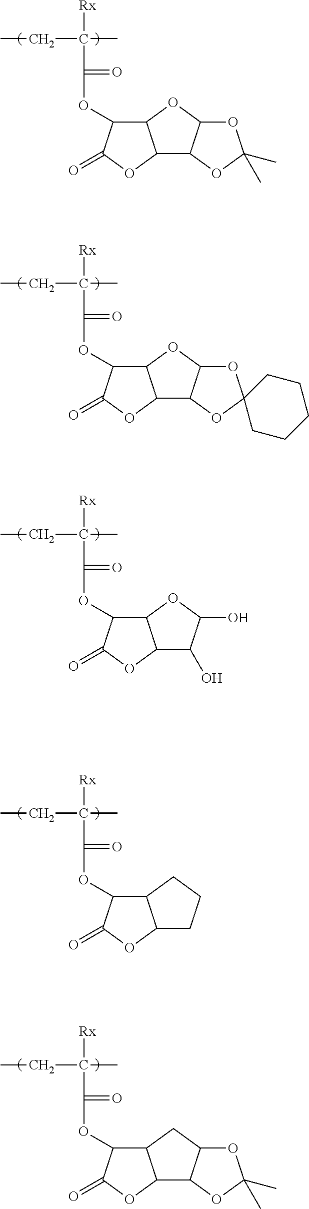

(In the formulae, Rx represents H, CH₃, CH₂OH, or CF₃)

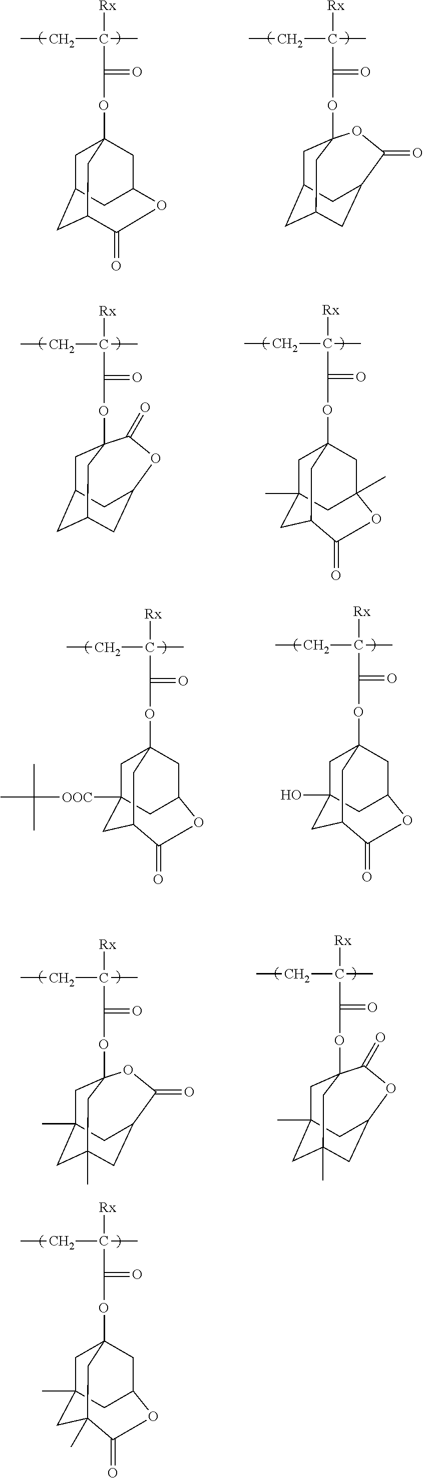

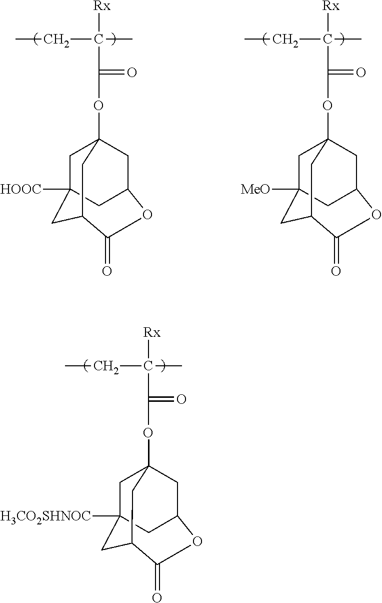

The repeating units other than the repeating units represented by the general formula (III), having a particularly preferred lactone group will be shown below. An improvement in pattern profile and iso-dense bias is attained by selection of the most appropriate lactone group.

(In the formulae, Rx represents H, CH₃, CH₂OH, or CF₃)

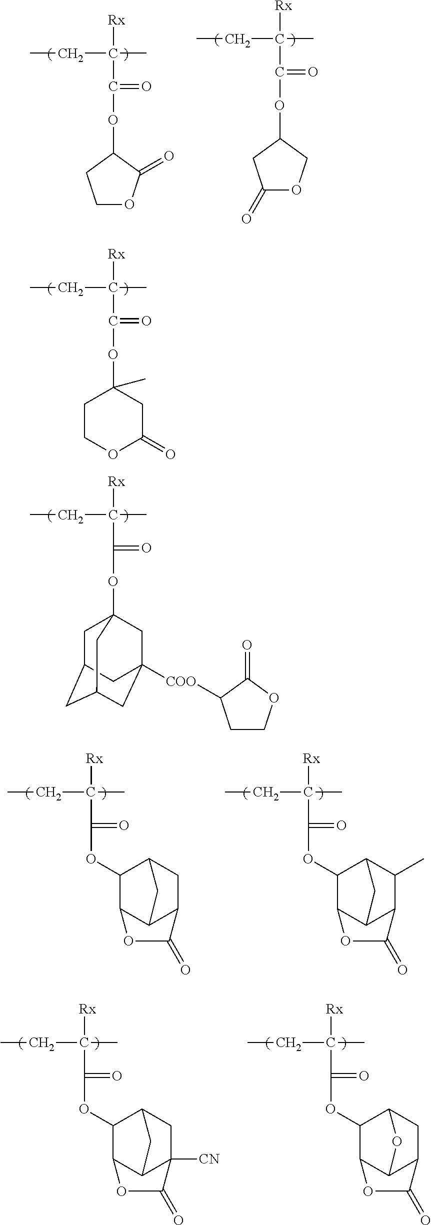

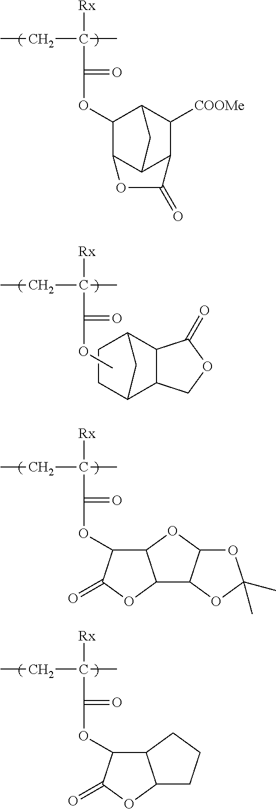

The repeating unit having a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or more, and more preferably 95% or more.

The content of the repeating units other than the repeating units represented by the general formula (III), having a lactone group, the sum thereof when a plurality of repeating units are contained, is preferably in the range of 15 to 60 mol %, more preferably 20 to 50 mol %, and still more preferably 30 to 50 mol %, based on all the repeating units in the resin.

Two or more kinds of lactone repeating units selected from among those represented by the general formula (III) can be simultaneously employed in order to enhance the effects of the present invention. In the case of combined use, it is preferable to select the two or more kinds from the lactone repeating units of the general formula (III) in which n is 1 and use a combination thereof.

It is preferable for the resin (B) to have a repeating unit other than the repeating units represented by the general formulae (AI) and (III), having a hydroxyl group or a cyano group. The possession of this repeating unit realizes enhancements of adhesion to substrate and developer affinity. The repeating unit having a hydroxyl group or a cyano group is preferably a repeating unit with a structure of alicyclic hydrocarbon substituted with a hydroxyl group or a cyano group, and preferably has no acid-decomposable group. In the alicyclic hydrocarbon structure substituted with a hydroxyl group or a cyano group, the alicyclic hydrocarbon structure preferably consists of an adamantyl group, a diamantyl group, or a norbornane group. The alicyclic hydrocarbon structures substituted with a hydroxyl group or a cyano group are preferably the partial structures represented by the following general formulae (VIIa) to (VIId).

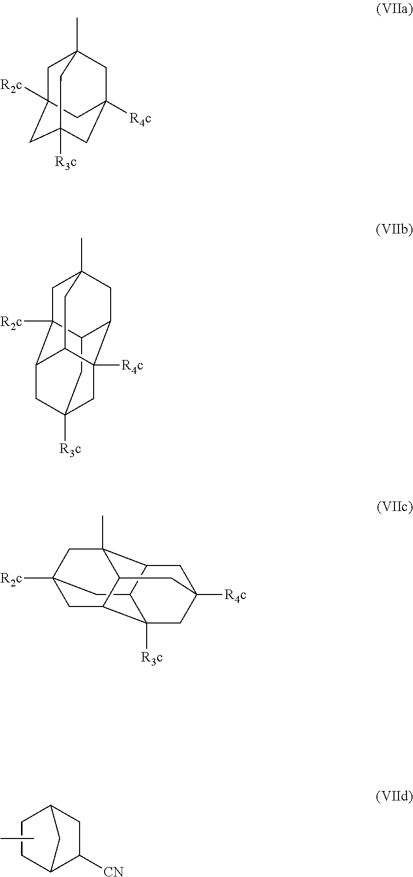

In the general formulae (VIIa) to (VIIc),

each of R₂c to R₄c independently represents a hydrogen atom, a hydroxyl group, or a cyano group, providing that at least one of R₂c to R₄c represents a hydroxyl group or a cyano group. Preferably, one or two of R₂c to R₄c are hydroxyl groups and the remainder are hydrogen atoms. In the general formula (VIIa), more preferably, two of the R_{2c} to R_{4c} are hydroxyl groups and the remainder are hydrogen atoms.

Examples of the repeating units having any of the partial structures of the general formulae (VIIa) to (VIId) include the repeating units represented by the following general formulae (AIIa) to (AIId).

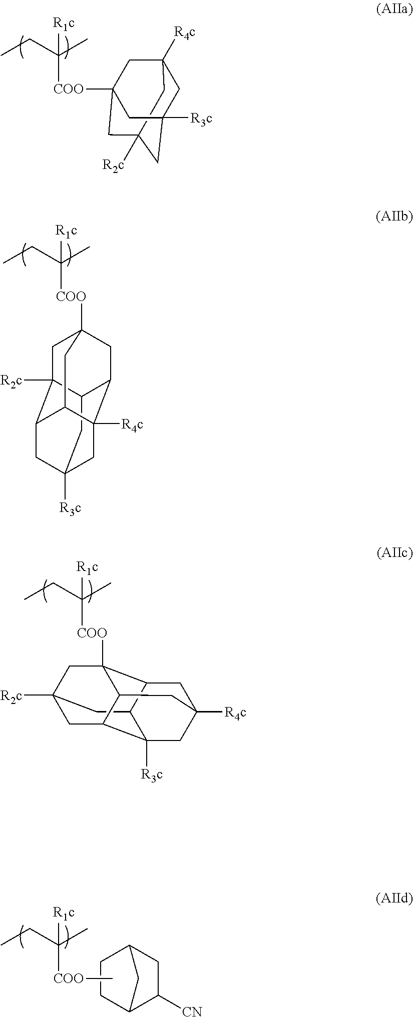

In the general formulae (AIIa) to (AIId),

R₁c represents a hydrogen atom, a methyl group, a trifluoromethyl group, or a hydroxymethyl group, and

R₂c to R₄c have the same meaning as R₂c to R₄c in the general formulae (VIIa) to (VIIc).

The content of the repeating unit having a hydroxyl group or a cyano group is preferably 5 to 40 mol %, more preferably 5 to 30 mol %, and still more preferably 10 to 25 mol %, based on all the repeating units of the resin (B).

Specific examples of the repeating units having a hydroxyl group or a cyano group will be shown below, but the present invention is not limited thereto.

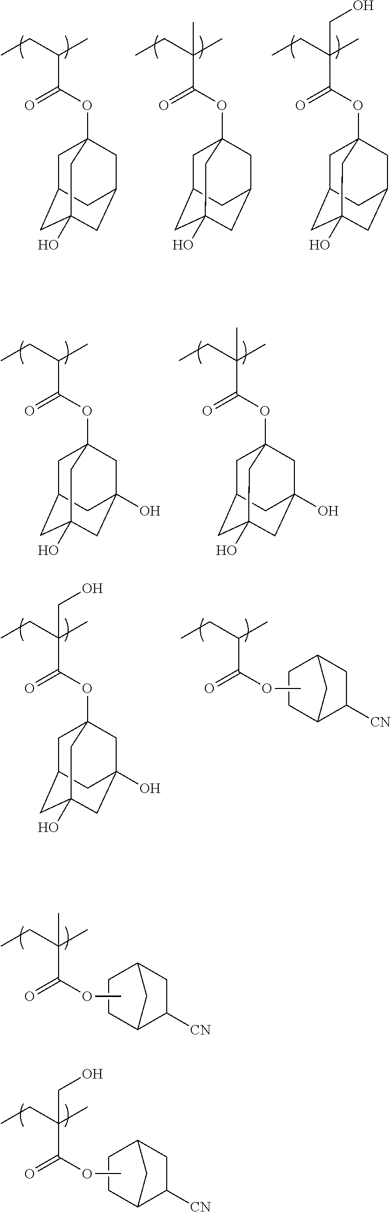

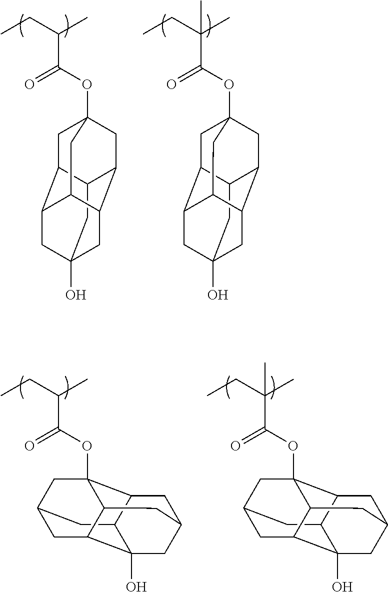

The resin used in the actinic-ray-sensitive or radiation-sensitive resin composition of the present invention may contain a repeating unit having an alkali-soluble group. Examples of the alkali-soluble group include a carboxyl group, a sulfonamido group, a sulfonylimido group, a bisulfonylimido group, and an aliphatic alcohol substituted at its α-position with an electron-withdrawing group (for example, a hexafluoroisopropanol group). The possession of a repeating unit having a carboxyl group is more preferred. The possession of the repeating unit having an alkali-soluble group increases the resolving power in contact hole usage. The repeating unit having an alkali-soluble group is preferably any of repeating units wherein the alkali-soluble group is directly bonded to the main chain of a resin such as a repeating unit of acrylic acid or methacrylic acid, a repeating unit wherein the alkali-soluble group is bonded via a linking group to the main chain of a resin and a repeating unit wherein the alkali-soluble group is introduced in a terminal of a polymer chain by the use of a chain transfer agent or polymerization initiator having the alkali-soluble group in the stage of polymerization. The linking group may have a monocyclic or polycyclic cyclohydrocarbon structure. The repeating unit of an acrylic acid or a methacrylic acid is particularly preferred.

The content of the repeating unit having an alkali-soluble group is preferably from 0 to 20 mol %, more preferably from 3 to 15 mol %, and still more preferably from 5 to 10 mol %, based on all the repeating units of the resin (B).

Specific examples of the repeating units having an alkali-soluble group will be shown below, but the present invention is not limited thereto.

In the formulae, Rx represents H, CH₃, CH₂OH, or CF₃.

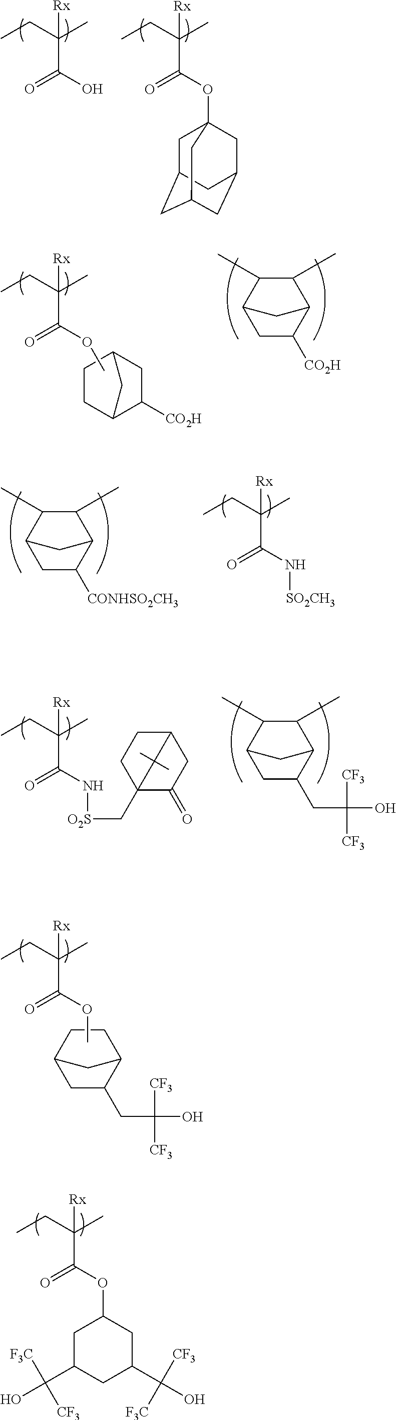

The resin (B) of the present invention can further contain a repeating unit that has a structure of an alicyclic hydrocarbon having no polar group, exhibiting no acid decomposability. Examples of such a repeating unit include any of the repeating units represented by the general formula (IV) below.

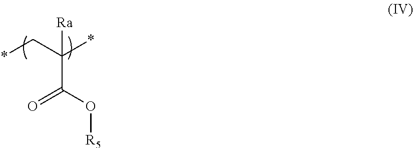

In the general formula (IV), R₅ represents a hydrocarbon group having at least one cyclic structure in which neither a hydroxyl group nor a cyano group is contained.

Ra represents a hydrogen atom, an alkyl group, or a —CH₂—O—Ra₂ group, in which Ra₂ represents a hydrogen atom, an alkyl group, or an acyl group. Ra preferably represents a hydrogen atom, a methyl group, a trifluoromethyl group, a hydroxymethyl group, or the like, and particularly preferably a hydrogen atom or a methyl group.

The cyclic structures contained in R₅ include a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group, a cyclooctyl group, and the like, or a cycloalkenyl group having 3 to 12 carbon atoms, such as a cyclohexenyl group and the like. Examples of the monocyclic hydrocarbon group preferably include a monocyclic hydrocarbon group having 3 to 7 carbon atoms, and more preferably a cyclopentyl group and a cyclohexyl group.

Examples of the polycyclic hydrocarbon group include a ring-assembly hydrocarbon group and a crosslinked-ring hydrocarbon group. Examples of the ring-assembly hydrocarbon group include a bicyclohexyl group, a perhydronaphthalene group, and the like. Examples of the crosslinked-ring hydrocarbon ring include a bicyclic hydrocarbon ring, such as a pinane ring, a bornane ring, a norpinane ring, a norbornane ring, a bicyclooctane ring (for example, a bicyclo[2.2.2]octane ring, a bicyclo[3.2.1]octane ring, and the like), etc.; a tricyclic hydrocarbon ring such as a homopaddlane ring, an adamantane ring, a tricyclo[5.2.1.0^{2,6}]decane ring, a tricyclo[4.3.1.1^{2,5}]undecane ring, and the like; and a tetracyclic hydrocarbon ring such as a tetracyclo[4.4.0.1^{2,5}.1^{7,10}]dodecane ring, a perhydro-1,4-methano-5,8-methanonaphthalene ring, and the like. Further, the crosslinked-ring hydrocarbon rings include a condensed-ring hydrocarbon ring, for example, a condensed rings formed by condensation of a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, a perhydrophenarene ring, and the like.

Examples of the preferable crosslinked-ring hydrocarbon ring include a norbornyl group, an adamantyl group, a bicyclooctanyl group, a tricyclo[5,2,1,0^{2,6}]decanyl group, and the like. Examples of the more preferable crosslinked-ring hydrocarbon ring include a norbornyl group and an adamantyl group.

These hydrocarbon groups may have substituents. Examples of the preferable substituents include a halogen atom, an alkyl group, a hydroxyl group protected by a protecting group, an amino group protected by a protecting group, and the like. The halogen atom is preferably a bromine, chlorine, or fluorine atom, and the alkyl group is preferably a methyl, ethyl, butyl, or t-butyl group. The alkyl group may further have a substituent, and examples of the substituent include a halogen atom, an alkyl group, a hydroxyl group protected by a protecting group, and an amino group protected by a protecting group.

Examples of the protecting group include an alkyl group, a cycloalkyl group, an aralkyl group, a substituted methyl group, a substituted ethyl group, an alkoxycarbonyl group, and an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl, or 2-methoxyethoxymethyl group. The substituted ethyl group is preferably a 1-ethoxyethyl or 1-methyl-1-methoxyethyl group. The acyl group is preferably an aliphatic acyl group having 1 to 6 carbon atoms, such as a formyl group, an acetyl group, a propionyl group, a butyryl group, an isobutyryl group, a valeryl group, a pivaloyl group, and the like. Examples of the alkoxycarbonyl group include an alkoxycarbonyl group having 1 to 4 carbon atoms, and the like.

The content of the repeating units that have a structure of alicyclic hydrocarbon having no polar group and exhibiting no acid decomposability is preferably from 0 to 40 mol %, and more preferably from 0 to 20 mol %, based on all the repeating units of resin (B).

Specific examples of the repeating units that have a structure of alicyclic hydrocarbon having no polar group, and exhibiting no acid decomposability will be shown below, but the present invention is not limited thereto. In the formulae, Ra represents H, CH₃, CH₂OH, or CF₃.

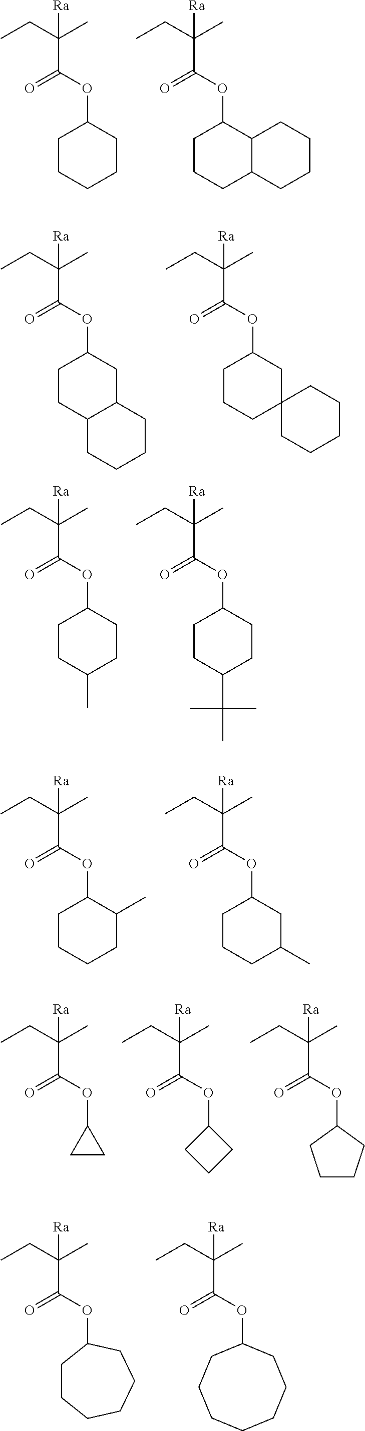

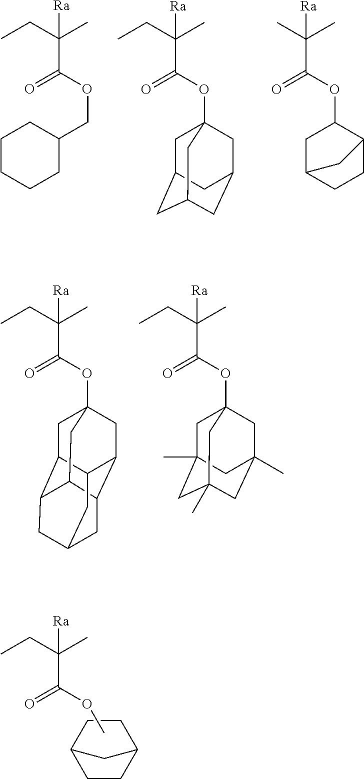

The Resin (B) used in the composition of the present invention may have, in addition to the above-described repeating structural units, various repeating structural units for the purpose of regulating the dry etching resistance, standard developer adaptability, substrate adhesion, resist profile and generally required properties of the resist such as resolving power, heat resistance, sensitivity, and the like.

Examples of such a repeating structural unit include the repeating structural units corresponding to the following monomers, which however are nonlimiting.

The use of such repeating structural units would enable fine regulation of the required properties of the resin used in the composition of the present invention, in particularly, (1) solubility in applied solvents, (2) film forming easiness (glass transition point), (3) alkali developability, (4) film thinning (selection of hydrophilicity/hydrophobicity and alkali-soluble groups), (5) adhesion of unexposed area to a substrate, (6) dry etching resistance, and the like.

Examples of such a monomer include a compound having an unsaturated bond, capable of addition polymerization, which is selected from acrylic esters, methacrylic esters, acrylamides, methacrylamides, allyl compounds, vinyl ethers, vinyl esters, and the like; etc.

In addition, any unsaturated compound capable of addition polymerization that is copolymerizable with monomers corresponding to the above various repeating structural units may be copolymerized therewith.

The molar ratios of the respective repeating structural units in the resin (B) used in the composition of the present invention are appropriately determined from the viewpoint of regulation of not only the dry etching resistance of the resist but also the standard developer adaptability, substrate adhesion, resist profile, and generally required performances of the resist, such as the resolution power, heat resistance, sensitivity, and the like. It is ensured that the content of the respective repeating structural units used in the resin (B) is no more than 100 mol % in total.

When the composition of the present invention is one for ArF exposure, it is preferable for the resin (B) used in the composition of the present invention to have no aromatic group from the viewpoint of transparency to an ArF beam. More specifically, the proportion of the repeating units having aromatic group is preferably 5 mol % or less in total in all the repeating units of the resin (B), and more preferably 3 mol % or less, or still more preferably, the repeating unit having an aromatic group is not contained. Further, the resin (B) preferably has a monocyclic or polycyclic alicyclic hydrocarbon structure.

Further, from the viewpoint of the compatibility with the hydrophobic resin as described later, it is preferable for the resin (B) to contain neither a fluorine atom nor a silicon atom.

Further, in the resin (B) used in the composition of the present invention, preferably, all the repeating units consist of (meth)acrylate-based repeating units. In this case, use can be made of any of resins (B), wherein all the repeating units consist of methacrylate-based repeating units, wherein all the repeating units consist of acrylate-based repeating units, and wherein all the repeating units consist of methacrylate-based repeating units and acrylate-based repeating units. However, it is preferable for the acrylate-based repeating units to account for 50 mol % or less of all the repeating units. In addition, a copolymer containing 20 to 50 mol % of (meth)acrylate-based repeating units having an acid-decomposable group, 20 to 50 mol % of (meth)acrylate-based repeating units having a lactone group, 5 to 30 mol % of (meth)acrylate-based repeating units having an alicyclic hydrocarbon structure substituted with a hydroxyl group or a cyano group, and 0 to 20 mol % of other (meth)acrylate-based repeating units is also preferable.

In the case where the composition of the present invention is irradiated with an KrF excimer laser beam, an electron beam, X-rays, or high-energy light rays at a wavelength of 50 nm or less (for example, EUV), it is preferable for the resin (B) to have hydroxystyrene repeating units. More preferably, the resin (B) is a copolymer of hydroxystyrene with hydroxystyrene protected by a group that is cleaved by the action of an acid (which may also be a three-dimensional or higher resin containing polymerization units other than the aforementioned groups), or a copolymer of hydroxystyrene with a (meth)acrylic acid tertiary alkyl ester (which may also be a three-dimensional or higher resin containing polymerization units other than the aforementioned groups).

Specific examples of such a resin include a resin (B′) having repeating units represented by the following general formula (A).

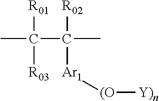

In the formula, each of R₀₁, R₀₂, and R₀₃ independently represents, for example, a hydrogen atom, an alkyl group, a cycloalkyl group, a halogen atom, a cyano group, or an alkoxycarbonyl group. Ar₁ represents, for example, an aromatic ring group. Further, R₀₃ and Ar₁ may be alkylene groups and bonded to each other so as to form a 5- or 6-membered ring in cooperation with a —C—C— chain.

Each of n Y's independently represents a hydrogen atom or a group that is cleaved by the action of an acid, provided that at least one of n Y's is a group that is cleaved by the action of an acid.

In the formula, n is an integer of 1 to 4, preferably 1 or 2, and more preferably 1.

The alkyl group as each of R₀₁ to R₀₃ is preferably an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, or a dodecyl group. An alkyl group having 8 or less carbon atoms is more preferred. Further, these alkyl groups may have a substituent.

The alkyl group contained in the alkoxycarbonyl group is preferably the same as the alkyl group mentioned above with respect to R₀₁ to R₀₃.

The cycloalkyl group may be monocyclic or polycyclic. A monocyclic alkyl group having 3 to 8 carbon atoms, such as a cyclopropyl group, a cyclopentyl group, a cyclohexyl group, and the like, is preferred. These cycloalkyl groups may have a substituent.

Examples of the halogen atom include a fluorine atom, a chlorine atom, a bromine atom, and an iodine atom. A fluorine atom is preferred.

In the case where R₀₃ represents an alkylene group, the alkylene group is preferably an alkylene group having 1 to 8 carbon atoms, such as a methylene group, an ethylene group, a propylene group, a butylene group, a hexylene group, an octylene group, and the like.

The aromatic ring as Ar₁ is preferably an aromatic ring having 6 to 14 carbon atoms, such as a benzene ring, a toluene ring, and a naphthalene ring. Further, these aromatic rings may have a substituent.

Examples of the group Y that is cleaved by the action of an acid include groups represented by —C(R₃₆)(R₃₇)(R₃₈), —C(R₀₁)(R₀₂)(OR₃₉), —C(═O)—O—C(R₃₆)(R₃₇)(R₃₈), —C(R₀₁)(R₀₂)—C(═O)—O—C(R₃₆)(R₃₇)(R₃₈), and —CH(R₃₆)(Ar).

In the formulae, each of R₃₆ to R₃₉ independently represents an alkyl group, a cycloalkyl group, an aryl group, an aralkyl group, or an alkenyl group. R₃₆ and R₃₇ may be bonded to each other to form a ring structure.

Each of R₀₁ to R₀₂ independently represents a hydrogen atom, an alkyl group, a cycloalkyl group, an aryl group, an aralkyl group, or an alkenyl group.

Ar represents an aryl group.

The alkyl group of R₃₆ to R₃₉, R₀₁, or R₀₂ is preferably an alkyl group having 1 to 8 carbon atoms, and examples thereof include a methyl group, an ethyl group, a propyl group, an n-butyl group, a sec-butyl group, a hexyl group, and octyl group.

The cycloalkyl groups as R₃₆ to R₃₉, R₀₁, or R₀₂ may be a monocyclic cycloalkyl group or a polycyclic cycloalkyl group. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, and a cyclooctyl group. The polycyclic cycloalkyl group is preferably a cycloalkyl group having 6 to 20 carbon atoms, and examples thereof include an adamantyl group, a norbornyl group, an isobornyl group, a camphonyl group, a dicyclopentyl group, an α-pinel group, a tricyclodecanyl group, a tetracyclododecyl group, and an androstanyl group. Further, the carbon atoms of each of the cycloalkyl groups may be partially substituted with a heteroatom, such as an oxygen atom and the like.

The aryl group of each of R₃₆ to R₃₉, R₀₁, R₀₂, or Ar is preferably an aryl group having 6 to 10 carbon atoms. Examples thereof include a phenyl group, a naphthyl group, and an anthryl group.

The aralkyl groups as R₃₆ to R₃₉, R₀₁, or R₀₂ are preferably aralkyl groups having 7 to 12 carbon atoms, and preferable examples thereof include a benzyl group, a phenethyl group, and a naphthylmethyl group.

The alkenyl groups of each of R₃₆ to R₃₉, R₀₁, and R₀₂ are preferably alkenyl groups having 2 to 8 carbon atoms, and examples thereof include a vinyl group, an allyl group, a butenyl group, and a cyclohexenyl group.

The ring formed by the mutual bonding of R₃₆ and R₃₇ may be monocyclic or polycyclic. The monocyclic structure is preferably an aliphatic hydrocarbon ring structure having 3 to 8 carbon atoms, and examples thereof include a cyclopropane structure, a cyclobutane structure, a cyclopentane structure, a cyclohexane structure, a cycloheptane structure, and a cyclooctane structure. The polycyclic structure is preferably an aliphatic hydrocarbon ring structure having 6 to 20 carbon atoms, and examples thereof include an adamantane structure, a norbornane structure, a dicyclopentane structure, a tricyclodecane structure, and a tetracyclododecane structure. Further, the carbon atoms of each of the aliphatic hydrocarbon ring structures may be partially substituted with a heteroatom, such as an oxygen atom and the like.

Each of the groups of R₃₆ to R₃₉, R₀₁, R₀₂, and Ar may have a substituent, and examples of the substituent include an alkyl group, a monovalent aliphatic hydrocarbon ring group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. Substituents having 8 or less carbon atoms are preferred.

The group that is cleaved by the action of an acid, Y, is more preferably a structure represented by the following general formula (B).

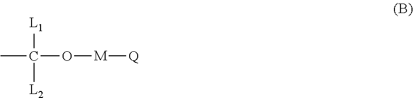

In the formula,

each of L₁ and L₂ independently represents a hydrogen atom, an alkyl group, a cycloalkyl group, an aryl group, or an aralkyl group.

M represents a single bond or a divalent linking group.

Q represents an alkyl group, an alicyclic group, an aromatic ring group, an amino group, an ammonium group, a mercapto group, a cyano group, or an aldehyde group. Further, these alicyclic groups and aromatic ring groups may contain heteroatoms.

Further, at least two of Q, M, and L₁ may be bonded to each other to form a 5- or 6-membered ring.

The alkyl groups as L₁ and L₂ are, for example, alkyl groups having 1 to 8 carbon atoms, and specific examples thereof include a methyl group, an ethyl group, a propyl group, an n-butyl group, a sec-butyl group, a hexyl group, and an octyl group.

The cycloalkyl groups as L₁ and L₂ are, for example, cycloalkyl groups each having 3 to 15 carbon atoms, and specific examples thereof include a cyclopentyl group, a cyclohexyl group, a norbornyl group, and an adamantyl group.

The aryl groups as L₁ and L₂ are, for example, aryl groups having 6 to 15 carbon atoms, and specific examples thereof include a phenyl group, a tolyl group, a naphthyl group, and an anthryl group.

The aralkyl groups as L₁ and L₂ are, for example, aralkyl groups having 6 to 20 carbon atoms, and specific examples thereof include a benzyl group and a phenethyl group.

The bivalent linking group as M is, for example, an alkylene group (for example, a methylene group, an ethylene group, a propylene group, a butylene group, a hexylene group, and an octylene group), a cycloalkylene group (for example, a cyclopentylene group and a cyclohexylene group), an alkenylene group (for example, an ethylene group, a propenylene group, and a butenylene group), an arylene group (for example, a phenylene group, a tolylene group, and a naphthylene group), —S—, —O—, —CO—, —SO₂—, —N(R₀)—, or a bivalent linking group resulting from combination of two or more of these groups. Here, R₀ represents a hydrogen atom or an alkyl group, and the alkyl group as R₀ is preferably an alkyl group having 1 to 8 carbon atoms. Specific examples of the alkyl group include a methyl group, an ethyl group, a propyl group, an n-butyl group, a sec-butyl group, a hexyl group, and an octyl group.

The alkyl group as Q is the same as the alkyl group mentioned above with respect to L₁ and L₂.

Examples of the alicyclic group or the aromatic ring group as Q include the cycloalkyl group and the aryl group mentioned above with respect to L₁ and L₂, which are preferably groups having 3 to 15 carbon atoms.

Examples of the alicyclic group containing a heteroatom and the aromatic ring group containing a heteroatom as Q include groups each having a heterocyclic structure, such as thiirane, cyclothiolane, thiophene, furan, pyrrole, benzothiophene, benzofuran, benzopyrrole, triazine, imidazole, benzimidazole, triazole, thiadiazole, triazole, pyrrolidone, and the like. However, the alicyclic group containing a heteroatom and the aromatic ring group containing a heteroatom are not limited to these as long it is a ring formed by carbon and a heteroatom or a ring formed by heteroatoms.

Examples of the ring that may be formed by the mutual bonding of at least two of Q, M, and L₁ include a 5- or 6-membered ring including at least two of Q, M, and L₁ so as to form a propylene group or a butylene group, and the 5- or 6-membered ring may contain an oxygen atom.

In the general formula (B), each of the groups represented by L₁, L₂, M, and Q may have a substituent. Examples of the substituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. Preferably, the number of carbon atoms of each of the substituents is 8 or less.

The group represented by the formula -(M-Q) is preferably a group having 1 to 30 carbon atoms, and more preferably a group having 5 to 20 carbon atoms. The group having 6 or more carbon atoms is particularly preferred from the viewpoint of outgas suppression.

Further examples of another preferable resin (B′) include a resin having the repeating units represented by the general formula (AI).

The content of the repeating units represented by the general formula (AI) in the resin (B)′ is preferably in the range of 3 to 90 mol %, more preferably 5 to 80 mol %, and particularly preferably 7 to 70 mol %, based on all the repeating units.

The resin suitable for KrF, EB, EUV, or the like may further contain repeating units other than the aforementioned repeating units. Preferable examples of such other repeating units include repeating units that are stable against the action of an acid, repeating units having lactone structures, and the like.

Here, specific examples of the repeating units that are stable against the action of an acid include the repeating units in which a non-acid-decomposable aryl structure or cycloalkyl structure is introduced in a side chain of the acrylic structure, such as repeating unit represented by the general formula (IV) [provided that specific examples of the cyclic structure contained in R₅ preferably include a monocyclic or polycyclic cycloalkyl group (preferably having 3 to 12 carbon atoms, and more preferably having 3 to 7 carbon atoms), a monocyclic or polycyclic cycloalkenyl group (preferably having 3 to 12 carbon atoms), an aryl group (preferably having 6 to 20 carbon atoms, and more preferably having 6 to 12 carbon atoms), an aralkyl group (preferably having 7 to 20 carbon atoms, and more preferably having 7 to 12 carbon atoms), and the like]. By the introduction of this structure, attainment of contrast regulation, enhancement of etching resistance, or the like can be expected.

The content of the repeating units that are stable against the action of an acid is preferably in the range of 0 to 40 mol %, and more preferably 0 to 20 mol %, based on all the repeating units of resin (B′).

Specific examples of the repeating units based on all the repeating units of resin (B′) will be shown below, including the repeating units represented by the general formula (IV), but the present invention is not limited thereto. In the formulae, Ra represents H, CH₃, CH₂OH, or CF₃.

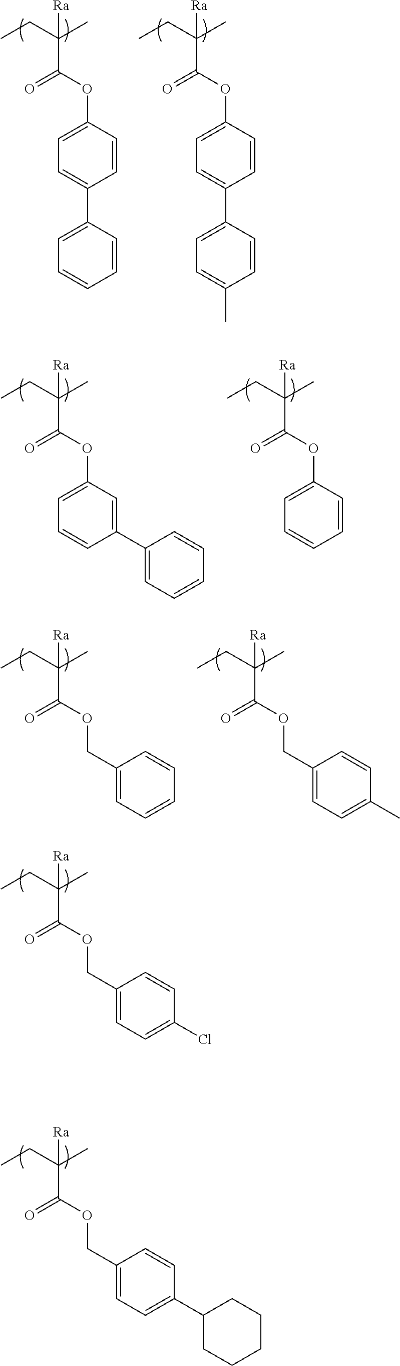

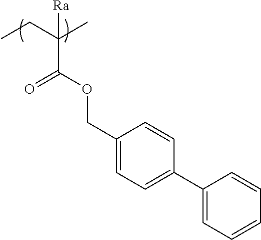

Examples of the repeating unit having a lactone structure which may be contained in the resin (B′) include the same as the repeating unit having a lactone structure which may be contained in the resin (B).

Specific examples of the resin as described above will be shown below, but the present invention is not limited thereto.

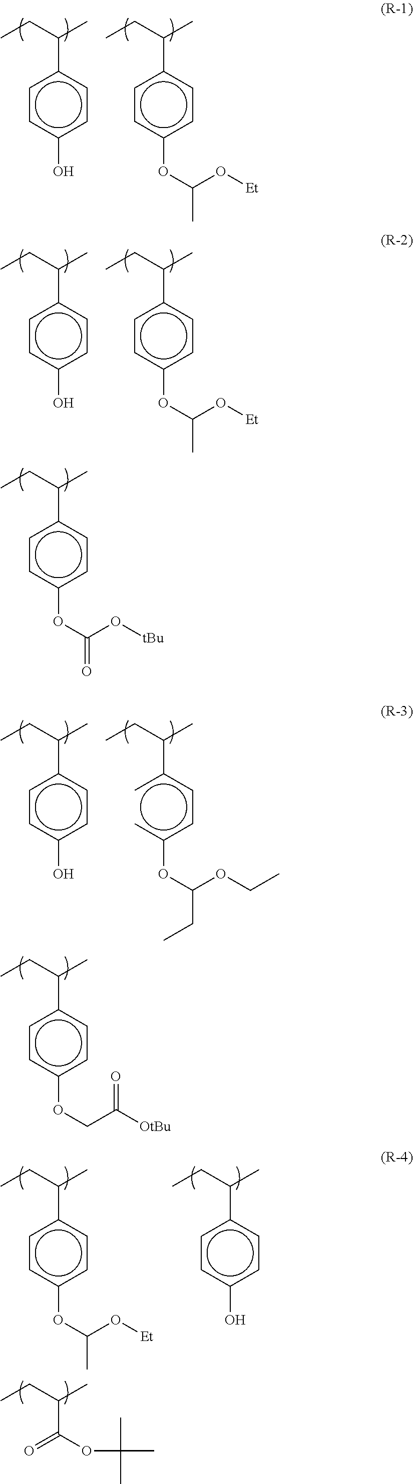

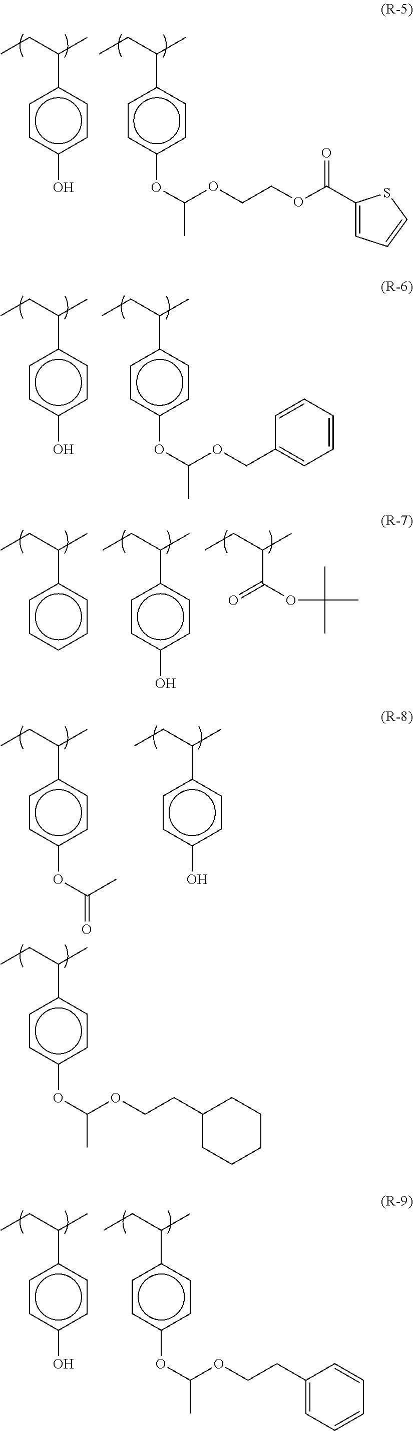

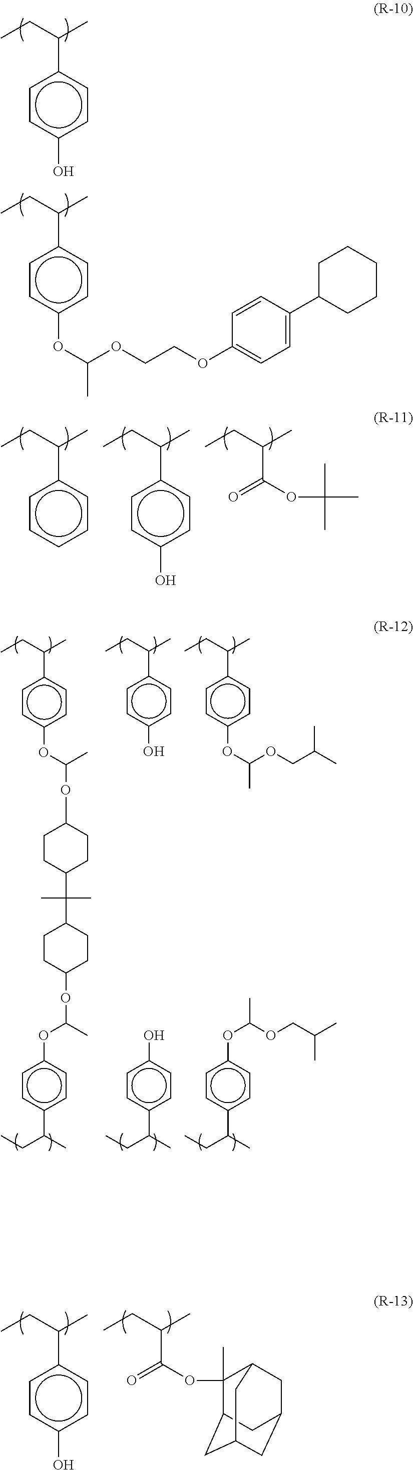

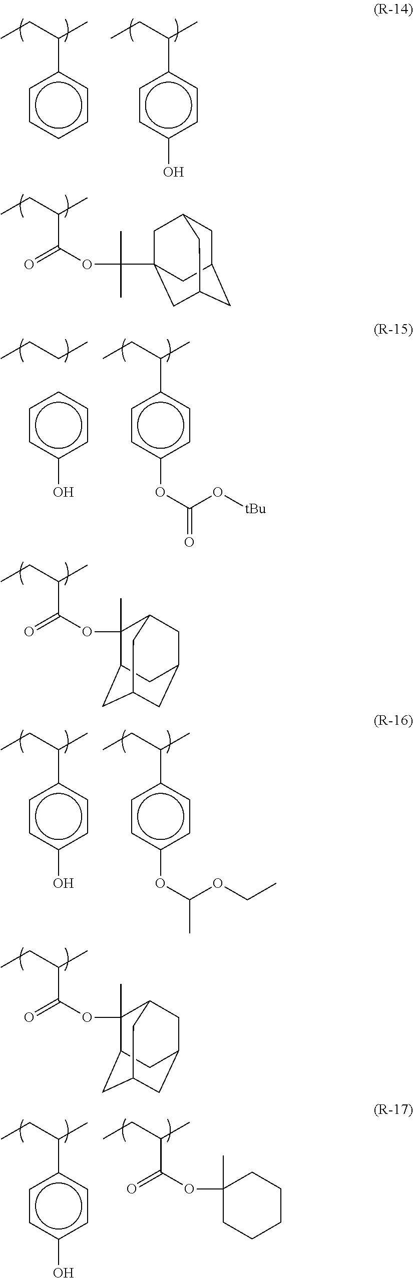

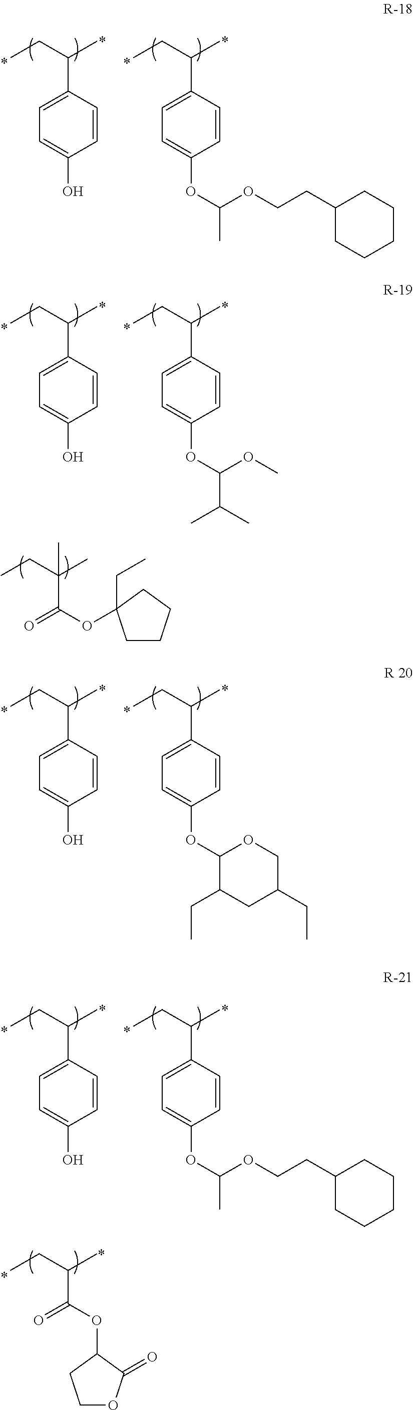

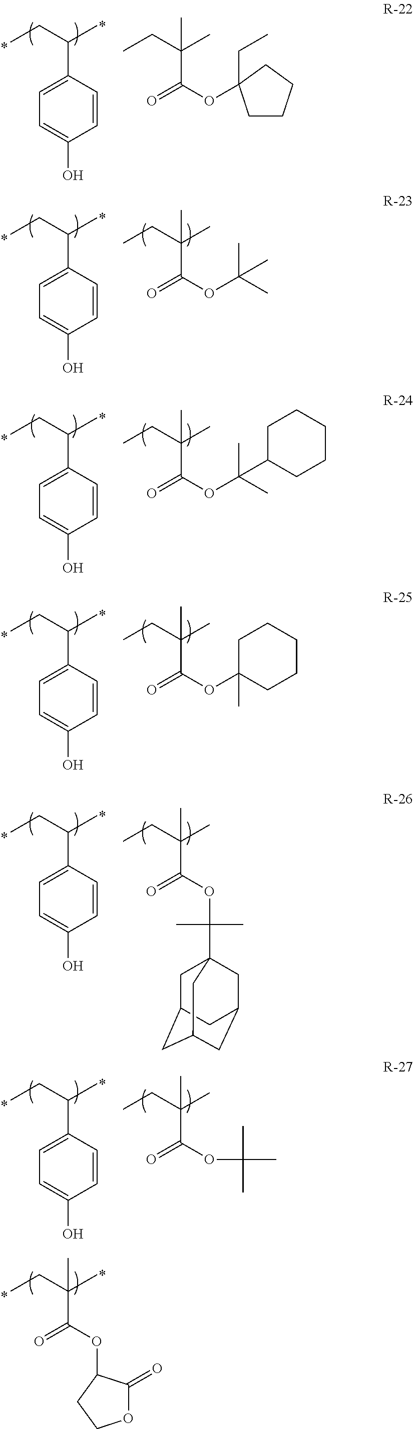

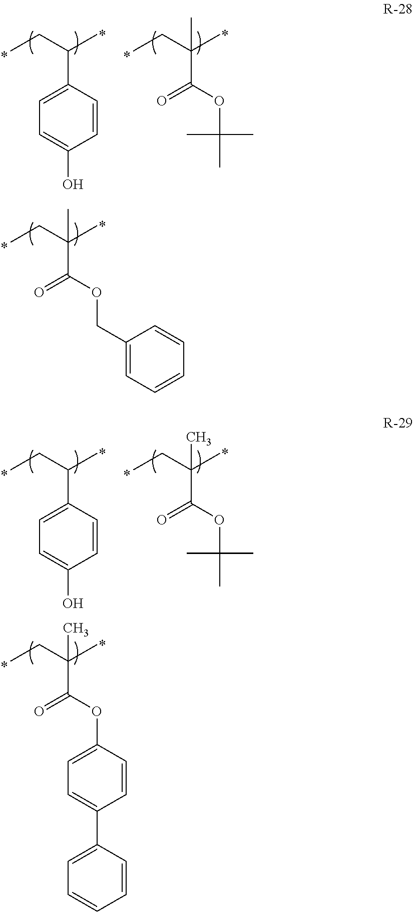

In the above specific examples, tBu represents a t-butyl group.

The content of the acid-decomposable groups is represented by the formula B/(B+S) with the number of acid-decomposable groups contained in the resin referring to (B) and the number of alkali-soluble groups not protected by any acid-cleavable group referring to (S). The content is preferably in the range of 0.01 to 0.7, more preferably 0.05 to 0.50, and still more preferably 0.05 to 0.40.

The resin (B) including the resin (B′) may be a commercially available product, if available, but can be synthesized by conventional techniques (for example, radical polymerization). Examples of the general synthetic methods include a batch polymerization method in which a monomer species and an initiator are dissolved in a solvent and heated so as to accomplish polymerization, a dropping polymerization method in which a solution of monomer species and initiator is added by dropping to a heated solvent over a period of 1 to 10 hours, and the like, with the dropping polymerization method being preferred. Examples of the reaction solvent include ethers such as tetrahydrofuran, 1,4-dioxane, diisopropyl ether, and the like; ketones such as methyl ethyl ketone, methyl isobutyl ketone, and the like; ester solvents such as ethyl acetate; amide solvents such as dimethylformamide, dimethylacetamide, and the like; solvents capable of dissolving the actinic-ray-sensitive or radiation-sensitive resin composition, such as propylene glycol monomethyl ether acetate, propylene glycol monomethyl ether, and cyclohexanone, as described hereinafter. It is preferable to perform the polymerization with the use of the same solvent as employed in the actinic-ray-sensitive or radiation-sensitive resin composition, whereby any particle generation during storage can be inhibited.

The polymerization reaction is preferably carried out in an atmosphere of inert gas, such as nitrogen or argon. The polymerization is initiated by the use of a commercially available radical initiator (an azo initiator, peroxide, and the like) as a polymerization initiator. As the radical initiators, an azo initiator is preferable, and an azo initiator having an ester group, a cyano group or a carboxyl group is more preferable. Preferable examples of the initiators include azobisisobutyronitrile, azobisdimethylvaleronitrile, dimethyl 2,2′-azobis(2-methylpropionate), and the like. According to necessity, the initiator is added additionally or in separate portions, and after completion of the reaction, the initiator is put into a solvent and a polymer is collected, for example, in the powder or solid form. The concentration during the reaction is from 5 to 50% by mass, and preferably from 30 to 50% by mass. The reaction temperature is generally from 10° C. to 150° C., preferably from 30° C. to 120° C., and more preferably from 60° C. to 100° C.

In addition, in order to inhibit aggregation of the resin after preparation of the composition, or the like, a step in which a resin synthesized is dissolved in a solvent to give a solution, and the solution is heated at about 30° C. to 90° C. for about 30 minutes to 4 hours, as described in, for example, JP2009-037108A

After the completion of the reaction, the mixture is allowed to stand to cool to room temperature and purified. In the purification, use is made of routine methods, such as a liquid-liquid extraction method in which residual monomers and oligomer components are removed by water washing or by the use of a combination of appropriate solvents, a method of purification in solution form such as ultrafiltration and the like capable of removal by extraction of only components of a given molecular weight or below, a re-precipitation method in which a resin solution is dropped into a poor solvent to coagulate the resin in the poor solvent and thus remove residual monomers, and the like, a method of purification in solid form such as washing of a resin slurry separated by filtration with the use of a poor solvent, and other methods. For example, the reaction solution is brought into contact with a solvent, wherein the resin is poorly soluble or insoluble (poor solvent) amounting to 10 times or less, preferably 10 to 5 times the volume of the reaction solution to precipitate the resin as a solid.

The solvent for use in the operation of precipitation or re-precipitation from a polymer solution (a precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents and the like.

The amount of precipitation or re-precipitation solvent to used can be appropriately selected according to intended efficiency, yield, and the like, but is generally in the range of 100 to 10000 parts by mass, preferably 200 to 2000 parts by mass, and more preferably 300 to 1000 parts by mass, based on 100 parts by mass of the polymer solution.

The temperature at which the precipitation or re-precipitation is carried out is generally in the range of approximately 0 to 50° C., preferably about room temperature (for example, approximately 20 to 35° C.), according to efficiency and ease of operation. The operation of precipitation or re-precipitation can be carried out by a publicly known method, such as a batch method, a continuous method, and the like with the use of a common mixing vessel such as an agitation vessel and the like.

The polymer obtained by the precipitation or re-precipitation is generally subjected to common solid/liquid separation, such as filtration, centrifugal separation, and the like, and dried before use. The filtration is carried out with the use of a filter medium ensuring solvent resistance, preferably under pressure. The drying is performed at approximately 30 to 100° C., and preferably approximately 30 to 50° C. under ordinary pressure or reduced pressure (preferably reduced pressure).

Moreover, after the resin precipitation and separation, the obtained resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to precipitate a resin (step a), separating the resin from the solution (step b), re-dissolving the resin in a solvent to obtain a resin solution A (step c), thereafter bringing the resin solution A into contact with a solvent wherein the resin is poorly soluble or insoluble amounting to less than 10 times (preferably 5 times or less) the volume of the resin solution A to precipitate a resin solid (step d), and separating the precipitated resin (step e).

The weight average molecular weight of the resin (B) of the present invention is preferably 1,000 to 200,000, more preferably 2,000 to 20,000, still more preferably 3,000 to 15,000, and particularly preferably 3,000 to 10,000 in terms of a polystyrene standard as measured by means of GPC. The regulation of the weight average molecular weight to 1,000 to 200,000 increases the viscosity of the composition to prevent deterioration of film-forming property. Further, deterioration of heat resistance and dry etching resistance, as well as deterioration of developability can be prevented by using the composition of the present invention.

The dispersity (molecular weight distribution) of the resin (B) for use is generally from 1 to 3, preferably from 1 to 2.6, more preferably from 1 to 2, and particularly preferably from 1.4 to 2.0. The lower the molecular weight distribution, the more excellent the resolving power and resist profile, and the smoother the side wall of the resist pattern to thereby attain an excellence in roughness. In the present invention, the proportion of resin (B) contained in the total composition, based on the total solid content, is preferably from 30 to 99% by mass, and more preferably from 60 to 95% by mass.

In the present invention, the resins (B) may be used singly or in combination of two or more kinds thereof.

[3] Basic Compound

The actinic-ray-sensitive or radiation-sensitive composition of the present invention preferably contains a basic compound.

The basic compound is preferably a nitrogen-containing organic basic compound.

Useful compounds are not particularly limited, but for example, the compounds classified into the following categories (1) to (4) are preferably used.

(1) Compound represented by the following general formula (BS-1):

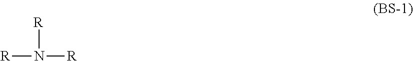

In the general formula (BS-1),

each R independently represents any one of a hydrogen atom, an (linear or branched) alkyl group, a cycloalkyl group (monocyclic or polycyclic), an aryl group, and an aralkyl group, provided that all the three R's are not hydrogen atoms at the same time.

The number of carbon atoms of the alkyl group as R is not particularly limited, but, it is generally 1 to 20, and preferably 1 to 12.

The number of carbon atoms of the cycloalkyl group as R is not particularly limited, but it is generally 3 to 20, and preferably 5 to 15.

The number of carbon atoms of the aryl group as R is not particularly limited, but it is generally 6 to 20, and preferably 6 to 10. In particular, examples of the aryl group include a phenyl group, a naphthyl group, and the like.

The number of carbon atoms of the aralkyl group as R is not particularly limited, but it is generally 7 to 20, and preferably 7 to 11. In particular, examples of the aralkyl group include a benzyl group and the like.

In the alkyl group, the cycloalkyl group, the aryl group, and the aralkyl group as by R, a hydrogen atom may be substituted with a substituent. Examples of the substituent include an alkyl group, a cycloalkyl group, an aryl group, an aralkyl group, a hydroxyl group, a carboxyl group, an alkoxy group, an aryloxy group, an alkylcarbonyloxy group, an alkyloxycarbonyl group, and the like.

In the compounds represented by the general formula (BS-1), it is preferable that only one R of the three R's be an organic group or that all the R's of the three R's be not hydrogen atoms.

Specific examples of the compounds of the general formula (BS-1) include tri-n-butylamine, tri-n-pentylamine, tri-n-octylamine, tri-n-decylamine, triisodecylamine, dicyclohexylmethylamine, tetradecylamine, pentadecyl amine, hexadecylamine, octadecylamine, didecylamine, methyloctadecylamine, dimethylundecylamine, N,N-dimethyldodecyl amine, methyl dioctadecylamine, N,N-dibutyl aniline, N,N-dihexylaniline, 2,6-diisopropylaniline, 2,4,6-tri(t-butyl)aniline, and the like.

Further, in the general formula (BS-1), the compound in which at least one of the R's is an alkyl group substituted with a hydroxyl group can be mentioned as a preferable form of the compounds. Specific examples of the compound include triethanolamine, N,N-dihydroxyethylaniline, and the like.

Furthermore, with respect to the alkyl group as R, an oxygen atom may be present in the alkyl chain so as to form an oxyalkylene chain. The oxyalkylene chain is preferably —CH₂CH₂O—. Specific examples thereof include tris(methoxyethoxyethyl)amine, compounds exemplified in column 3 line 60 et seq. of U.S. Pat. No. 6,040,112, and the like.

(2) Compound with Nitrogen-Containing Heterocyclic Structure

The heterocyclic structure may not have aromaticity. Further, it may have a plurality of nitrogen atoms, and also may have a heteroatom other than nitrogen. Examples thereof include compounds with an imidazole structure (2-phenylbenzoimidazole, 2,4,5-triphenylimidazole, and the like), compounds with a piperidine structure (N-hydroxyethylpiperidine, bis(1,2,2,6,6-pentamethyl-4-piperidyl)sebacate, and the like), compounds with a pyridine structure (4-dimethylaminopyridine and the like), and compounds with an antipyrine structure (antipyrine, hydroxyantipyrine, and the like).

Furthermore, compounds with two or more ring structures can be appropriately used. Specific examples thereof include 1,5-diazabicyclo[4.3.0]non-5-ene, 1,8-diazabicyclo[5.4.0]-undec-7-ene, and the like.

(3) Amine Compound Containing Phenoxy Group

The amine compounds containing a phenoxy group are those having a phenoxy group at the end of the alkyl group of each of the amine compound opposite to the nitrogen atom. The phenoxy group may have a substituent, such as an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group, and the like.

Compounds having at least one oxyalkylene chain between the phenoxy group and the nitrogen atom are preferable. The number of oxyalkylene chains in each molecule is preferably in the range of 3 to 9, more preferably 4 to 6. Among the oxyalkylene chains, —CH₂CH₂O— is preferable.

Particular examples thereof include 2-[2-{2-(2,2-dimethoxy-phenoxyethoxy)ethyl}-bis-(2-methoxyethyl)]-amine, compounds (C1-1) to (C3-3) exemplified in the paragraph [0066] of U.S. Patent Application Publication No. 2007/0224539 A1, and the like.

(4) Ammonium Salt

Ammonium salts can also be appropriately used. Hydroxides and carboxylates are preferable. Specific preferable examples thereof include tetraalkylammonium hydroxides, a typical example of which is tetrabutylammonium hydroxide.

Examples of other compounds usable in the composition of the present invention include compounds synthesized in Examples of JP2002-363146A compounds described in the paragraph [0108] of JP2007-298569A, and the like.

These basic compounds are used singly or in combination of two or more kinds thereof.

The content of the basic compound to be used is usually from 0.001 to 10% by mass, and preferably from 0.01 to 5% by mass, based on the solids of the actinic-ray-sensitive or radiation-sensitive resin composition of the present invention.

The molar ratio of the acid generator to the basic compound is preferably from 2.5 to 300. That is, the molar ratio of 2.5 or more is preferred from the viewpoint of sensitivity and resolution, and 300 or less is preferred from the viewpoint of inhibition of the reduction of resolution by the thickening of the pattern in aging after exposure until heat treatment. The molar ratio is more preferably 5.0 to 200, and still more preferably 7.0 to 150.

[4] Low-Molecular-Weight Compound Containing Nitrogen Atom and Containing Group that is Cleaved by Action of Acid

The composition of the present invention can include a low-molecular-weight compound containing a nitrogen atom and a group that is cleaved by the action of an acid (which is also referred to as a “low-molecular-weight compound (D)” or a “compound (D)”).

The group that is cleaved by the action of an acid is not particularly limited, but an acetal group, a carbonate group, a carbamate group, a tertiary ester group, a tertiary hydroxyl group, and a hemiaminal ether group are preferred, and a carbamate group and a hemiaminal ether group are particularly preferred.

The molecular weight of the low-molecular-weight compound (D) containing a group that is cleaved by the action of an acid is preferably 100 to 1000, more preferably 100 to 700, and particularly preferably 100 to 500.

As the compound (D), an amine derivative containing group that is cleaved by the action of an acid on a nitrogen atoms is preferred.

The compound (D) may contain a carbamate group having a protecting group on a nitrogen atom. The protecting group constituting the carbamate group can be represented by the following general formula (d-1).

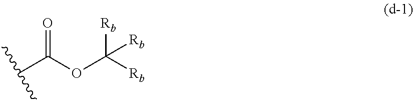

In the general formula (d-1),

each Rb independently represents a hydrogen atom, an alkyl group, a cycloalkyl group, an aryl group, an aralkyl group, or an alkoxyalkyl group. Rb's may be bonded to each other to form a ring.

The alkyl group, the cycloalkyl group, the aryl group, or the aralkyl group represented by Rb may be substituted with a functional group such as a hydroxyl group, a cyano group, an amino group, a pyrrolidino group, a piperidino group, a morpholino group, an oxo group, and the like, an alkoxy group, or a halogen atom. This case comes under the alkoxyalkyl group represented by Rb.

Examples of the alkyl group, the cycloalkyl group, the aryl group, or the aralkyl group of Rb above (the alkyl group, the cycloalkyl group, the aryl group, and the aralkyl group may be substituted with the above-described functional group, an alkoxy group, or a halogen atom) include a group derived from a linear or branched alkane such as methane, ethane, propane, butane, pentane, hexane, heptane, octane, nonane, decane, undecane, dodecane, and the like, or a group where the group derived from an alkane is substituted with one or more kinds of or one or more groups of cycloalkyl groups such as a cyclobutyl group, a cyclopentyl group, a cyclohexyl group, and the like; a group derived from a cycloalkane such as cyclobutane, cyclopentane, cyclohexane, cycloheptane, cyclooctane, norbornane, adamantane, noradamantane, and the like, or a group where the group derived from a cycloalkane is substituted with one or more kinds of or one or more groups of linear or branched alkyl group such as a methyl group, an ethyl group, an n-propyl group, an i-propyl group, an n-butyl group, a 2-methylpropyl group, a 1-methylpropyl group, a t-butyl group, and the like; a group derived from an aromatic compound such as benzene, naphthalene, anthracene, and the like, or a group where the group derived from an aromatic compound is substituted with one or more kinds of or one or more groups of linear or branched alkyl group such as a methyl group, an ethyl group, an n-propyl group, an i-propyl group, an n-butyl group, a 2-methylpropyl group, a 1-methylpropyl group, a t-butyl group, and the like; a group derived from a heterocyclic compound such as pyrrolidine, piperidine, morpholine, tetrahydrofuran, tetrahydropyran, indole, indoline, quinoline, perhydroquinoline, indazole, benzimidazole, and the like, or a group where the group derived from a heterocyclic compound is substituted with one or more kinds of or one or more groups of linear or branched alkyl group or aromatic compound-derived group; a group where the group derived from a linear or branched alkane or the group derived from a cycloalkane is substituted with one or more kinds of or one or more groups of aromatic compound-derived group such as a phenyl group, a naphthyl group, an anthracenyl group, and the like; a group where the substituent above is substituted with a functional group such as a hydroxyl group, a cyano group, an amino group, a pyrrolidino group, a piperidino group, a morpholino group, an oxo group, and the like; etc.

Rb is preferably a linear or branched alkyl group, a cycloalkyl group, or an aryl group, and more preferably a linear or branched alkyl group or a cycloalkyl group.

Examples of the ring formed by the mutual bonding of two Rb's include an alicyclic hydrocarbon group, an aromatic hydrocarbon group, a heterocyclic hydrocarbon group, or derivatives thereof, and the like.

Specific structures of the group represented by the general formula (d-1) will be shown below.

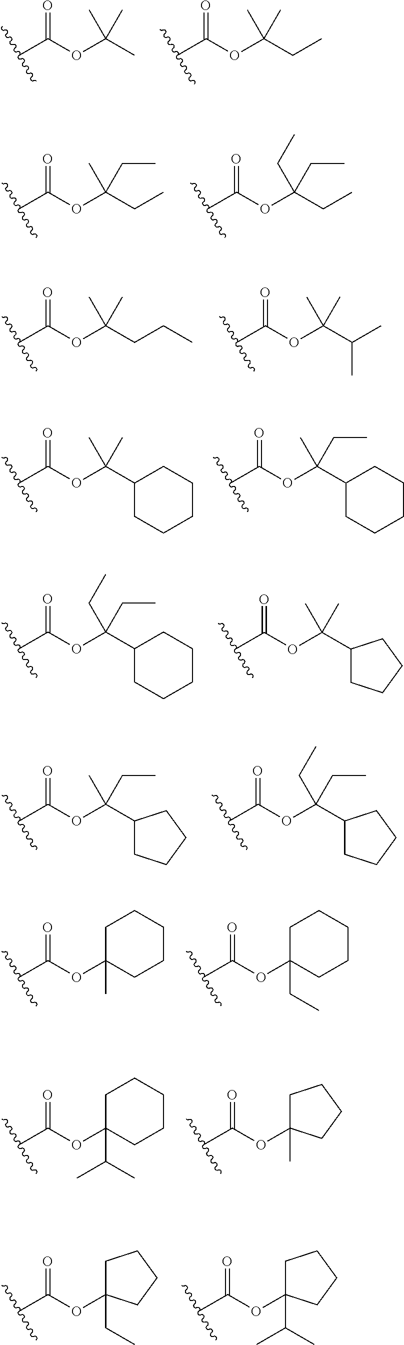

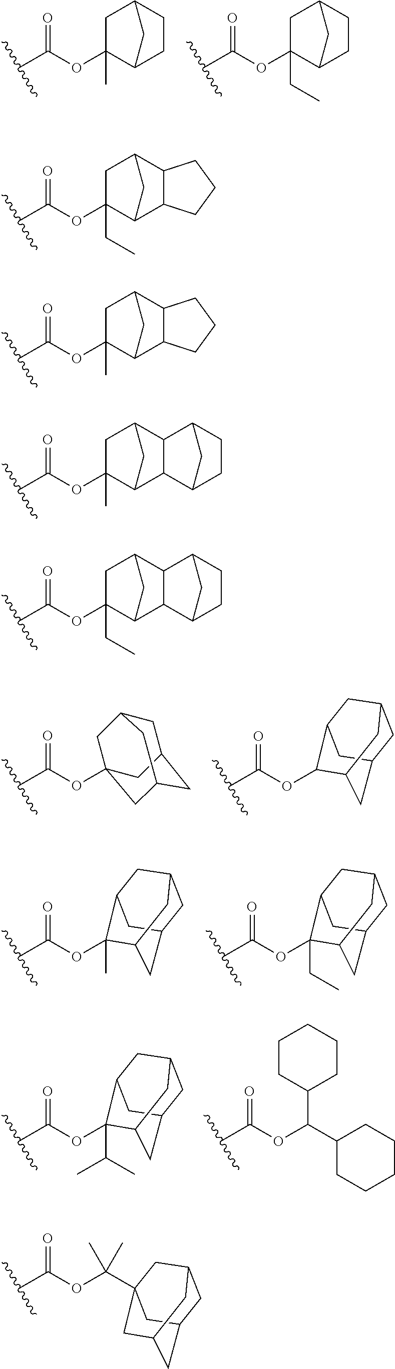

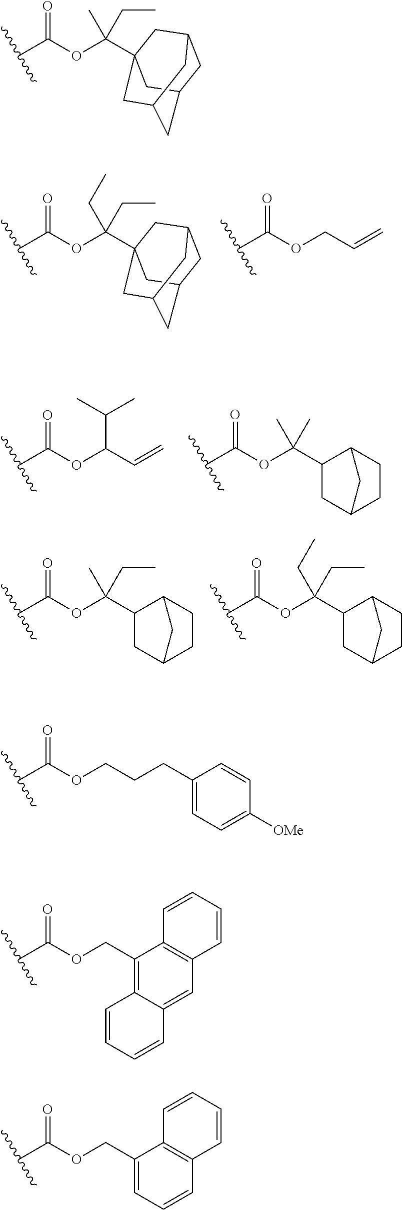

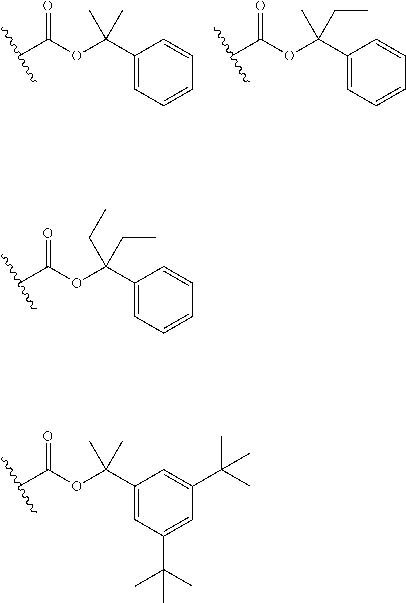

The compound (D) can be formed by any combination of the basic compound and a structure represented by the general formula (d-1).

The compound (D) is particularly preferably one having a structure represented by the following general formula (A).

Further, the compound (D) may correspond to the basic compound as long as it is a low-molecular-weight compound containing group which is cleaved by the action of an acid.

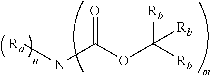

In the general formula (A), Ra represents a hydrogen atom, an alkyl group, a cycloalkyl group, an aryl group, or an aralkyl group. Further, with n=2, two Ra's may be the same as or different from each other, or the two Ra's may be bonded to each other to form a divalent heterocyclic hydrocarbon group (preferably having 20 or less carbon atoms) or a derivative thereof.

Rb has the same meaning as Rb in the general formula (d-1), and preferable examples thereof are also the same. However, in —C(Rb)(Rb)(Rb), when one or more Rb's are hydrogen atoms, at least one of the remaining Rb's is a cyclopropyl group, a 1-alkoxyalkyl group, or an aryl group.

n represents an integer of 0 to 2, and m represents an integer of 1 to 3, with n+m=3.

In the general formula (A), the alkyl group, the cycloalkyl group, the aryl group, or the aralkyl group represented by Ra may be the same substituent as one which substitutes the alkyl group, the cycloalkyl group, the aryl group, or the aralkyl group represented by Rb. Specific examples of the alkyl group, the cycloalkyl group, the aryl group, or the aralkyl group of Ra (the alkyl group, the cycloalkyl group, the aryl group, or the aralkyl group may be substituted with the above-described group) are the same as those described with respect to Rb.

Furthermore, examples of the divalent heterocyclic hydrocarbon group (preferably having 1 to 20 carbon atoms) formed by the mutual bonding of Ra's or a derivative thereof include a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, 1,5,9-triazacyclododecane, and the like; a group as obtained by substituting the above heterocyclic-compound-derived group with at least one or at least one type of linear or branched-alkane-derived group, cycloalkane-derived group, aromatic-compound-derived group, heterocyclic-compound-derived group or functional group, such as a hydroxyl group, a cyano group, an amino group, a pyrrolidino group, a piperidino group, a morpholino group, an oxo group, and the like; etc.

Specific particularly preferable examples of the compound (D) in the present invention will be shown below, but the present invention is not limited thereto.

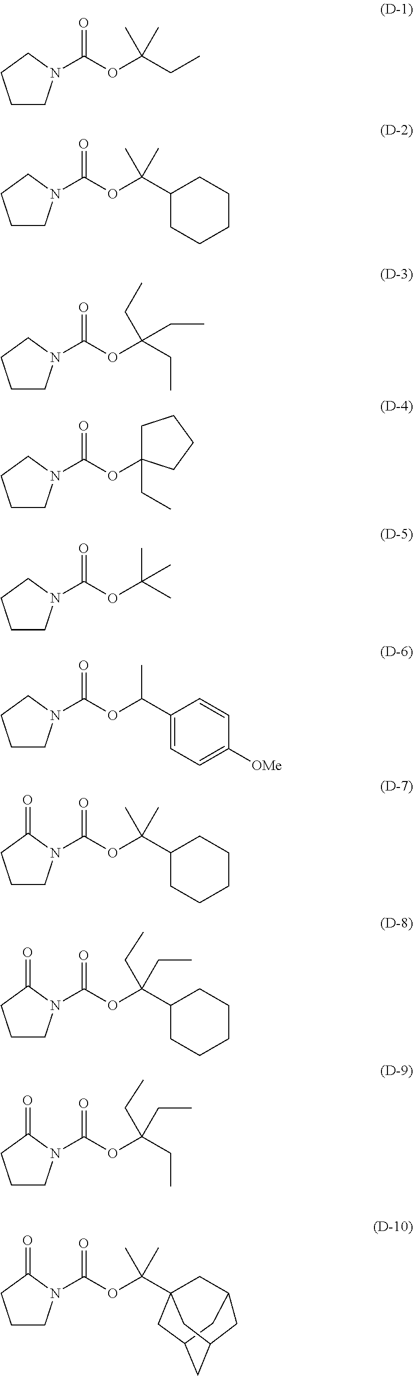

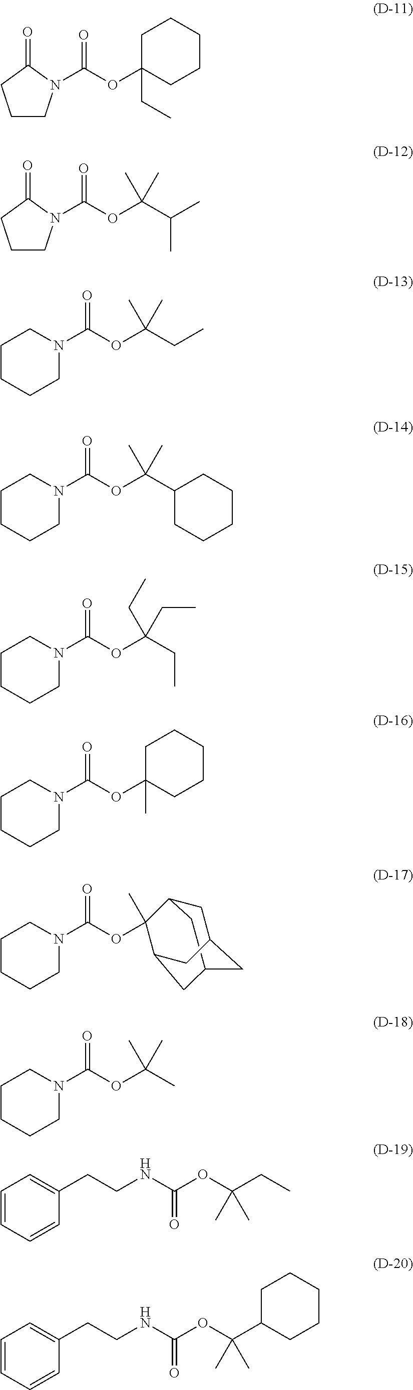

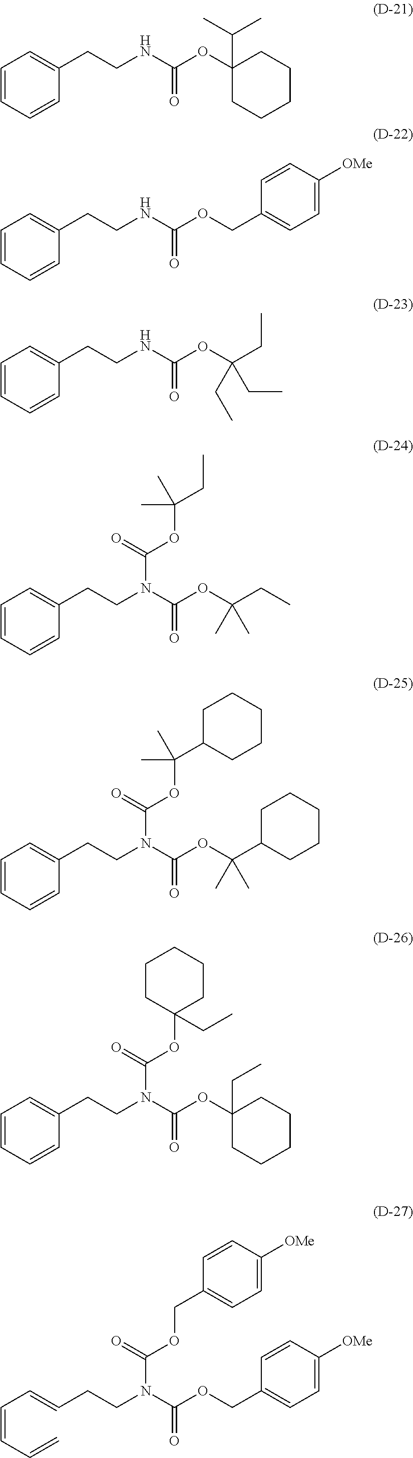

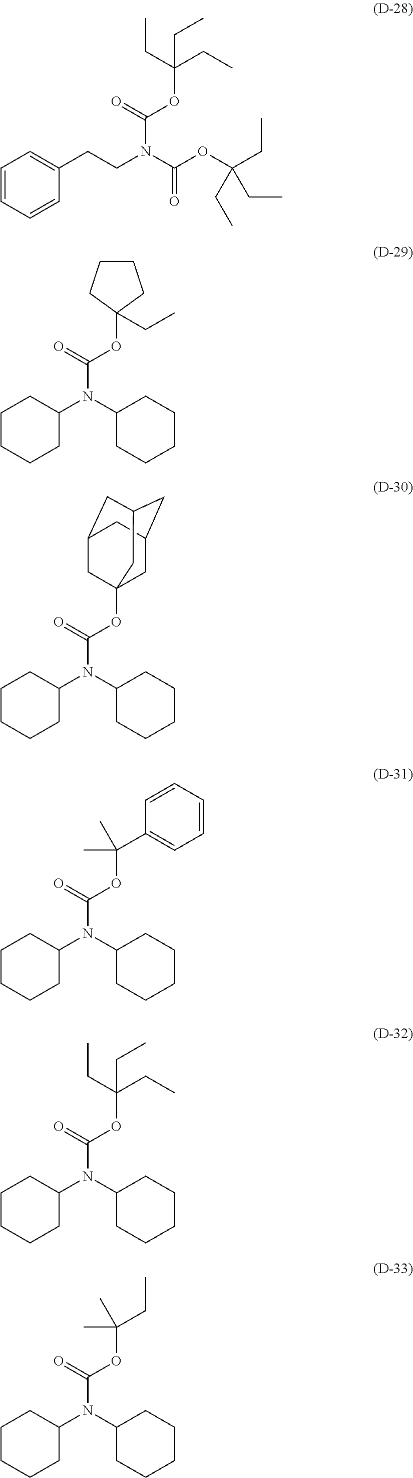

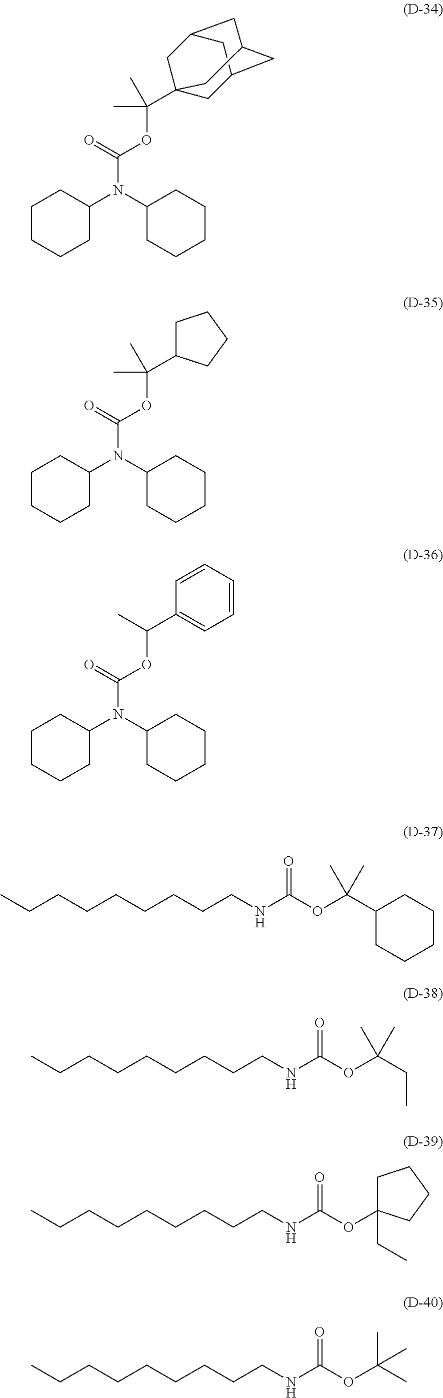

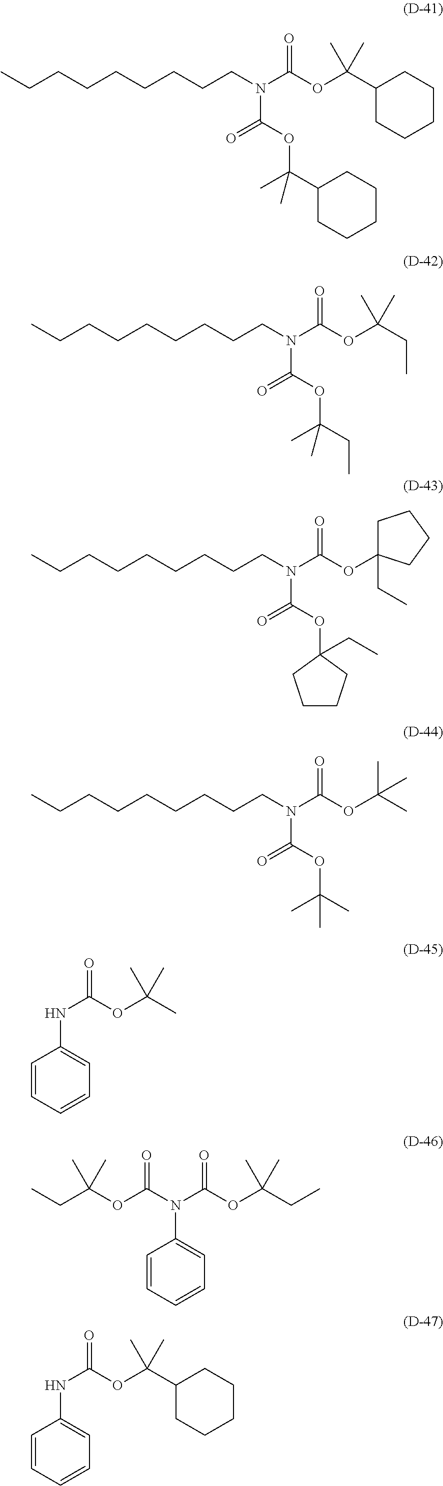

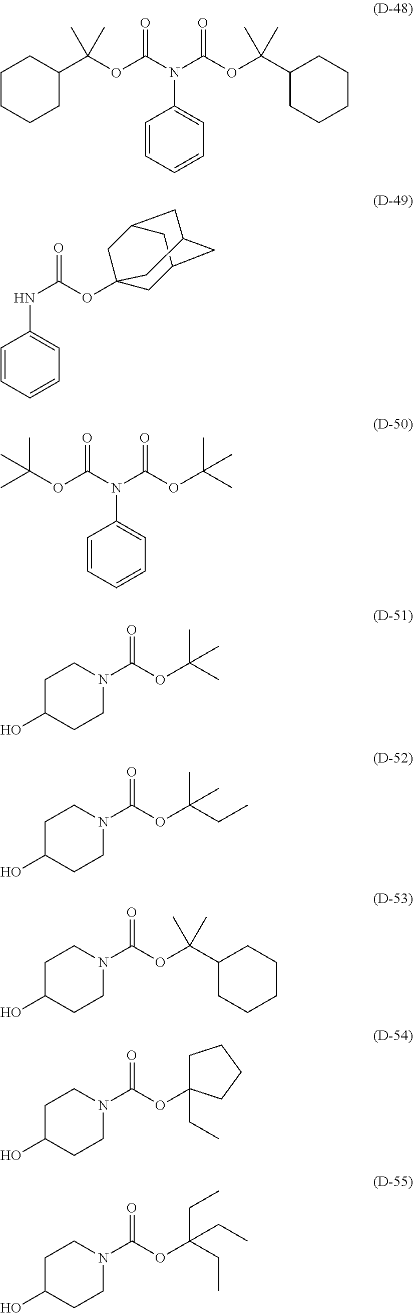

The compound represented by the general formula (A) can be synthesized according to JP2007-298569A, JP2009-199021A, or the like.

In the present invention, the low molecule compound (D) containing a nitrogen atom and containing a group that is cleaved by the action of an acid may be used singly or used after mixing two or more kinds thereof.

The actinic-ray-sensitive or radiation-sensitive resin composition of the present invention may not include the low molecule compound (D) containing a nitrogen atom and containing a group that is cleaved by the action of an acid, but if included, the content of the compound (D) is usually from 0.001 to 20% by mass, preferably from 0.001 to 10% by mass, and more preferably from 0.01 to 5% by mass, based on all solids of the actinic-ray-sensitive or radiation-sensitive resin composition.

With respect to the ratio of the acid generator to the compound (D) used in the composition, preferably, the acid generator/[compound (D)+the basic compound](molar ratio)=2.5 to 300. The reason for this is that the molar ratio is preferred to be 2.5 or higher from the viewpoint of sensitivity and resolving power. The molar ratio is preferred to be 300 or below from the viewpoint of the inhibition of any resolving power deterioration due to thickening of resist pattern over time from exposure to heating treatment. The acid generator/[compound (D)+the basic compound](molar ratio) is more preferably 5.0 to 200, and still more preferably 7.0 to 150.

[5] Basic Compound or Ammonium Salt Compound (E) which Decreases Basicity upon Irradiation with Actinic-Ray or Radiation

The actinic-ray-sensitive or radiation-sensitive resin composition of the present invention preferably contains a basic compound or an ammonium salt compound which decreases basicity upon irradiation with an actinic-ray or a radiation (which is also referred to as a “compound (E)”).

The compound (E) is preferably a compound (E-1) having a basic functional group or an ammonium group, and a group which generates an acidic functional group upon irradiation with an actinic-ray or a radiation. That is, the compound (E) is preferably an ammonium salt compound having a basic functional group and a group which generates an acidic functional group upon irradiation with an actinic-ray or a radiation, or an ammonium group and a group which generates an acidic functional group upon irradiation with an actinic-ray or a radiation.

Examples of the compound (E) or (E-1), which decomposes and is generated upon irradiation with an actinic-ray or a radiation, and thus decreases basicity include a compound represented by the following general formula (PA-I), (PA-II) or (PAIII), and from the viewpoint of attaining excellent effects to a high degree in all of LWR, uniformity in local pattern dimension, and DOF (Depth of Focus), the compound represented by the general formula (PA-II) or (PA-III) is particularly preferred.

First, the compound represented by the general formula (PA-I) will be described.

Q-A₁-(X)ₙ—B—R (PA-I)

In the general formula (PA-I),

A₁ represents a single bond or a divalent linking group,

Q represents —SO₃H or —CO₂H, and Q corresponds to an acidic functional group which is generated upon irradiation with an actinic-ray or a radiation,

X represents —SO₂— or —CO—,

n represents 0 or 1,

B represents a single bond, an oxygen atom, or —N(Rx)-,

Rx represents a hydrogen atom or a monovalent organic group, and

R represents a monovalent organic group containing a basic functional group or a monovalent organic group containing an ammonium group.

Next, the compound represented by the general formula (PA-II) will be described.

Q₁-X₁—NH—X₂-Q₂ (PA-II)

In the general formula (PA-II),

each of Q₁ and Q2 independently represents a monovalent organic group, provided that any one of Q₁ and Q2 contains a basic functional group, and Q₁ and Q2 may be bonded to each other to form a ring and the ring formed may contain a basic functional group,

each of X₁ and X₂ independently represents —CO— or —SO₂—, and

—NH— corresponds to an acidic functional group which is generated upon irradiation with an actinic-ray or a radiation.

Next, the compound represented by the general formula (PA-III) will be described.

Q₁-X₁—NH—X₂-A₂-(X₃)ₘ—B-Q₃ (PA-III)

In the general formula (PA-III),

each of Q₁ and Q₃ independently represents a monovalent organic group, provided that any one of Q₁ and Q₃ contains a basic functional group, and Q₁ and Q₃ may be bonded to each other to form a ring and the ring formed may contain a basic functional group,

each of X₁, X₂, and X₃ independently represents —CO— or —SO₂—,

A₂ represents a divalent linking group,

B represents a single bond, an oxygen atom, or —N(Qx)-,

Qx represents a hydrogen atom or a monovalent organic group,

when B is —N(Qx)-, Q3 and Qx may be bonded to each other to form a ring,

m represents 0 or 1, and

—NH— corresponds to an acidic functional group which is generated upon irradiation with an actinic-ray or a radiation.

Specific examples of the compound (E) which generates the compound represented by the general formula (PA-I) upon irradiation with an actinic-ray or a radiation will be shown below, but the present invention is not limited thereto.

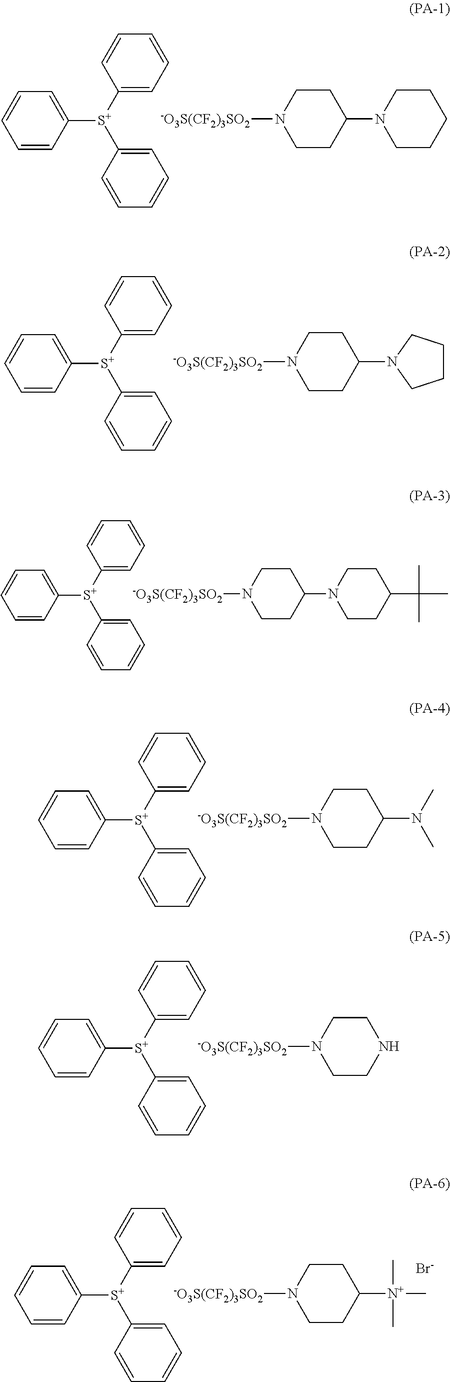

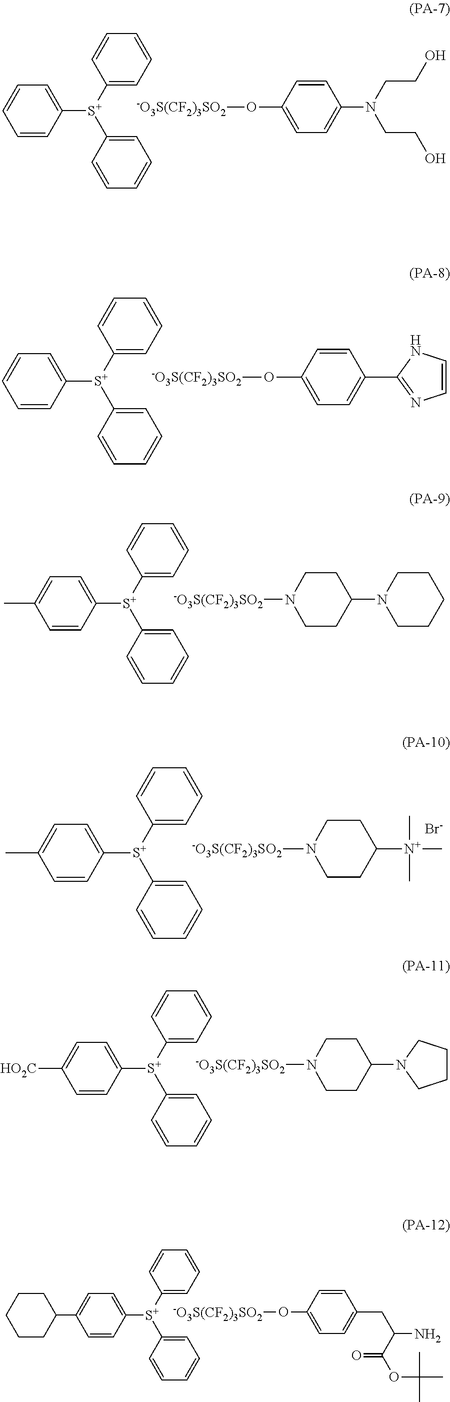

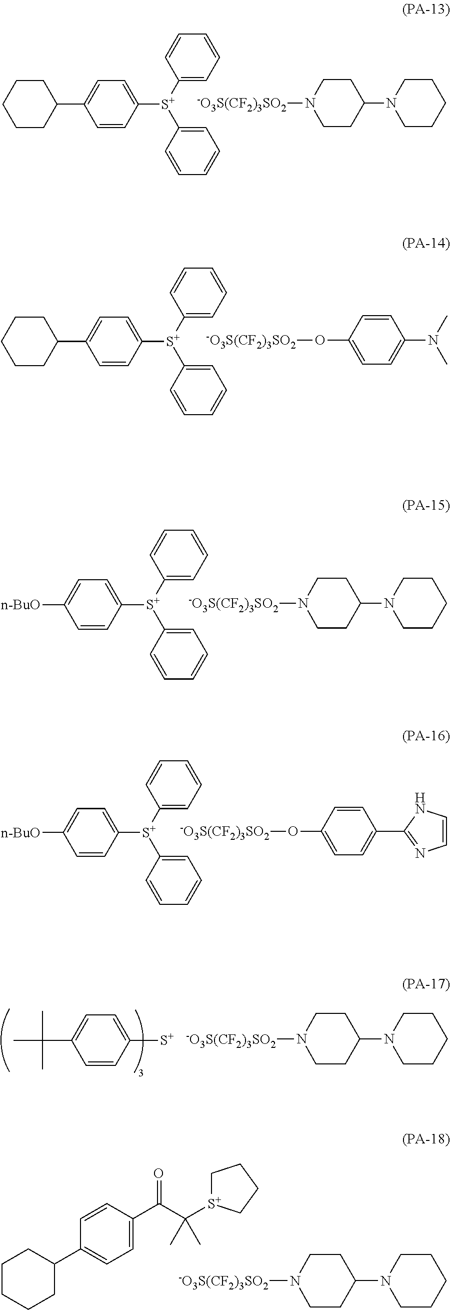

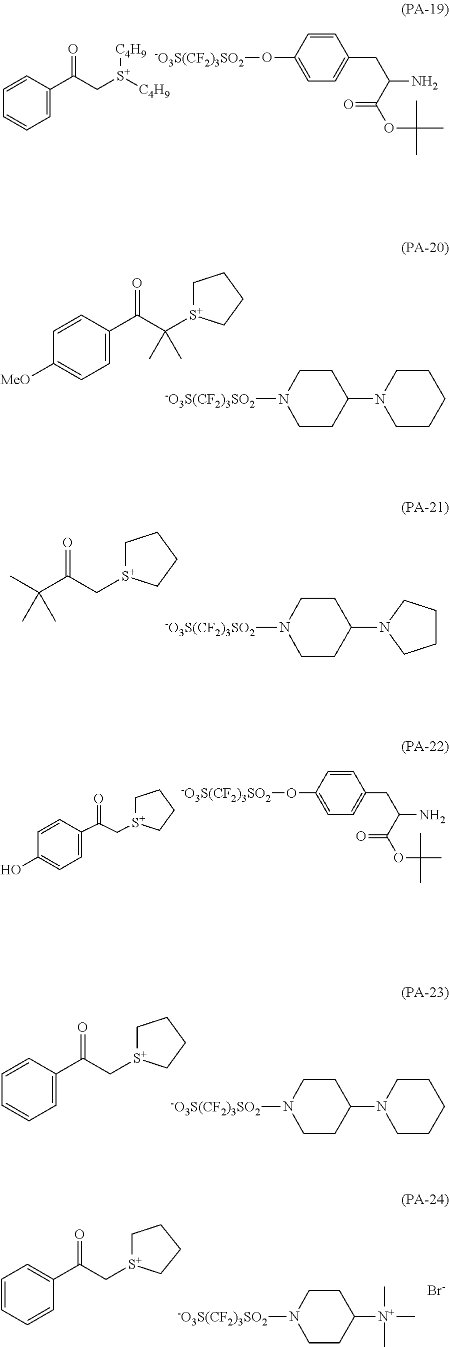

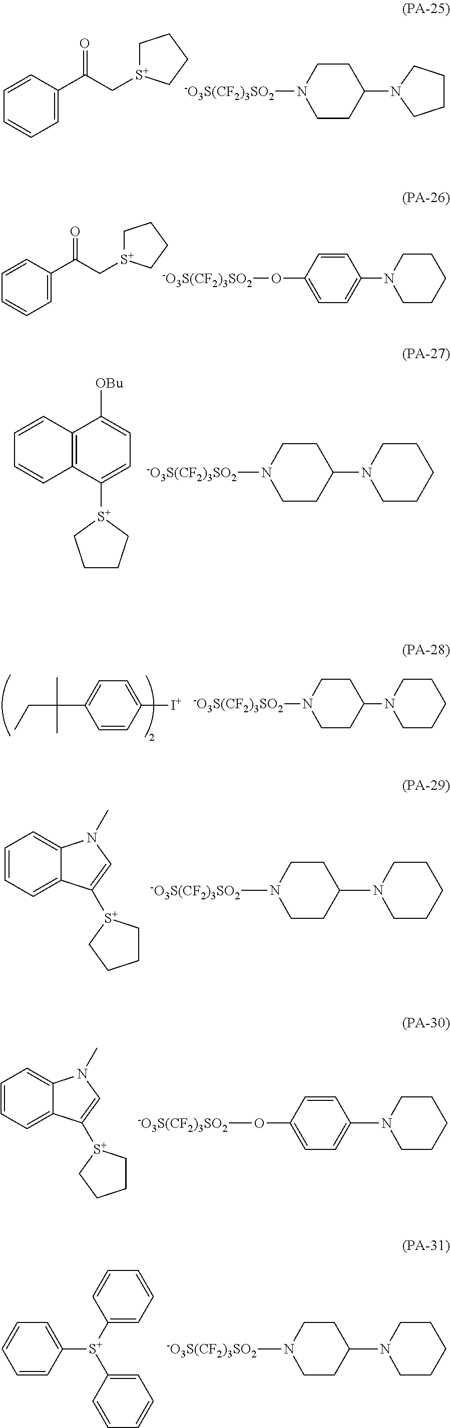

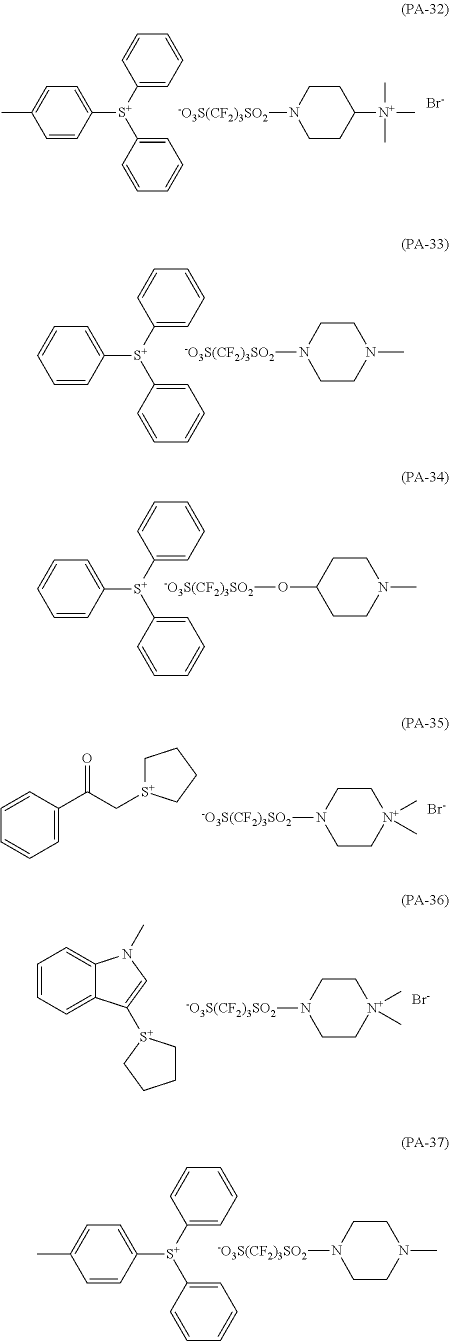

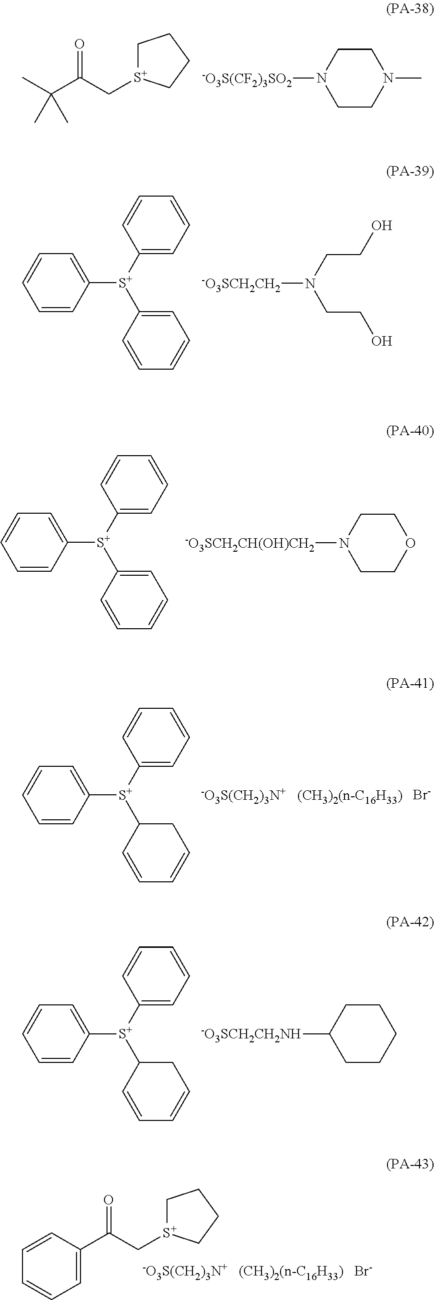

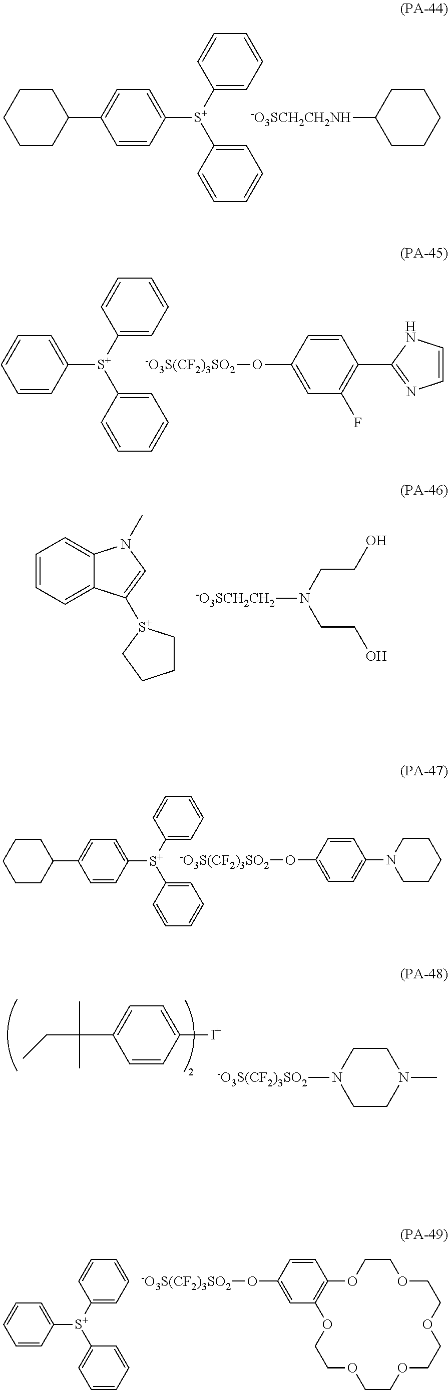

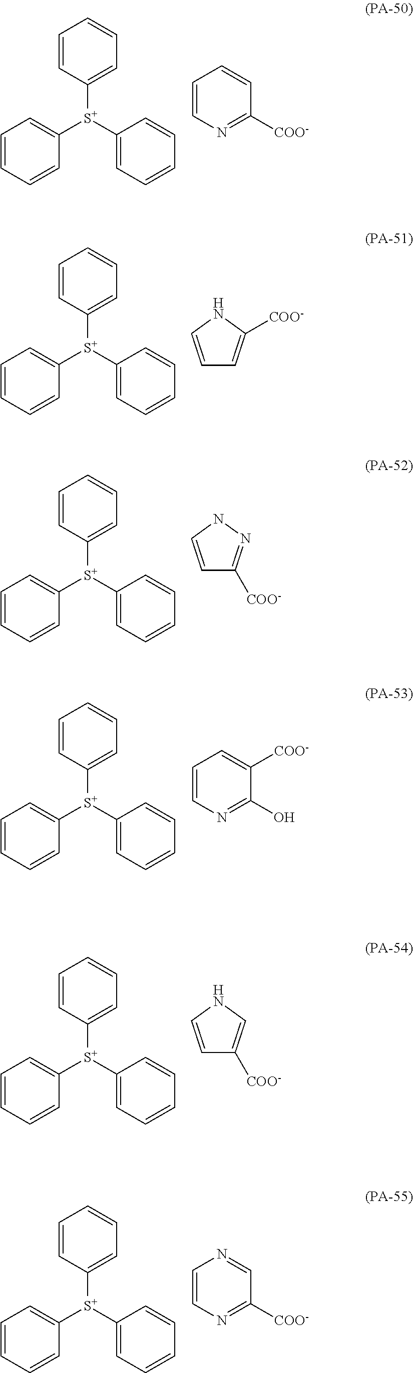

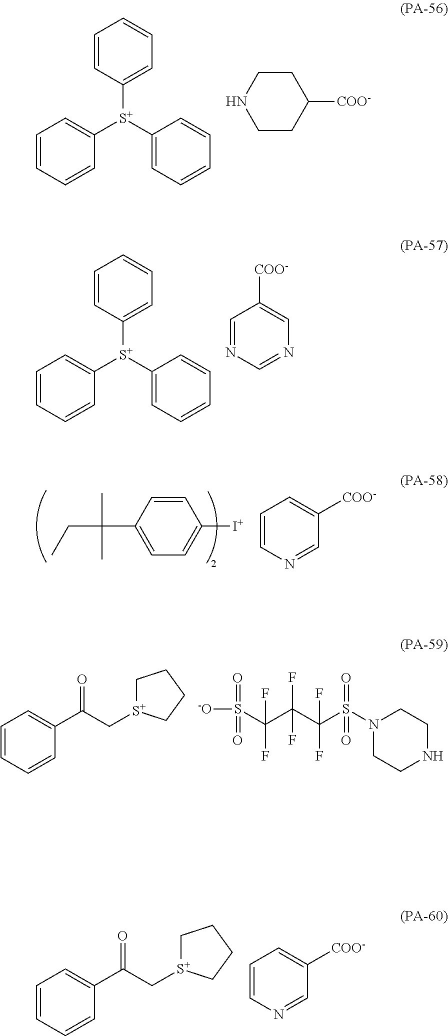

These compounds can be easily synthesized from the compound represented by the general formula (PA-I), or a lithium, sodium, or potassium salt, and a hydroxide, a bromide, a chloride, or the like of iodonium or sulfonium, and the like through the salt exchange method described in Japanese PCT National Publication No. 11-501909 or JP2003-246786A. Alternatively, the compounds can be synthesized according to the synthesis method described in JP7-333851A.

Specific examples of the compound (E) which generate the compound represented by the general formula (PA-II) or (PA-III) upon irradiation with an actinic-ray or a radiation will be shown below, but the present invention is not limited thereto.

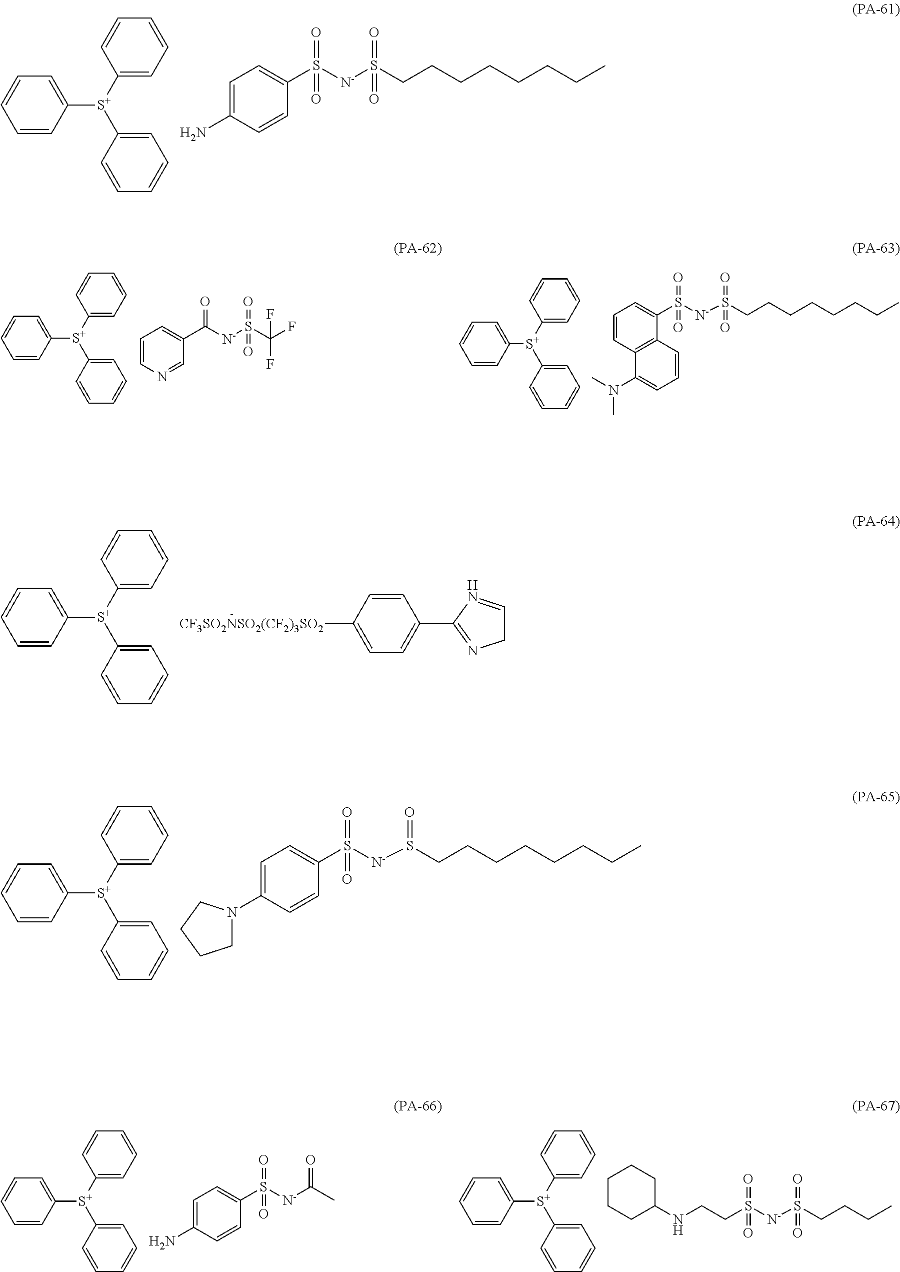

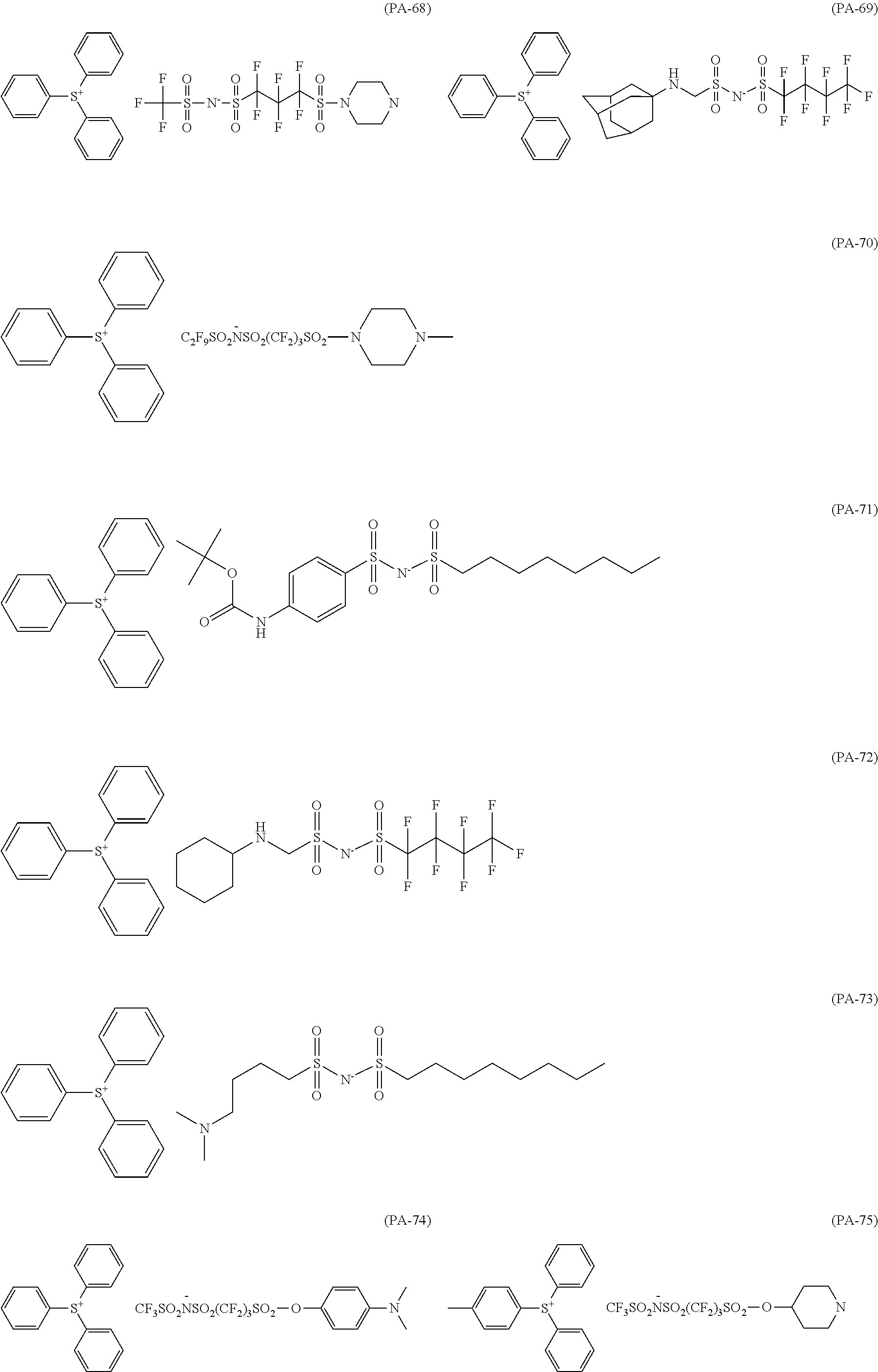

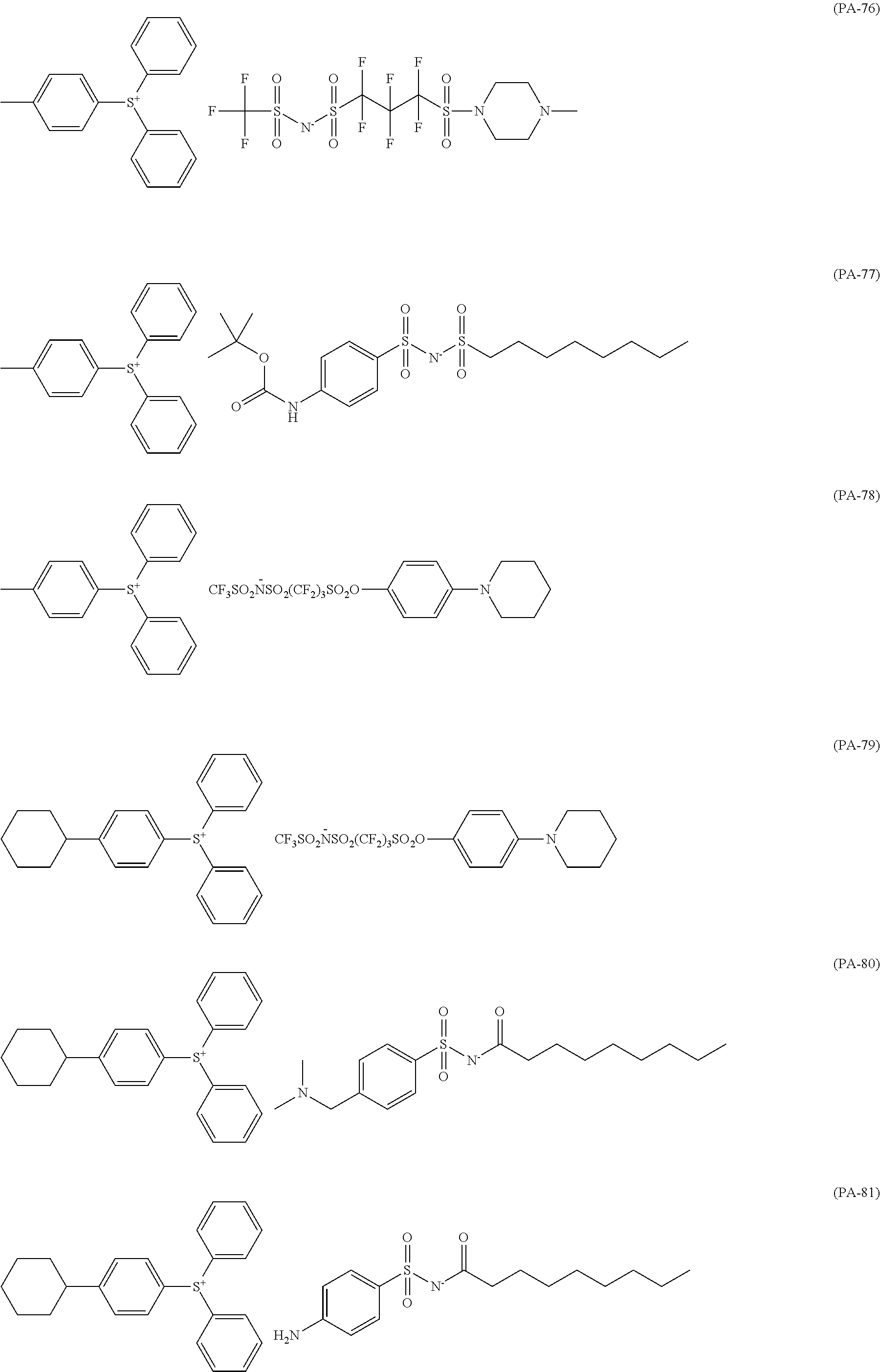

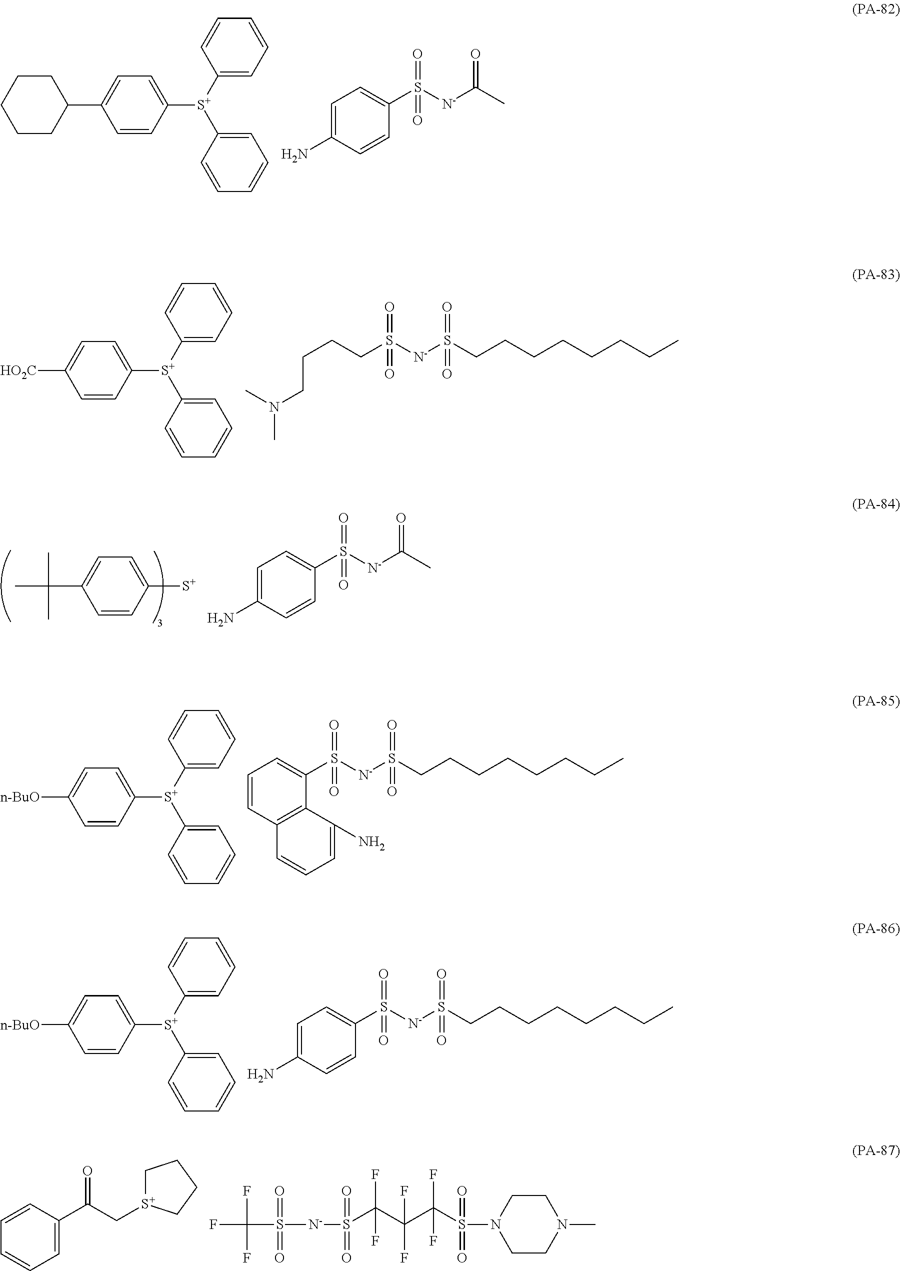

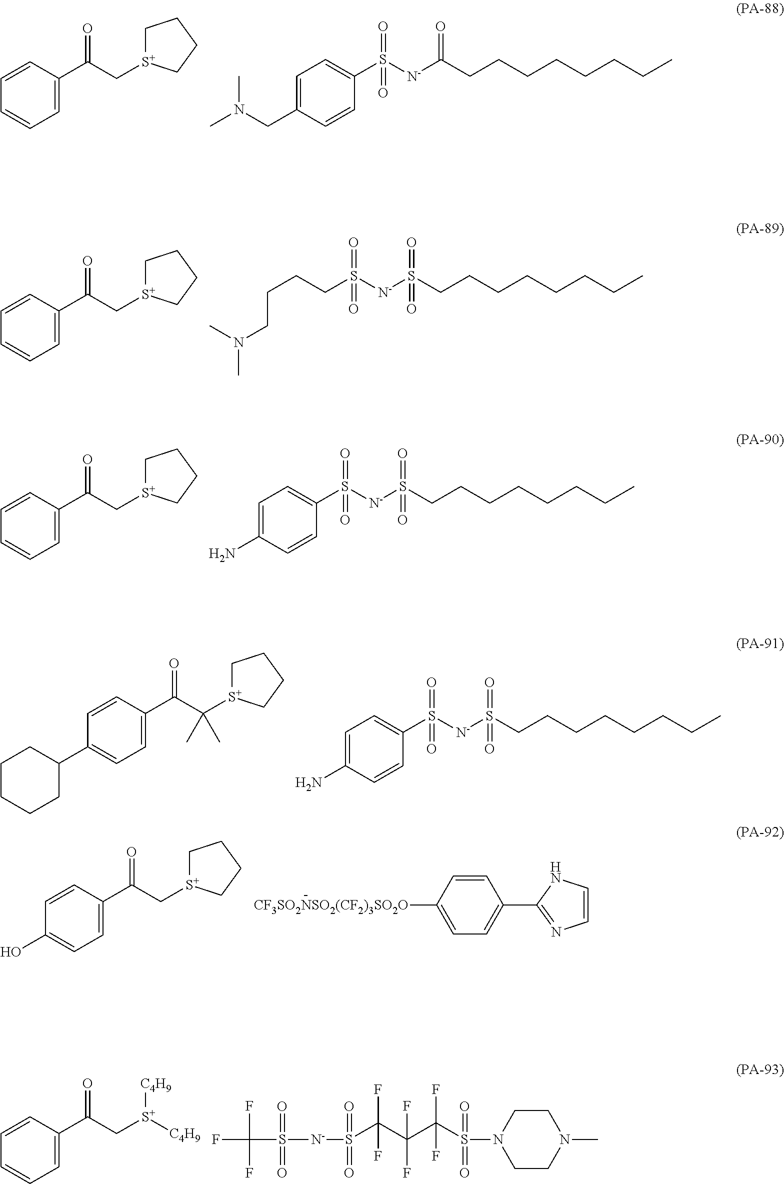

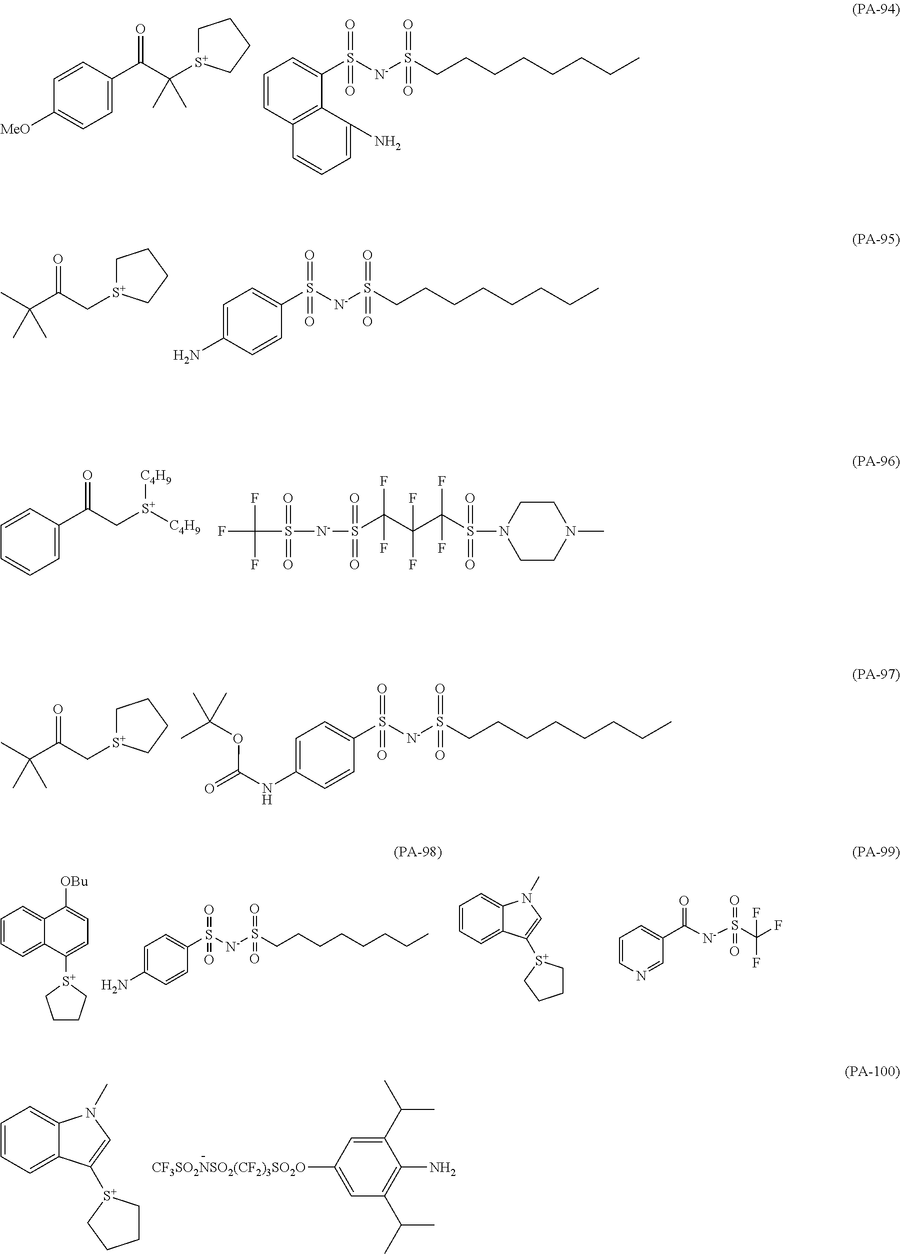

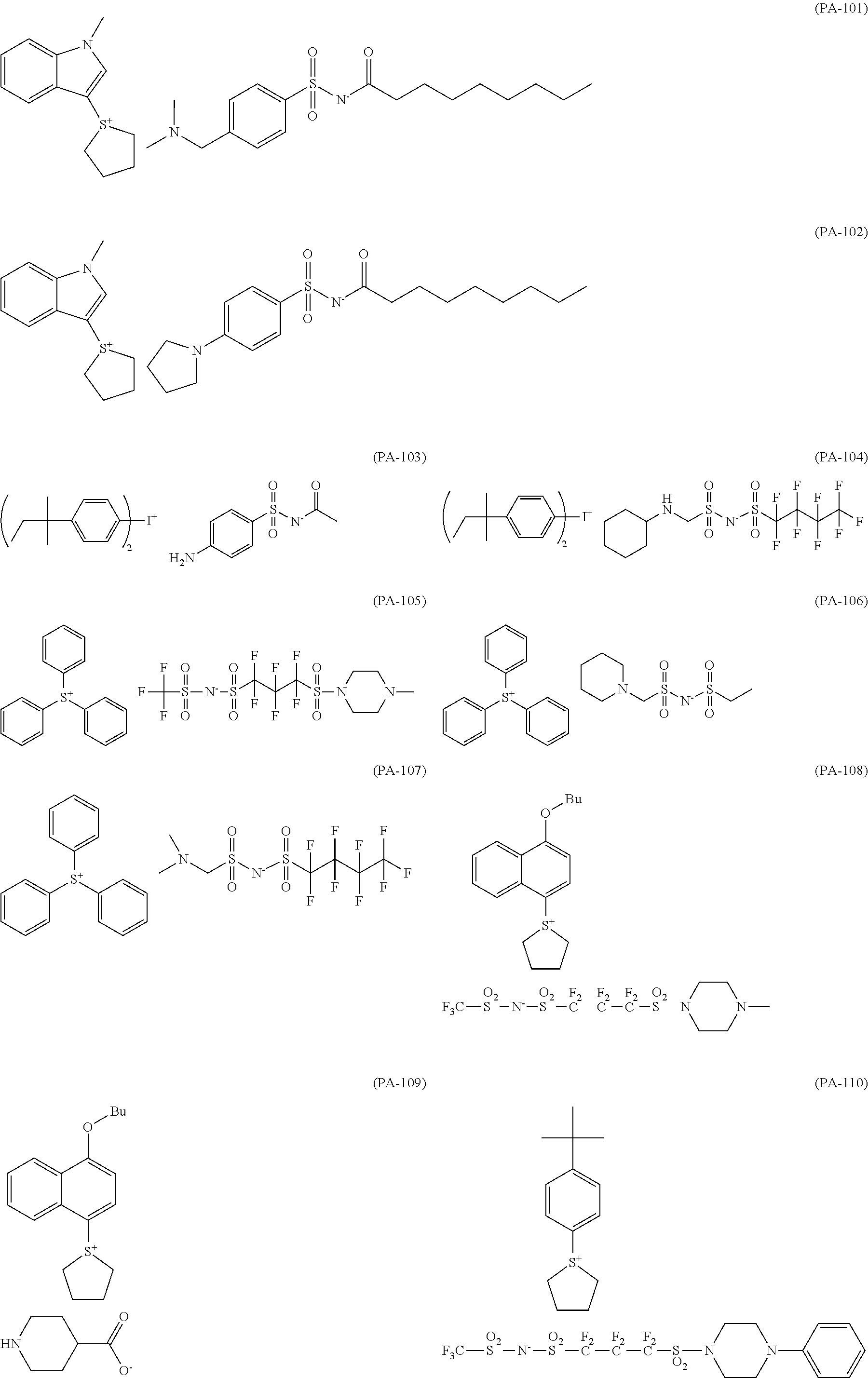

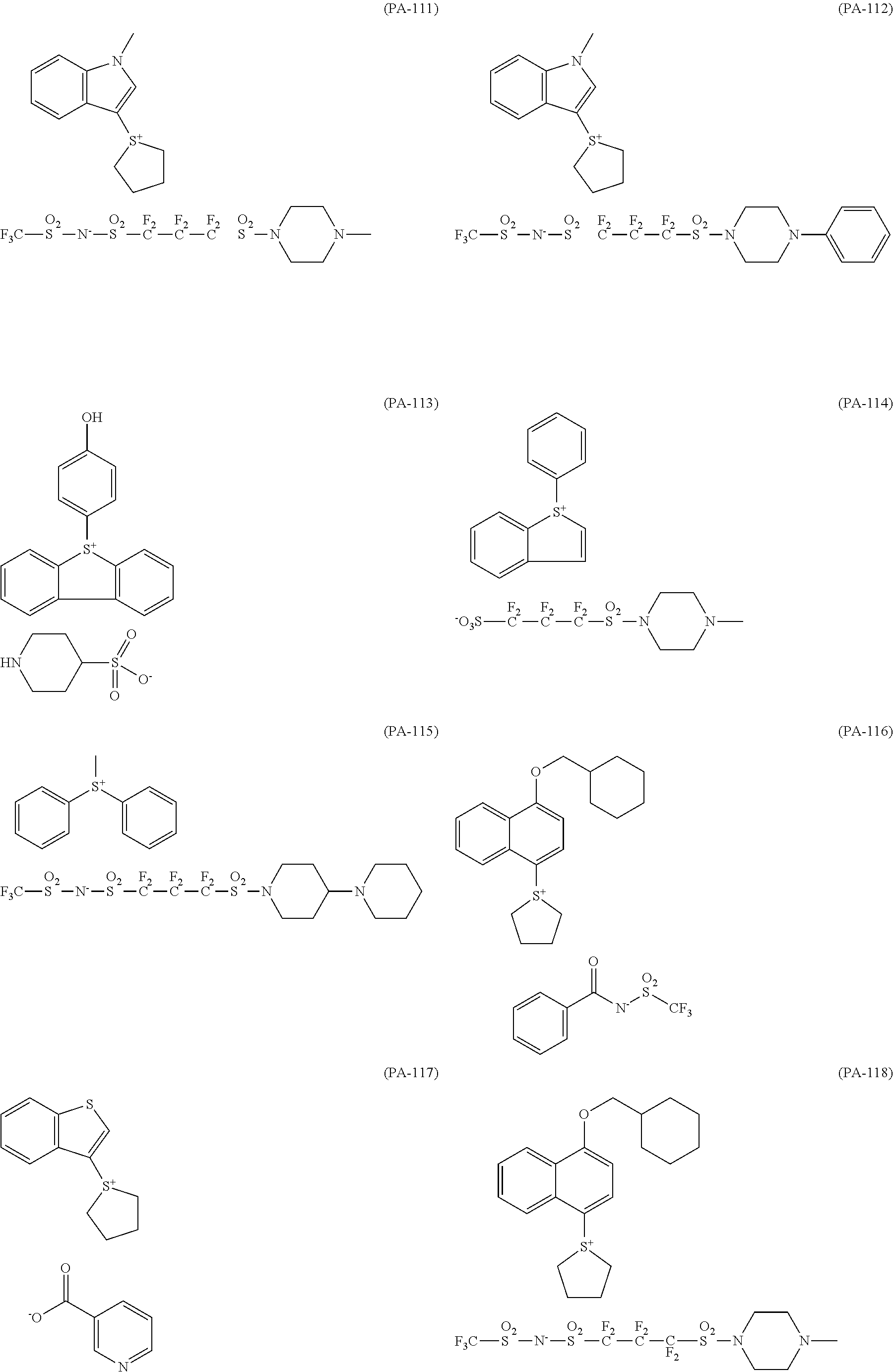

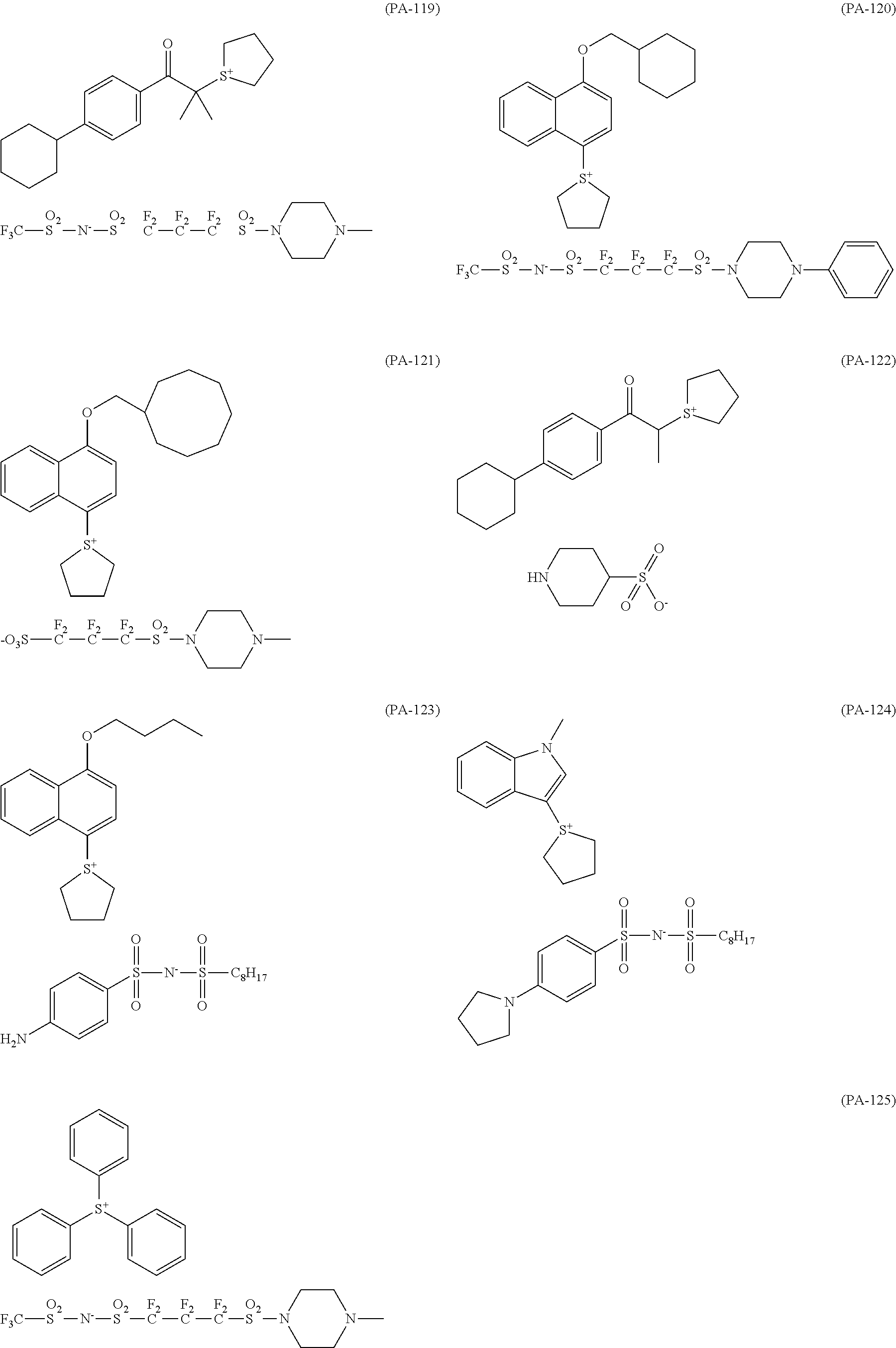

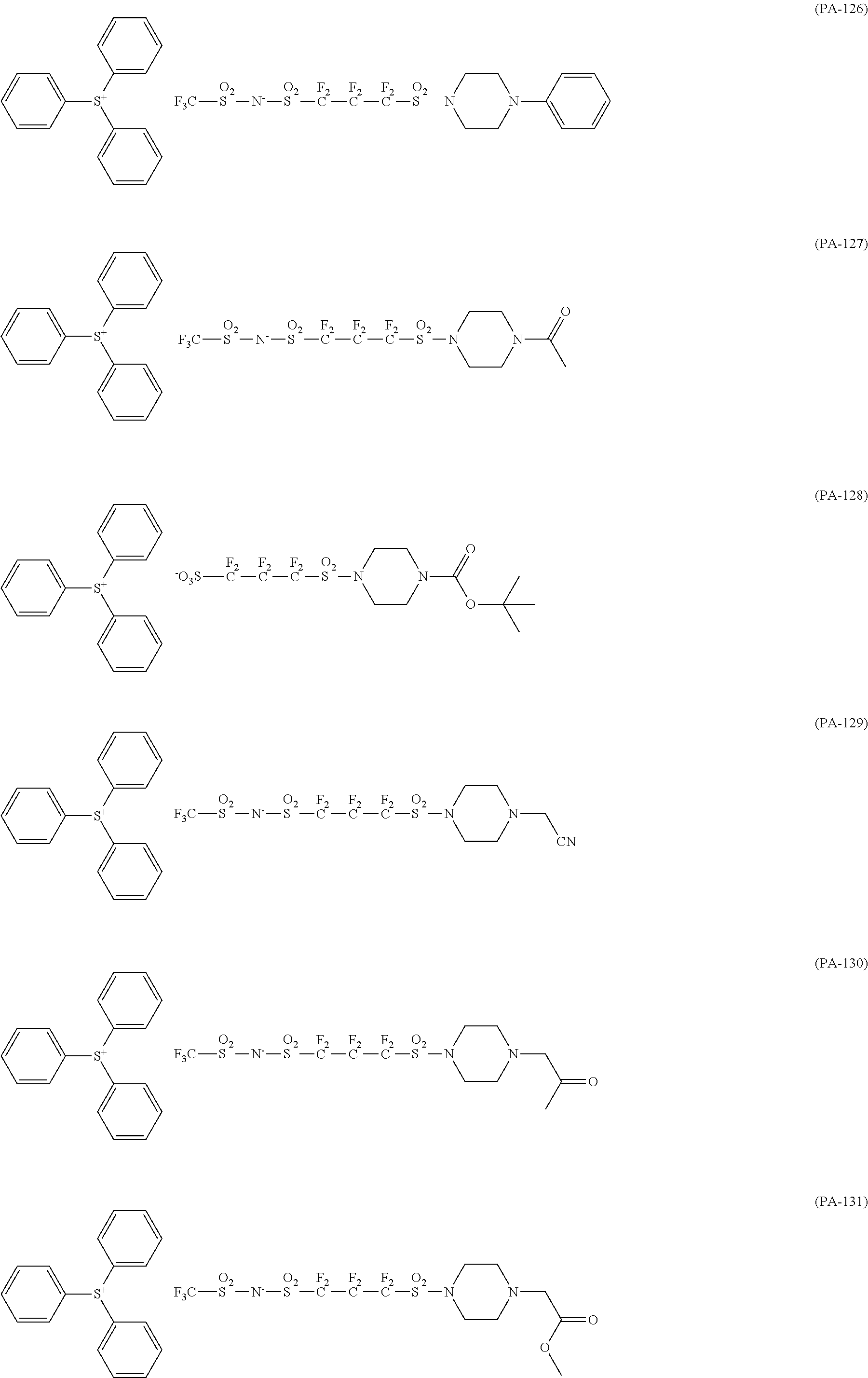

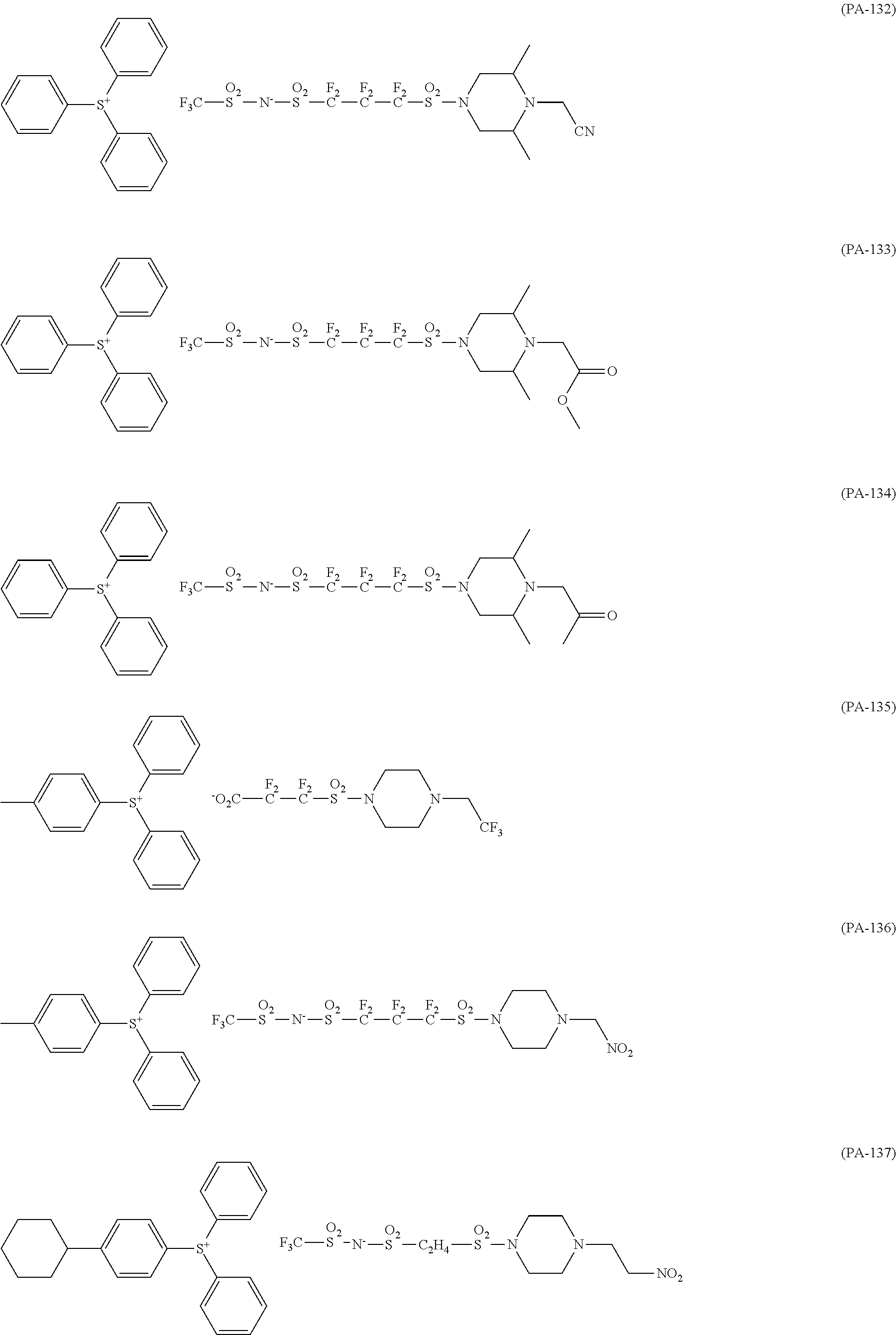

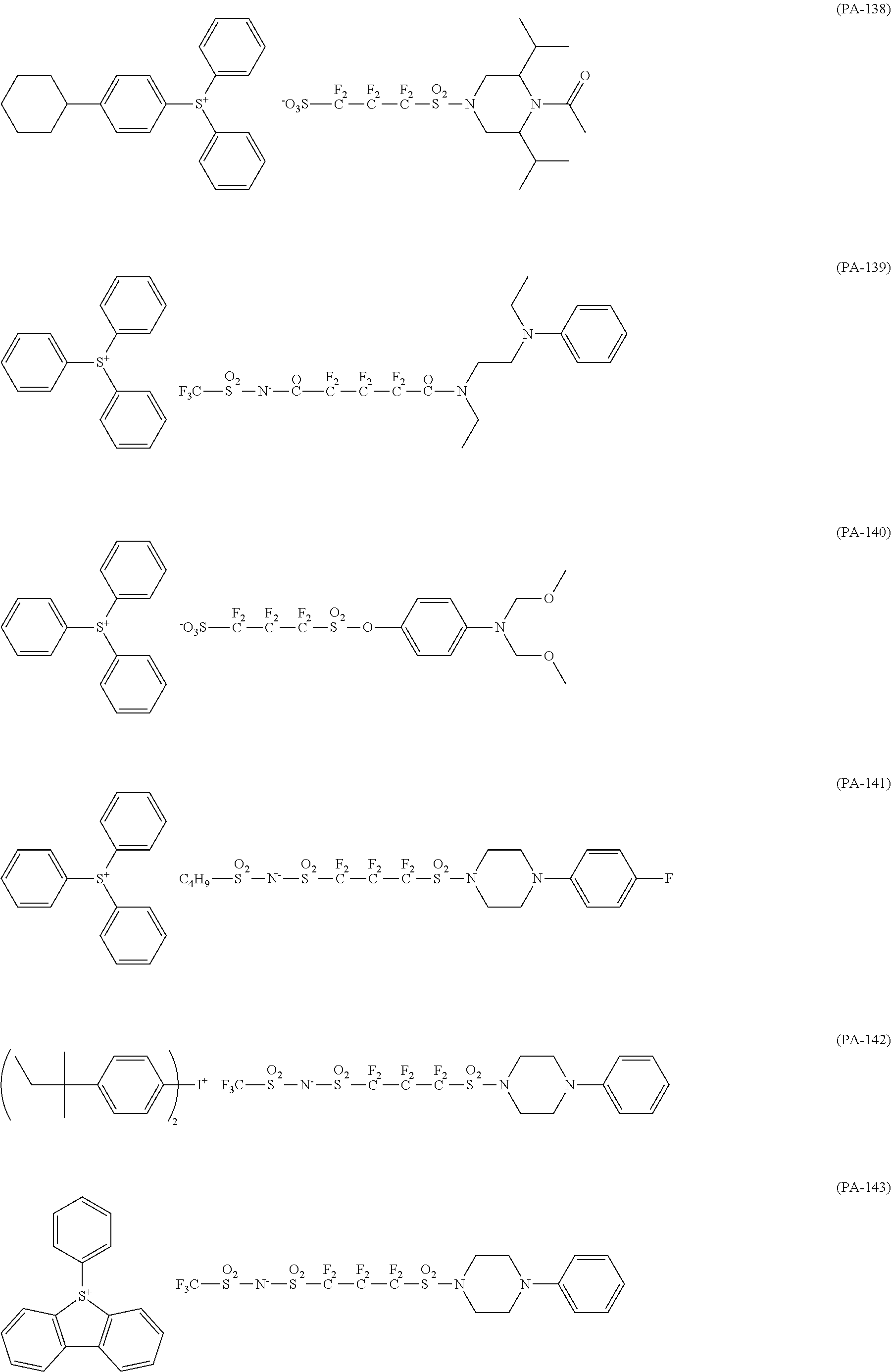

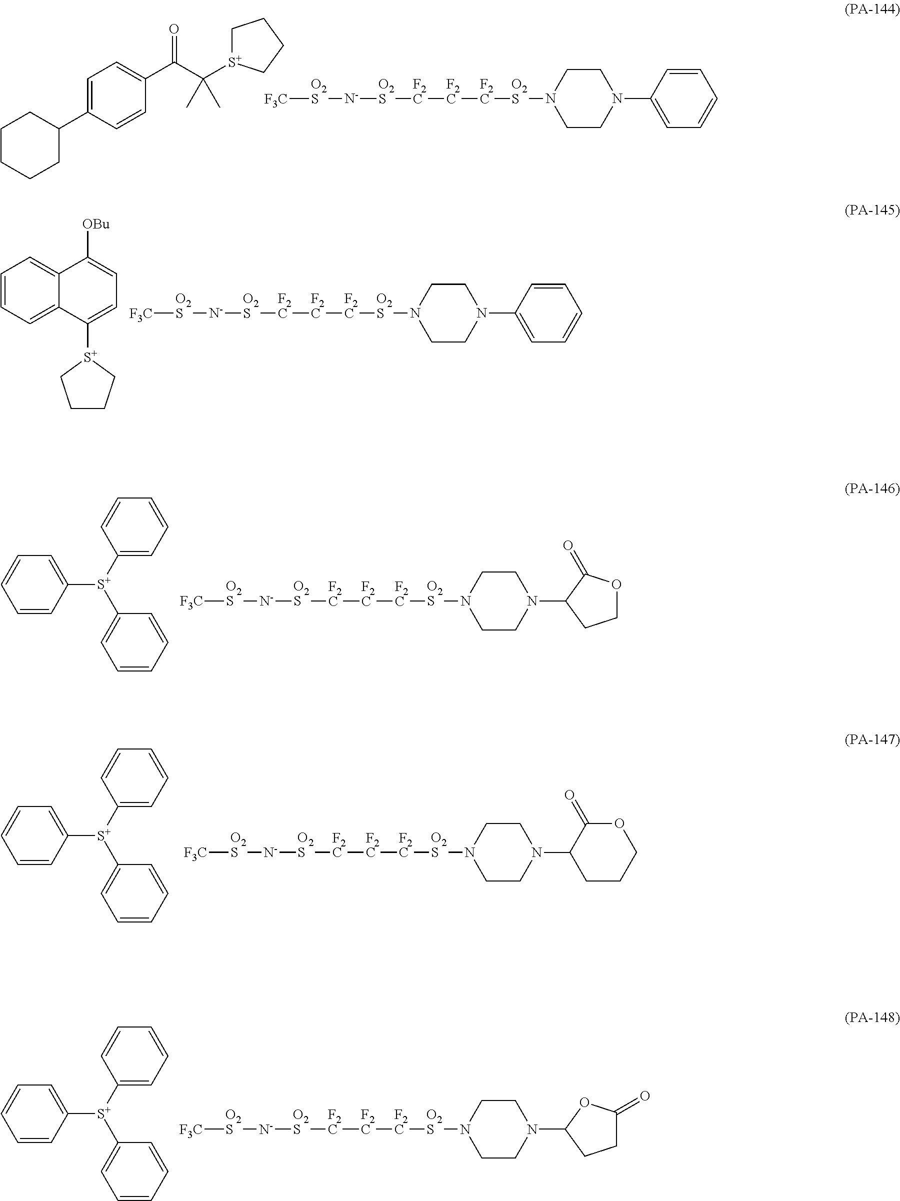

These compounds can be easily synthesized using a general a sulfonic esterification reaction or a sulfonamide-forming reaction. For example, the compounds can be obtained by a method in which a bissulfonyl halide compound is reacted in such a manner that one of the sulfonyl halide moieties is selectively reacted with an amine, alcohol, or the like including a partial structure represented by the general formula (PA-II) or (PA-III) to form a sulfonamide bond or a sulfonic ester bond, and thereafter the other sulfonyl halide moiety is hydrolyzed, or by a method in which a cyclic sulfonic anhydride is subjected to ring cleavage with an amine or alcohol including a partial structure represented by the general formula (PA-II). The amine or alcohol including a partial structure represented by the general formula (PA-II) or (PA-III) can be synthesized by reacting an amine or alcohol with an anhydride such as (R′O₂C)₂O, (R′SO₂)₂O, and the like, or an acid chloride compound such as R′O₂CCl, R′SO₂Cl, and the like (R′ represents a methyl group, an n-octyl group, a trifluoromethyl group, or the like) under basicity.

Synthesis of the compound (E) can be particularly based on Synthesis Examples of JP2006-330098A and JP2011-100105A, or the like.

The molecular weight of the compound (E) is preferably 500 to 1000.

The actinic-ray-sensitive or radiation-sensitive resin composition in the present invention may not contain a compound (E), but the content of the compound (E) is preferably from 0.1 to 20% by mass, and more preferably from 0.1 to 10% by mass, based on the solids of the actinic-ray-sensitive or radiation-sensitive resin composition.

[6] Surfactant

The composition of the present invention preferably further contains a surfactant. The surfactant is preferably a fluorinated and/or siliconized surfactant.

Examples of such a surfactant include Megafac F176 and Megafac R08 available from Dainippon Ink & Chemicals, Inc., PF656 or PF6320 available from Omnova Solutions, Inc., Troysol S-366 available from Troy Chemical Co., Ltd., Fluorad FC430 available from Sumitomo 3M Limited., polysiloxane polymer KP-341 available from Shin-Etsu Chemical Co., Ltd., and the like.

Furthermore, surfactants other than these fluorinated and/or siliconized surfactants may also be used. Specific examples thereof include polyoxyethylene alkyl ethers, polyoxyethylene alkyl aryl ethers, and the like.

Moreover, known surfactants can be appropriately used. Examples of the useful surfactants include those described in [0273] et seq in the specification of U.S. 2008/0248425 A1.

These surfactants may be used singly or in combination of two or more kinds thereof.

The amount of the surfactant to be used is preferably from 0 to 2% by mass, still more preferably from 0.0001 to 2% by mass, and particularly preferably from 0.0005 to 1% by mass, based on the total solids of the composition.

[7] Solvent

The solvent that is usable in the preparation of the composition is not particularly limited as long as it can dissolve the components of the composition, but examples thereof include an alkylene glycol monoalkyl ether carboxylate (propylene glycol monomethyl ether acetate or the like), an alkylene glycol monoalkyl ether (propylene glycol monomethyl ether or the like), an alkyl lactate (ethyl lactate, methyl lactate, or the like), a cyclolactone (γ-butyrolactone or the like, preferably having 4 to 10 carbon atoms), a linear or cyclic ketone (2-heptanone, cyclohexanone, or the like, preferably having 4 to 10 carbon atoms), an alkylene carbonate (ethylene carbonate, propylene carbonate or the like), an alkyl carboxylate (preferably an alkyl acetate such as butyl acetate), an alkyl alkoxyacetate (preferably ethyl ethoxypropionate) and the like. Examples of other useful solvents include those described in the paragraph [0244] et seq. of U.S. 2008/0248425 A1 and the like.

Among the above solvents, an alkylene glycol monoalkyl ether carboxylate, an alkylene glycol monoalkyl ether, and an ethyl lactate are preferred.

These solvents may be used singly or in combination of two or more kinds thereof. When two or more kinds of the solvents are mixed together, it is preferable to mix a hydroxylated solvent with a non-hydroxylated solvent. The mass ratio of the hydroxylated solvent to the non-hydroxylated solvent is 1/99 to 99/1, preferably 10/90 to 90/10, and more preferably 20/80 to 60/40.

The hydroxylated solvent is preferably an alkylene glycol monoalkyl ether or an alkyl lactate. The non-hydroxylated solvent is preferably an alkylene glycol monoalkyl ether carboxylate.

[8] Other Components

The composition of the present invention can appropriately contain, in addition to the above-described components, a dissolution-suppressing compound having a molecular weight of 3000 or less, a dye, a plasticizer, a photosensitizer, a light absorber, or the like as described in Proceeding of SPIE, 2724, 355 (1996), or the like.

[9] Pattern Forming Method

The composition of the present invention is used, for example, after the above components are dissolved in a solvent, filtered, and then applied onto a support. The filter is preferably made of polytetrafluoroethylene, polyethylene, or nylon having a pore size of 0.1 μm or less, more preferably 0.05 μm or less, and still more preferably 0.03 μm or less. In the filtration using a filter, for example, cyclic filtration may be carried out as described in JP2002-62667A or filtration with serial connection of different kinds of filters may be carried out. Further, in addition to the filtration using a filter, a deaeration process or the like may be added.

The composition is applied onto a substrate, such as one for use in the production of integrated circuit elements (for example, silicon/silicon dioxide coating), by appropriate application means, such as a spinner. Thereafter, the applied composition is dried to a photosensitive film.

This film is irradiated with an actinic-ray or a radiation through a predetermined mask, preferably baked (heated), developed, and rinsed. Thus, a favorable pattern can be obtained. Further, when the film is irradiated with an electron beam, lithography without a mask (direct lithography) is generally carried out.

The actinic-ray or the radiation is not particularly limited, and, for example, a KrF excimer laser, an ArF excimer laser, EUV light, an electron beam, or the like is preferable, and an ArF excimer laser, EUV light, or an electron beam is particularly preferable.

As the alkaline developer in the development step, a quaternary ammonium salt, typically such as tetramethylammonium hydroxide is used, but an inorganic alkali, a primary to tertiary amine, an alcoholamine, a cycloamine, and the like can also be used.

Furthermore, to the above alkaline developer, appropriate amounts of an alcohol and a surfactant may be further added.

The alkali concentration of the alkaline developer is generally from 0.1 to 20% by mass.

The pH value of the alkaline developer is generally from 10.0 to 15.0.

Pure water can be used as the rinse liquid, and an appropriate amount of surfactant may be added thereto and then used.

Moreover, prior to the formation of a photosensitive film, a substrate may be coated with an antireflection film. As the antireflection film, not only an inorganic film of titanium, titanium oxide, titanium nitride, chromium oxide, carbon, amorphous silicon and the like but also an organic film composed of a light absorber and a polymer substance can be used. Further, as the organic antireflection film, commercially available organic antireflection films, such as the DUV30 Series and DUV40 Series available from Brewer Science Inc., AR-2, AR-3, and AR-5 available from Shipley Co., L.L.C., and the like can be used.

The interstice between the film and a lens may be filled with a liquid (immersion medium) whose refractive index is higher than that of air during irradiation with an actinic-ray or a radiation to carry out exposure (liquid immersion exposure). This would bring about an enhancement of the resolution power. The liquid for liquid immersion to be used is preferably water. Water is preferred from the viewpoint of a refractive index with a low temperature coefficient, easy availability and easy handling.

Furthermore, a medium having a refractive index of 1.5 or more can be used since it can improve the refractive index. This medium may be an aqueous solution or an organic solvent.

In the case of using water as the liquid for liquid immersion, additives for the purpose of improving the refractive index, and the like may be added at some proportions. Examples of such additives are particularized in Chapter 12 of “Process and Material of Liquid Immersion Lithography” published by CMC Publishing Co., Ltd. On the other hand, the presence of a substance being opaque against the 193-nm light or presence of an impurity whose refractive index is greatly different from that of water invites a distortion of optical image projected on the film. Accordingly, it is preferred to use distilled water as the water to be used. Further, use may be made of water having been purified through an ion exchange filter or the like. The electrical resistance of pure water is preferably 18.3 MΩcm or more, and the TOC (total organic carbon) thereof is preferably 20 ppb or less. The deaeration treatment is desirable.

[10] Hydrophobic Resin

The actinic-ray-sensitive or radiation-sensitive resin composition of the present invention may further include a hydrophobic resin containing at least one of a fluorine atom and a silicon atom (which is also referred to as a “hydrophobic resin (HR)”), particularly when it is applied for liquid immersion exposure. This would bring about uneven localization of the hydrophobic resin (HR) on the surface layer of the film, and in the case where the liquid for liquid immersion is water, there would be attained an improvement of the static/dynamic contact angle on the resist film surface with reference to water, and accordingly an enhancement of the traceability of the liquid for liquid immersion.

Although the hydrophobic resin (HR) is unevenly localized on the interface as aforementioned, differing from the surfactant, the hydrophobic resin does not necessarily have to have a hydrophilic group in its molecule and does not need to contribute toward uniform mixing of polar/nonpolar substances.

The hydrophobic resin typically contains a fluorine atom and/or a silicon atom. The fluorine atom and/or the silicon atom in the hydrophobic resin (HR) may be contained in the main chain or the side chain of the resin.

In the case where the hydrophobic resin contains a fluorine atom, the fluorine atom-containing partial structure is preferably a resin having a fluorine atom-containing alkyl group, a fluorine atom-containing cycloalkyl group, or a fluorine atom-containing aryl group.

The alkyl group containing a fluorine atom is a linear or branched alkyl group in which at least one hydrogen atom is substituted with a fluorine atom, preferably having 1 to 10 carbon atoms, and more preferably having 1 to 4 carbon atoms, and may have another substituent.

The cycloalkyl group containing a fluorine atom is a monocyclic or polycyclic cycloalkyl group in which at least one hydrogen atom is substituted with a fluorine atom, and may have another substituent.

Examples of the fluorine atom-containing aryl group include an aryl group such as a phenyl, a naphthyl group, and the like, in which at least one hydrogen atom is substituted with a fluorine atom, and may have another substituent.

Preferable examples of the fluorine atom-containing alkyl group, the fluorine atom-containing cycloalkyl group, and the fluorine atom-containing aryl group include a group represented by any one of the following general formulae (F2) to (F4), but the present invention is not limited thereto.

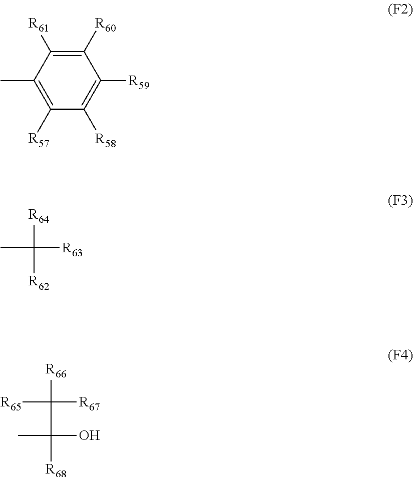

In the general formulae (F2) to (F4),

each of R₅₇ to R₆₈ independently represents a hydrogen atom, a fluorine atom, or an (linear or branched) alkyl group, provided that at least one of R₅₇ to R₆₁, at least one of R₆₂ to R₆₄, and at least one of R₆₅ to R₆₈ represents a fluorine atom, or an alkyl group (preferably having 1 to 4 carbon atoms) having at least one hydrogen atom thereof substituted with a fluorine atom.

It is preferable that all of R₅₇ to R₆₁ and R₆₅ to R₆₇ be fluorine atoms. R₆₂, R₆₃, and R₆₈ are preferably fluoroalkyl groups (preferably having 1 to 4 carbon atoms), and more preferably perfluoroalkyl groups having 1 to 4 carbon atoms. When R₆₂ and R₆₃ are perfluoroalkyl groups, R₆₄ is preferably a hydrogen atom. R₆₂ and R₆₃ may be bonded to each other to form a ring.

Specific examples of the group represented by the general formula (F2) include a p-fluorophenyl group, a pentafluorophenyl group, a 3,5-di(trifluoromethyl)phenyl group and the like.

Specific examples of the group represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferred, and a hexafluoroisopropyl group and a heptafluoroisopropyl group are more preferred.

Specific examples of the group represented by the general formula (F4) include —C(CF₃)₂OH, —C(C₂F₅)₂OH, —C(CF₃)(CF₃)OH, —CH(CF₃)OH, and the like, and —C(CF₃)₂OH is preferred.

The fluorine atom-containing partial structure may be bonded directly to the main chain or may be bonded to the main chain through a group selected from the group consisting of an alkylene group, a phenylene group, an ether bond, a thioether bond, a carbonyl group, an ester bond, an amide bond, a urethane bond, and a ureylene bond, or a group formed by combination of two or more of these groups and bonds.

Examples of the preferable fluorine atom-containing repeating unit will be shown below.

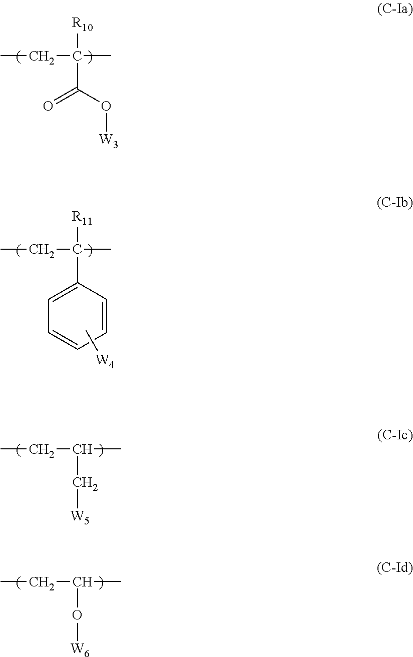

In the formulae, each of R₁₀ and R₁₁ independently represents a hydrogen atom, a fluorine atom, or an alkyl group. The alkyl group is preferably a linear or branched alkyl group having 1 to 4 carbon atoms, and may have a substituent, and examples of the alkyl group having a substituent includes, in particular, a fluorinated alkyl group.

Each of W₃ to W₆ independently represents an organic group having at least one or more fluorine atoms. Specific examples thereof include the atomic groups of (F2) to (F4) above.

Furthermore, the hydrophobic resin may further contain, in addition to these, the units as shown below, as a fluorine atom-containing repeating unit.

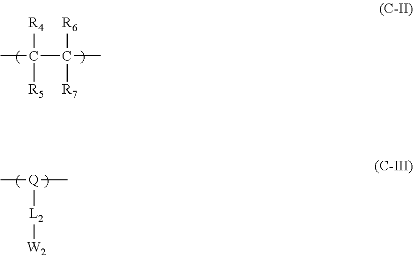

In the formulae, each of R₄ to R₇ independently represents a hydrogen atom, a fluorine atom, or an alkyl group. The alkyl group is preferably a linear or branched alkyl group having 1 to 4 carbon atoms and may have a substituent, and examples of the alkyl group having a substituent includes, in particular, a fluorinated alkyl group.

However, at least one of R₄ to R₇ represents a fluorine atom. R₄ and R₅ or R₆ and R₇ may form a ring.

W₂ represents an organic group containing at least one fluorine atom. Specific examples thereof include the atomic groups of (F2) to (F4) above.

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combination of a plurality of these groups.

Q represents an alicyclic structure. The alicyclic structure may have a substituent and may be monocyclic or polycyclic, and in the case of a polycyclic structure, the structure may be a crosslinked structure. The monocyclic structure is preferably a cycloalkyl group having 3 to 8 carbon atoms, and examples thereof include a cyclopentyl group, a cyclohexyl group, a cyclobutyl group, a cyclooctyl group, and the like. Examples of the polycyclic structure include a group containing a bicyclo structure, a tricyclo structure, a tetracyclo structure, and the like, having 5 or more carbon atoms. A cycloalkyl group having 6 to 20 carbon atoms is preferred, and examples thereof include an adamantyl group, a norbornyl group, a dicyclopentyl group, a tricyclodecanyl group, a tetracyclododecyl group, and the like. A part of carbon atoms in the cycloalkyl group may be substituted with a heteroatom such as an oxygen atom and the like. Particularly preferable examples of Q include a norbornyl group, a tricyclodecanyl group, a tetracyclododecyl group, and the like.

The hydrophobic resin may contain a silicon atom.

The resin preferably has an alkylsilyl structure (preferably a trialkylsilyl group) or a cyclic siloxane structure as the silicon atom-containing partial structure.

Specific examples of the alkylsilyl structure and the cyclic siloxane structure include the groups represented by the following general formulae (CS-1) to (CS-3), and the like.

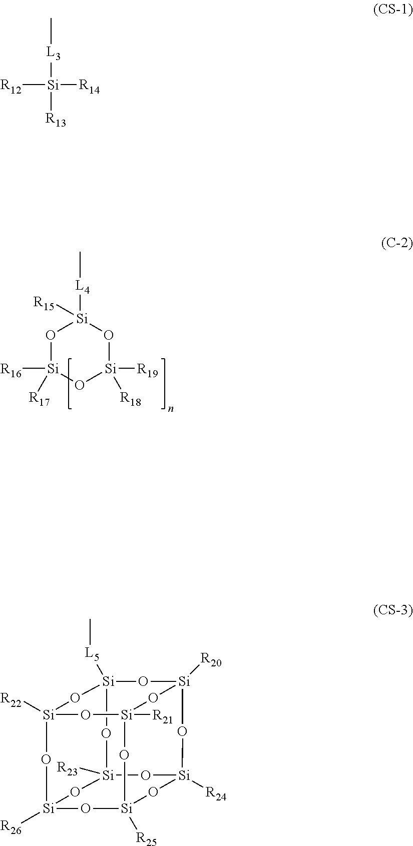

In the general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group include a sole group or a combination of two or more groups selected from the group consisting of an alkylene group, a phenylene group, an ether bond, a thioether bond, a carbonyl group, an ester bond, an amide bond, a urethane bond, and a ureylene bond.

n represents an integer of 1 to 5. n is preferably an integer of 2 to 4.

The repeating unit having at least either a fluorine atom or a silicon atom is preferably a (meth)acrylate-based repeating unit.

Specific examples of the repeating unit having at least either a fluorine atom or a silicon atom will be shown below, but the present invention is not limited thereto. Further, in the specific examples, X₁ represents a hydrogen atom, —CH₃, —F, or —CF₃, and X₂ represents —F or —CF₃.

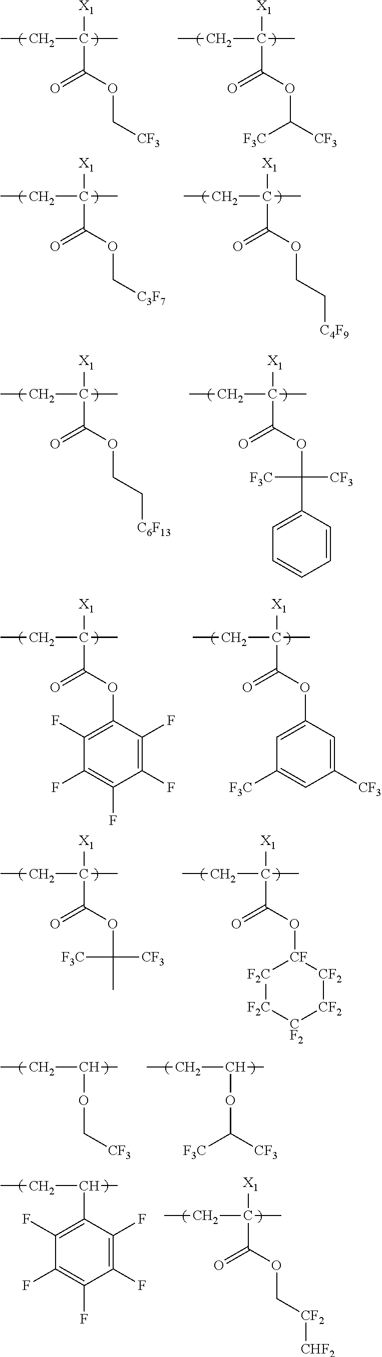

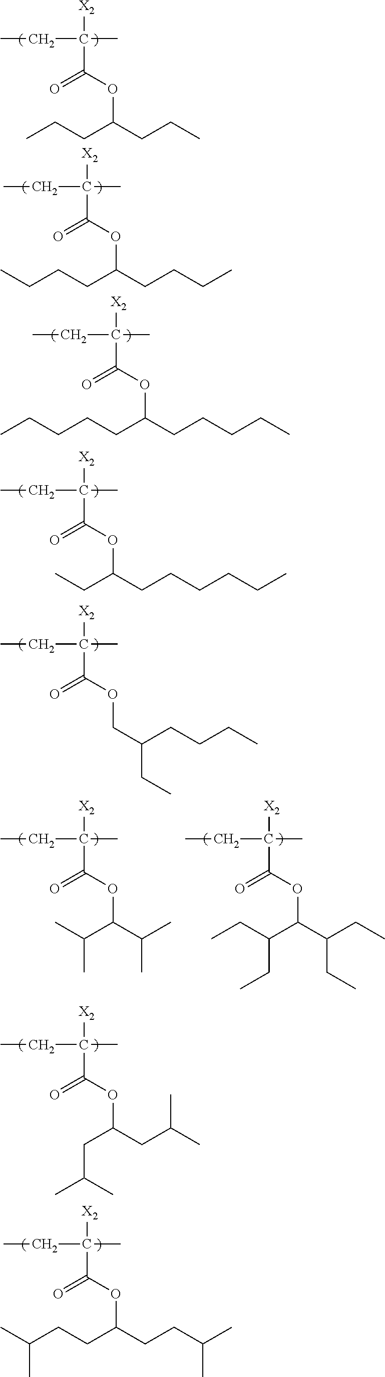

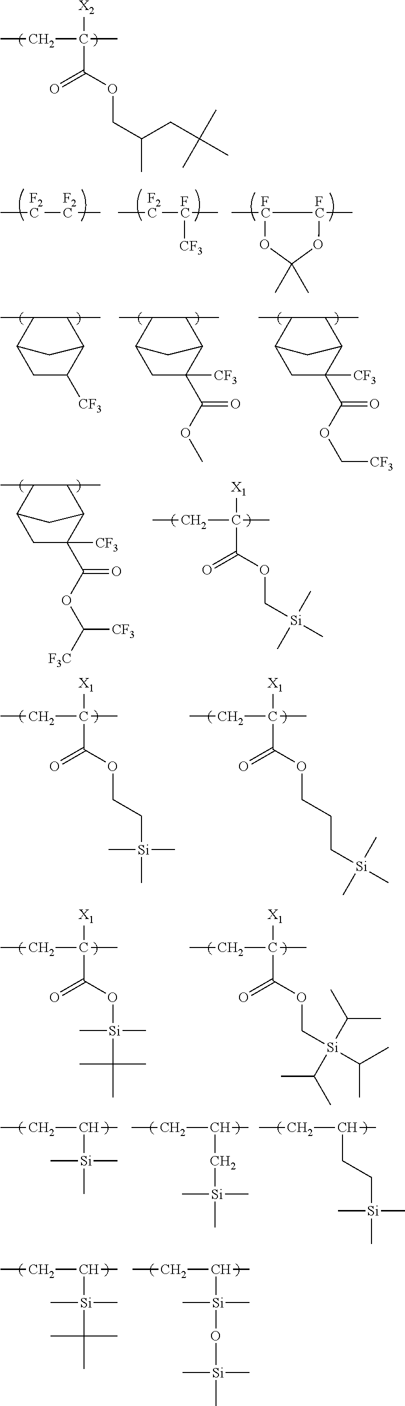

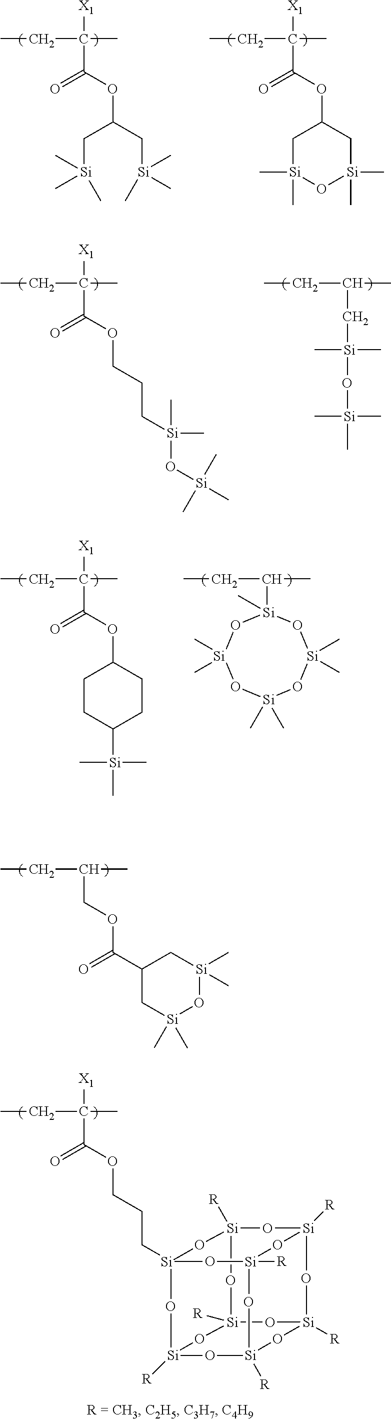

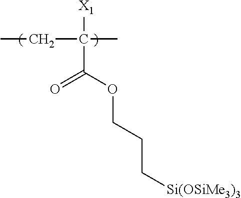

The hydrophobic resin preferably contains (b) a repeating unit having at least one group selected from the group consisting of following (x) to (z):

(x) an alkali-soluble group,

(y) a group which decomposes by the action of an alkaline developer to increase the solubility in an alkaline developer (hereinafter also referred to as “polarity converting group”), and

(z) a group which decomposes by the action of an acid to increase the solubility in an alkaline developer.

The repeating unit (b) includes the following types:
(b′) a repeating unit having at least either a fluorine atom or a silicon atom and at least one group selected from the group consisting of (x) to (z) above, on one side chain,
(b*) a repeating unit having at least one group selected from the group consisting of (x) to (z) above and having neither a fluorine atom nor a silicon atom, and
(b″) a repeating unit having at least one group selected from the group consisting of (x) to (z) above on one side chain and at the same time, having at least either a fluorine atom or a silicon atom on a side chain different from the side chain above in the same repeating unit.

The hydrophobic resin more preferably contains a repeating unit (b′) as the repeating unit (b). That is, it the repeating unit (b) having at least one group selected from the group consisting of (x) to (z) above still more preferably has at least either a fluorine atom or a silicon atom.

In the case where the hydrophobic resin contains the repeating unit (b*), the resin is preferably a copolymer with a repeating unit having at least either a fluorine atom or a silicon atom (a repeating unit different from the repeating units (b′) and (b″) above). Further, in the repeating unit (b″), the side chain having at least one group selected from the group consisting of (x) to (z) and the side chain having at least either a fluorine atom or a silicon atom are preferably bonded to the same carbon atom in the main chain, that is, have a positional relationship like the following formula (K1).

In the formula, B1 represents a partial structure having at least one group selected from the group consisting of (x) to (z), and B2 represents a partial structure having at least either a fluorine atom or a silicon atom.

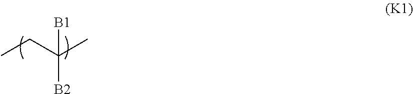

The group selected from the group consisting of (x) to (z) is preferably (x) an alkali-soluble group or (y) a polarity converting group, and more preferably (y) a polarity converting group.

Examples of the alkali-soluble group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group, and the like.

Preferred alkali-soluble groups include a fluorinated alcohol group (preferably hexafluoroisopropanol), a sulfonimido group and a bis(carbonyl)methylene group.

The repeating unit (bx) having (x) an alkali-soluble group includes a repeating unit where an alkali-soluble group is directly bonded to the main chain of the resin, such as repeating unit of an acrylic acid or a methacrylic acid; a repeating unit where an alkali-soluble group is bonded to the main chain of the resin through a linking group; and the like. Further, an alkali-soluble group may be introduced into the polymer chain terminal by using an alkali-soluble group-containing polymerization initiator or chain transfer agent at the polymerization. All of these cases are preferable.

In the case where the repeating unit (bx) is a repeating unit having at least either a fluorine atom or a silicon atom (that is, a repeating unit corresponding to the repeating unit (b′) or (b″)), examples of the fluorine atom-containing partial structure in the repeating unit (bx) are the same as those in the above-described repeating unit having at least either a fluorine atom or a silicon atom, and the groups represented by the general formulae (F2) to (F4) are preferred. Further, examples of the silicon atom-containing partial structure in the repeating unit (bx) include the same as those in the above-described repeating unit having at least either a fluorine atom or a silicon atom, and the groups represented by the general formulae (CS-1) to (CS-3) are preferred.

The content of the repeating unit (bx) having (x) an alkali-soluble group is preferably from 1 to 50 mol %, more preferably from 3 to 35 mol %, and still more preferably from 5 to 20 mol %, based on all the repeating units in the hydrophobic resin.

Specific examples of the repeating unit (bx) having (x) an alkali-soluble group are illustrated below, but the present invention is not limited thereto. In specific examples, X₁ represents a hydrogen atom, —CH₃, —F, or —CF₃.

(In the formulae, Rx represents H, CH₃, CH₂OH, or CF₃)

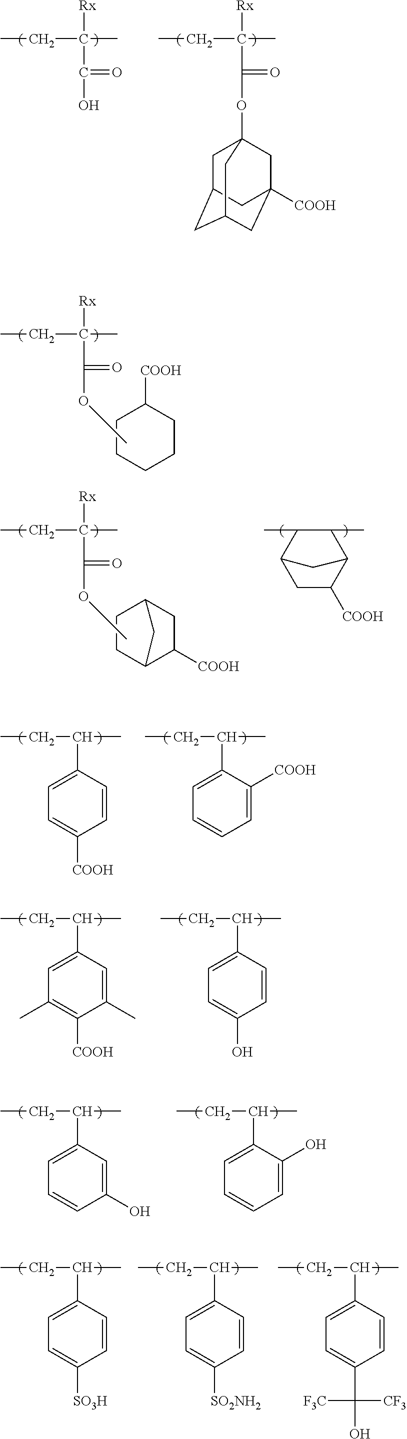

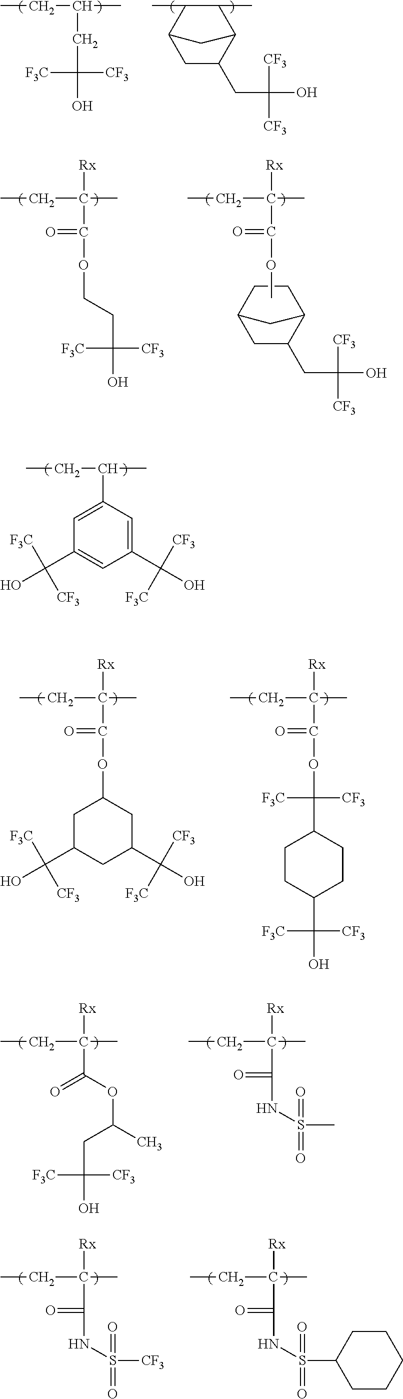

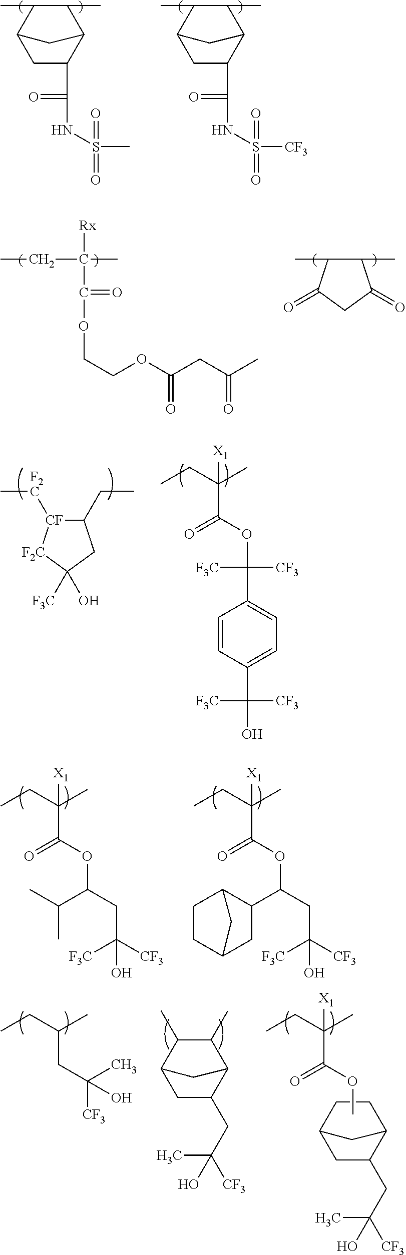

Examples of the polarity converting group (y) include a lactone group, a carboxylic ester group (—COO—), an acid anhydride group (—C(O)OC(O)—), an acid imido group (—NHCONH—), a carboxylic acid thioester group (—COS—), a carbonic ester group (—OC(O)O—), a sulfuric ester group (—OSO₂O—), a sulfonic ester group (—SO₂O), and the like, with a lactone group being preferred.

As for the polarity converting group (y), both an embodiment where the group is contained, for example, in a repeating unit of an acrylic ester or a methacrylic ester and thereby is introduced into the side chain of the resin, and an embodiment where the group is introduced into the terminal of the polymer chain by using a polymerization initiator or chain transfer agent having (y) a polarity converting group, are preferable.

Specific examples of the repeating unit (by) having (y) a polarity converting group include repeating units having a lactone structure represented by formulae (KA-1-1) to (KA-1-17) described later.

The repeating unit (by) having (y) a polarity converting group is preferably a repeating unit having at least either a fluorine atom or a silicon atom (that is, a repeating unit corresponding to the repeating unit (b′) or (b″)). The resin containing the repeating unit (by) has hydrophobicity, and this is preferable, particularly in view of reduction of development defect.

Examples of the repeating unit (by) include a repeating unit represented by the general formula (K0).

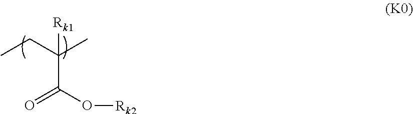

In the formula, Rₖ₁ represents a hydrogen atom, a halogen atom, a hydroxyl group, an alkyl group, a cycloalkyl group, an aryl group, or a polarity converting group-containing group.

Rₖ₂ represents an alkyl group, a cycloalkyl group, an aryl group, or a polarity converting group-containing group.

However, at least either one of Rₖ₁ and Rₖ₂ represents a polarity converting group-containing group.

The polarity converting group indicates a group which decomposes by the action of an alkaline developer to increase the solubility in an alkaline developer, as described above. The polarity converting group is preferably a group X in a partial structure represented by the general formula (KA-1) or (KB-1).

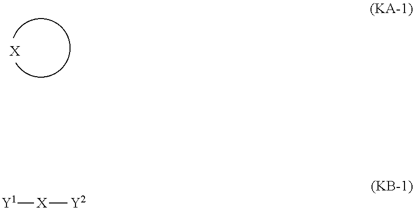

In general formulae (KA-1) and (KB-1), X represents a carboxylic ester group: —COO—, an acid anhydride group: —C(O)OC(O)—, an acid imido group: —NHCONH—, a carboxylic acid thioester group: —COS—, a carbonic ester group: —OC(O)O—, a sulfuric ester group: —OSO₂O—, or a sulfonic ester group: —SO₂O—.

Each of Y¹ and Y² which may be the same as or different from each other, represents an electron-withdrawing group.

Moreover, the repeating unit (by) contains a group having a partial structure represented by the general formula (KA-1) or (KB-1) and thereby has a preferable group capable of increasing the solubility in an alkaline developer, and as in the case of the partial structure represented by the general formula (KA-1) or the partial structure represented by (KB-1) where Y¹ and Y² are monovalent, when the partial structure does not have a bond, the group having the partial structure is a group having a monovalent or higher valent group formed by removing at least one arbitrary hydrogen atom in the partial structure.

The partial structure represented by the general formula (KA-1) or (KB-1) is connected to the main chain of the hydrophobic resin at an arbitrary position through a substituent.

The partial structure represented by the general formula (KA-1) is a structure forming a ring structure together with the group as X.

In the formula (KA-1), X is preferably a carboxylic ester group (that is, a case of forming a lactone ring structure as KA-1), an acid anhydride group or a carbonic ester group, and more preferably a carboxylic ester group.

The ring structure represented by the general formula (KA-1) may have a substituent and, for example, may have nka substituents Zₖₐ₁.

When a plurality of Zₖₐ₁'s are present, each of them independently represents a halogen atom, an alkyl group, a cycloalkyl group, an ether group, a hydroxyl group, an amido group, an aryl group, a lactone ring group or an electron-withdrawing group.

Zₖₐ₁'s may be combined with each other to form a ring. Examples of the ring formed by mutual linking of Zₖₐ₁'s include a cycloalkyl ring and a heterocyclic ring (for example, a cyclic ether ring, a lactone ring, and the like).

nka represents an integer of 0 to 10, preferably an integer of 0 to 8, more preferably an integer of 0 to 5, still more preferably an integer of 1 to 4, and most preferably an integer of 1 to 3.

The electron-withdrawing group as Zₖₐ₁ has the same meaning as the electron-withdrawing group of Y¹ and Y² as described later. The electron-withdrawing group above may be substituted with another electron-withdrawing group.

Zₖₐ₁ is preferably an alkyl group, a cycloalkyl group, an ether group, a hydroxyl group or an electron-withdrawing group, more preferably an alkyl group, a cycloalkyl group or an electron-withdrawing group. The ether group is preferably an ether group substituted, for example, with an alkyl group or a cycloalkyl group, that is, an alkyl ether group, or the like. The electron-withdrawing group has the same meaning as above.

Examples of the halogen atom as Zₖₐ₁ include a fluorine atom, a chlorine atom, a bromine atom, an iodine atom, and the like with a fluorine atom being preferred.

The alkyl group as Zₖₐ₁ may have a substituent and may be either linear or branched. The linear alkyl group is preferably an alkyl group having 1 to 30 carbon atoms, and more preferably having 1 to 20 carbon atoms, and examples thereof include a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group, and the like. The branched alkyl group is preferably an alkyl group having 3 to 30 carbon atoms, and more preferably 3 to 20 carbon atoms, and examples thereof include an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanoyl group, and the like. An alkyl group having 1 to 4 carbon atoms, such as a methyl group, an ethyl group, an n-propyl group, an i-propyl group, an n-butyl group, an i-butyl group, a t-butyl group, and the like, is preferable.

The cycloalkyl group as Zₖₐ₁ may have a substituent and may be monocyclic or polycyclic, and in the case of polycyclic, the cycloalkyl group may be a crosslinked cycloalkyl group. That is, in this case, the cycloalkyl group may have a bridged structure. The monocyclic cycloalkyl group is preferably a cycloalkyl group having 3 to 8 carbon atoms, and examples thereof include a cyclopropyl group, a cyclopentyl group, a cyclohexyl group, a cyclobutyl group, a cyclooctyl group, and the like. The polycyclic cycloalkyl group includes a group having a bicyclo structure, a tricyclo structure, a tetracyclo structure, and the like and having 5 or more carbon atoms, and a cycloalkyl group having 6 to 20 carbon atoms is preferable. Examples thereof include an adamantyl group, a norbornyl group, an isobornyl group, a camphanyl group, a dicyclopentyl group, an α-pinel group, a tricyclodecanyl group, a tetracyclododecyl group and an androstanyl group. As the cycloalkyl group, structures shown below are also preferable. Incidentally, a part of carbon atoms in the cycloalkyl group may be substituted for by a heteroatom such as an oxygen atom and the like.

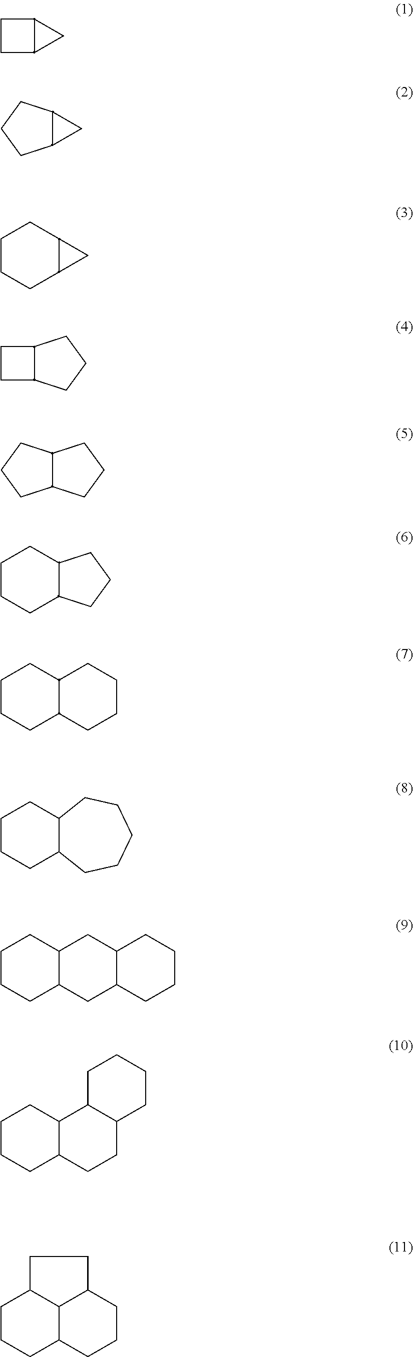

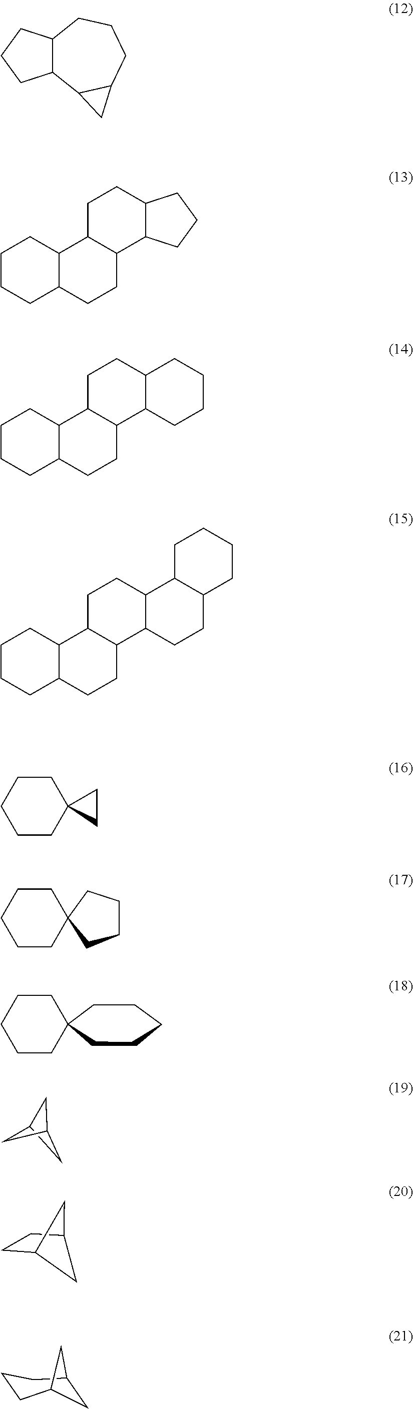

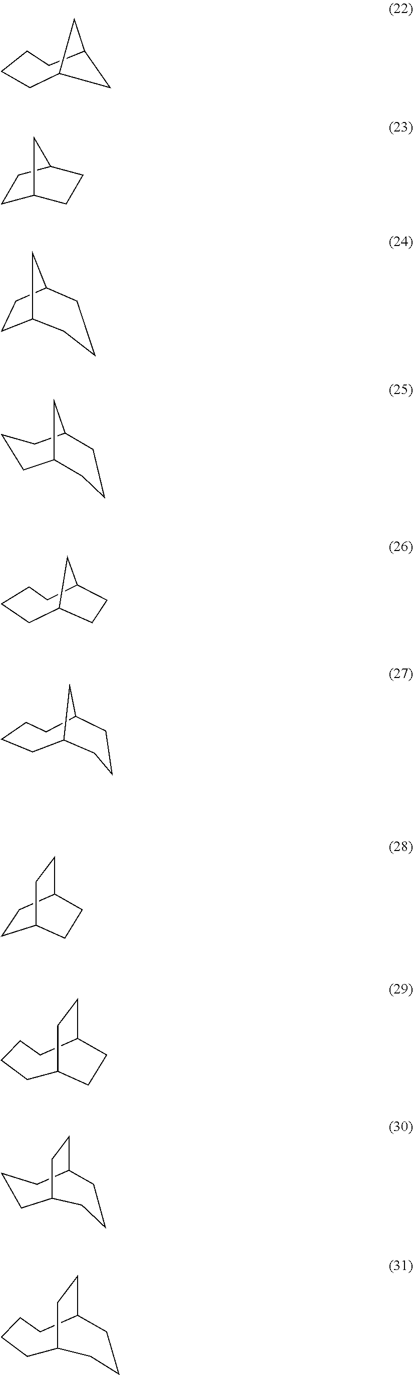

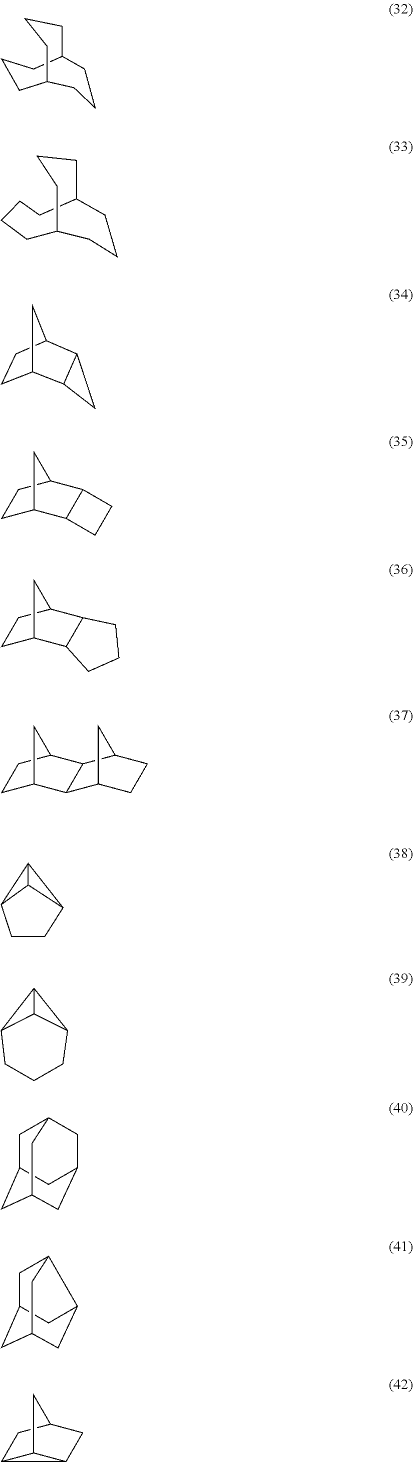

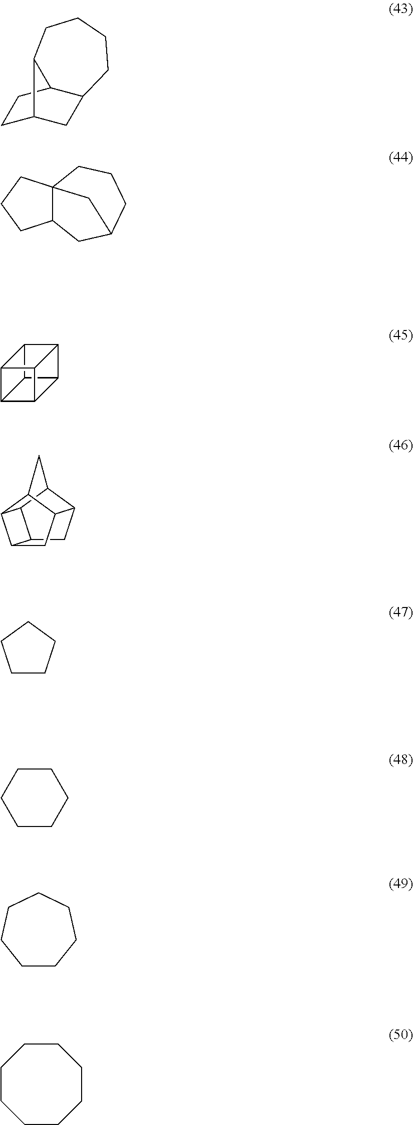

Preferable examples of the alicyclic moiety include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group. An adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group are more preferred.

The substituent of the alicyclic structure includes an alkyl group, a halogen atom, a hydroxyl group, an alkoxy group, a carboxyl group and an alkoxycarbonyl group. The alkyl group is preferably a lower alkyl group such as a methyl group, an ethyl group, a propyl group, an isopropyl group, a butyl group, and the like, and more preferably a methyl group, an ethyl group, a propyl group or an isopropyl group. The alkoxy group is preferably an alkoxy group having 1 to 4 carbon atoms, such as a methoxy group, an ethoxy group, a propoxy group, a butoxy group, and the like. Examples of the substituent which the alkyl group and alkoxy group may have include a hydroxyl group, a halogen atom, an alkoxy group (preferably having 1 to 4 carbon atoms), and the like.

Furthermore, the groups above may further have a substituent, and examples of the further substituent include a hydroxyl group, a halogen atom (for example, fluorine, chlorine, bromine, and iodine), a nitro group, a cyano group, the above-described alkyl group, an alkoxy group such as a methoxy group, an ethoxy group, a hydroxyethoxy group, a propoxy group, a hydroxypropoxy group, an n-butoxy group, an isobutoxy group, a sec-butoxy group, a t-butoxy group, and the like, an alkoxycarbonyl group such as a methoxycarbonyl group, an ethoxycarbonyl group, and the like, an aralkyl group such as a benzyl group, a phenethyl group, a cumyl group, and the like, an acyl group such as an aralkyloxy group, a formyl group, an acetyl group, a butyryl group, a benzoyl group, a cinnamyl group, a valeryl group, and the like, an acyloxy group such as a butyryloxy group and the like, the above-described alkenyl group, an alkenyloxy group such as a vinyloxy group, a propenyloxy group, an allyloxy group, a butenyloxy group, and the like, the above-described aryl group, an aryloxy group such as a phenoxy group and the like, and an aryloxycarbonyl group such as a benzoyloxy group and the like.

It is preferable that X in the general formula (KA-1) be a carboxylic ester group and the partial structure represented by the general formula (KA-1) be a lactone ring, and preferably a 5- to 7-membered lactone ring.

Incidentally, it is preferable that as in (KA-1-1) to (KA-1-17) shown below, another ring structure is condensed to a 5- to 7-membered lactone ring as the partial structure represented by the general formula (KA-1) in the form of forming a bicyclo or spiro structure.

Examples of the peripheral ring structure with which the ring structure represented by the general formula (KA-1) may be combined include those in (KA-1-1) to (KA-1-17) shown below and structures based on these structures.

The structure containing a lactone ring structure represented by the general formula (KA-1) is more preferably a structure represented by any one of the following (KA-1-1) to (KA-1-17). Further, the lactone structure may be bonded directly to the main chain. Preferred structures are (KA-1-1), (KA-1-4), (KA-1-5), (KA-1-6), (KA-1-13), (KA-1-14), and (KA-1-17).

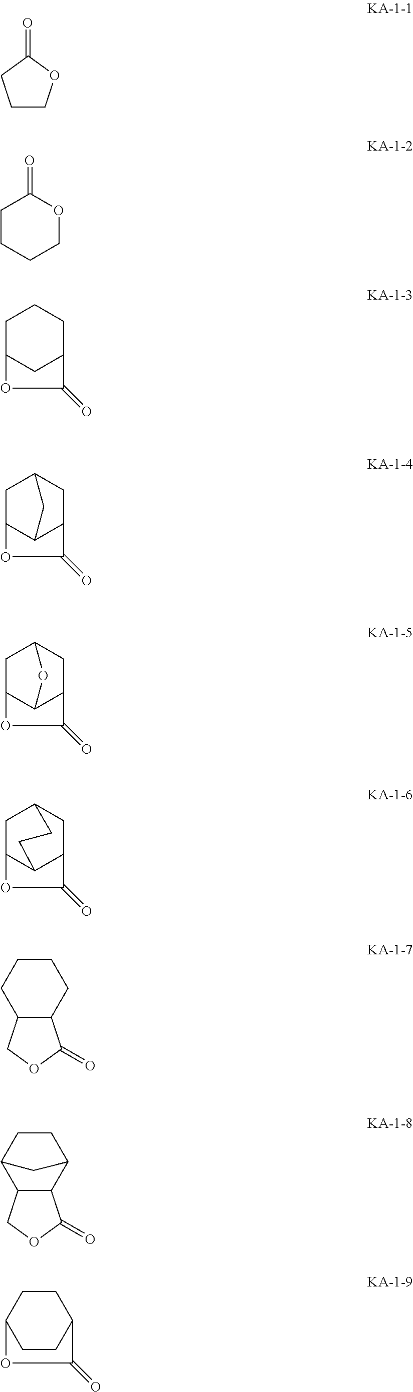

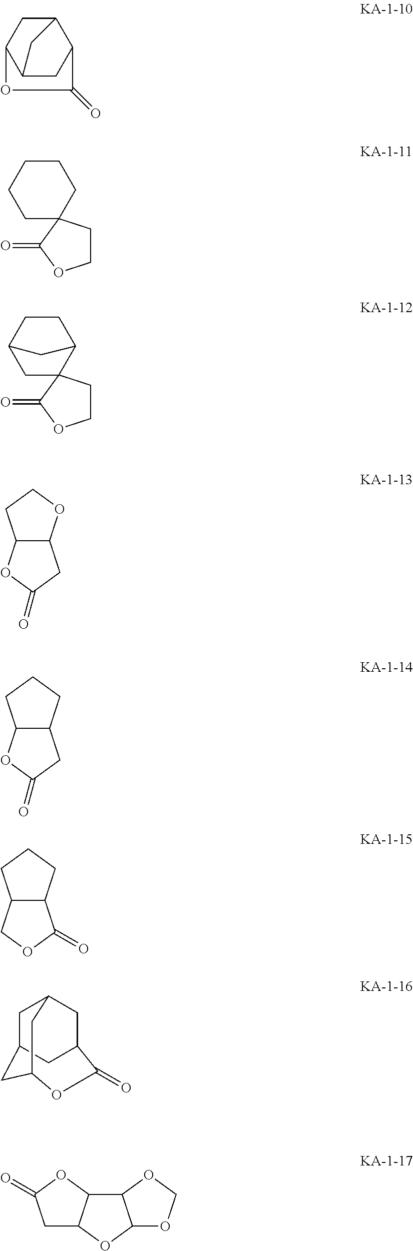

The structure containing the above-described lactone ring structure may or may not have a substituent. Preferable examples of the substituent are the same as those of the substituent Zₖₐ₁ which may be contained in the ring structure represented by the general formula (KA-1).

In the general formula (KB-1), X preferably includes a carboxylic ester group (—COO—).

In the general formula (KB-1), each of Y¹ and Y² independently represents an electron-withdrawing group.

The electron-withdrawing group is a partial structure represented by the following formula (EW). In the formula (EW), * represents a bond directly bonded to (KA-1) or a bond directly bonded to X in (KB-1).

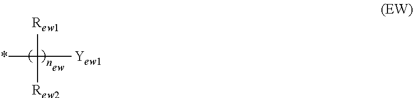

In the formula (EW),

n_{ew} is a repetition number of the linking group represented by —C(R_{ew1})(R_{ew2})—, and represents an integer of 0 or 1. In the case where n_{ew} is 0, this indicates bonding by a single bond and direct bonding of Y_{ew1}.

Y_{ew1} is a halogen atom, a cyano group, a nitrile group, a nitro group, a halo(cyclo)alkyl, a haloaryl group represented by —C(R_{f1})(R_{f2})—R_{f3}, an oxy group, a carbonyl group, a sulfonyl group, a sulfinyl group, or a combination thereof. Further, the electron-withdrawing group may be, for example, a structure shown below. The “halo(cyclo)alkyl group” indicates an alkyl or cycloalkyl group that is at least partially halogenated. The term “haloaryl group” indicates an aryl group that is at least partially halogenated. In the structural formulae below, each of R_{ew3} and R_{ew4} independently represents an arbitrary structure. The partial structure represented by the general formula (EW) has an electron-withdrawing property irrespective of structures of R_{ew3} and R_{ew4} and may be combined with, for example, the main chain of the resin, but is preferably an alkyl group, a cycloalkyl group, or an alkyl fluoride group.

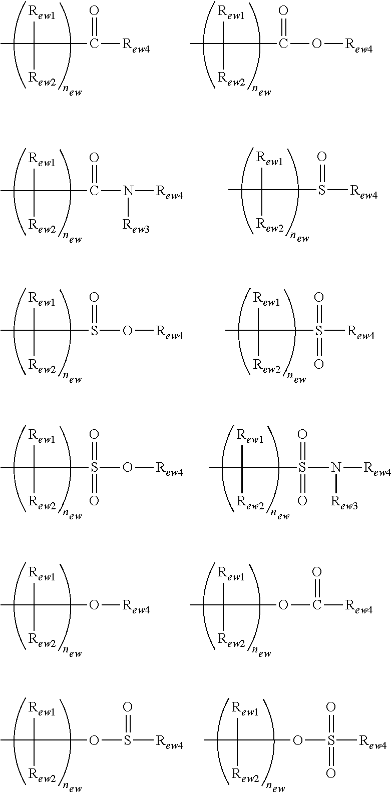

In the case where Y_{ew1} is a divalent or higher-valent group, the remaining bond forms bonding to an arbitrary atom or substituent. At least any one group of Y_{ew1}, R_{ew1}, and R_{ew2} may be combined with the main chain of a hydrophobic resin through a further substituent.

Y_{ew1} is preferably a halogen atom, or a halo(cyclo)alkyl or haloaryl group represented by —C(R_{f1})(R_{f2})—R_{f3}.

Each of R_{ew1} and R_{ew2} independently represents an arbitrary substituent, and represents, for example, a hydrogen atom, an alkyl group, a cycloalkyl group, or an aryl group.

At least two of R_{ew1}, R_{ew2}, and Y_{ew1} may be combined with each other to form a ring.

Here, R_{f1} represents a halogen atom, a perhaloalkyl group, a perhalocycloalkyl group or a perhaloaryl group and is preferably a fluorine atom, a perfluoroalkyl group, or a perfluorocycloalkyl group, and more preferably a fluorine atom or a trifluoromethyl group.

Each of R_{f2} and R_{f3} independently represents a hydrogen atom, a halogen atom or an organic group, and R_{f2} and R_{f3} may be combined with each other to form a ring. Examples of the organic group include an alkyl group, a cycloalkyl group, an alkoxy group, and the like. R_{f2} preferably represents the same group as R_{f1} or is combined with R_{f3} to form a ring.

R_{f1} to R_{f3} may be combined with each other to form a ring, and examples of the ring formed include a (halo)cycloalkyl ring, a (halo)aryl ring, and the like.

Examples of the (halo)alkyl group in R_{f1} to R_{f3} include the alkyl groups in Zₖₐ₁ and halogenated structures thereof.

Examples of the (per)halocycloalkyl group and the (per)haloaryl group in the ring formed by combination of R_{f2} and R_{f3} in R_{f1} to R_{f3} include structures resulting from halogenation of cycloalkyl groups in Zₖₐ₁, and a fluoroalkyl group represented by —C₍ₙ₎F₍₂ₙ₋₂₎H and a perfluoroaryl group represented by —C₍ₙ₎F₍ₙ₋₁₎ are preferable, where the carbon number n is not particularly limited but is preferably from 5 to 13, and more preferably 6.

The ring which may be formed by combination of at least two of R_{ew1}, R_{ew2}, and Y_{ew1} with each other is preferably a cycloalkyl group or a heterocyclic group, and the heterocyclic group is preferably a lactone ring group. Examples of the lactone ring include structures represented by the formulae (KA-1-1) to (KA-1-17).

Incidentally, the repeating unit (by) may have a plurality of partial structures represented by the general formula (KA-1), a plurality of partial structures represented by the general formula (KB-1), or both a partial structure represented by the general formula (KA-1) and a partial structure represented by the general formula (KB-1).

Further, the partial structure of the general formula (KA-1) may partially or entirely serve also as the electron-withdrawing group of Y¹ or Y² in the general formula (KB-1). For example, in the case where X in the general formula (KA-1) is a carboxylic ester group, the carboxylic ester group may function as the electron-withdrawing group of Y¹ or Y² in the general formula (KB-1).

Moreover, in the case where the repeating unit (by) comes under the repeating unit (b*) or the repeating unit (b″) and has a partial structure represented by the general formula (KA-1), the partial structure represented by the general formula (KA-1) is more preferably a partial structure where the polarity converting group is —COO— in the structure represented by the general formula (KA-1). The repeating unit (by) may be a repeating unit having a partial structure shown below.

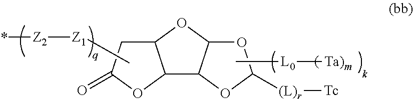

In the general formula (bb),

Z₁ represents a single bond, an ether bond, an ester bond, an amide bond, a urethane bond, or a urea bond and when a plurality of Z₁'s are present each Z₁ may be the same as or different from each other. Z₁ is preferably an ester bond.

Z₂ represents a chained or cyclic alkylene group and when a plurality of Z₂'s are present, they may be the same as or different from each other. Z₂ represents preferably an alkylene group having 1 or 2 carbon atoms or a cycloalkylene group having 5 to 10 carbon atoms.

Each Ta independently represents an alkyl group, a cycloalkyl group, an alkoxy group, a nitrile group, a hydroxyl group, an amido group, an aryl group, or an electron-withdrawing group (having the same meaning as the electron-withdrawing group of Y¹ and Y² in the general formula (KB-1)) and is preferably an alkyl group, a cycloalkyl group or an electron-withdrawing group, and more preferably an electron-withdrawing group. When a plurality of Ta's are present, they may be combined with each other to form a ring.

L₀ represents a single bond or an m+1-valent hydrocarbon group (preferably having 20 or less carbon atoms) and is preferably a single bond. The single bond as L₀ occurs when m is 1. The m+1-valent hydrocarbon group as L₀ represents an m+1-valent hydrocarbon group formed by removing m−1 arbitrary hydrogen atoms from, for example, an alkylene group, a cycloalkylene group, a phenylene group, or a combination thereof.

Each L independently represents a carbonyl group, a carbonyloxy group, or an ether group.

Tc represents a hydrogen atom, an alkyl group, a cycloalkyl group, a nitrile group, a hydroxyl group, an amido group, an aryl group, or an electron-withdrawing group (having the same meaning as the electron-withdrawing group of Y¹ and Y² in the general formula (KB-1)).

* represents a bond to the main chain or side chain of the resin. That is, a partial structure represented by the formula (bb) may be directly bonded to the main chain, or a partial structure represented by the formula (bb) may be bonded to the side chain of the resin. Incidentally, the bond to the main chain is a bond to an atom present in bonds constituting the main chain, and the bond to the side chain is a bond to an atom present in the portion other than the bonds constituting the main chain.

m represents an integer of 1 to 28, preferably an integer of 1 to 3, and more preferably 1.

k represents an integer of 0 to 2, and preferably 1.

q is a repetition number of the group (Z2-Z1) and represents an integer of 0 to 5, and

preferably 0 to 2.

r represents an integer of 0 to 5.

Incidentally, -L₀-(Ta)ₘ may be substituted in place of -(L)ᵣ-Tc.

It is also preferable to have a fluorine atom at the terminal of a sugar lactone or have a fluorine atom on a side chain different from the side chain on the sugar lactone side in the same repeating unit (this case comes under the repeating unit (b″)).

The chained alkylene group as Z₂ has, in the case of a linear alkylene group, preferably having 1 to 30 carbon atoms, and more preferably having 1 to 20 carbon atoms, and in the case of a branched alkylene group, preferably has 3 to 30, and more preferably 3 to 20 carbon atoms. Specific examples of the chained alkylene group as R₂ include groups formed by removing one arbitrary hydrogen atom from specific examples of the alkyl group as Zₖₐ₁.

The cyclic alkylene group as Z₂ is preferably an alkylene group having 3 to 8 carbon atoms, and specific examples thereof include groups formed by removing one arbitrary hydrogen atom from the cycloalkyl group as Zₖₐ₁.

The preferable carbon number and specific examples of the alkyl group and a cycloalkyl group as Ta and Tc are the same as those described for the alkyl group and a cycloalkyl group as Zₖₐ₁.

The alkoxy group as Ta is preferably an alkoxy group having 1 to 8 carbon atoms, and examples thereof include a methoxy group, an ethoxy group, a propoxy group, a butoxy group, and the like.

The aryl group as Ta and Tc is preferably an aryl group having 6 to 12 carbon atoms, and examples thereof include a phenyl group and a naphthyl group.

The preferable carbon number and specific examples of the alkylene group and a cycloalkylene group as L₀ are the same as those described for the chained alkylene group and the cyclic alkylene group as Z₂.

As the more specific structure of the repeating unit (bb), a repeating unit having a partial structure shown below is preferred.

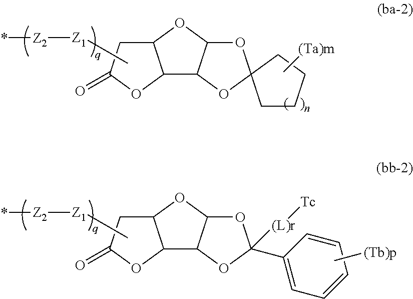

In the general formulae (ba-2) and (bb-2), n represents an integer of 0 to 11, preferably an integer of 0 to 5, and more preferably 1 or 2.

p represents an integer of 0 to 5, preferably an integer of 0 to 3, and more preferably 1 or 2.

Each Tb independently represents an alkyl group, a cycloalkyl group, an alkoxy group, a nitrile group, a hydroxyl group, an amido group, an aryl group, or an electron-withdrawing group (having the same meaning as the electron-withdrawing group of Y¹ and Y² in the general formula (KB-1)) and is preferably an alkyl group, a cycloalkyl group or an electron-withdrawing group. When a plurality of Tb's are present, they may be combined with each other to form a ring.

* represents a bond to the main chain or side chain of the resin. That is, a partial structure represented by the formula (ba-2) or (bb-2) may be directly bonded to the main chain, or a partial structure represented by the formula (ba-2) or (bb-2) may be bonded to the side chain of the resin.

Z₁, Z₂, Ta, Tc, L, *, m, q, and r have the same meaning as those in the general formula (bb), and preferable examples are also the same.

The repeating unit (by) may be a repeating unit having a partial structure represented by the general formula (KY-0).

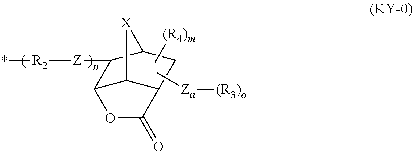

In the general formula (KY-0),

R₂ represents a chained or cyclic alkylene group and when a plurality of R₂'s are present, they may be the same as or different from each other.

R₃ represents a linear, branched, or cyclic hydrocarbon group where a part or all of hydrogen atoms on the constituent carbons are substituted with a fluorine atom.

R₄ represents a halogen atom, a cyano group, a hydroxyl group, an amido group, an alkyl group, a cycloalkyl group, an alkoxy group, a phenyl group, an acyl group, an alkoxycarbonyl group, or a group represented by R—C(═O)— or R—C(═O)O— (wherein R represents an alkyl group or a cycloalkyl group). When a plurality of R₄'s are present, they may be the same as or different from each other, and two or more R₄'s may be bonded to each other to form a ring.

X represents an alkylene group, an oxygen atom, or a sulfur atom.

Each of Z and Za represents a single bond, an ether bond, an ester bond, an amide bond, a urethane bond, or a urea bond, and when a plurality of Z's or Za's are present, they may be the same as or different from each other.

* represents a bond to the main chain or side chain of the resin.

o is the number of substituents and represents an integer of 1 to 7.

m is the number of substituents and represents an integer of 0 to 7.

n is a repetition number and represents an integer of 0 to 5.

The structure of —R₂—Z— is preferably a structure represented by —(CH₂)ₗ—COO— (wherein l represents an integer of 1 to 5).

The preferable range of carbon number and specific examples of the chained or cyclic alkylene group as R₂ are the same as those described for the chained alkylene group and cyclic alkylene group in Z₂ of the general formula (bb).

The carbon number of the linear, branched, or cyclic hydrocarbon group as R₃ is, in the case of a linear hydrocarbon group, preferably from 1 to 30, and more preferably from 1 to 20, in the case of a branched hydrocarbon group, preferably from 3 to 30, and more preferably from 3 to 20, and in the case of a cyclic hydrocarbon group, from 6 to 20. Specific examples of R₃ include specific examples of the alkyl group and a cycloalkyl group as Zₖₐ₁.

The preferable carbon numbers and specific examples of the alkyl group and a cycloalkyl group as R₄ and R are the same as those described with respect to the alkyl group and the cycloalkyl group as Zₖₐ₁.

The acyl group as R₄ is preferably an acyl group having 1 to 6 carbon atoms, and examples thereof include a formyl group, an acetyl group, a propionyl group, a butyryl group, an isobutyryl group, a valeryl group, a pivaloyl group, and the like.

The alkyl moiety in the alkoxy group and the alkoxycarbonyl group as R₄ include a linear, branched, or cyclic alkyl moiety, and the preferable carbon number and specific examples of the alkyl moiety are the same as those described for the alkyl group and the cycloalkyl group of Zₖₐ₁.

The alkylene group as X includes a chained or cyclic alkylene group, and the preferable carbon number and specific examples thereof are the same as those described for the chained alkylene group and the cyclic alkylene group as R₂.

Further, the specific structure of the repeating unit (by) also includes a repeating unit having a partial structure shown below.

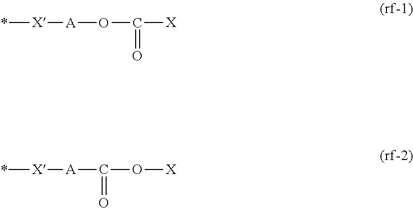

In the general formulae (rf-1) and (rf-2),

X′ represents an electron-withdrawing substituent and is preferably a carbonyloxy group, an oxycarbonyl group, a fluorine atom-substituted alkylene group, or a fluorine atom-substituted cycloalkylene group.

A represents a single bond, a divalent linking group represented by —C(Rx)(Ry)-, wherein each of Rx and Ry independently represents a hydrogen atom, a fluorine atom, an alkyl group (preferably having 1 to 6 carbon atoms, which may be substituted with a fluorine atom or the like), or a cycloalkyl group (preferably having 5 to 12 carbon atoms, which may be substituted with a fluorine atom or the like). Each of Rx and Ry is preferably a hydrogen atom, an alkyl group, or a fluorine atom-substituted alkyl group.

X represents an electron-withdrawing group and specific examples thereof include the electron-withdrawing groups as Y¹ and Y². X is preferably an alkyl fluoride group, a cycloalkyl fluoride group, an aryl group substituted with fluorine or an alkyl fluoride group, an aralkyl group substituted with fluorine or an alkyl fluoride group, a cyano group, or a nitro group.

* represents a bond to the main chain or side chain of the resin, that is, a bond which is bonded to the main chain of the resin through a single bond or a linking group.

Incidentally, when X′ is a carbonyloxy group or an oxycarbonyl group, A is not a single bond.

The polarity converting group decomposes by the action of an alkaline developer to effect polarity conversion, whereby the receding contact angle with water of the resin composition film after alkali development can be decreased. Decrease in the receding contact angle with water of the film after alkali development is preferable from the viewpoint of suppressing the development defect.

The receding contact angle with water of the resin composition film after alkali development is preferably 50° or less, more preferably 40° or less, still more preferably 35° or less, and most preferably 30° or less, at a temperature of 23±3° C. and a humidity of 45±5%.

The receding contact angle is a contact angle measured when a contact line recedes on the liquid droplet-substrate interface, and this is generally known to be useful in simulating the mobility of a liquid droplet in the dynamic state. In a simple manner, the receding contact angle can be defined as a contact angle at the time of the liquid droplet interface receding when a liquid droplet ejected from a needle tip is landed on a substrate and then the liquid droplet is again suctioned into the needle. In general, the receding contact angle can be measured by a contact angle measuring method called an expansion/contraction method.

The hydrolysis rate of the hydrophobic resin for an alkaline developer is preferably 0.001 nm/sec or more, more preferably 0.01 nm/sec or more, still more preferably 0.1 nm/sec or more, and most preferably 1 nm/sec or more.

The hydrolysis rate of the hydrophobic resin for an alkaline developer as used herein is the rate at which the thickness of a resin film formed only of the hydrophobic resin decreases when treated with TMAH (an aqueous tetramethylammonium hydroxide solution) (2.38% by mass) at 23° C.

The repeating unit (by) is more preferably a repeating having at least two or more polarity converting groups.

In the case where the repeating unit (by) has at least two polarity converting groups, the repeating unit preferably has a group containing a partial structure having two polarity converting groups represented by the following general formula (KY-1). Incidentally, when the structure represented by the general formula (KY-1) does not have a bond, this is a group containing a monovalent or higher valent group formed by removing at least one arbitrary hydrogen atom in the structure.

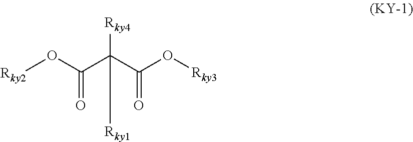

In the general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group. Alternatively, R_{ky1} and R_{ky4} may be bonded to the same atom to form a double bond. For example, R_{ky1} and R_{ky4} may be bonded to the same oxygen atom to form a part (═O) of a carbonyl group.

Each of R_{ky2} and R_{ky3} independently represents an electron-withdrawing group, or while R_{ky1} and R_{ky2} are combined to form a lactone ring, R_{ky3} is an electron-withdrawing group. The lactone ring formed is preferably a structure of (KA-1-1) to (KA-1-17). Examples of the electron-withdrawing group are the same as those for Y₁ and Y₂ in the general formula (KB-1), and a halogen atom and a halo(cyclo)alkyl or haloaryl group represented by —C(R_{f1})(R_{f2})—R_{f3} are preferable. Preferably, R_{ky3} is a halogen atom or a halo(cyclo)alkyl or haloaryl group represented by —C(R_{f1})(R_{f2})—R_{f1}, and R_{ky2} is combined with R_{ky1} to form a lactone ring or is an electron-withdrawing group containing no halogen atom.

R_{ky1}, R_{ky2}, and R_{ky4} may be combined with each other to form a monocyclic or polycyclic structure.

Specific examples of R_{ky1} and R_{ky4} include the same groups as those for Zₖₐ₁ in the formula (KA-1).

The lactone ring formed by combination of R_{ky1} and R_{ky2} is preferably a structure of (KA-1-1) to (KA-1-17). Examples of the electron-withdrawing group are the same as those for Y₁ and Y₂ in the general formula (KB-1).

The structure represented by the general formula (KY-1) is preferably a structure represented by the following general formula (KY-2). Here, the structure represented by the general formula (KY-2) is a group having a monovalent or higher valent group formed by removing at least one arbitrary hydrogen atom in the structure.

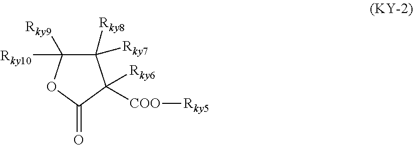

In the formula (KY-2),

each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group.

Two or more members of R_{ky6} to R_{ky10} may be combined with each other to form a monocyclic or polycyclic structure.

R_{ky5} represents an electron-withdrawing group. Examples of the electron-withdrawing group are the same as those for Y₁ and Y₂, and a halogen atom and a halo(cyclo)alkyl or haloaryl group represented by —C(R_{f1})(R_{f2})—R_{f3} are preferable.

Specific examples of R_{ky5} to R_{ky10} include the same groups as those for Zₖₐ₁ in the formula (KA-1).

The structure represented by the formula (KY-2) is preferably a partial structure represented by the following general formula (KY-3).

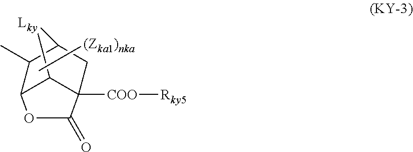

In the formula (KY-3), Zₖₐ₁ and nₖₐ have the same meanings as in the general formula (KA-1). R_{ky5} has the same meaning as in the formula (KY-2).

L_{ky} represents an alkylene group, an oxygen atom, or a sulfur atom. Examples of the alkylene group of L_{ky} include a methylene group, an ethylene group, and the like. L_{ky} is preferably an oxygen atom or a methylene group, and more preferably a methylene group.

The repeating unit (b) is not limited as long as it is a repeating unit obtained by polymerization such as addition polymerization, condensation polymerization and addition condensation, but a repeating unit obtained by addition polymerization of a carbon-carbon double bond is preferable. Examples thereof include an acrylate-based repeating unit (including a system having a substituent at the α- or β-position), a styrene-based repeating unit (including a system having a substituent at the α- or β-position), a vinyl ether-based repeating unit, a norbornene-based repeating unit, a maleic acid derivative (such as maleic anhydride or a derivative thereof, maleimide, and the like) repeating unit, and the like. An acrylate-based repeating unit, a styrene-based repeating unit, a vinyl ether-based repeating unit and a norbornene-based repeating unit are preferable, an acrylate-based repeating unit, a vinyl ether-based repeating unit and a norbornene-based repeating unit are more preferable, and an acrylate-based repeating unit is most preferable.

In the case where the repeating unit (by) is a repeating unit having at least either a fluorine atom or a silicon atom (that is, a repeating unit corresponding to the repeating unit (b′) or (b″)), examples of the fluorine atom-containing partial structure in the repeating unit (by) are the same as those in the above-described repeating unit having at least either a fluorine atom or a silicon atom, and the groups represented by the general formulae (F2) to (F4) are preferable. Further, examples of the silicon atom-containing partial structure in the repeating unit (by) are the same as those in the above-described repeating unit having at least either a fluorine atom or a silicon atom, and the groups represented by the general formulae (CS-1) to (CS-3) are preferable.

In the hydrophobic resin, the content of the repeating unit (by) is preferably from 10 to 100 mol %, more preferably from 20 to 99 mol %, still more preferably from 30 to 97 mol %, and most preferably from 40 to 95 mol %, based on all the repeating units in the hydrophobic resin.

Specific examples of the repeating unit (by) having a group capable of increasing the solubility in an alkaline developer are illustrated below, but the present invention is not limited thereto. Specific examples of the repeating unit (by) also include those described as specific examples of the repeating unit (a3) of the resin (A).

As for the specific examples shown below, Ra represents a hydrogen atom, a fluorine atom, a methyl group, or a trifluoromethyl group.

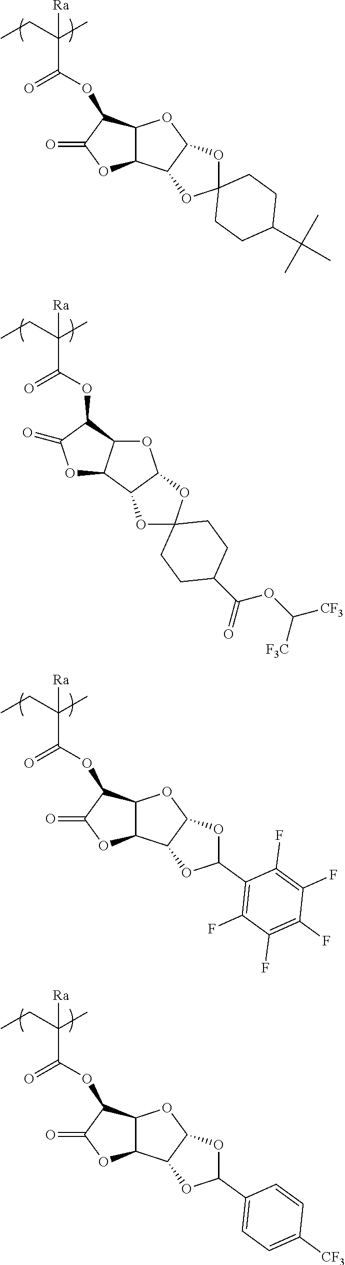

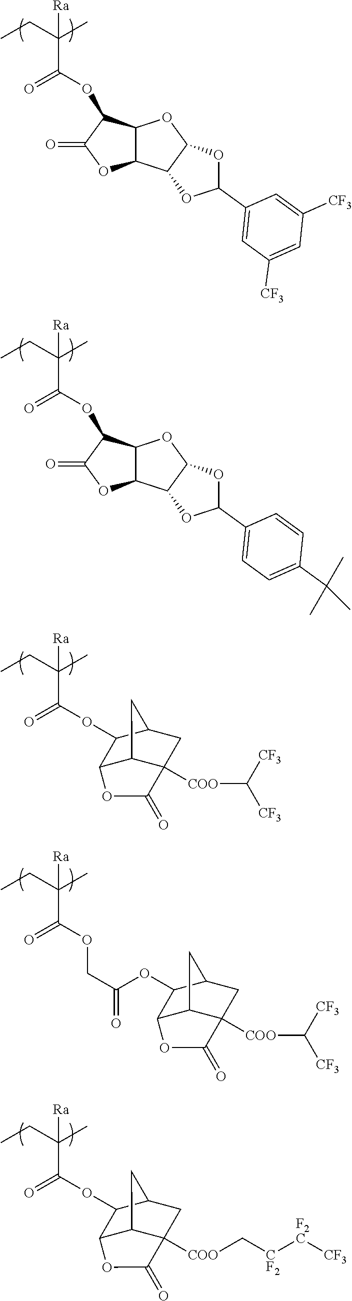

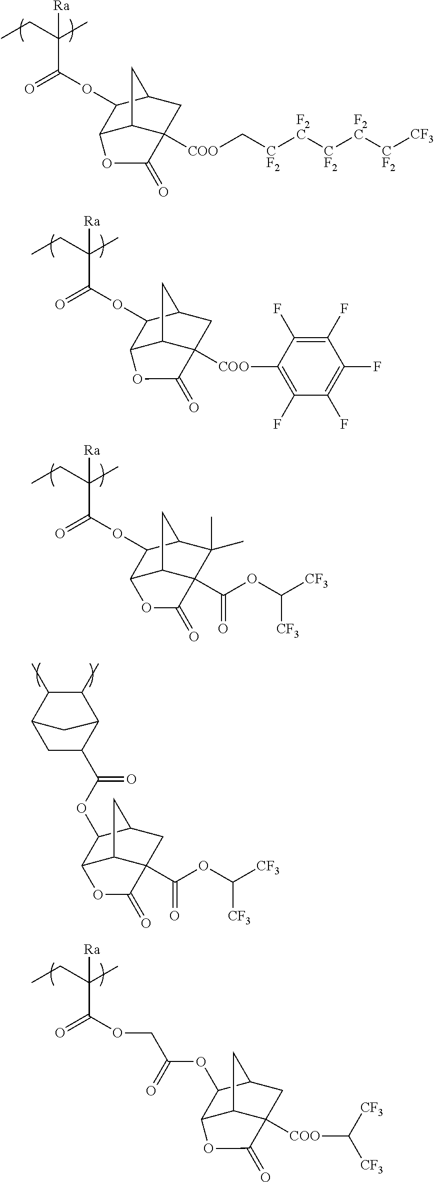

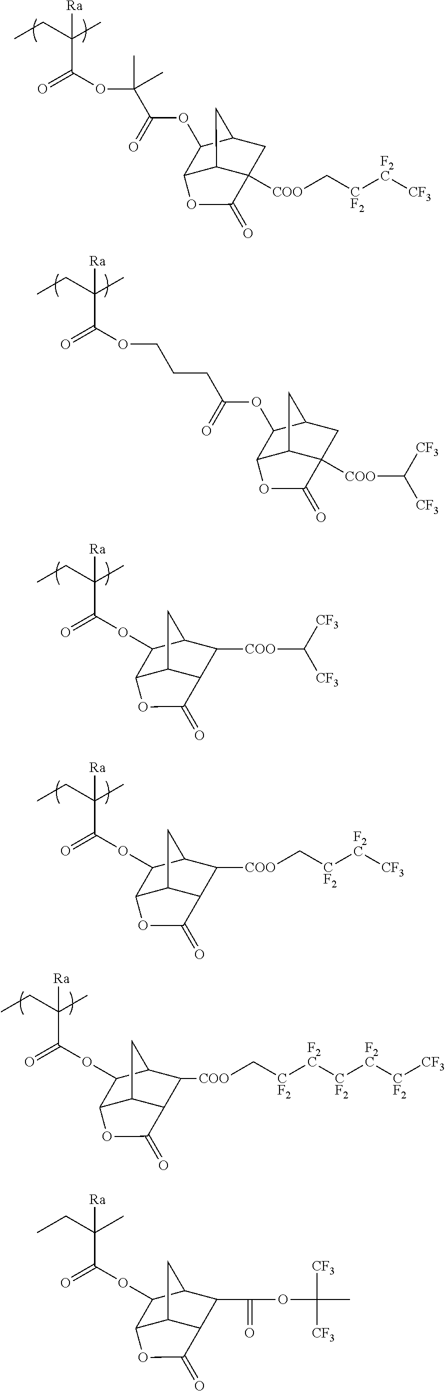

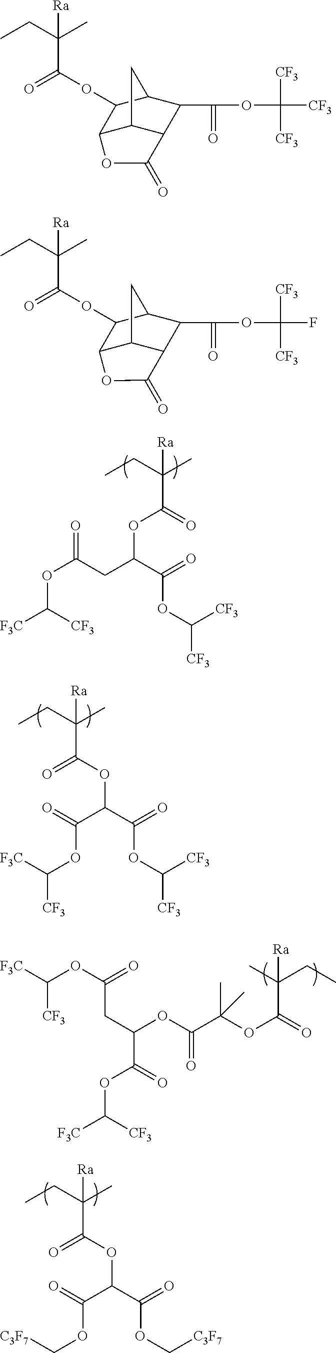

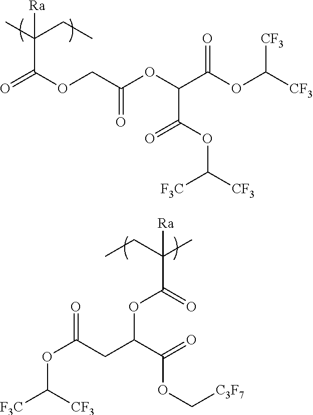

As for a method for synthesize the repeating unit (by) containing a polarity converting group (y) as described above, the repeating unit (by) can be synthesized with reference to the method described in WO2010/067905A, WO2010/067905A, or the like.

Examples of the repeating unit (bz) having (z) a group which decomposes by the action of an acid in the hydrophobic resin are the same as those of the repeating unit having an acid-decomposable group in the resin (A).

In the case where the repeating unit (bz) is a repeating unit having at least either a fluorine atom or a silicon atom (that is, a repeating unit corresponding to the repeating unit (b′) or (b″)), examples of the fluorine atom-containing partial structure in the repeating unit (bz) are the same as those in the above-described repeating unit having at least either a fluorine atom or a silicon atom, and the groups represented by the general formulae (F2) to (F4) are preferable. Further, examples of the silicon atom-containing partial structure in the repeating unit (by) are the same as those in the above-described repeating unit having at least either a fluorine atom or a silicon atom, and the groups represented by the general formulae (CS-1) to (CS-3) are preferable.

In the hydrophobic resin, the content of the repeating unit (bz) having (z) a group which decomposes by the action of an acid is preferably from 1 to 80 mol %, more preferably from 10 to 80 mol %, and still more preferably from 20 to 60 mol %, based on all the repeating units in the hydrophobic resin.

While the repeating unit (b) having at least one group selected from the group consisting of (x) to (z) is described above, the content of the repeating unit (b) in the hydrophobic resin is preferably from 1 to 98 mol %, more preferably from 3 to 98 mol %, still more preferably from 5 to 97 mol %, and most preferably from 10 to 95 mol %, based on all the repeating units in the hydrophobic resin.

The content of the repeating unit (b′) is preferably from 1 to 100 mol %, more preferably from 3 to 99 mol %, still more preferably from 5 to 97 mol %, and most preferably from 10 to 95 mol %, based on all the repeating units in the hydrophobic resin.

The content of the repeating unit (b*) is preferably from 1 to 90 mol %, more preferably from 3 to 80 mol %, still more preferably from 5 to 70 mol %, and most preferably from 10 to 60 mol %, based on all the repeating units in the hydrophobic resin. The content of the repeating unit having at least either a fluorine atom or a silicon atom, which is used together with the repeating unit (b*), is preferably from 10 to 99 mol %, more preferably from 20 to 97 mol %, still more preferably from 30 to 95 mol %, and most preferably from 40 to 90 mol %, based on all the repeating units in the hydrophobic resin.

The content of the repeating unit (b″) is preferably from 1 to 100 mol %, more preferably from 3 to 99 mol %, still more preferably from 5 to 97 mol %, and most preferably from 10 to 95 mol %, based on all the repeating units in the hydrophobic resin.

The hydrophobic resin may further contain a repeating unit represented by the following general formula (III).

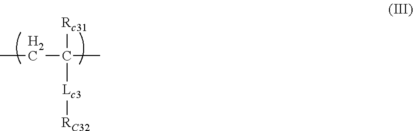

In the general formula (III),

R_{c31} represents a hydrogen atom, an alkyl group, an alkyl group which may be substituted with fluorine, a cyano group, or a —CH₂—O-Rac₂ group, wherein Rac₂ represents a hydrogen atom, an alkyl group, or an acyl group. R_{c31} is preferably a hydrogen atom, a methyl group, a hydroxymethyl group, or a trifluoromethyl group, and particularly preferably a hydrogen atom or a methyl group.

R_{c32} represents a group having an alkyl group, a cycloalkyl group, an alkenyl group, or a cycloalkenyl group. Each of these groups may be substituted with a fluorine atom- or silicon atom-containing group, or the like.

L_{c3} represents a single bond or a divalent linking group.

The alkyl group of R_{c32} in the general formula (III) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably a phenyl group or a naphthyl group, having 6 to 20 carbon atoms, and the group may have a substituent.

R_{c32} is preferably an unsubstituted alkyl group or a fluorine atom-substituted alkyl group.

The divalent linking group of L_{c3} is preferably an alkylene group (preferably having 1 to 5 carbon atoms), an oxy group, a phenylene group, or an ester bond (a group represented by —COO—).

The hydrophobic resin preferably further contains a repeating unit represented by the following general formula (BII-AB).

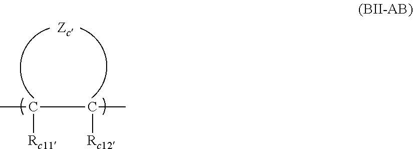

In the formula (BII-AB), each of R_{c11}′ and R_{c12}′ independently represents a hydrogen atom, a cyano group, a halogen atom, or an alkyl group.

Z_{c}′ represents an atomic group for forming an alicyclic structure containing two carbon atoms (C—C) to which Z_{c}′ is bonded.

In the case where each group in the repeating units represented by the general formulae (III) and (BII-AB) is substituted with a fluorine atom- or silicon atom-containing group, the repeating unit corresponds also to the above-described repeating unit having at least either a fluorine atom or a silicon atom.

Specific examples of the repeating units represented by the general formulae (III) and (BII-AB) are illustrated below, but the present invention is not limited thereto. In the formulae, Ra represents H, CH₃, CH₂OH, CF₃, or CN. Incidentally, the repeating unit where Ra is CF₃ corresponds also to the above-described repeating unit having at least either a fluorine atom or a silicon atom.

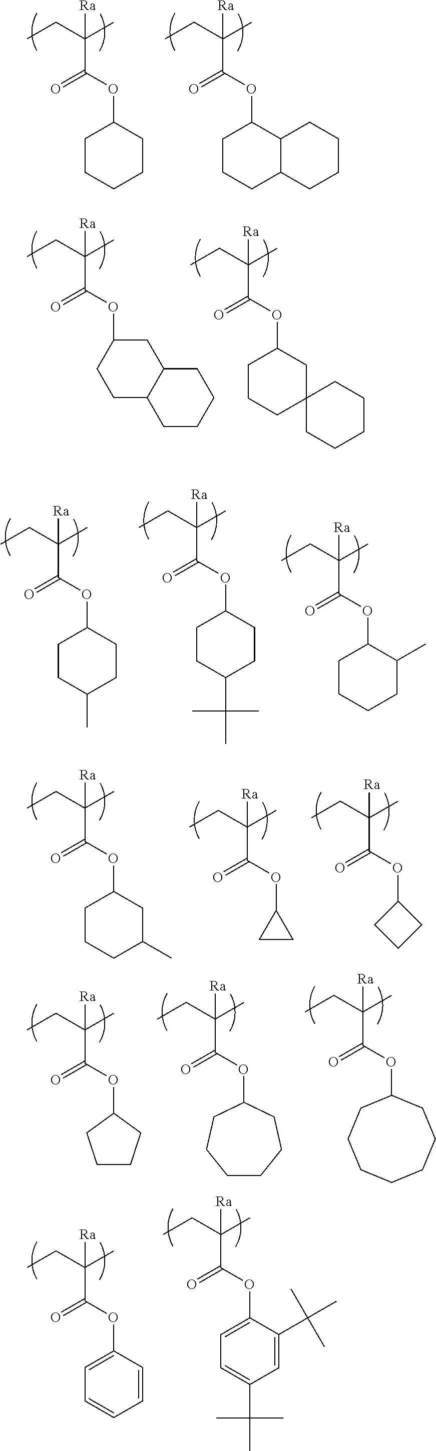

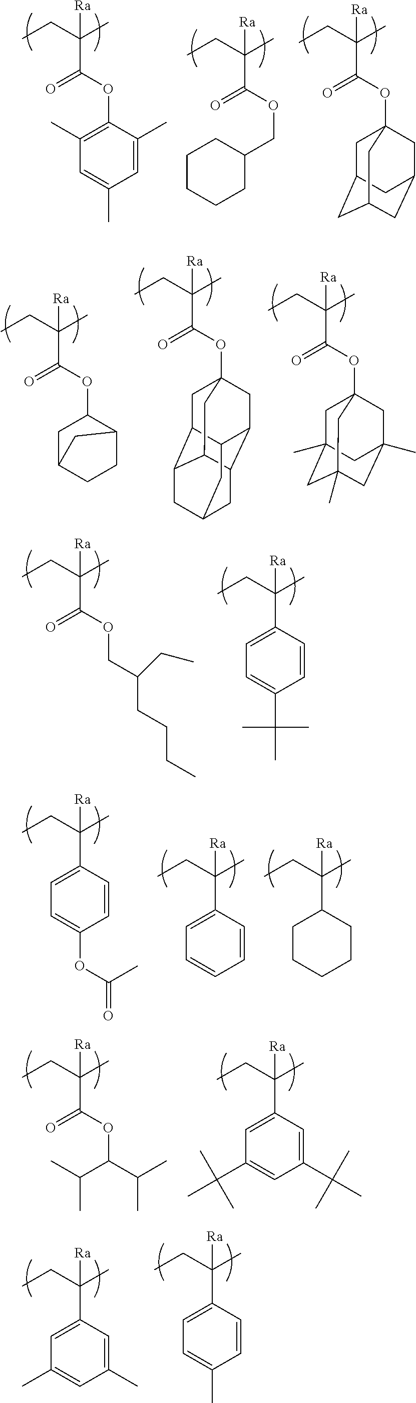

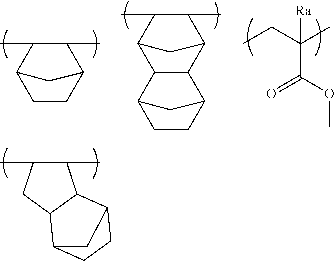

In the hydrophobic resin, similarly to the resin (B), it is of course preferable that the content of impurities such as a metal and the like is small, but also, the content of residual monomers or oligomer components is preferably from 0 to 10% by mass, more preferably from 0 to 5% by mass, still more preferably from 0 to 1% by mass. When these conditions are satisfied, a resist composition free from extraneous substances in a liquid or change with aging of sensitivity or the like can be obtained. Furthermore, in view of resolution, resist profile, side wall of resist pattern, roughness, and the like, the molecular weight distribution (Mw/Mn, also referred to as “polydispersity”) is preferably in the range of 1 to 3, more preferably in the range of 1 to 2, still more preferably in the range of 1 to 1.8, and most preferably in the range of 1 to 1.5.

As for the resin (B), various commercially available products may be used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours, and the like. A dropping polymerization method is preferred.

The reaction solvent, the polymerization initiator, the reaction conditions (for example, a temperature, a concentration, and the like), and the purification method after reaction are the same as those described for the resin (B).

Specific examples of the hydrophobic resin (HR) will be shown below. Further, the molar ratio of repeating units (corresponding to repeating units starting from the left), the weight average molecular weight, and the polydispersity of each resin are shown in the Table 1 below.

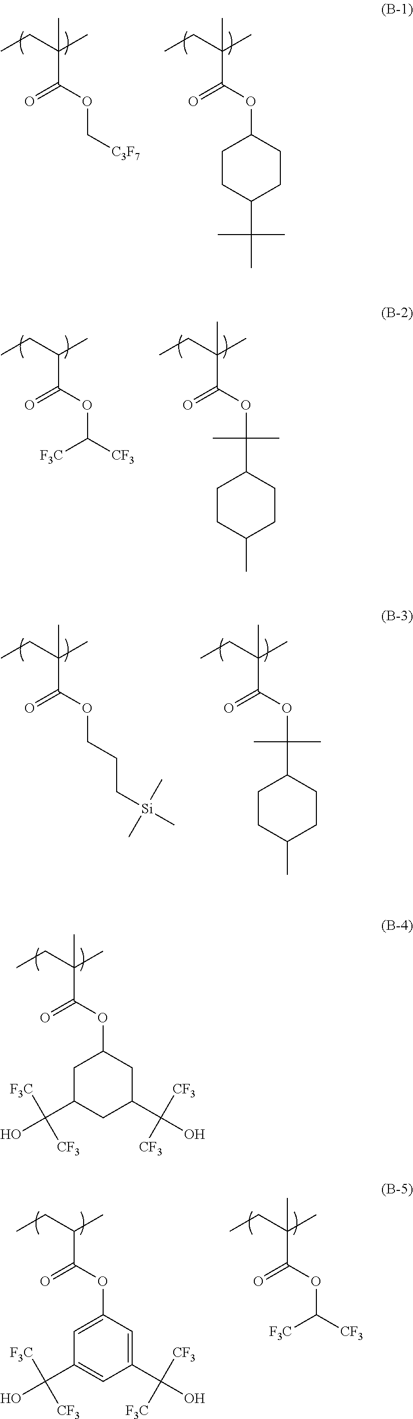

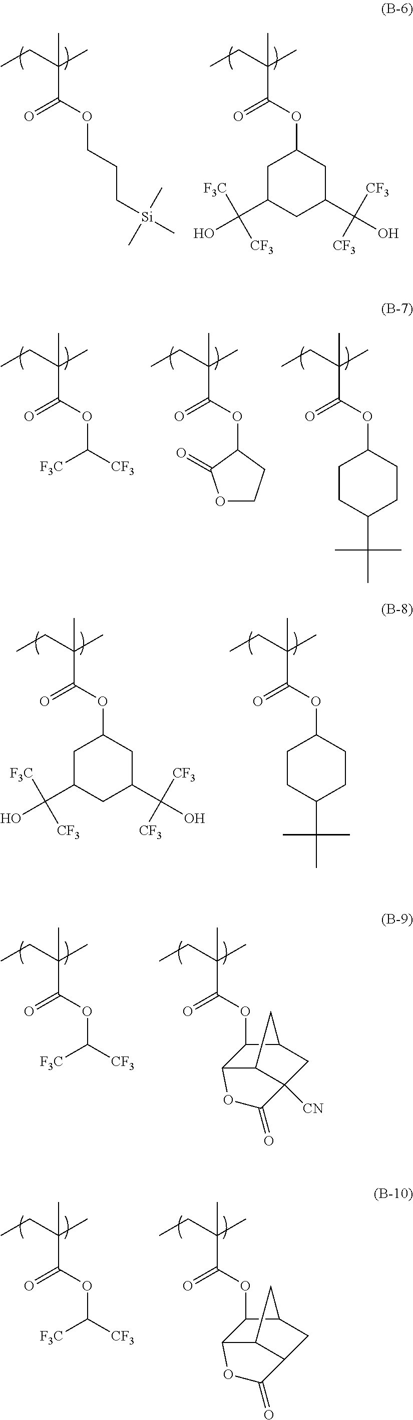

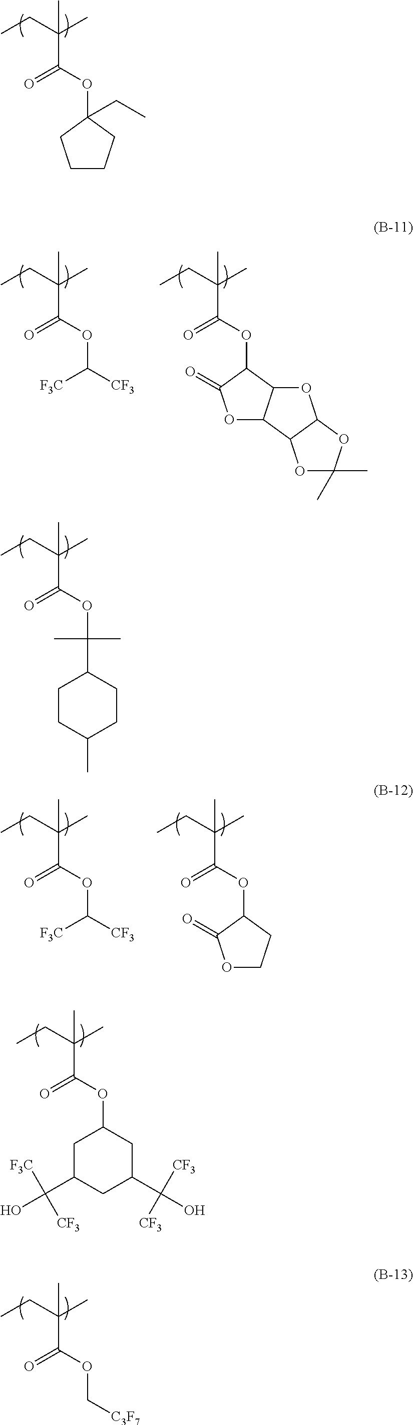

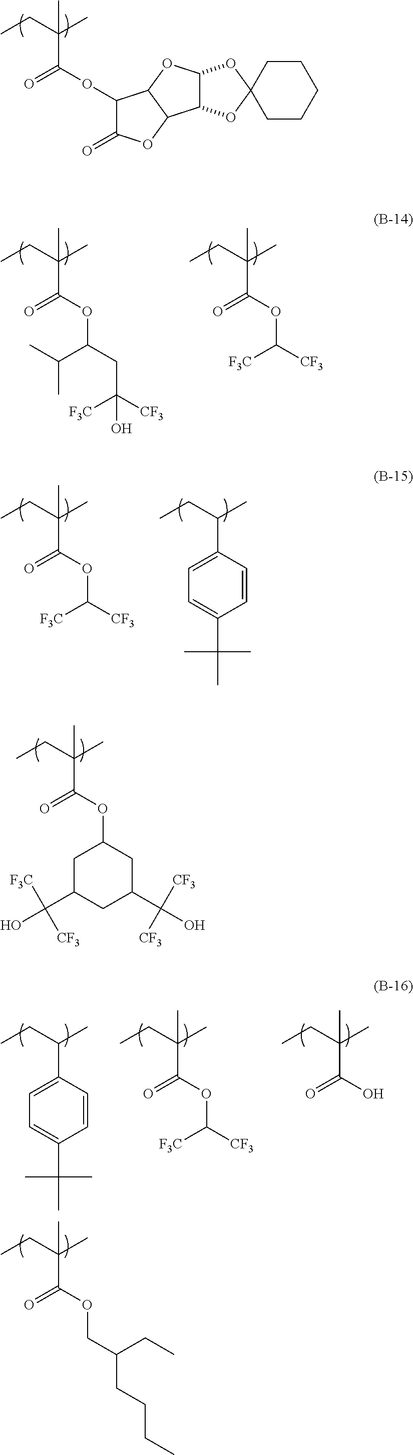

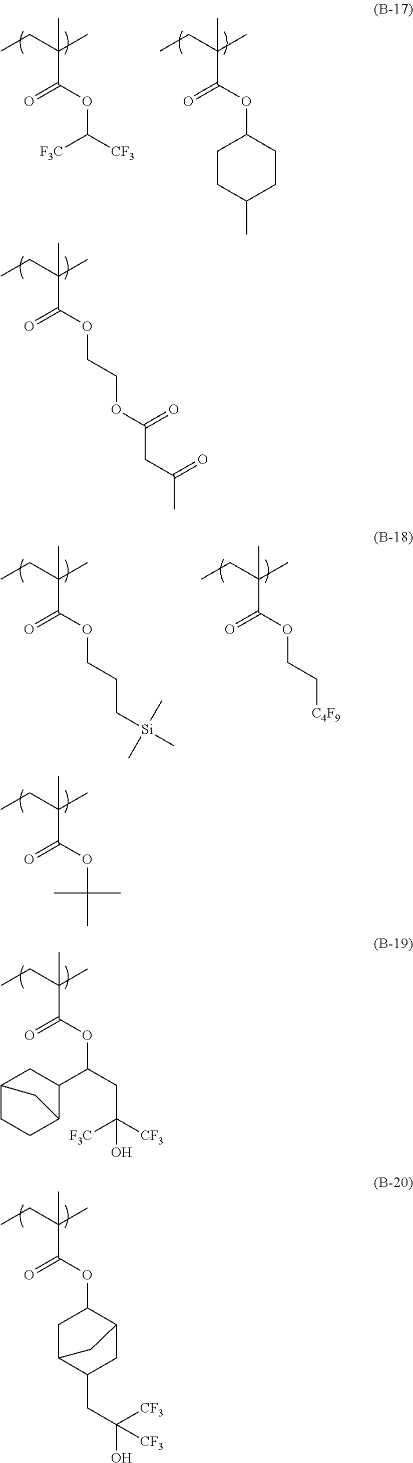

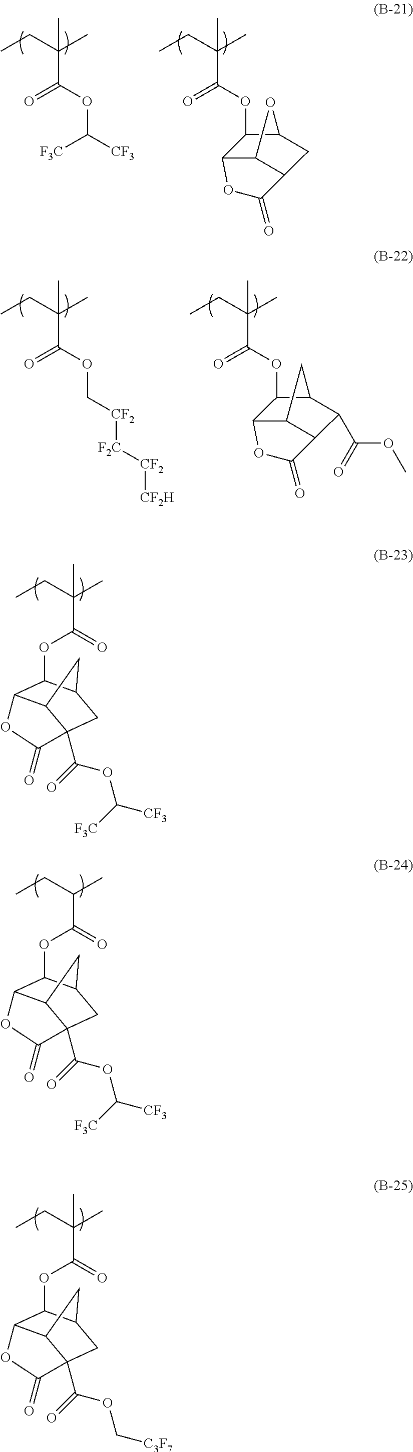

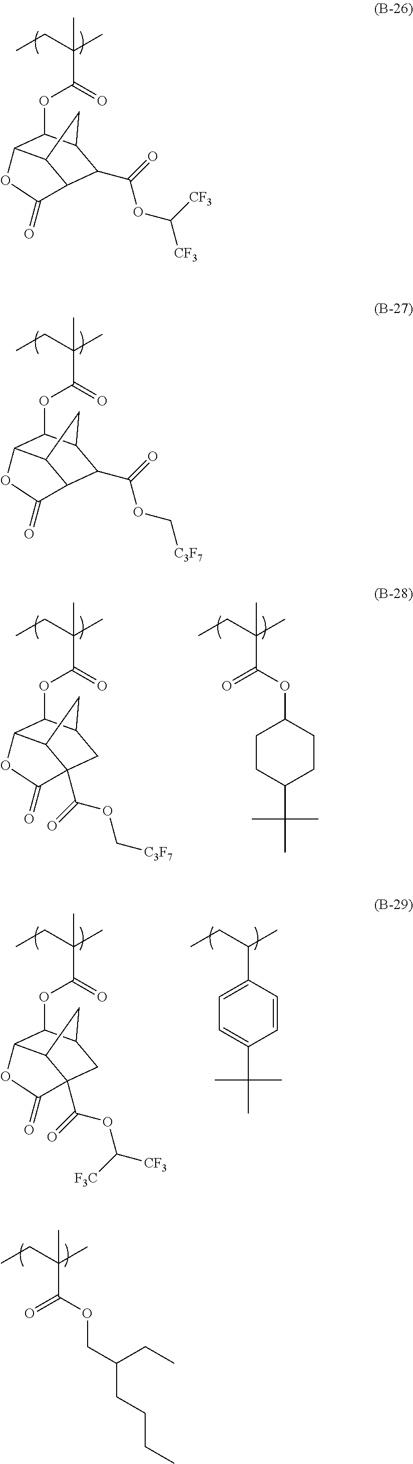

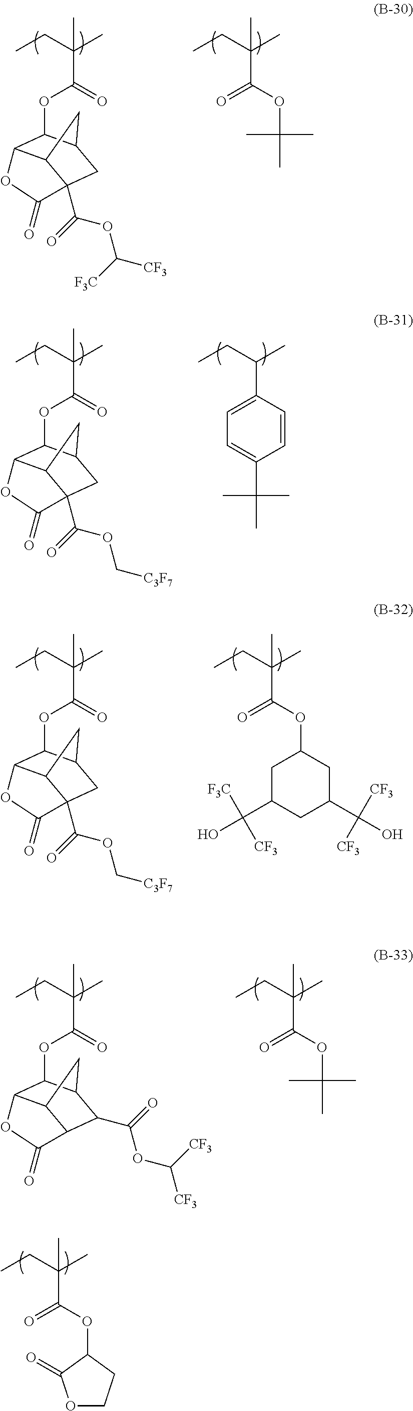

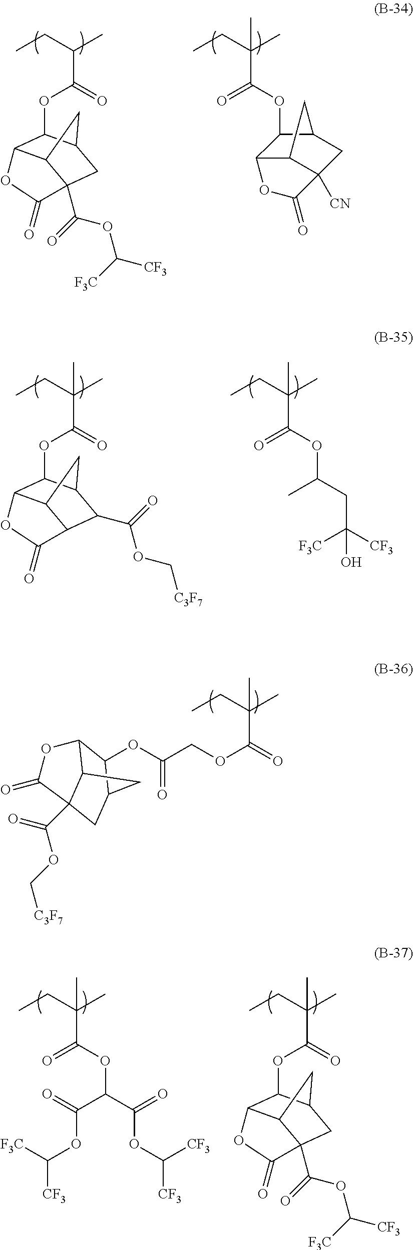

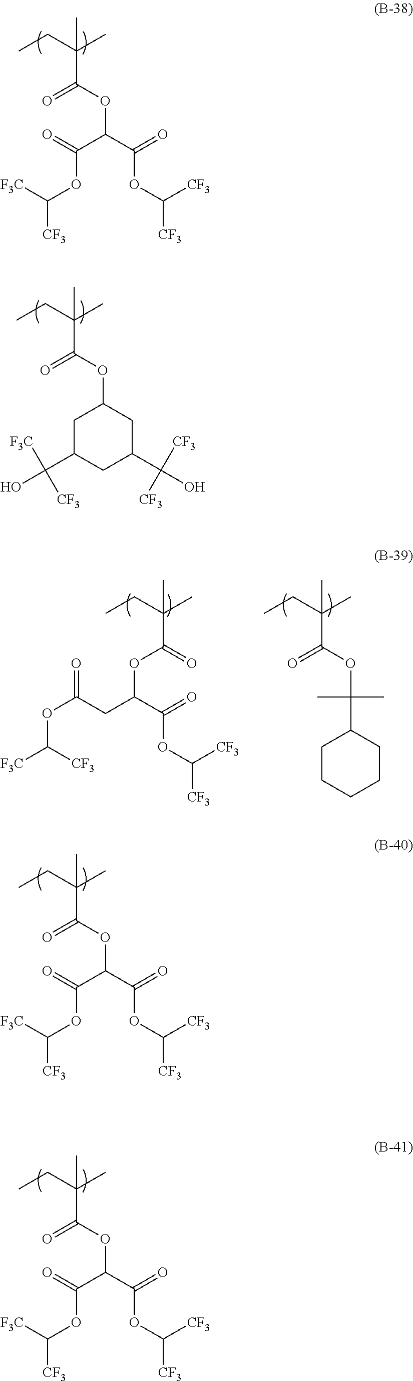

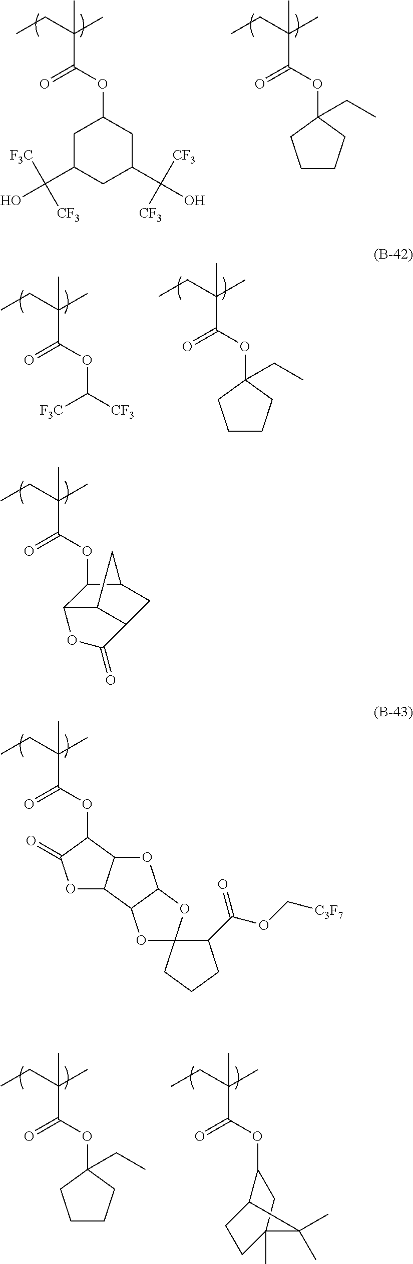

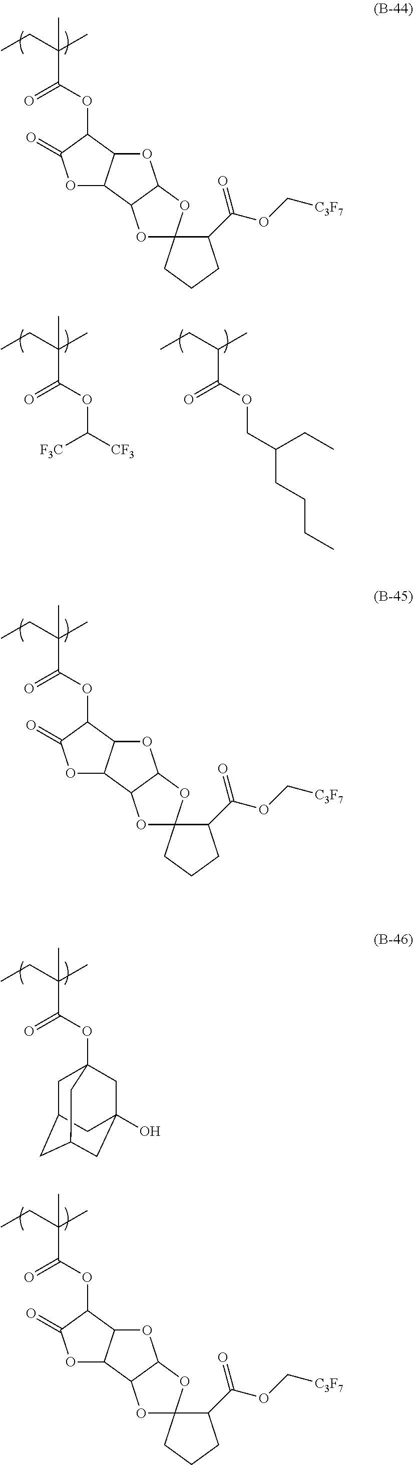

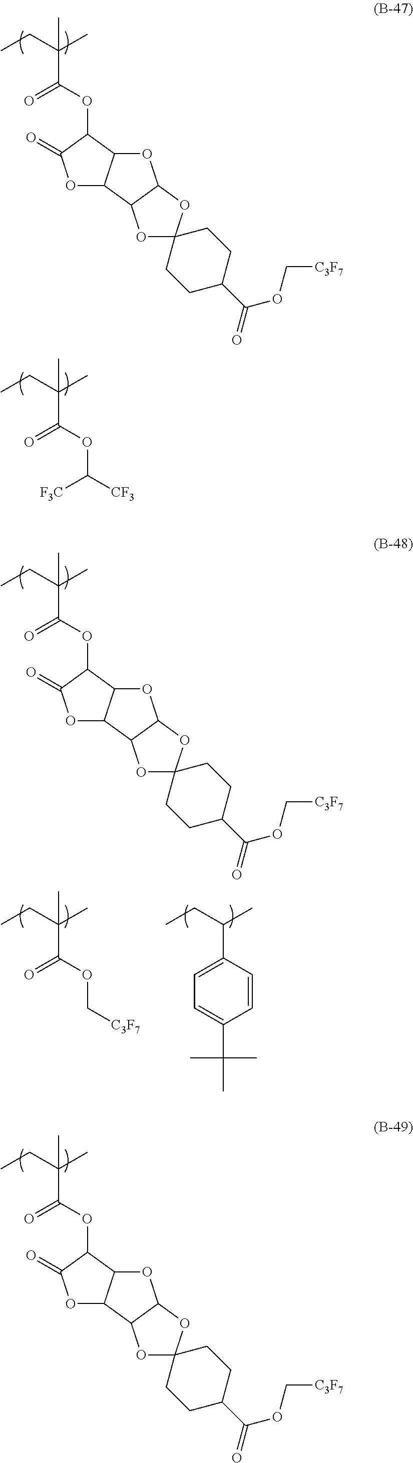

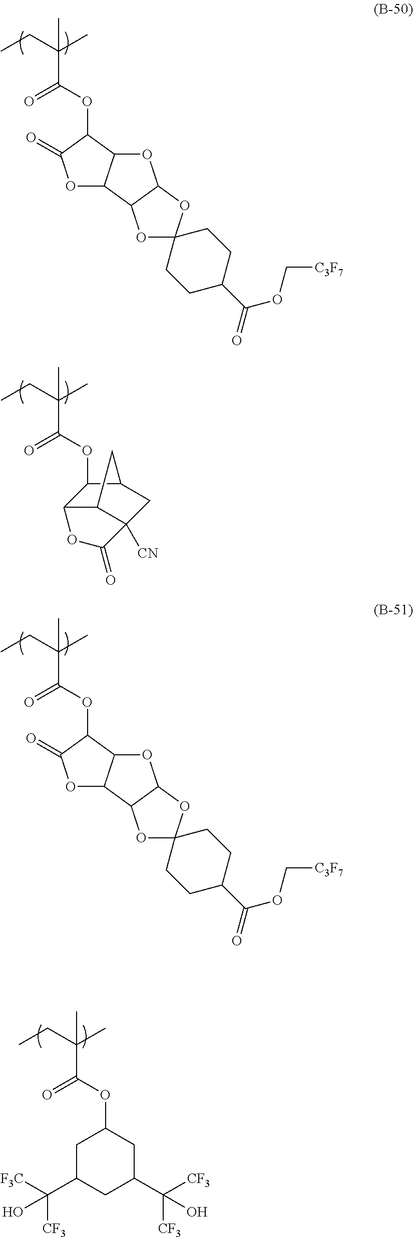

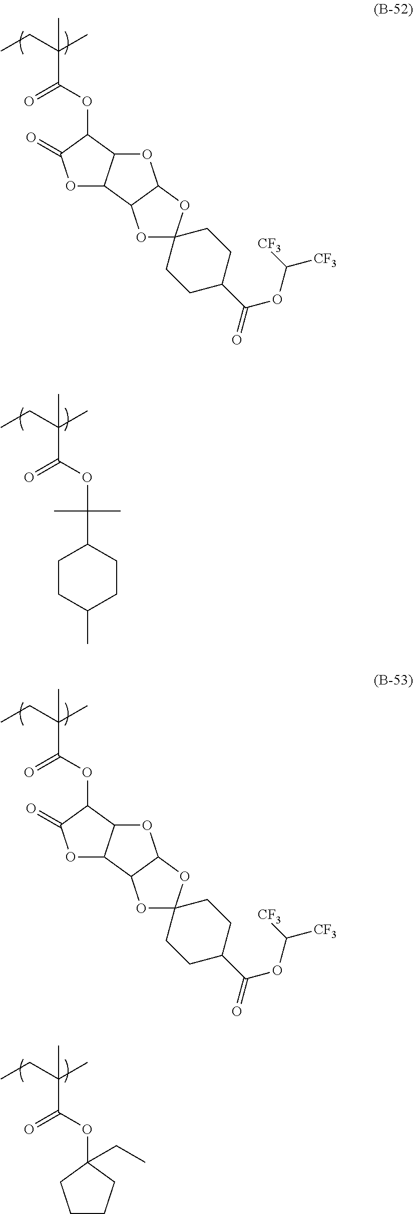

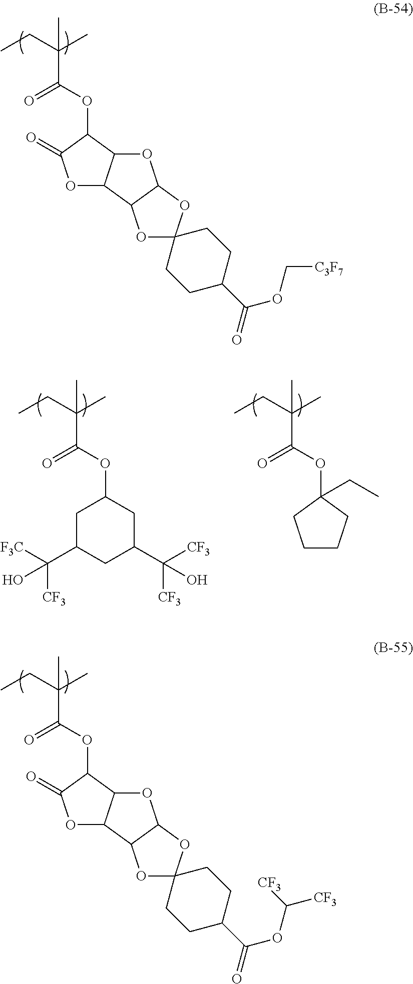

TABLE 1

| | Compositional ratio | | |
|---|---|---|---|
| Polymer | (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

The actinic-ray-sensitive or radiation-sensitive resin composition of the present invention contains a hydrophobic resin containing at least either a fluorine atom or a silicon atom, and the hydrophobic resin is unevenly distributed to the surface layer of a film formed of the actinic-ray-sensitive or radiation-sensitive resin composition, so that in the case where the liquid for liquid immersion is water, the receding contact angle for water on the film surface as well as the traceability of the liquid for liquid immersion can be enhanced.

The receding contact angle of a film after baking a coating composed of the actinic-ray-sensitive or radiation-sensitive resin composition of the present invention of the present invention but before exposure is preferably from 60 to 90°, more preferably 65° or more, still more preferably 70° or more, and particularly preferably 75° or more, at the temperature during exposure (usually room temperature 23±3° C.), and a humidity of 45±5%.

The hydrophobic resin is, as described above, unevenly distributed to the interface but unlike a surfactant, need not have necessarily a hydrophilic group in the molecule and may not contribute to uniform mixing of polar/nonpolar substances.

In the liquid immersion exposure step, the liquid for liquid immersion must move on a wafer following the movement of an exposure head that is scanning the wafer at a high speed and forming an exposure pattern. Therefore, the contact angle of the liquid for liquid immersion with the resist film in a dynamic state is important, and the resist is required to have a performance of allowing a liquid droplet to follow the high-speed scanning of an exposure head with no remaining.

The hydrophobic resin is hydrophobic and therefore, liable to worsen the development residue (scum) and BLOB defect after alkali development, but by virtue of having three or more polymer chains through at least one branch part, the alkali dissolution rate is enhanced as compared with a linear chain-type resin and in turn, the performance in terms of development residue (scum) and the BLO defect is improved.

In the case where the hydrophobic resin contains a fluorine atom, the fluorine atom content is preferably from 5 to 80% by mass, and more preferably from 10 to 80% by mass, based on the molecular weight of the hydrophobic resin. Further, the fluorine atom-containing repeating unit preferably accounts for 10 to 100 mol %, and more preferably 30 to 100 mol %, based on all the repeating units in the hydrophobic resin.

In the case where the hydrophobic resin contains a silicon atom, the silicon atom content is preferably from 2 to 50% by mass, and more preferably from 2 to 30% by mass, based on the weight average molecular weight of the hydrophobic resin. Further, the silicon atom-containing repeating unit preferably accounts for 10 to 90 mol %, and more preferably from 20 to 80 mol %, based on all the repeating units in the hydrophobic resin.

The weight average molecular weight of the hydrophobic resin is preferably from 1,000 to 100,000, more preferably from 2,000 to 50,000, and still more preferably from 3,000 to 30,000. Here, the weight average molecular weight of the resin indicates a molecular weight in terms of polystyrene measured by GPC (carrier: tetrahydrofuran (THF)).

The hydrophobic resin in the actinic-ray-sensitive or radiation-sensitive resin composition may be used by appropriately adjusting its content to give an actinic-ray-sensitive or radiation-sensitive resin film having a receding contact angle in the range above, but the content thereof is preferably from 0.01 to 20% by mass, more preferably from 0.1 to 15% by mass, still more preferably from 0.1 to 10% by mass, and particularly preferably from 0.5 to 8% by mass, based on the entire solid content of the actinic-ray-sensitive or radiation-sensitive resin composition.

The hydrophobic resin may be used singly or in combination of two or more kinds thereof.

### EXAMPLES

The present invention will be explained below in more detail by reference to Examples, but the present invention is not limited thereto.

### Synthesis Example 1

### Synthesis of Onium Salt of Triphenylsulfonium 1,1-difluoro-3-(decahydroisoquinoline-2-sulfonyl)methane-1-sulfonate (Photoacid Generator A-2)

### (1) Synthesis of 1,1-Difluoromethane-1,1-disulfonyl difluoride

Bis(fluorosulfonyl)methane was obtained by a method described in Journal of Fluorine Chemistry, 1994, vol. 69, pp. 152-162, using bis(chlorosulfonyl)methane (available from Tokyo Chemical Industry Co., Ltd.) as a starting raw material. 1,1-Difluoromethane-1,1-disulfonyl difluoride was synthesized by a method described in Journal of Fluorine Chemistry, 1997, vol. 83, pp. 145-150 using the above compound as a raw material.

### (2) Synthesis of Photoacid Generator A-2

Under a nitrogen air flow, a mixture of 4.0 g (12.65 mmol) of 1,1-difluoromethane-1,1-disulfonyl difluoride obtained in (1), 2.56 g (25.3 mmol) of triethylamine, and 30 mL of diisopropyl ether was ice-cooled, and a mixed solution of 1.08 g (12.6 mmol) of decahydroisoquinoline and 15 mL of diisopropyl ether was added dropwise thereto over 30 minutes. The mixture was stirred for 1 hour under ice-cooling and further stirred at room temperature for 1 hour. The organic layer obtained was washed successively with water, a saturated aqueous ammonium chloride solution, and water, subsequently the organic layer was dried over sodium sulfate, and then the solvents were removed. To the reaction product obtained were added 20 mL of ethanol and 200 mg of sodium hydroxide. The mixture was stirred at room temperature for 2 hours, and then dilute hydrochloride acid was added thereto for neutralization to obtain an ethanol solution of the sulfonic acid represented by the following formula.

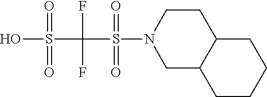

A triphenylsulfonium acetate solution was added to the solution of sulfonic acid in ethanol, the mixture was stirred at room temperature for 2 hours, and then 300 mL of chloroform was added thereto. The organic layer obtained was washed successively with water, a saturated aqueous ammonium chloride solution, and water, and then purified by column chromatography (SiO₂, chloroform/methanol=5/1) to obtain 3.0 g (4.68 mmol) of an onium salt of a photoacid generator A-2 represented by the following formula as a white solid.

Meanwhile, the triphenylsulfonium acetate solution was prepared by adding 5.07 g (13 mmol) of triphenylsulfonium iodide, 2.25 g (13.5 mmol) of silver acetate, 120 mL of acetonitrile, and 60 mL of water, and then stirring the mixture at room temperature for 1 hour, followed by filtration of the reaction solution.

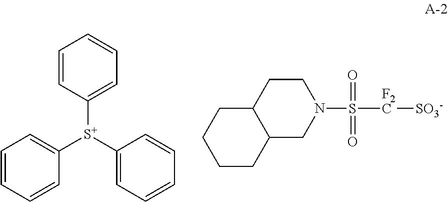

¹H-NMR (300 MHz, CDCl₃) δ 1.00 (m, 3H), 1.65 (m, 6H), 2.79 (bt, 1H), 3.15 (bt, 1H), 3.80 (bd, 1H), 3.95 (bd, 1H), 7.70 (m, 15H) ¹⁹F-NMR (300 MHz, CDCl₃) δ−132.1 (m, 2F)

By the same method as in Synthesis Example 1, another photoacid generator shown in Table 2 below was synthesized.

### Preparation of Actinic-Ray-Sensitive or Radiation-Sensitive Resin Composition and Resist Evaluation (1)

### Examples 1 to 24 and Comparative Examples 1 to 4

The components shown in Table 2 below were dissolved in a solvent to prepare a solution with a solid concentration of 4% by mass with respect to each of Examples and Comparative Examples, and the solution was filtered through a polyethylene filter having a pore size of 0.05 μm to prepare an actinic-ray-sensitive or radiation-sensitive resin composition. The actinic-ray-sensitive or radiation-sensitive resin composition was evaluated by the following method and the results are shown in the same Table.

As for the respective components in Table 2, the ratio of the components in the case of using a plurality of the components indicates a mass ratio.

Further, in Table 2, in the case where the actinic-ray-sensitive or radiation-sensitive resin composition contains a hydrophobic resin (HR), the use configuration is denoted as “Added”. Meanwhile, in the case where a film is formed using an actinic-ray-sensitive or radiation-sensitive resin composition containing no hydrophobic resin (HR), and then an overcoat protective film containing a hydrophobic resin (FIR) is formed on the upper layer, the addition configuration is denoted as “TC”.

TABLE 2

| | Composition | | | | | | | |
|---|---|---|---|---|---|---|---|---|
| | Photoacid | | Basic compound, | Hydrophobic | Solvent | | Evaluation results | |
| | generator | Resin (B) | Compound (D), or | resin HR | (mass | Surfactant | Development | Pattern |
| | (g) | (10 g) | Compound (E) (g) | (35 mg) | ratio) | (10 mg) | defect | shape |
| Example 1 | A-2 | A | DIA | Added | A1 | W-1 | 0.25 | A |
| | (2.2) | | (0.4) | B-2 | (100) | | | |
| Example 2 | A-3 | B | APCA | Added | A1/B1 | W-2 | 0.30 | A |
| | (2.0) | | (0.35) | B-10 | (60/40) | | | |
| Example 3 | A-7 | C | DBA | Added | A1/A2 | W-1 | 0.20 | A |
| | (2.0) | | (0.38) | B-12 | (90/10) | | | |
| Example 4 | A-10 | D | APCA | Added | A1/A3 | W-3 | 0.34 | A |
| | (1.8) | | (0.25) | B-18 | (90/10) | | | |
| Example 5 | A-12 | E | PBI | Added | A1 | W-1 | 0.32 | A |
| | (2.0) | | (0.4) | B-28 | (100) | | | |
| Example 6 | A-14 | C | DIA | Added | A1 | W-4 | 0.40 | A |
| | (1.5) | | (0.35) | B-52 | (100) | | | |
| Example 7 | A-16 | D | PBI | — | A1/A2 | — | 0.45 | A |
| | (2.2) | | (0.4) | | (90/10) | | | |
| Example 8 | A-2 | A | PEA | Added | A1/B1 | W-1 | 0.23 | A |
| | (1.2) | | (0.42) | B-2 | (60/40) | | | |
| | A-7 | | | | | | | |
| | (0.4) | | | | | | | |
| Example 9 | A-2 | A (5 g) | DIA | Added | A1 | W-2 | 0.21 | A |
| | (1.8) | D (5 g) | (0.4) | B-12 | (100) | | | |
| Example 10 | A-2 | A | PBI | TC | A1 | W-1 | 0.24 | A |
| | (1.0) | | (0.35) | B-4 | (100) | | | |
| | A-7 | | | | | | | |
| | (0.5) | | | | | | | |
| Example 11 | A-2 | A (3 g) | DBA | TC | A1/B2 | W-2 | 0.22 | A |
| | (2.0) | D (7 g) | (0.25) | B-28 | (80/20) | | | |
| Example 12 | A-18 | D | TMEA | — | A1 | W-3 | 0.48 | A |
| | (1.4) | | (0.35) | | (100) | | | |
| Example 13 | A-20 | A | APCA | Added | A1 | W-3 | 0.20 | A |
| | (1.4) | | (0.25) | B-10 | (100) | | | |
| Example 14 | A-21 | A | TMEA | — | A1 | W-3 | 0.49 | A |
| | (1.4) | | (0.35) | | (100) | | | |
| Example 15 | A-2 | A | D-5 | Added | A1/A2/A3 | — | 0.24 | A |
| | (2.2) | | (0.3) | B-2 | (90/10/3) | | | |
| Example 16 | A-7 | C | D-13 | Added | A1 | W-1 | 0.19 | A |
| | (2.0) | | (0.25) | B-28 | (100) | | | |
| Example 17 | A-2 | D | D-51 | Added | A1/B2 | W-1 | 0.23 | A |
| | (2.2) | | (0.35) | B-52 | (80/20) | | | |
| Example 18 | A-2 | A | D-52 | Added | A1 | — | 0.22 | A |
| | (2.2) | | (0.28) | B-2 | (100) | | | |
| Example 19 | A-7 | A | PA-70 | Added | A1/A2/A3 | W-1 | 0.18 | A |
| | (2.0) | | (0.2) | B-28 | (90/10/3) | | | |
| Example 20 | A-7 | C | PA-108 | Added | A1 | W-3 | 0.18 | A |
| | (2.0) | | (0.35) | B-2 | (100) | | | |
| Example 21 | A-10 | C | PA-119 | Added | A1/B2 | W-3 | 0.32 | A |
| | (1.8) | | (0.33) | B-52 | (80/20) | | | |
| Example 22 | A-7 | D | PA-135 | Added | A1/A2/A3 | — | 0.19 | A |
| | (2.0) | | (0.2) | B-52 | (90/10/3) | | | |
| Example 23 | A-10 | A | PA-146 | Added | A1/A2/A3 | W-2 | 0.34 | A |
| | (1.8) | | (0.25) | B-2 | (90/10/3) | | | |
| Example 24 | A-2 | C | PA-114 | Added | A1 | W-4 | 0.21 | A |
| | (2.2) | | (0.3) | B-29 | (100) | | | |
| Comparative | RA-1 | A | DIA | Added | A1 | W-1 | 0.75 | B |
| Example 1 | (2.0) | | (0.4) | B-12 | (100) | | | |
| Comparative | RA-2 | D | APCA | Added | A1 | W-1 | 0.62 | B |
| Example 2 | (2.0) | | (0.4) | B-10 | (100) | | | |
| Comparative | RA-3 | D | APCA | Added | A1 | W-1 | 1.73 | C |
| Example 3 | (1.8) | | (0.4) | B-10 | (100) | | | |
| Comparative | RA-4 | D | PBI | Added | A1 | W-1 | 1.52 | C |
| Example 4 | (1.5) | | (0.4) | B-28 | (100) | | | |

The abbreviations in Table will be shown below.

[Photoacid Generator]

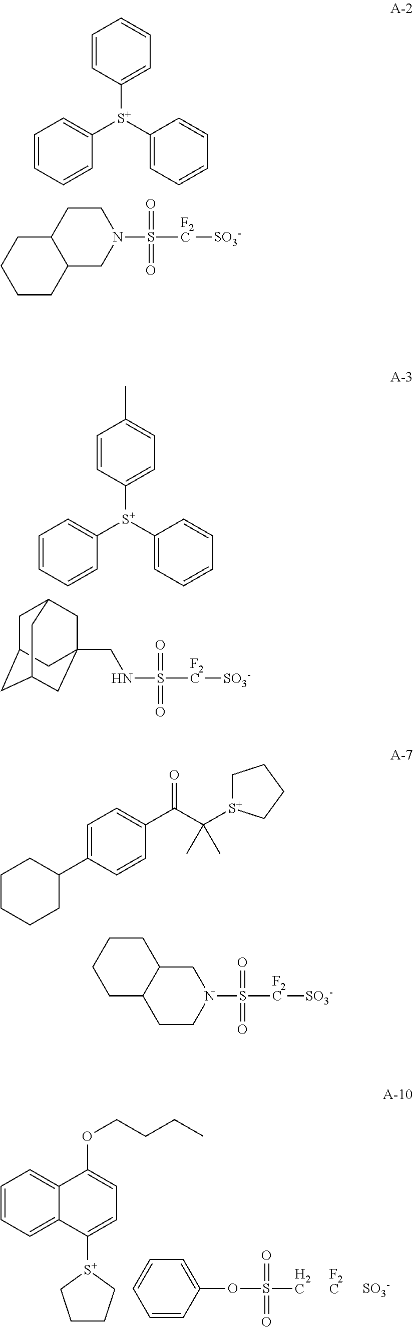

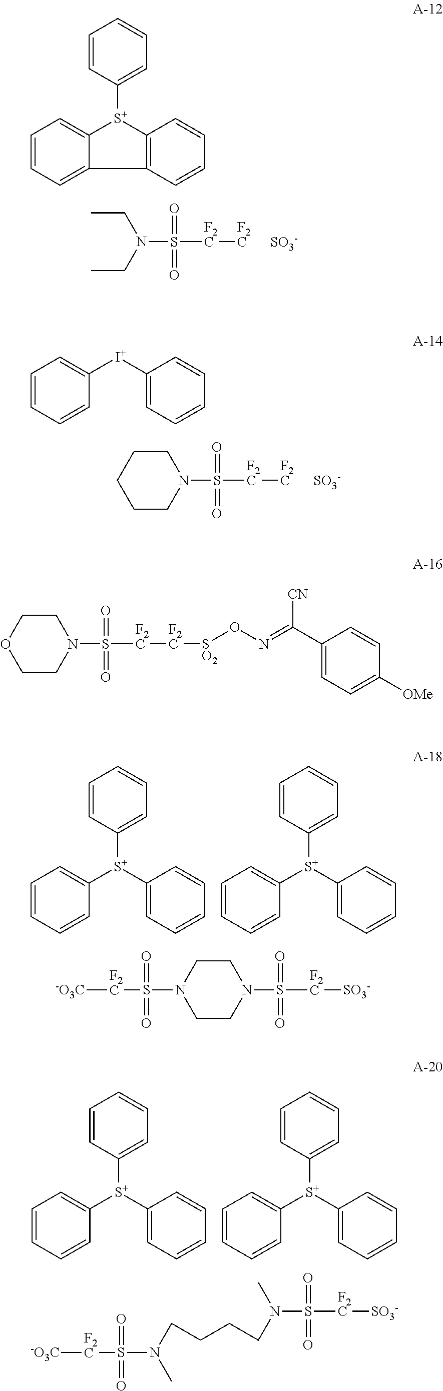

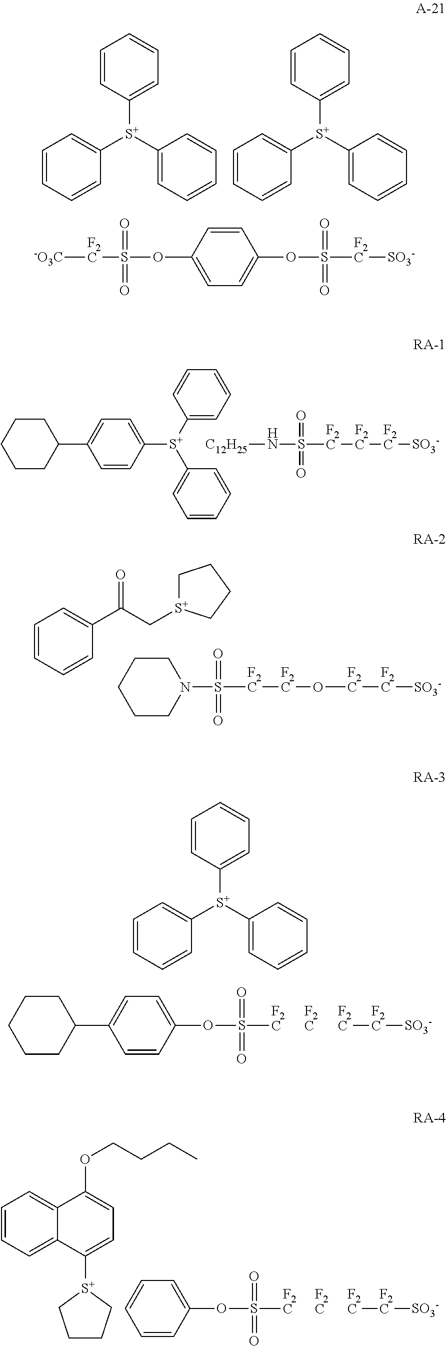

[Resin]

The structures, the mass average molecular weight (Mw), and the dispersity (Mw/Mn) of the resin (B) used in Examples will be shown below.

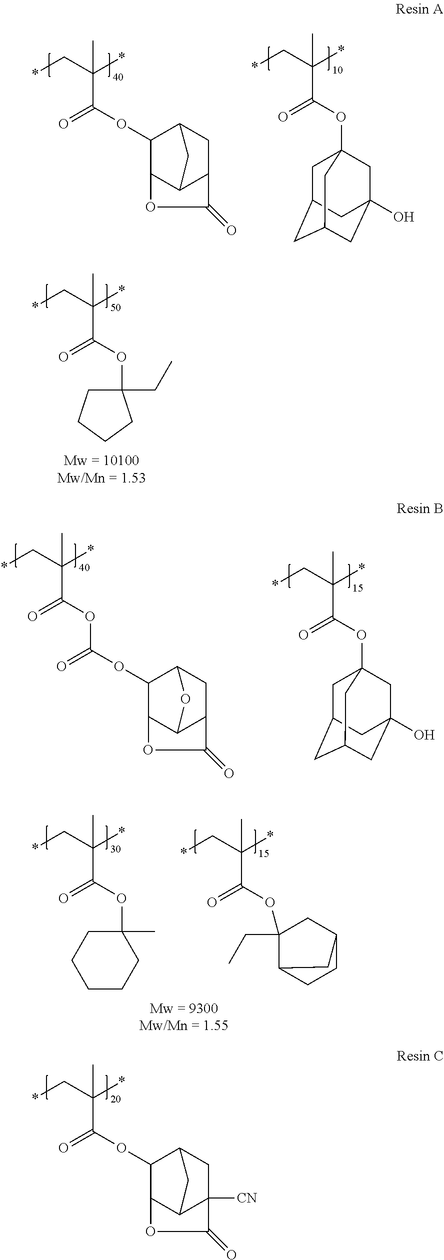

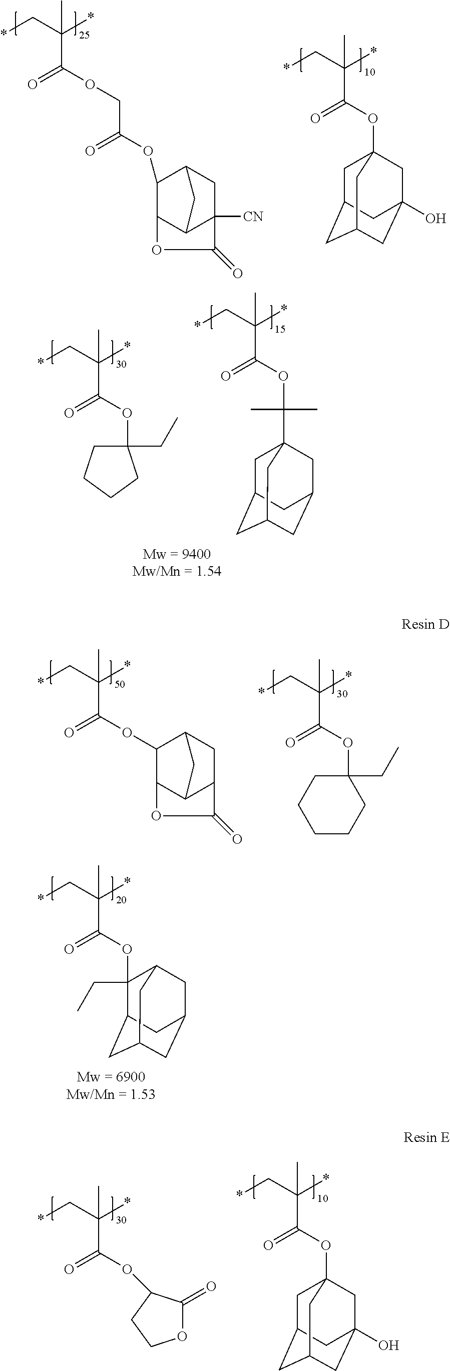

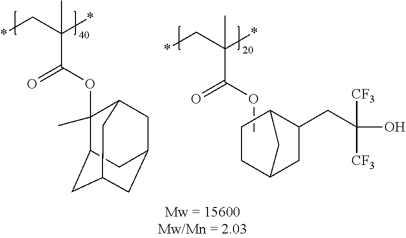

[Basic Compounds]

DIA: 2,6-Diisopropylaniline

PEA: N-Phenyldiethanolamine

TMEA: Tris(methoxyethoxyethyl)amine

APCA: 4-Hydroxy-1-tert-butoxycarbonylpiperidine

DBA: N,N-Dibutylaniline

PBI: Phenylbenzoimidazole

[Surfactant]

W-1: Megafac F176 (available from Dainippon Ink & Chemicals, Inc.) (fluorinated)

W-2: Megafac R08 (available from Dainippon Ink & Chemicals, Inc.) (fluorinated and siliconized)

W-3: Troysol S-336 (available from Troy Chemical Co., Ltd.)

W-4: PF656 (available from OMNOVA Solutions, Inc., fluorinated)

[Solvent]

A1: Propylene glycol monomethyl ether acetate

A2: Cyclohexanone

A3: γ-Butyrolactone

B1: Propylene glycol monomethyl ether

B2: Ethyl lactate

### Exposure Condition 1 (ArF Dry Exposure)

### Examples 7 and 12, and Comparative Example 4

ARC29A for forming an organic antireflection film (available from Nissan Chemical Industries, Ltd.) was coated on an 8-inch silicon wafer and baked at 205° C. for 60 seconds to form an antireflection film having a thickness of 78 nm on the silicon wafer. The composition prepared above was coated thereon and baked at 110° C. for 60 seconds to form a resist film having a thickness of 120 nm. The obtained wafer was subjected to exposure through a 6% halftone mask with a line width of 75 nm and a pattern of line:space=1:1, using an ArF excimer laser scanner (PAS5500/1100, available from ASML, NA 0.75). Thereafter, the resist film was heated at 90° C. for 60 seconds, developed with an aqueous tetramethylammonium hydroxide solution (2.38% by mass) for 30 seconds, then rinsed with pure water, and spin-dried to obtain a resist pattern.

### Exposure Condition 2 (ArF Liquid Immersion Exposure)

### Examples 1 to 6, 8, 9, and 13 to 24, Comparative Example 1 to 3

ARC29SR for forming an organic antireflection film (available from Nissan Chemical Industries, Ltd.) was coated on a 12-inch silicon wafer and baked at 205° C. for 60 seconds to form an antireflection film having a thickness of 95 nm on the silicon wafer. The composition prepared above was coated thereon and baked at 85° C. for 60 seconds to form a resist film having a thickness of 100 nm. The obtained wafer was subjected to exposure through a 6% halftone mask with a line width of 48 nm and a pattern of line:space=1:1, using an ArF excimer laser immersion scanner (XT-1700Fi, available from ASML, NA 1.20, σo/σi=0.94/0.74). Pure water was used as a liquid for liquid immersion. Thereafter, the resist film was heated at 90° C. for 60 seconds, developed with an aqueous tetramethylammonium hydroxide solution (2.38% by mass) for 30 seconds, then rinsed with pure water, and spin-dried to form a resist pattern.

### Exposure Condition 3 (ArF Liquid Immersion Exposure)

### Examples 10 and 11

Under the same exposure condition 2 except that after forming the above-described resist film having a thickness of 100 nm and before exposure, a top coat composition prepared using the hydrophobic resin described in Table 2 was coated on the resist film, and baked at 115° C. for 60 seconds to form a top coat film having a film thickness of 0.05 μm in the exposure condition 2, a resist pattern was formed.

[Development Defect]

Using a defect inspection apparatus, KLA 2360 available from KLA Tencor Japan, Ltd., measurement was performed in a random mode by setting a pixel size of the defect inspection apparatus to 0.16 m and a threshold value to 20. Development defects extracted from the difference produced when superposing pixel units with a reference image were detected, and the number of development defects per unit area was computed. A smaller value indicates higher performance.

### Evaluation of Pattern Shape

### Exposure Condition 1 (ArF Dry Exposure)

### Examples 7 and 12, and Comparative Example 4

The cross-sectional shape of a 75-nm line pattern obtained by a minimum exposure amount exhibiting a 75-nm line pattern of a mask was observed by a scanning electron microscope. The rectangular shape is denoted as A, the round-top shape is denoted as C, and a slightly round-top shape is denoted as B.

### Exposure Condition 2 and Exposure Condition 3 (ArF Liquid Immersion Exposure)

### Examples 1 to 6, 8 to 11, and 13 to 24, and Comparative Examples 1 to 3

The cross-sectional shape of a 48-nm line pattern obtained by a minimum exposure amount exhibiting a 48-nm line pattern of a mask was observed by a scanning electron microscope. The rectangular shape is denoted as A, the round-top shape is denoted as C, and a slightly round-top shape is denoted as B.

In Table 2, it can be seen that the pattern formed using the actinic-ray-sensitive or radiation-sensitive resin composition of the present invention is excellent in the pattern shape and reduction in the development defect, and thus, can be used preferably for an ArF dry exposure process and an ArF liquid immersion exposure.

### Preparation of Actinic-Ray-Sensitive or Radiation-Sensitive Resin Composition and Resist Evaluation (2)

### Example 25

The components shown below were dissolved in a solvent, and the solution was filtered through a polyethylene filter having a pore size of 0.1 μm to prepare a positive type resist solution having a solid concentration of 9.5% by mass. The positive type resist solution prepared was uniformly coated on a silicon substrate treated with hexamethyldisilazane using a spin coater, and dried by heating on a hot plate at 100° C. for 90 seconds to form a resist film having a film thickness of 0.4 μm.

The resist films were patternwise exposed through a line-and-space mask by means of a KrF excimer laser stepper (NA=0.63), and immediately after the exposure, the resist film was baked on a hot plate at 110° C. for 90 seconds. Thereafter, the resist film was developed with a 2.38% by mass aqueous tetramethylammonium hydroxide solution at 23° C. for 60 seconds, rinsed with pure water for 30 seconds and dried to form a line pattern. By taking the exposure amount which exhibited a line-and-space (L/S=1/1) mask pattern having a line width of 180 nm as an optimal exposure, a profile in terms of an optimal exposure amount was observed by means of a scanning electron microscope (SEM), and as a result, it was found that the pattern shape had a superior rectangular shape. From this result, it was found that the composition of the present invention is suitably used in a KrF exposure process.

Acid generator: A-1 (0.6 g)

Resin: R-1 (9.7 g)

Basic compound: Tetrabutylammonium hydroxide (0.02 g)

Surfactant: Megafac F176 (available from Dainippon Ink & Chemicals, Inc.) (0.01 g)

Solvent: Mixture solution of propylene glycol monomethyl ether acetate and propylene glycol monomethyl ether (6/4 mass ratio)

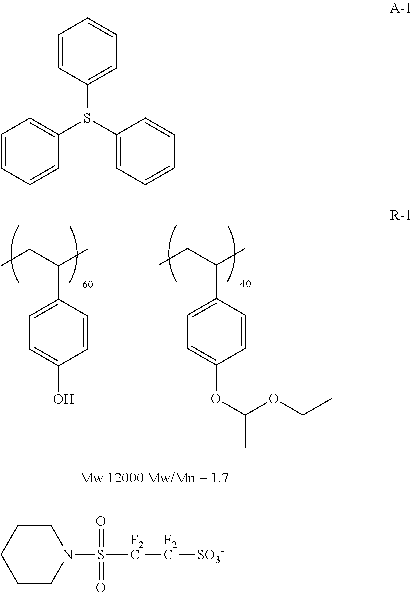

### Preparation of Actinic-Ray-Sensitive or Radiation-Sensitive Resin Composition and Resist Evaluation (3)

### Example 26

The same components as in Example 25 except that the resin (R-1) was changed to a resin (R-2) shown below were dissolved in a solvent, and the solution was filtered through a polytetrafluoroethylene filter having a pore size of 0.1 μm to prepare a positive type resist solution having a solid concentration of 4.0% by mass. The positive type resist solution prepared was uniformly coated on a silicon substrate with Cr laminated on the surface as a photomask blank model using a spin coater, and dried by heating on a hot plate at 100° C. for 60 seconds to form a resist film having a film thickness of 0.12 μm.

This resist film was irradiated using a lithographic apparatus for electron beam projection (accelerating voltage, 100 keV) available from Nikon Corp. Immediately after the irradiation, the resist film was heated at 110° C. for 90 seconds on a hot plate. Thereafter, the resist film was developed at 23° C. for 60 seconds with an aqueous tetramethylammonium hydroxide solution having a concentration of 2.38% by mass, rinsed with pure water for 30 seconds, and then dried to form a line-and-space pattern. By taking the exposure amount which exhibited a line-and-space (L/S=1/1) mask pattern having a line width of 50 nm as an optimal exposure, a profile in terms of an optimal exposure amount was observed by means of a scanning electron microscope (SEM), and as a result, it was found that the pattern shape had a superior rectangular shape. From this result, it was found that the composition of the present invention is suitably used in electron beam projection lithography.

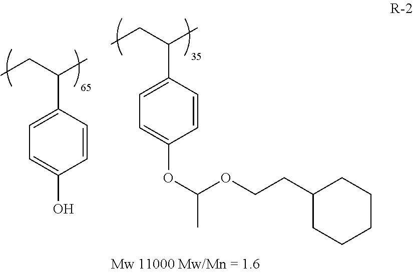

### Preparation of Actinic-Ray-Sensitive or Radiation-Sensitive Resin Composition and Resist Evaluation (4)

### Example 27

The same components as in Example 25 except that the resin (R-1) was changed in a resin (R-3) shown below were dissolved in a solvent, and the solution was filtered through a polytetrafluoroethylene filter having a pore size of 0.1 μm to prepare a positive type resist solution having a solid concentration of 2% by mass. The positive type resist solution prepared was uniformly coated on a silicon substrate treated with hexamethyldisilazane using a spin coater, and dried by heating on a hot plate at 100° C. for 60 seconds to form a resist film having a film thickness of 0.05 μm.

The obtained resist film was irradiated with EUV light (wavelength 13 nm), and immediately after the irradiation, the resist film was heated at 110° C. for 90 seconds on a hot plate. Thereafter, the resist film was developed at 23° C. for 60 seconds with an aqueous tetramethylammonium hydroxide (TMAH) solution having a concentration of 2.38% by mass, rinsed with pure water for 30 seconds, and then dried to form a line-and-space pattern.

By taking the exposure amount which exhibited a line-and-space (L/S=1/1) mask pattern having a line width of 50 nm as an optimal exposure, a profile in terms of an optimal exposure amount was observed by means of a scanning electron microscope (SEM), and as a result, it was found that the pattern shape had a superior rectangular shape. From this result, it was found that the composition of the present invention is suitably used in an EUV exposure process.

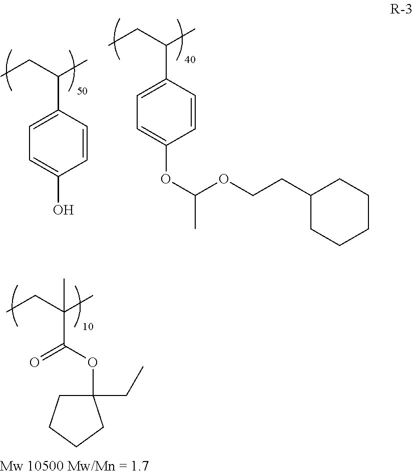

What is claimed is:

1. An actinic-ray-sensitive or radiation-sensitive resin composition comprising:
(A) a compound which generates an acid represented by the following general formula (I) or (I′) upon irradiation with an actinic-ray or a radiation, and
(B) a resin which decomposes by an action of an acid to increase a solubility of the resin in an alkaline developer. 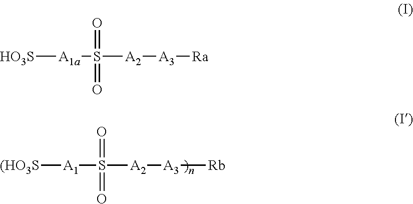
(In the general formulae (I) and (I′),
each of A₁ₐ and A₁ independently represents a methylene group or ethylene group which may be substituted with a fluorine atom or a fluoroalkyl group. In case of an ethylene group, the ethylene group is containable of an oxygen atom in the ethylene chain,
A₂ represents a single bond, an oxygen atom, or —N(Rx)-, and when a plurality of A₂'s are present, each of A₂'s independently represents a single bond, an oxygen atom, or —N(Rx)-,
Rx represents a hydrogen atom, an aryl group, an alkyl group, or a cycloalkyl group, and the alkyl group is containable of an oxygen atom, a sulfur atom, or a nitrogen atom in the alkyl chain,
A₃ represents a single bond or —C(═O)—, and when a plurality of A₃'s are present, each of A₃ independently represents a single bond or —C(═O)—,
Ra represents a hydrogen atom or an organic group,
n represents 2 or 3, and
Rb represents an n-valent linking group.
When A₂ is —N(Rx)-, Ra and Rx, or Rb and Rx may be bonded to each other to form a ring).

2. The composition according to claim 1, wherein the compound (A) is an onium salt of the sulfonic acid represented by the general formula (I) or (I′).

3. The composition according to claim 1, wherein the compound (A) is a sulfonium salt of the sulfonic acid represented by the general formula (I) or (I′).

4. The composition according to claim 2, wherein in the general formulae (I) and (I′), A₂ is —N(Rx)-, and Ra and Rx, or Rb and Rx are bonded to each other to form a ring.

5. The composition according to claim 3, wherein in the general foimulae (I) and (I′), A₂ is —N(Rx)-, and Ra and Rx, or Rb and Rx are bonded to each other to form a ring.

6. The composition according to claim 1, further comprising (C) a hydrophobic resin.

7. The composition according to claim 1, wherein in the general formula (I), the organic group represented by Ra has a cyclic structure.

8. The composition according to claim 3, wherein the cation moiety of the compound (A) is a sulfonium salt having a structure represented by the following general formula (ZI-3) or (ZI-4). 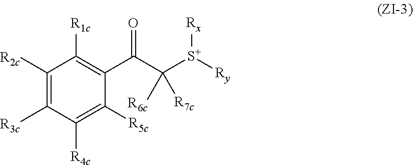
(In the general formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,
each of R_{6c} and R_{7c} independently represents a hydrogen atom, an alkyl group, a cycloalkyl group, a halogen atom, a cyano group, or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group, and
at least two or more of R_{1c} to R_{5c}, R_{5c} and R_{6c}, R_{6c} and R_{7c}, R_{5c} and Rₓ, and Rₓ and R_{y} may be bonded to each other to form a ring structure, wherein the ring structure is containable of an oxygen atom, a sulfur atom, a ketone group, an ester bond, or an amide bond). 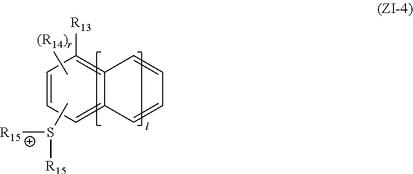
(In the general formula (ZI-4),
R₁₃ represents a group containing a hydrogen atom, a fluorine atom, a hydroxyl group, an alkyl group, a cycloalkyl group, an alkoxy group, an alkoxycarbonyl group, or a cycloalkyl group. The groups containing an alkyl group, a cycloalkyl group, an alkoxy group, an alkoxycarbonyl group, and a cycloalkyl group may have a substituent,
R₁₄ represents a group containing a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group, and when a plurality of R₁₄'s are present, each of R₁₄'s independently represents a group containing a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. The groups containing an alkyl group, a cycloalkyl group, an alkoxy group, an alkoxycarbonyl group, an alkylcarbonyl group, an alkylsulfonyl group, a cycloalkylsulfonyl group, and a cycloalkyl group may have a substituent,
each R₁₅ independently represents an alkyl group, a cycloalkyl group, or a naphthyl group. Two R₁₅'s may be bonded to each other to form a ring. The groups may have a substituent,
l represents an integer of 0 to 2, and
r represents an integer of 0 to 8).

9. The composition according to claim 1, wherein the resin (B) contains a repeating unit having a lactone structure.

10. An actinic-ray-sensitive or radiation-sensitive film formed using the composition according to claim 1.

11. A pattern forming method comprising:
forming a film using the composition according to claim 1,
exposing the film, and
developing the exposed film.

12. The method according to claim 11, wherein the exposure is carried out through a liquid for liquid immersion.
